(19) United States
(12) Patent Application Publication
(10) Pub. No.: US 2026/0052832 A1
(43) Pub. Date: Feb. 19, 2026

(54) COMPOUND AND ORGANIC ELECTROLUMINESCENCE DEVICE

(71) Applicant: Samsung Electronics Co., Ltd., Suwon-si (KR)

(72) Inventors: Satoshi INAYAMA, Kanagawa (JP); Eigo MIYAZAKI, Kanagawa (JP); Mitsunori ITO, Kanagawa (JP)

(21) Appl. No.: 19/294,951

(22) Filed: Aug. 8, 2025

(30) Foreign Application Priority Data
Aug. 15, 2024 (JP) 2024-135594
Jun. 11, 2025 (KR) 10-2025-0076650

(51) Int. Cl. H10K 50/12; C09K 11/06; H10K 85/30; H10K 85/40; H10K 85/60

(52) U.S. Cl. CPC H10K 50/12; C09K 11/06; H10K 85/346; H10K 85/40; H10K 85/622; H10K 85/626; H10K 85/654; H10K 85/6572; C09K 2211/185

(57) ABSTRACT

A compound with a peak wavelength in an emission spectrum in a blue wavelength region, and an organic electroluminescence device including an emission layer that includes the compound. The compound includes a specific nitrogen-containing condensed cyclic structure and a specific transition dipole moment orientation. An organic electroluminescence device including an emission layer that includes a phosphorescent complex and the compound having a specific nitrogen-containing condensed cyclic structure and a specific transition dipole moment orientation.

### CROSS-REFERENCE TO RELATED APPLICATIONS

This application claims priority to Japanese Patent Application No. 2024-135594, filed on Aug. 15, 2024, in the Japan Patent Office, and Korean Patent Application No. 10-2025-0076650, filed on Jun. 11, 2025, in the Korean Intellectual Property Office, and all benefits accruing therefrom under 35 U.S.C. § 119, the disclosures of which in their entirety are incorporated by reference herein.

### BACKGROUND

### 1. Field

The disclosure relates to a compound and an organic electroluminescence device.

### 2. Description of the Related Art

Organic electroluminescence devices (hereinafter also referred to as ‘organic EL devices’) have been used in various light-emitting devices such as smartphones, display screens such as for laptops, or televisions. Luminescent materials have been used in an emission layer of organic EL devices, and fluorescent materials, phosphorescent materials, and thermally delayed active fluorescent materials have been reported as luminescent materials (Non-patent document 1). In organic EL devices that use fluorescent materials, which provide fluorescence emission from singlet-excited states, based on the principles of luminescence, have been commercialized. However, in many conventional organic EL devices the luminescence efficiency is 5% or less. On the other hand, organic EL devices using phosphorescent materials have achieved luminescence efficiency exceeding 20%, and thus, have already been put into practical use for providing emission in green and red regions of the visible spectrum. However, due to very limited device lifespan of using phosphorescent materials for blue emission, fluorescence materials are still used for blue color.

Recently, to improve luminescence efficiency of organic EL devices as well as improving lifespan of organic EL devices, organic EL devices using a luminescence method combining phosphor sensitizers and luminescent materials have been proposed (Non-patent document 2). In organic EL devices in the art, host materials and luminescent materials are used in an emission layer, and excitons generated in molecules of the host materials transfer energy to the luminescent material, which emits light. When fluorescent materials are used as the luminescent materials the luminescence efficiency reaches 5% at most. However, by the addition of phosphor sensitizers to the emission layer, triplet energy which was previously unavailable can also account for luminescence, and in some instances, the luminescence efficiency of organic EL devices may be improved to 10% or more. In addition, an extension of device lifespan has been reported using phosphor sensitizers as luminescent materials, and thus, such organic EL devices are attracting attention as candidates for next-generation organic EL devices.

However, even organic EL devices that emit light by combining phosphor sensitizers and luminescent materials exhibit low external quantum efficiency compared to organic EL devices using phosphorescent materials. Therefore, luminescent materials that can achieve higher efficiency in organic EL devices are of interest.

In order to improve external quantum efficiency of organic EL devices, light extraction efficiency needs to be improved. According to non-patent document 3, it has been reported that, by orienting the transition dipole moment of the emitter in the film including the emitter formed on the substrate plane, in a horizontal direction relative to the substrate plane, the inefficient, vertically oriented emitter that cannot contribute to luminescence as a device is lost, thereby improving the light extraction efficiency. Non-patent document 3 describes that the molecular orientation of luminescent materials is related to the improvement of external quantum efficiency. Formula S1:

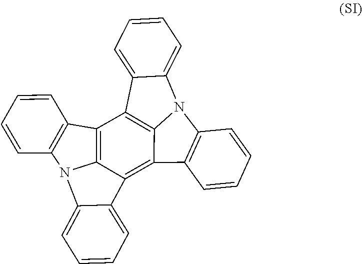 [SMILES: c1ccc2c(c1)c1c3c4ccccc4n4c5ccccc5c(c5c6ccccc6n2c15)c34]

As a method of measuring the molecular orientation of luminescent materials, angle-resolved photoluminescence (PL) spectroscopy has been reported (non-patent document 4). TDO values obtained by angle-resolved PL spectroscopy correspond to the statistical orientation of transition dipole moment.

In addition, there have been reports on the application of compound derivatives of the compound represented by Formula (S1) (hereinafter referred to as a nitrogen-containing condensed polycyclic compound (S1)) used as the basic skeleton in organic electronic devices. In Patent Document 1, it is reported that, when a derivative of the nitrogen-containing condensed polycyclic compound (S1) is used as an active layer in an organic transistor, it exhibits p-type channel characteristics and high hole mobility. In addition, in Patent Document 2, it is reported that a derivative of the nitrogen-containing condensed polycyclic compound (S1) with an aryl group introduced as a substituent can function as a luminescent material for an organic EL device, and that such an organic EL device exhibits high luminescence efficiency. Accordingly, the nitrogen-containing condensed polycyclic compound (S1) has been found to provide an efficient compound skeleton for organic semiconductor materials. In addition, in Patent Document 3, it is shown that an organic EL device using a derivative of the nitrogen-containing condensed polycyclic compound (S1) as a luminescent material in combination with a phosphorescent complex exhibits luminescence efficiency of 5% or more, and that an organic EL device emitting blue light with a full width at half maximum of 20 nm or less and having a small spectral full width at half maximum can be manufactured.

### PATENT DOCUMENTS

Patent Document 1: WO2013/084805
Patent Document 2: JP2020-107742

### SUMMARY

A compound that has a peak wavelength in a blue wavelength region of an emission spectrum and enables high-efficiency luminescence is described. An organic EL device including an emission layer that includes the compound is described. Also, a means for achieving high-efficiency luminescence in a organic EL device in which a peak wavelength is in a blue wavelength region of an emission spectrum is described.

Additional aspects will be set forth in part in the description which follows and, in part, will be apparent from the description, or may be learned by practice of the presented embodiments of the disclosure.

To solve the aforementioned technical problems, the inventors of the disclosure conducted a thorough review of many different compounds. In addition, the inventors of the disclosure have confirmed that the aforementioned technical problems can be solved by a compound having a specific nitrogen-containing condensed polycyclic structure that satisfies a specific relationship in molecular lengths in a biaxial orientation, and has a molecular weight in a range of about 1000 g/mol to about 1400 g/mol. Although not limited in theory, when an emission layer includes a compound of the disclosure having a specific nitrogen-containing condensed polycyclic structure, satisfies a specific relationship in molecular lengths of a two-axis direction, and has a molecular weight in a range of about 1000 g/mol to about 1400 g/mol, an in particular, when an emission layer includes the compound in combination with a phosphorescent material, significantly high efficiency (excellent luminescence efficiency) of an organic electroluminescence device may be achieved. Here, regarding the term “molecular lengths in two-axis directions” in the present specification, two directions connecting two opposite benzene rings among four benzene rings located on the outer side of the nitrogen-containing condensed polycyclic compound (S1) are called two-axis directions, and two axes representing the two-axis directions intersect, but the angle of intersection is not particularly limited.

Accordingly, at least one of the technical problems of the disclosure may be solved by a compound represented by Formula (1):

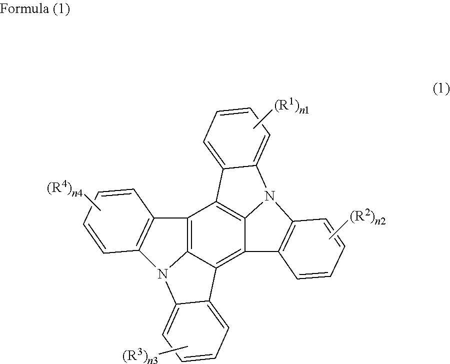

In Formula (1),
R¹ to R⁴ may each independently be of the following groups of (1a) to (1d):
(1a) a substituted or unsubstituted C1-C20 alkyl group,
(1b) a substituted or unsubstituted C1-C20 alkoxy group,
(1c) a substituted or unsubstituted aromatic hydrocarbon group, or
(1d) a substituted or unsubstituted heterocyclic group, and
n1 to n4 may each independently be 1, 2, 3, or 4, provided that, when n1 is 2 or more, each R¹ may be identical to or different from the others, when n2 is 2 or more, each R² may be identical to or different from the others, when n3 is 2 or more, each R³ may be identical to or different from the others, and when n4 is 2 or more, each R⁴ may be identical to or different from the others,
wherein the compound may have a molecular weight in a range of about 1000 g/mol to about 1400 g/mol, a molecular length L₁ and a molecular length L₂ in two-axis directions of the compound may each independently be, as defined by the following equations, in a range of about 16 angstroms (Å) to about 38 Å, and
a product of the molecular length L₁ and the molecular length L₂ may be in a range of about 490 Å² or about 1200 Å²:

$$Molecular length {L}_{1} = ( longest end - to - end distance {L}_{1 x} between a carbon atom of substituent {R}^{1} and a carbon atom of substituent {R}^{3} ) + ( in the presence of substituent {R}^{1} ( hereinafter referred to as substituent {R}^{1 p} ) other than substituent {R}^{1} used in calculation of longest end - to - distance {L}_{1 x} between a carbon atom binding to substituent {R}^{1 p} and a carbon atom of substituent {R}^{1 p} ) + ( in the presence of substituent {R}^{3} ( hereinafter referred to as substituent {R}^{3 p} ) other than substituent {R}^{3} used in calculation of longest end - to - end distance {L}_{1 y} , longest end - to - end distance {L}_{1 z} between a carbon atom binding to subtituent {R}^{3 p} and a carbon atom of subtituent {R}^{3 p} ) ; \qquad Equation 1 A$$

$$Molecular length {L}_{2} = ( longest end - to - end distance {L}_{2 x} between a carbon atom of substituent {R}^{2} and a carbon atom of substituent {R}^{4} ) + ( in the presence of substituent {R}^{2} ( hereinafter referred to as substituent {R}^{2 p} ) other than substituent {R}^{2} used in calculation of longest end - to - distance {L}_{2 x} , longest end - to - end distance {L}_{2 y} between a carbon atom binding to substituent {R}^{2 p} and a carbon atom of substituent {R}^{2 p} ) + ( in the presence of substituent {R}^{4} ( hereinafter referred to as substituent {R}^{4 p} ) other than substituent {R}^{4} used in calculation of longest end - to - end distance {L}_{2 x} , longest end - to - end distance {L}_{2 z} between a carbon atom binding to subtituent {R}^{4 p} and a carbon atom of subtituent {R}^{4 p} ) ; \qquad Equation 1 B$$

provided that, when each of substituents R^{1p} to R^{4p} exists in plural in the definition above, the longest end-to-end distance of each of substituents R^{1p} to RAP existing in plural is added up to L_{1y}, L_{1z}, L_{2y}, and L_{2z}, respectively.

The organic electroluminescence device includes an emission layer including a compound that has a structure represented by Formula (1), satisfies a specific relationship in molecular lengths in two-axis directions, and has a molecular weight in a range of about 1000 g/mol to about 1400 g/mol.

The organic electroluminescence device includes an emission layer including a phosphorescent complex and a compound that has a structure represented by Formula (1), satisfies a specific relationship in molecular lengths in two-axis directions, and has a molecular weight in a range of about 1000 g/mol to about 1400 g/mol.

The organic electroluminescence device includes an emission layer including a host material and a compound that has a structure represented by Formula (1), satisfies a specific relationship in molecular lengths in two-axis directions, and has a molecular weight in a range of about 1000 g/mol to about 1400 g/mol.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic cross-sectional view of an organic electroluminescence device according to an embodiment;

FIG. 2 is a schematic cross-sectional view of an organic electroluminescence device according to another embodiment;

FIG. 3 is a schematic cross-sectional view of an organic electroluminescence device according to other embodiments;

FIG. 4 is a graph showing correlation between molecular lengths of a compound according to an embodiment and transition dipole moment orientation (TDO); and

FIG. 5 shows an emission spectrum of a compound in a toluene solution, according to an embodiment.

### DETAILED DESCRIPTION

Reference will now be made in detail to embodiments, examples of which are illustrated in the accompanying drawings, wherein like reference numerals refer to like elements throughout the specification. In this regard, the present embodiments may have different forms and should not be construed as being limited to the descriptions set forth herein. Accordingly, the embodiments are merely described below, by referring to the figures, to explain aspects.

Hereafter, embodiments of the disclosure will be described. In addition, the disclosure is not limited to the following embodiments, and may be modified in various ways within the scope of the patent claims. In addition, the embodiments described in the present specification may be combined arbitrarily to form other embodiments.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms.

These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. Therefore, reference to “an” element in a claim followed by reference to “the” element is inclusive of one element as well as a plurality of the elements.

“At least one” is not to be construed as limiting “a” or “an.” “Or” means “and/or.” As used herein, the term “and/or” includes any and all combinations of one or more of the associated listed items.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

In the present specification, the expression ‘P and Q are each independently’ refers that P and Q may be the same or different. In addition, in the present specification, the expression ‘A and/or B’ refers to A, B, or a combination thereof. In addition, unless otherwise specified, concentration and % refer to mass concentration and mass %, respectively, and a ratio refers to mass ratio unless otherwise specified. In addition, unless otherwise specified, manipulation and measurements of physical properties shall be performed at room temperature (20° C. to 25° C.) and relative humidity of 40% RH to 50% RH.

In addition, in the present specification, the expression ‘a group derived from a ring’ refers to a group in which hydrogen atoms directly bonded to ring-forming atoms in a ring structure are displaced by the valence number from the ring structure, resulting in free valence numbers. Here, the ring-forming atoms refer to atoms that directly form a ring structure. For example, in the case of a benzene ring, ring-forming atoms are carbon atoms and do not include hydrogen atoms.

Provided is a compound that enables high efficiency of an organic electroluminescence device (organic EL device).

The following nitrogen-containing condensed polycyclic compounds (S1) are known as general materials, but the problem is that an organic EL device using the nitrogen-containing condensed polycyclic compound (S1) has low efficiency. Thus, a study to improve light extraction efficiency (ηₒᵤₜ) in external quantum efficiency of Equation (ii) was conducted to achieve high efficiency (excellent luminescence efficiency) of an organic EL device:

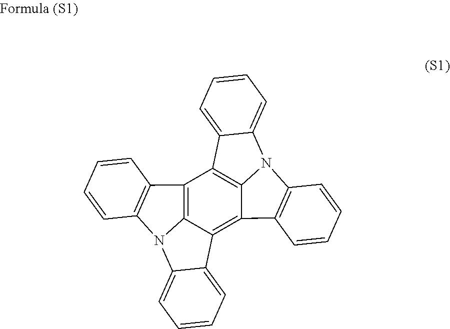 [SMILES: c1ccc2c(c1)c1c3c4ccccc4n4c5ccccc5c(c5c6ccccc6n2c15)c34]

Light extraction efficiency:

$$\begin{matrix}{η}_{ext} = {η}_{int} \times {η}_{out} \\ {η}_{ext} : external quantum efficiency \\ {η}_{int} : internal quantum efficiency \\ {η}_{out} : light extraction efficiency .\end{matrix} \qquad ( ii )$$

Generally, it is known that light extraction efficiency is improved by orienting molecules so that the transition dipole moment of a dopant is horizontal with respect to a substrate (emission layer). Referring to various interpretations that have been made regarding the derivatives of the nitrogen-containing condensed polycyclic compounds (S1) synthesized to date, it has been discovered that the molecular length of a compound in two-axis directions is related to TDO orientation (TDO) (hereinafter also referred to simply as “TDO”) of the compound in a thin film. Therefore, according to the disclosure, a compound having high TDO in a thin film may be synthesized by calculating the molecular length of the compound in two-axis directions based on the simulation results using a DFT calculation. In addition, when using such a compound as a dopant in an emission layer, a high-efficiency organic EL device (e.g., a blue organic EL device) may be provided.

A current organic electroluminescence device, in particular, further improvement in terms of high efficiency (excellent luminescence efficiency) is of interest. The organic EL device uses a derivative of a nitrogen-containing condensed polycyclic compound (S1) as a base skeleton for improvement in terms of high efficiency (excellent luminescence efficiency).

The compound of the disclosure is represented by Formula (1) and having a molecular weight in a range of about 1000 g/mol to about 1400 g/mol, and also satisfying that the molecular length L₁ and the molecular length L₂ in two-axis directions may each independently be, as defined by the equation 1A and equation 1B, respectively, in a range of about 16 Å to about 38 Å and a product of the molecular length L₁ and the molecular length L₂ may be in a range of about 490 Å² to about 1200 Å². Hereinafter, the compound represented by Formula (1) may also be referred to as ‘the compound of Formula (1)’ or ‘the compound of the disclosure’:

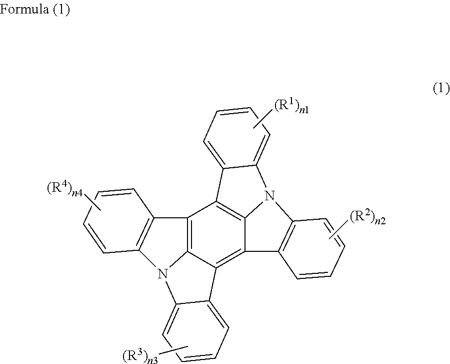

wherein R¹ to R⁴ may each independently be one of the following groups of (1a) to (1d):
(1a) a substituted or unsubstituted C1-C20 alkyl group;
(1b) a substituted or unsubstituted C1-C20 alkoxy group;
(1c) a substituted or unsubstituted aromatic hydrocarbon group; or
(1d) a substituted or unsubstituted heterocyclic group, and
n1 to n4 may each independently be 1, 2, 3, or 4, provided that, when n1 is 2 or more, each R¹ may be identical to or different from the others, when n2 is 2 or more, each R² may be identical to or different from the others, when n3 is 2 or more, each R³ may be identical to or different from the others, and when n4 is 2 or more, each R⁴ may be identical to or different from the others:

$$Molecular length {L}_{1} = ( longest end - to - end distance {L}_{1 x} between a carbon atom of substituent {R}^{1} and a carbon atom of substituent {R}^{3} ) + ( in the presence of substituent {R}^{1} ( hereinafter referred to as substituent {R}^{1 p} ) other than substituent {R}^{1} used in calculation of longest end - to - distance {L}_{1 x} between a carbon atom binding to substituent {R}^{1 p} and a carbon atom of substituent {R}^{1 p} ) + ( in the presence of substituent {R}^{3} ( hereinafter referred to as substituent {R}^{3 p} ) other than substituent {R}^{3} used in calculation of longest end - to - end distance {L}_{1 y} , longest end - to - end distance {L}_{1 z} between a carbon atom binding to subtituent {R}^{3 p} and a carbon atom of subtituent {R}^{3 p} ) ; \qquad Equation 1 A$$

$$Molecular length {L}_{2} = ( longest end - to - end distance {L}_{2 x} between a carbon atom of substituent {R}^{2} and a carbon atom of substituent {R}^{4} ) + ( in the presence of substituent {R}^{2} ( hereinafter referred to as substituent {R}^{2 p} ) other than substituent {R}^{2} used in calculation of longest end - to - distance {L}_{2 x} , longest end - to - end distance {L}_{2 y} between a carbon atom binding to substituent {R}^{2 p} and a carbon atom of substituent {R}^{2 p} ) + ( in the presence of substituent {R}^{4} ( hereinafter referred to as substituent {R}^{4 p} ) other than substituent {R}^{4} used in calculation of longest end - to - end distance {L}_{2 x} , longest end - to - end distance {L}_{2 z} between a carbon atom binding to subtituent {R}^{4 p} and a carbon atom of subtituent {R}^{4 p} ) , \qquad Equation 1 B$$

provided that, when each of substituents R^{1p} to R^{4p} exists in plural in the definition above, the longest end-to-end distance of each of substituents R^{1p} to RAP existing in plural is added up to L_{1y}, L_{1z}, L_{2y}, and L_{2z}, respectively.

According to an embodiment, the compound represented by Formula (1) may be represented by Formula (2) and have a molecular weight in a range of about 1000 g/mol to about 1400 g/mol, wherein a molecular length L₃ and a molecular length L₄ in two-axis directions may each independently be, as defined by the equation 2A and equation 2B, respectively, in a range of about 16 Å to about 38 Å and a product of the molecular length L₃ and the molecular length L₄ may be in a range of about 490 Å² to about 1200 Å²:

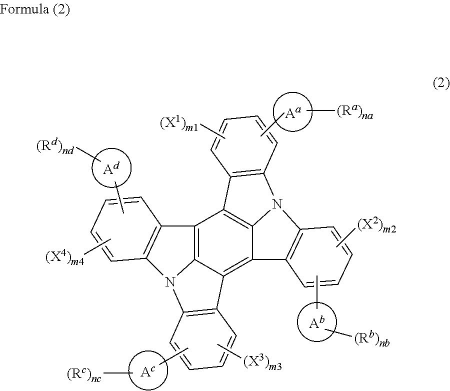

wherein, in Formula (2),
A^{a} to A^{d} may each independently be a benzene ring or a heterocyclic ring,
R^{a} to R^{d} may each independently be a hydrogen atom, an unsubstituted C1-C20 alkyl group, an unsubstituted C1-C20 alkoxy group, an unsubstituted C6-C20 arylamino group, a substituted or unsubstituted aromatic hydrocarbon group, or a substituted or unsubstituted aromatic heterocyclic group,
wherein
when A^{a} is a benzene ring, na is 5, and when A^{a} is a heterocyclic ring, na is an upper limit of possible number of substitution with A^{a},
when A^{b} is a benzene ring, nb is 5, and when A^{b} is a heterocyclic ring, nb is an upper limit of possible number of substitution with A^{b},
when A^{c} is a benzene ring, nc may be 5, and when A^{c} is a heterocyclic ring, nc may be an upper limit of possible number of substitution with A^{c},
when A^{d} is a benzene ring, nd is 5, and when A^{d} is a heterocyclic ring, nd is an upper limit of possible number of substitution with A^{d},
X¹ to X⁴ may each independently be a hydrogen atom, an unsubstituted C1-C20 alkyl group, an unsubstituted C1-C20 alkoxy group, or a substituted or unsubstituted aromatic hydrocarbon group, and
m1 to m4 may be 3:

$$Molecular length {L}_{3} = ( longest end - to - end distance {L}_{3 x} between a carbon atom of substituent {R}^{a} and a carbon atom of substituent {R}^{c} ) + ( in a case where substituent {X}^{1} is a group other than a hydrogen atom , longest end - to - end distance {L}_{3 y} between a carbon atom binding to substituent {X}^{1} and a carbon atom of substituent {X}^{1} ) + ( in a case where substituent {X}^{3} is agroup other than hydrogen atom , longest end - to - end distance {L}_{3 z} between a carbon atom binding to substituent {X}^{3} and a carbon atom of substituent {X}^{3} {L}_{3 z} ) ; \qquad Equation 2 A$$

$$Molecular length {L}_{4} = ( longest end - to - end distance {L}_{4 x} between a carbon atom of substituent {R}^{b} and a carbon atom of substituent {R}^{d} ) + ( in a case where substituent {X}^{2} is a group other than a hydrogen atom , longest end - to - end distance {L}_{4 y} between a carbon atom binding to substituent {X}^{2} and a carbon atom of substituent {X}^{2} ) + ( in a case where substituent {X}^{4} is agroup other than hydrogen atom , longest end - to - end distance {L}_{4 z} between a carbon atom binding to substituent {X}^{4} and a carbon atom of substituent {X}^{4} ) , \qquad Equation 2 B$$

provided that, when each of substituents R^{a} to R^{d} is a hydrogen atom in the definition above, carbon atoms of substituents A^{a} to A^{d} correspond to carbon atoms of substituents R^{a} to R^{d}, respectively, and when substituents X¹ to X⁴ are each a hydrogen atom, the longest end-to-end distances thereof, i.e., L_{3y}, L_{3z}, L_{4y}, and L_{4z}, are each 0.

Here, the term “possible number of substitution” refers to the possible number of substitution in the structure of the compound. For example, when A^{a} is a carbazole ring, the possible number of substitution is 8. In addition, for example, when R^{a}(s) in the number of na are all hydrogen atoms, the compound is unsubstituted because there is no substituent.

In addition, according to an embodiment, the compound represented by Formula (1) may be represented by Formula (3) and have a molecular weight in a range of about 1000 g/mol to about 1400 g/mol, wherein a molecular length L₅ and a molecular length L₆ in two-axis directions may each independently be, as defined by the equation 3A and equation 3B, respectively, in a range of about 16 Å to about 38 Å and a product of the molecular length L₅ and the molecular length L₆ may be in a range of about 490 Å² to about 1200 Å²:

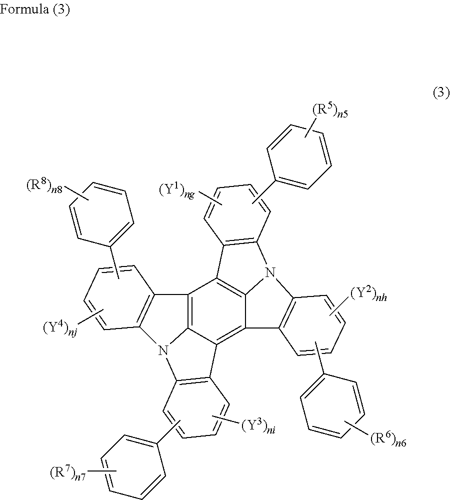

wherein, in Formula (3),
R⁵ to R⁸ may each independently be a hydrogen atom, an unsubstituted C1-C20 alkyl group, an unsubstituted C1-C20 alkoxy group, a substituted or unsubstituted aromatic hydrocarbon group, or a substituted or unsubstituted aromatic heterocyclic group,
n5 to n8 may be 5,
Y¹ to Y⁴ may each independently be a hydrogen atom, an unsubstituted C1-C20 alkyl group, an unsubstituted C1-C20 alkoxy group, or a substituted or unsubstituted aromatic hydrocarbon group, and
ng to nj may be 3:

$$Molecular length {L}_{5} = ( longest end - to - end distance {L}_{5 x} of a carbon atom of substituent {R}^{5} and a carbon atom of substituent {R}^{7} ) + ( in a case where substituent {Y}^{1} is a group other than a hydrogen atom , longest end - to - end distance {L}_{5 y} between a carbon atom binding to substituent {Y}^{1} and a carbon atom of substituent {Y}^{1} ) + ( in a case where substituent {Y}^{3} is a group other than a hydrogen atom , longest end - to - end distnace {L}_{5 y} between a carbon atom binding to substituent {Y}^{3} and a carbon atom of substituent {Y}^{3} ) ; \qquad Equation 3 A$$

$$Molecular length {L}_{6} = ( longest end - to - end distance {L}_{6 x} of a carbon atom of substituent {R}^{6} and a carbon atom of substituent {R}^{8} ) + ( in a case where substituent {Y}^{2} is a group other than a hydrogen atom , longest end - to - end distance {L}_{6 y} between a carbon atom binding to substituent {Y}^{2} and a carbon atom of substituent {Y}^{2} ) + ( in a case where substituent {Y}^{4} is a group other than a hydrogen atom , longest end - to - end distnace {L}_{6 z} between a carbon atom binding to substituent {Y}^{4} and a carbon atom of substituent {Y}^{4} ) ; \qquad Equation 3 B$$

provided that, when each of substituents R⁵ to R⁸ is a hydrogen atom in the definition above, carbon atoms of a benzene ring including substituent R⁵ to R⁸ correspond to carbon atoms of substituent R⁵ to R⁸, respectively, and when substituents Y¹ to Y⁴ are each a hydrogen atom, the longest end-to-end distances thereof, i.e., L₅, L_{5z}, L_{6y}, and L_{6z} are each 0.

That is, the compound of the disclosure may be: the compound represented by Formula (1) and having a molecular weight in a range of about 1000 g/mol to about 1400 g/mol, and also satisfying a specific relationship in the molecular length L₁ and the molecular length L₂ in two-axis directions; the compound represented by Formula (2) and having a molecular weight in a range of about 1000 g/mol to about 1400 g/mol, and also satisfying a specific relationship in the molecular length L₃ and the molecular length L₄ in two-axis directions; or the compound represented by Formula (3) and having a molecular weight in a range of about 1000 g/mol to about 1400 g/mol, and also satisfying a specific relationship in the molecular length L₅ and the molecular length L₆ in two-axis directions. According to an embodiment, by this configuration, the TDO of the compound described herein in a thin film may be greater than 90% but less than or equal to 100%. When an emission layer includes the compound described herein, particularly, when an emission layer includes the compound of the disclosure in combination with a phosphorescent material (more preferably, a phosphorescent complex), an organic EL device including the emission layer may achieve significantly improved efficiency (significantly excellent luminescence efficiency).

Hereinafter, unless otherwise specified, the properties of the compound represented by Formula (1) are considered to be similar to those of the compounds represented by Formula (2) and Formula (3). In addition, a compound represented by Formula (4) which will be described below is considered to be similar to properties as the compound represented by Formula (1).

As described above, according to an embodiment, the TDO of the compound represented by Formula (1) in a thin film may be greater than 90% but less than or equal to 100%. The inventors of the disclosure have discovered that TDO may be increased (i.e., close to 100%) when using a compound having a structure in which the molecular length is extended in any two directions (two-axis directions). That is, increasing TDO may be achieved by designing a compound having a structure in which the molecular length is extended in two directions (two-axis direction). For example, it is considered desirable to introduce substituents (e.g., R¹ to R⁴), each of which molecular length is extended in the direction connecting the terminal group of substituent R¹ and the terminal group of substituent R³ and in the direction connecting the terminal group of substituent (R²) and the terminal group of substituent (R⁴). Specifically, as shown in Formula (4), each of R¹ to R⁴ may be referred as follows depending on the position of substitution: R¹ may be referred to as R^{1a} to R^{1d}; R² may be referred to as R^{2a} to R^{2d}; R³ may be referred to as R^{3a} to R^{3d}; and R⁴ may be referred to as R^{4a} to R^{4d}. In this case, at least one combination selected from: R^{1b} and R^{3b}; and Ric and R^{3c} and at least one combination selected from: R^{2b} and R^{4b}; and R^{2c} and R^{4c} may preferably include one of the groups of (1a) to (1d). More preferably, at least one combination selected from R^{1b} and R^{3b}, and R^{1c} and R^{3c}, and at least one combination selected from: R^{2b} and R^{4b}, and R^{2c} and R^{4c}, may preferably include the group of (1c) or (1d).

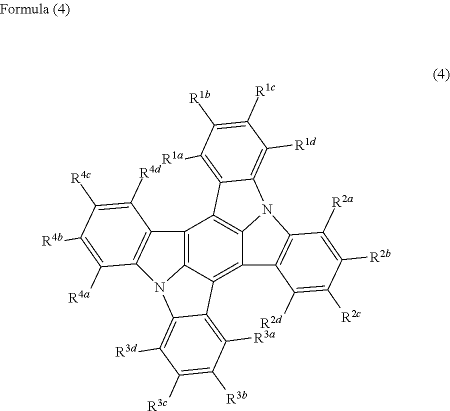

The reason why TDO may be increased (i.e., close to 100%) by using a compound having a structure in which the molecular length is extended in two-axis directions is presumed to be as follows.

For example, when a compound has a structure in which the molecular length is extended in two-axis directions, the molecules may form a large plate, increasing planarity, and thus the molecules may be easily oriented horizontally within the emission layer. Accordingly, TDO of the compound may achieve a range of about 90% to about 100%.

In addition, this mechanism is based on assumption, and thus its accuracy does not affect the technical scope of the disclosure. In addition, the same applies to other assumptions made in the present specification, in that any errors as such do not affect the technical scope of the disclosure.

In addition, the fact that the molecular length in two-axis directions in the compound represented by Formula (1) is related to TDO of the compound in a thin film (hereinafter this relationship is referred to as ‘relationship of the disclosure’) is also one of discoveries by the disclosure. Furthermore, based on this insight, it has been discovered that the technical problem may be solved by controlling the molecular length (depending on types of substituents and substitution position of substituents) in two-axis directions of the compound represented by formula (1) according to TDO of the compound in a thin film.

In other words, in an embodiment, TDO of the target compound in a thin film may be controlled by appropriately selecting the molecular length (depending on types of substituents and substitution position of substituents) in two-axis directions of the target compound with respect to the compound represented by Formula (1). Also, in another embodiment, the molecular length (depending on types of substituents and substitution position of substituents) of the target compound may be determined according to TDO of the target compound in a thin film with respect to the compound represented by Formula (1).

In addition, TDO of the compound represented by formula (2) in a thin film may be greater than 90% but less than or equal to 100%. The molecular length in two-axis directions in the compound represented by Formula (2) is related to TDO of the compound in a thin film (this relationship is referred to as ‘relationship of the disclosure’). Therefore, in an embodiment, TDO of the compound represented by Formula (2) in a thin film may be controlled by appropriately selecting the molecular length (depending on types of substituents and substitution position of substituents) in two-axis directions of the compound. Also, in another embodiment, the molecular length (depending on types of substituents and substitution position of substituents) of the compound represented by Formula (2) may be determined (controlled) according to TDO of the compound in a thin film.

In an embodiment, TDO of the compound represented by Formula (3) in a thin film may be greater than 90% but less than or equal to 100%. The molecular length in two-axis directions in the compound represented by Formula (3) is related to TDO of the compound in a thin film (this relationship is referred to as ‘relationship of the disclosure’). Therefore, in an embodiment, TDO of the compound represented by Formula (3) in a thin film may be controlled by appropriately selecting the molecular length (depending on types of substituents and substitution position of substituents) in two-axis directions of the compound. Also, in another embodiment, the molecular length (depending on types of substituents and substitution position of substituents) of the compound represented by Formula (3) may be determined (controlled) according to TDO of the compound in a thin film.

In consideration of existing technologies, a method of achieving high efficiency of an organic EL device without impairing optical properties of a luminescent material has been developed by designing a compound (i.e., the compound represented by Formula (1)) in which a substituent that improves light extraction efficiency is introduced to the nitrogen-containing condensed polycyclic compound (S1). Accordingly, a blue luminescent material (i.e., the compound represented by formula (1)) having high TDO in a thin film, a composition and an organic EL device that include the blue luminescent material, and an organic EL display including the organic EL device may be provided.

As such, an aspect of the disclosure provides the compound represented by Formula (1). In addition, another aspect of the disclosure provides an organic electroluminescence device including an emission layer that includes the compound represented by Formula (1). In addition, another aspect of the disclosure provides an organic electroluminescence device including an emission layer that includes the compound represented by Formula (1) and a phosphorescent complex which will be described below.

Hereinafter, a compound represented by Formula (1) according to an embodiment and an organic electroluminescence device according to an embodiment including the compound represented by Formula (1) in an emission layer will be described below.

### Compound Represented by Formula (1)

The disclosure relates to a compound represented by Formula (1):

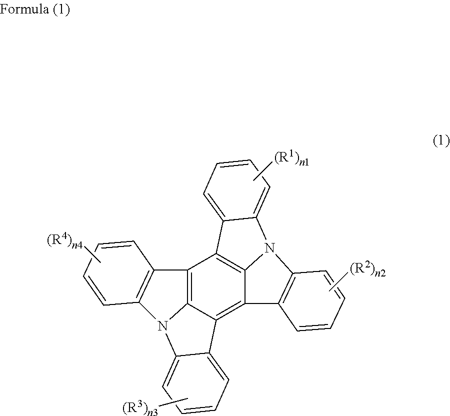

wherein, in Formula (1),
R¹ to R⁴ may each independently be one of the following groups of (1a) to (1d):
(1a) a substituted or unsubstituted C1-C20 alkyl group;
(1b) a substituted or unsubstituted C1-C20 alkoxy group;
(1c) a substituted or unsubstituted aromatic hydrocarbon group; and
(1d) a substituted or unsubstituted heterocyclic group,
n1 to n4 may each independently be 1, 2, 3, or 4, provided that, when n1 is 2 or more, each R¹ may be identical to or different from the others, when n2 is 2 or more, each R² may be identical to or different from the others, when n3 is 2 or more, each R³ may be identical to or different from the others, and when n4 is 2 or more, each R⁴ may be identical to or different from the others.

In Formula (1), among the groups of (1a) to (1d), the groups of (1a), (1b), and (1c) are preferable, and the groups of (1a) and (1c) are more preferable.

In Formula (1), when the groups of (1a) to (1d) are substituted with other substituents, the other substituents are not particularly limited. However, in Formula (1), substituent substituting the groups of (1a) to (1d) may each independently be at least one substituent selected from the group consisting of a halogen atom, a cyano group, a C1-C20 alkyl group, a C1-C20 haloalkyl group, a C1-C20 alkoxy group, a C1-C20 alkylamino group, a C6-C20 arylamino group, an aromatic C6-C30 hydrocarbon group, and a heterocyclic group with a ring-forming atom number of 3 to 30. These substituents may be used for substitution, but may be in an unsubstituted state.

The C1-C20 alkyl group of (1a) is not particularly limited, and may be in a linear form, a branched form, or a cyclic form. Among these forms, the linear form or the branched form is preferable in terms of luminescence efficiency. The number of carbon atoms in the alkyl group may be 2 or more, 3 or more, and preferably 4 or more, in terms of luminescence efficiency. In addition, the number of carbon atoms in the alkyl group may be 10 or less, 8 or less, and preferably 6 or more, in terms of luminescence efficiency. In this regard, the number of carbon atoms in the alkyl group may be 4 or more. Examples of the alkyl group are not particularly limited, but may include a methyl group, an ethyl group, an n-propyl group, an isopropyl group, an n-butyl group, an sec-butyl group (s-butyl group), a tert-butyl group (t-butyl group), an i-butyl group, a 2-ethylbutyl group, a 3,3-dimethylbutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldodecyl group, a 2-octyldecyl group, an n-tridecyl group, an n-tetradecyl group, an n-pentadecyl group, an n-hexadecyl group, a 2-ethylhexadecyl group, a 2-butylhexadecyl group, an n-heptadecyl group, an n-octadecyl group, an n-nonadecyl group, an n-icosyl group, and the like. Among these examples, the alkyl group in a branched form may be preferred, and examples of the alkyl group may be an isopropyl group or a tert-butyl group.

In addition, the term “a substituted C1-C20 alkyl group’ refers to a group obtained by which an unsubstituted C1-C20 alkyl group is substituted with a substituent. Therefore, the number of the substituted alkyl group may be greater than 20.

The C1-C20 alkoxyl group of (1b) is not particularly limited, and may be in a linear form, a branched form, or a cyclic form. Among these forms, the linear form or the branched form is preferable in terms of luminescence efficiency. The number of carbon atoms in the alkoxy group may be in a range of 1 to 10, in terms of luminescence efficiency. Also, from the same point of view, the number of carbon atoms in the alkoxy group may preferably be in a range of 1 to 8, =in a range of 1 to 6, and preferably be 1. The alkyl group constituting the alkoxy group is not particularly limited, but for example, may refer to the aforementioned description made to the alkyl group. Examples of the alkoxy group are not particularly limited, but may include a methoxy group, an ethoxy group, an n-propoxy group, an isopropoxy group, a butoxy group, a pentyloxy group, a hexyloxy group, an octyloxy group, a nonyloxy group, a decyloxy group, and the like. Among these examples, the alkoxy group may be preferably a methoxy group.

In addition, the term “a substituted C1-C20 alkoxy group’ refers to a group obtained by which an unsubstituted C1-C20 alkoxy group is substituted with a substituent. Therefore, the number of the substituted alkoxy group may be greater than 20.

The aromatic hydrocarbon group of (1c) refers to a group derived from one or more hydrocarbon rings having aromaticity. The hydrocarbon ring having aromaticity in the present specification refers to a hydrocarbon ring having aromaticity in part or in whole of the group.

When the aromatic hydrocarbon group includes two or more hydrocarbon rings having aromaticity, these rings may be condensed or bonded to each other via single bonds. In addition, when the aromatic hydrocarbon group includes two or more hydrocarbon rings having aromaticity, one atom may also serve as a ring-forming atom of any of these rings.

The number of carbon atoms in the aromatic hydrocarbon group may preferably be in a range of 6 to 30, in a range of 6 to 20, preferably be in a range of 6 to 18, and more preferably be in a range of 6 to 16, in terms of luminescence efficiency.

Examples of the aromatic hydrocarbon group are not particularly limited, but may include groups consisting of a phenyl group, a mesityl group, an iso-propylphenyl group, a di(iso-propyl) phenyl group, a tri (iso-propyl)phenyl group, a tert-butylphenyl group, a di(tert-butyl)phenyl group, a tri (tert-butyl)phenyl group, a biphenyl group (e.g., a biphenyly group), a (tert-butyl) biphenylyl group, a terphenyl group, a naphthyl group, a fluorenyl group, an anthracenyl group, a terphenyl group, a quaterphenyl group, a quinquephenyl group, a sexiphenyl group, a triphenylenyl group, a pyrenyl group, a benzofluorenyl group, a chrycenyl group, and a combination thereof. Among these examples, the aromatic hydrocarbon group may be preferably a tri (iso-propyl)phenyl group, a tert-butylphenyl group, a bis(tert-butyl)phenyl group, and a (tert-butyl) biphenylyl group, and more preferably a 2,4,6-tri (iso-propyl)phenyl group, a 2-(tert-butyl)-4,6-di(iso-propyl)phenyl group, a 4-tert-butylphenyl group, a 3,5-di(tert-butyl)phenyl group, or a 4′-tert-butyl-4-biphenylyl group.

In addition, the term ‘substituted aromatic hydrocarbon group’ refers to a group obtained by which an unsubstituted aromatic hydrocarbon group is substituted with a substituent. Therefore, when the number of carbon atoms of the aromatic hydrocarbon group is less than or equal to a specific upper limit of number of carbon atoms, for example, less than or equal to 30, the number of carbon atoms of the substituted aromatic hydrocarbon group may exceed the upper limit.

The heterocyclic group of (1d) refers to a group derived from one or more heterocyclic rings. The heterocyclic group is not particularly limited, and may be, for example, both an aromatic heterocyclic group and a non-aromatic heterocyclic group. Among these examples, the heterocyclic group may be an aromatic heterocyclic group in terms of color purity of luminescence. The number of ring-forming atoms in the heterocyclic group may p be in a range of 3 to 30, in a range of 5 to 20, and preferably in a range of 6 to 14. In addition, as described above, the ring-forming atom refers to an atom that directly forms a ring structure. If there are atoms outside a ring that includes double bonds with atoms that constitute a ring structure, such atoms are not included as ring-forming atoms.

The aromatic heterocyclic group refers to a group derived from one or more heterocyclic rings having aromaticity. The heterocyclic ring having aromaticity in the present specification refers to a heterocyclic ring having aromaticity in part or in whole. When the heterocyclic ring has aromaticity in part, the aromaticity may be derived from a heterocyclic ring portion of the ring or from a hydrocarbon ring portion of that ring. Examples of the heterocyclic ring having aromaticity are not particularly limited, but may include a ring in which one or more hetero atoms (e.g., a nitrogen atom (N), an oxygen atom (O), a phosphorus atom (P), a sulfur atom(S), a silicon atom (Si), etc.) are ring-forming atoms and the remaining ring-forming atoms are carbon atoms (C). In addition, as in cases where a carbon atom constituting a ring structure is a ketone group (C═O) or a thioketone group (C═S), or C═NH or where a sulfur atom constituting a ring structure is a sulfinyl group (S═O) or a sulfonyl group (S(═O)═O), atoms constituting a ring structure may be bonded with atoms outside the ring via double bonds. In this case, in the specification, atoms outside the ring structure that form double bonds with atoms constituting a ring structure are defined as part of the heterocyclic ring having aromaticity. In addition, when atoms outside the ring that form double bonds are bonded with hydrogen atoms through single bonds, these hydrogen atoms are also defined as part of the heterocyclic ring having aromaticity. Examples of the heterocyclic ring having aromaticity are not particularly limited, but may include a pyridine ring, a pyrazine ring, a pyridazine ring, a pyrimidine ring, a triazine ring, a quinoline ring, an isoquinoline ring, a quinoxaline ring, a quinazoline ring, a naphthyridine ring, an acridine ring, a phenazine ring, a benzoquinoline ring, a benzoisoquinoline ring, a phenanthridine ring, a phenanthroline ring, a benzoquinone ring, a coumarin ring, an anthraquinone ring, a fluorenone ring, a furan ring, a thiophene ring, a benzofuran ring, a benzothiophene ring, a dibenzofuran ring, a dibenzothiophene ring, a pyrrole ring, an indole ring, a carbazole ring, an indolocarbazole ring, an imidazole ring, a benzimidazole ring, a pyrazole ring, an indazole ring, an oxazole ring, an isoxazole ring, a benzoxazole ring, a benzoisoxazole ring, a thiazole ring, an isothiazole ring, a benzothiazole ring, a benzoisothiazole ring, an imidazolinone ring, a benzimidazolinone ring, an imidazopyridine ring, an imidazopyrimidine ring, an imidazophenanthridine ring, a benzimidazophenanthridine ring, an azadibenzofuran ring, an azacarbazole ring, an azadibenzothiophene ring, a diazadibenzofuran ring, a diazacarbazole ring, a diazaadibenzothiophene ring, a xanthone ring, a thioxanthone ring, and the like.

When the aromatic heterocyclic group includes two or more heterocyclic rings having aromaticity, these rings may be condensed or bonded to each other via single bonds. In addition, when the aromatic heterocyclic group includes two or more heterocyclic rings having aromaticity, one atom may also serve as a ring-forming atom of any of these rings.

The number of ring-forming atoms in the aromatic heterocyclic group (i.e., the sum of the number of ring-forming carbon atoms and the number of ring-forming hetero atoms) may be in a range of 3 to 30, and in terms of peak wavelengths in an emission spectrum and color purity of luminescence, the number may be in a range of 5 to 20, and preferably in a range of 6 to 14. The number of ring-forming hetero atoms in the aromatic heterocyclic group is not particularly limited, but in terms of peak wavelengths in an emission spectrum and color purity of luminescence, the number may p be in a range of 1 to 10. In addition, from the same perspective, the number of ring-forming hetero atoms in the aromatic heterocyclic group may be in a range of 1 to 5, and preferably be in a range of 1 to 3.

Examples of the aromatic heterocyclic group are not particularly limited, but may include a thienyl group, a furanyl group, a pyrrolyl group, an imidazolyl group, a thiazolyl group, an oxazolyl group, an oxadiazolyl group, a triazolyl group, a pyridyl group, a bipyridyl group, a pyrimidyl group, a triazinyl group, an acridinyl group, a pyridazinyl group, a pyrazinyl group, a quinolinyl group, a quinazolinyl group, a quinoxalinyl group, a phenoxazinyl group, a phthalazinyl group, a pyridopyrimidinyl group, a pyridopyrazinyl group, a pyrazinopyrazinyl group, an isoquinolinyl group, an indolyl group, a carbazolyl group, a benzoxazolyl group, a benzoimidazolyl group, a benzothiazolyl group, a benzocarbazolyl group, a benzothiophenyl group, a dibenzothiophenyl group, a thienothienyl group, a benzofuranyl group, a phenanthrolinyl group, a thiazolyl group, an isoxazolyl group, an oxadiazolyl group, a thiadiazolyl group, a phenothiazinyl group, a dibenzosilolyl group, a dibenzofuranyl group, a xanthonyl group, and the like. Among these examples, the aromatic heterocyclic group may be preferably a triazinyl group, a carbazolyl group, a benzoxazolyl group, or a xanthonyl group.

In addition, the non-aromatic heterocyclic group refers to a group derived from one or more heterocyclic rings having no aromaticity. In the specification, the non-aromatic heterocyclic ring refers to a heterocyclic ring that does not have aromaticity either in part or in whole. Examples of the non-aromatic heterocyclic ring are not particularly limited, but may include a ring in which one or more hetero atoms (e.g., N, O, P, S, Si, etc.) are ring-forming atoms and the remaining ring-forming atoms are C. As a hetero atom, N and O may be preferable in terms of peak wavelengths in an emission spectrum and color purity of luminescence. In addition, as in cases where a carbon atom constituting a ring structure is a ketone group (C═O) or a thioketone group (C═S), or C═NH or where a sulfur atom constituting a ring structure is a sulfinyl group (S═O) or a sulfonyl group (S(═O)═O), atoms constituting a ring structure may be bonded with atoms outside the ring via double bonds. In this case, in the specification, atoms outside the ring structure that form double bonds with atoms constituting a ring structure are defined as part of the non-aromatic heterocyclic ring. In addition, when atoms outside the ring that form double bonds are bonded with hydrogen atoms through single bonds, these hydrogen atoms are also defined as part of the non-aromatic heterocyclic ring. Examples of the non-aromatic heterocyclic ring are not particularly limited, but may include a pyrrolidine ring, a tetrahydrofuran ring, a tetrahydrothiophene ring, a piperidine ring, a tetrahydropyran ring, a tetrahydrothiopyran ring, a dioxane ring, a morpholine ring, a dioxolane ring, and the like.

When the non-aromatic heterocyclic group includes two or more non-aromatic heterocyclic rings, these rings may be bonded or condensed to each other via single bonds. In addition, when the non-aromatic heterocyclic group includes two or more non-aromatic heterocyclic rings, one atom may also serve as a ring-forming atom of any of these rings.

The number of ring-forming atoms in the non-aromatic heterocyclic group (i.e., the sum of the number of ring-forming carbon atoms and the number of ring-forming hetero atoms) may be in a range of 3 to 30, and in terms of peak wavelengths in an emission spectrum and color purity of luminescence, the number may be in a range of 5 to 20, and preferably be in a range of 6 to 14. The number of ring-forming hetero atoms in the non-aromatic heterocyclic group is not particularly limited, but in terms of peak wavelengths in an emission spectrum and color purity of luminescence, the number may be in a range of 1 to 10. In addition, from the same perspective, the number of ring-forming hetero atoms in the non-aromatic heterocyclic group may be in a range of 1 to 5, and preferably be in a range of 1 to 3.

Examples of the non-aromatic heterocyclic group are not particularly limited, but may include a pyrrolidinyl group, a tetrahydrofuranyl group, a tetrahydrothienyl group, a piperidinyl group, a tetrahydropyranyl group, a tetrahydrothiopyranyl group, a dioxanyl group, a morphonyl group, a dioxolanyl group, and the like.

In addition, the term ‘substituted heterocyclic group’ refers to a group obtained by which an unsubstituted heterocyclic group is substituted with a substituent. Thus, when the number of ring-forming atoms in the heterocyclic group is less than or equal to a specific upper limit of ring-forming atoms, such as less than or equal to 30, and when a substituent forms a ring structure, the number of ring-forming atoms in the substituted heterocyclic group may exceed the upper limit.

Substituents for substitution of the groups of (1a) to (1d) may be an unsubstituted C1-C20 alkyl group, an unsubstituted C1-C20 alkoxy group, an unsubstituted C6-C30 aromatic hydrocarbon group, an unsubstituted aromatic C6-C30 hydrocarbon group, and an unsubstituted heterocyclic group with a ring-forming atom number of 3 to 30, each of which is the same as the unsubstituted groups described in (1a) to (1d).

Examples of a halogen atom used as a substituent for substitution of the groups of (1a) to (1d) are not particularly limited, but may include a fluorine atom (F), a chlorine atom (Cl), a bromine atom (Br), or an iodine atom (I). Among these examples, the halogen atom may be preferably F in terms of luminescence efficiency.

The substituent for substitution of the groups of (1a) to (1d) may be a cyano group, which is denoted by CN.

An unsubstituted C1-C20 halogenated alkyl group, which is a substituent for substitution of the groups of (1a) to (1d), may be a group obtained by which at least one hydrogen atom of the alkyl group described in (1a) is substituted with the aforementioned halogen atom. In terms of luminescence efficiency, F may be preferable as the halogen atom. Examples of the halogenated alkyl group are not limited thereto, but may include, for example, a trifluoromethyl group, a trichloromethyl group, a tribromomethyl group, a triiodomethyl group, and the like. Among these examples, the halogenated alkyl group may be preferably a fluorinated alkyl group, and more preferably a trifluoromethyl group.

The unsubstituted C1-C20 alkylamino group as the substituent for substitution of the groups of (1a) to (1d) may be formed by which any one of atoms constituting the unsubstituted groups of (1a) to (1d) bonded with the nitrogen atom of the alkylamino group via a single bond in Formula (1). An alkyl group constituting the alkylamino group is not particularly limited, but may be, for example, the same as described in (1a). The alkylamino group is not particularly limited, and but may be a monoalkylamino group or a dialkylamino group. Examples of the alkylamino group are not particularly limited, but may include an N-methylamino group, an N-ethylamino group, an N-propylamino group, an N-isopropylamino group, an N-butylamino group, an N-isobutylamino group, an N-sec-butylamino group, an N-tert-butylamino group, an N-pentylamino group, an N-hexylamino group, an N,N,N-dimethylamino group, an N-methyl-N-ethylamino group, an N,N-diethylamino group, an N,N-dipropylamino group, an N,N-diisopropylamino group, an N,N-dibutylamino group, an N,N-diisobutylamino group, an N,N-dipentylamino group, an N,N-dihexylamino group, and the like.

The unsubstituted C6-C20 arylamino group as the substituent for substitution of the groups of (1a) to (1d) may be formed by which any one of atoms constituting the unsubstituted groups of (1a) to (1d) bonded with the nitrogen atom of the arylamino group via a single bond in Formula (1). An aryl group constituting the arylamino group is not particularly limited, but may be, for example, the same as the aromatic hydrocarbon group (i.e., an aryl group) described in (1c). The arylamino group is not particularly limited, and but may be a monoarylamino group or a diarylamino group. Examples of the arylamino group are not particularly limited, but may include an N-phenylamino group, an N-biphenylamino group, an N-terphenylamino group, an N,N-diphenylamino group, an N-biphenyl-N-phenylamino group, and the like.

Here, as a preferably substituent for substitution of the group of (1a) to (1d), a halogen atom, a cyano group, an unsubstituted C1-C20 alkyl group, an unsubstituted C1-C20 alkoxy group, and an unsubstituted C6-C20 arylamino group may be preferable. In addition, among these examples, a halogen atom and an unsubstituted C1-C20 alkyl group may be preferable, F, or a linear or branched unsubstituted C1-C20 alkyl group may be preferable, and a branched unsubstituted C1-C20 alkyl may be particularly preferable. In addition, F, a methyl group, an ethyl group, an isopropyl group, and a tert-butyl group may be particularly preferable.

As a substituent for substitution of the group of (1c), a branched unsubstituted C1-C20 alkyl group, a branched unsubstituted C1-C10 alkyl group may be preferable, and a branched unsubstituted C1-C5 alkyl group may be more preferable. For example, an isopropyl group and a tert-butyl group may be particularly preferable.

In the compound of Formula (1), R¹ to R⁴ may each independently include at least one group selected from Group (2X). In addition, in the compound of Formula (1), R¹ and R³ may each independently include at least one group selected from Group (2X), and R² and R⁴ may each independently include at least one group selected from Group (2X).

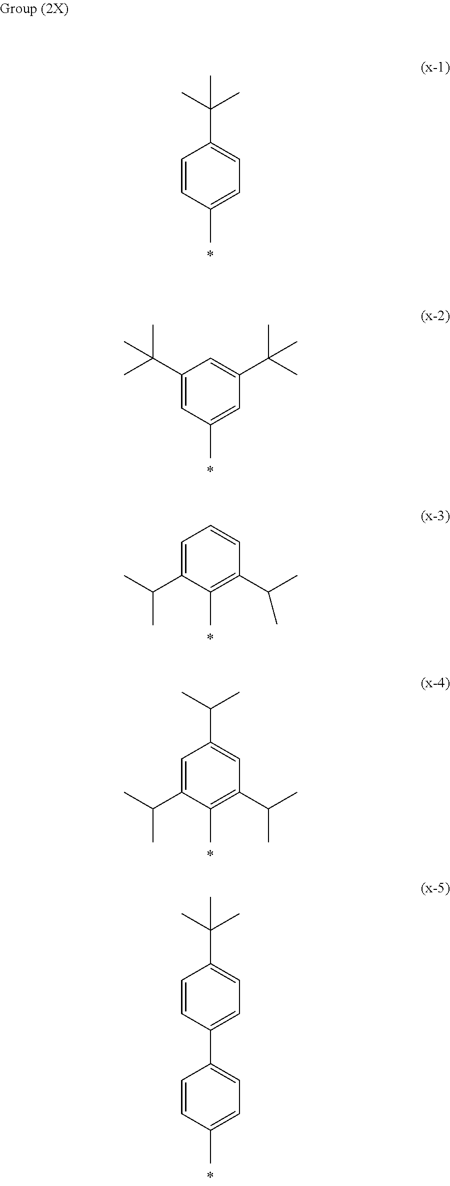

That is, according to an embodiment, in the compound of Formula (1), R¹ to R⁴ may each independently be a group selected from Group (2X), and n1 to n4 may each independently be 1, 2, 3, or 4, provided that, when n1 is 2 or more, each R¹ may be identical to or different from the others, when n2 is 2 or more, each R² may be identical to or different from the others, when n3 is 2 or more, each R³ may be identical to or different from the others, and when n4 is 2 or more, each R⁴ may be identical to or different from the others. In addition, * in Group (2X) indicates a binding site.

In addition, according to an embodiment, in the compound of Formula (1), R¹ to R⁴ may each independently be a group selected from Group (2X), and n1 to n4 may each independently be 1 or 2, provided that, when n1 is 2, each R¹ may be identical to or different from the others, when n2 is 2, each R² may be identical to or different from the others, when n3 is 2, each R³ may be identical to or different from the others, and when n4 is 2, each R⁴ may be identical to or different from the others.

In an embodiment, the compound represented by Formula (1) may be a compound represented by Formula (2):

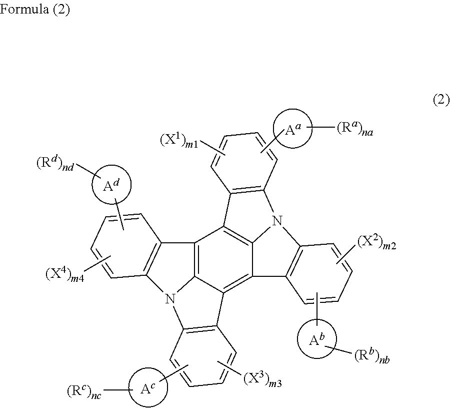

wherein, in Formula (2),
A^{a} to A^{d} may each independently be a benzene ring or a heterocyclic ring,
R^{a} to R^{d} may each independently be a hydrogen atom, an unsubstituted C1-C20 alkyl group, an unsubstituted C1-C20 alkoxy group, an unsubstituted C6-C20 arylamino group, a substituted or unsubstituted aromatic hydrocarbon group, or a substituted or unsubstituted aromatic heterocyclic group,
when A^{a} is a benzene ring, na is 5, and when A^{a} is a heterocyclic ring, na is an upper limit of possible number of substitution with A^{a},
when A^{b} is a benzene ring, nb is 5, and when A^{b} is a heterocyclic ring, nb is an upper limit of possible number of substitution with A^{b},
when A^{c} is a benzene ring, nc is 5, and when A^{c} is a heterocyclic ring, nc is an upper limit of possible number of substitution with A^{c},
when A^{d} is a benzene ring, nd is 5, and when A^{d} is a heterocyclic ring, nd is an upper limit of possible number of substitution with A^{d},
X¹ to X⁴ may each independently be a hydrogen atom, an unsubstituted C1-C20 alkyl group, an unsubstituted C1-C20 alkoxy group, or a substituted or unsubstituted aromatic hydrocarbon group, and
m1 to m4 may be 3.

In Formula (2), at least one of R^{a}, at least one of R^{b}, at least one of R^{c}, and at least one of R^{d} may be preferably an unsubstituted C1-C20 alkyl group, an unsubstituted C1-C20 alkoxy group, an substituted or unsubstituted aromatic hydrocarbon group, or an substituted or unsubstituted aromatic heterocyclic group. In addition, in Formula (2), at least one R^{a}, at least one R^{b}, at least one R^{c}, and at least one R^{d} may be preferably an unsubstituted C1-C20 alkyl group or an unsubstituted C1-C20 alkoxy group.

In an embodiment, the compound represented by Formula (1) may be a compound represented by Formula (3):

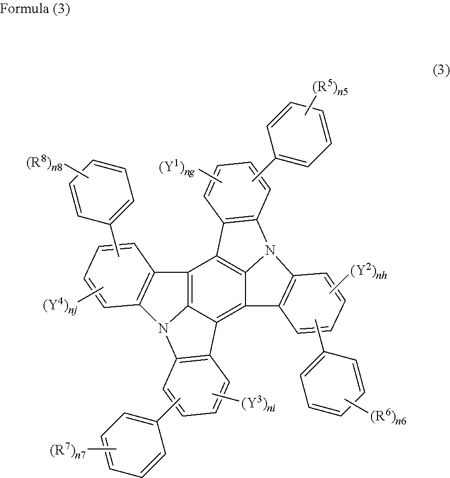

wherein, in Formula (3),
R⁵ to R⁸ may each independently be a hydrogen atom, an unsubstituted C1-C20 alkyl group, an unsubstituted C1-C20 alkoxy group, a substituted or unsubstituted aromatic hydrocarbon group, or a substituted or unsubstituted aromatic heterocyclic group,
n5 to n8 may be 5,
Y¹ to Y⁴ may each independently be a hydrogen atom, an unsubstituted C1-C20 alkyl group, an unsubstituted C1-C20 alkoxy group, or a substituted or unsubstituted aromatic hydrocarbon group, and
ng to nj may be 3.

In Formula (3), at least one of R⁵, at least one of R⁶, at least one of R⁷, and at least one of R⁸ may be preferably an unsubstituted C1-C20 alkyl group, an unsubstituted C1-C20 alkoxy group, an substituted or unsubstituted aromatic hydrocarbon group, or an substituted or unsubstituted aromatic heterocyclic group. In addition, in Formula (3), at least one R⁵, at least one R⁶, at least one R⁷, and at least one R⁸ may be preferably an unsubstituted C1-C20 alkyl group or an unsubstituted C1-C20 alkoxy group.

For a description of each group in Formulae (2) and (3), a reference is made to the description of the groups in Formula (1).

In an embodiment, the compound of Formula (1) may be a compound represented by Formula (4):

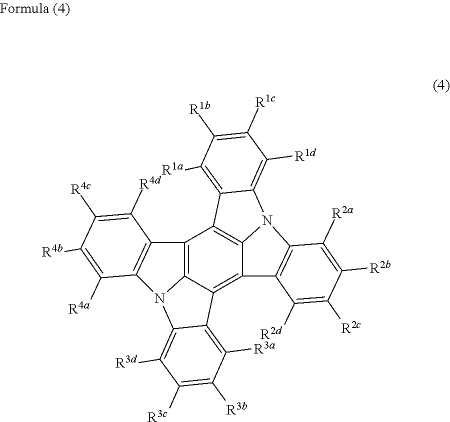

wherein, in Formula (4),
R^{1a} to R^{1d}, R^{2a} to R^{2d}, R^{3a} to R^{3d}, and R^{4a} to R^{4d} may each independently be a hydrogen atom or a group selected from Group (1X):

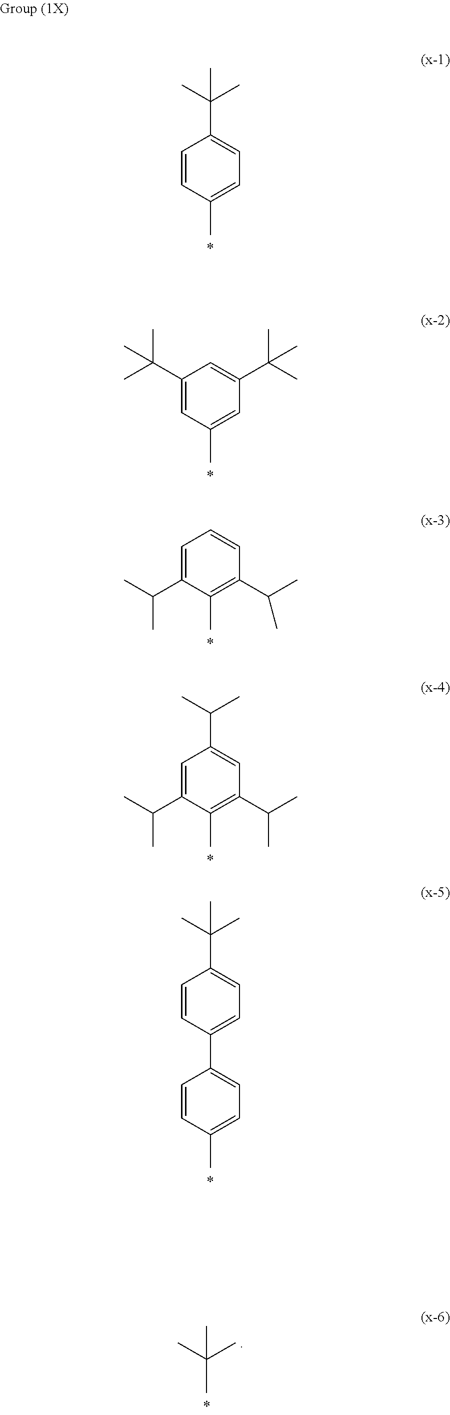

Here, at least one of R^{1a} to R^{1d}, at least one of R^{2a} to R^{2d}, at least one of R^{3a} to R^{3d}, and at least one of R^{4a} to Rad may be groups selected from Group (1X). In addition, * in Group (1X) indicates a binding site.

According to an embodiment, in Formula (4), at least one of R^{1a} to R^{1d}, at least one of R^{2a} to R^{2d}, at least one of R^{3a} to R^{3d}, and at least one of R^{4a} to R^{4d} may be groups selected from Group (2X). Accordingly, the molecular length may be extended in two-axis directions, resulting in a higher TDO.

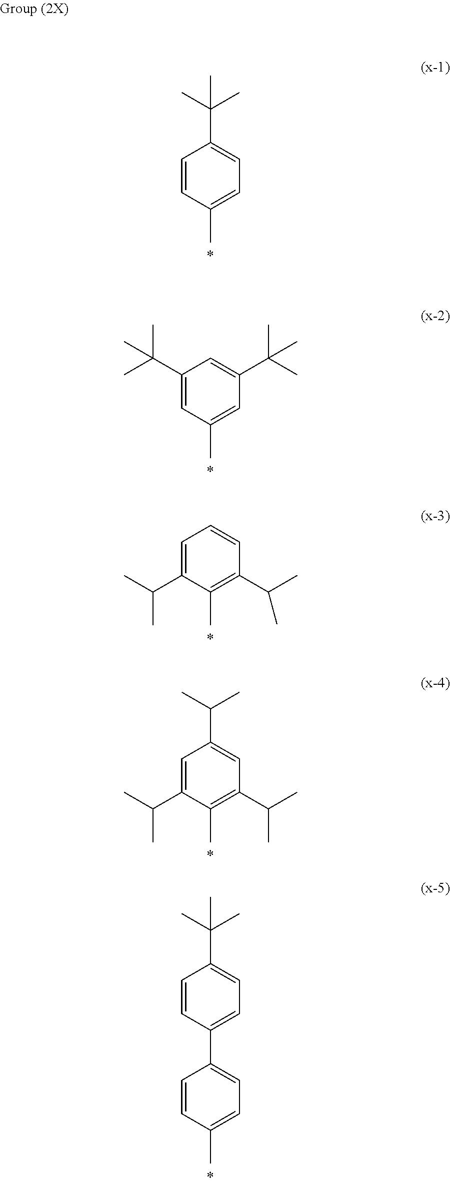

In addition, according to an embodiment, in Formula (4), groups of at least one combination of: R^{1b} and R^{3b}; and R^{1c} and R^{3c} and groups of at least one combination of: R^{2b} and R^{4b}; and R^{2c} and R^{4c} may be groups selected from Group (2X). Accordingly, the molecular length may be extended in two-axis directions, resulting in a higher TDO. In addition, * in Group (2X) indicates a binding site.

Therefore, according to an embodiment, in Formula (4),
R^{1a} to R^{4a} (i.e., R¹ª, R²ª, R³ª, and R⁴ª) and Rid to R^{d} (i.e., Rid, R^{2d}, R^{3d}, and R^{4d}) may each independently be a hydrogen atom or groups selected from Group (3X):

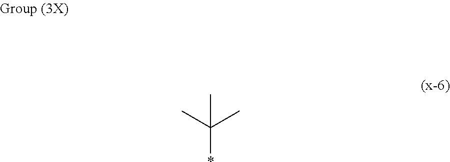 [SMILES: *C(C)(C)C]

wherein * indicates a binding site, and
R^{1b} to R^{4b} (i.e., R^{1b}, R^{2b}, R^{3b}, and R^{4b}) and R^{1c} to R^{4c} (i.e., R^{1c}, R^{2c}, R^{3c}, and R^{4c}) may each independently be a hydrogen atom or groups selected from Group (2X):

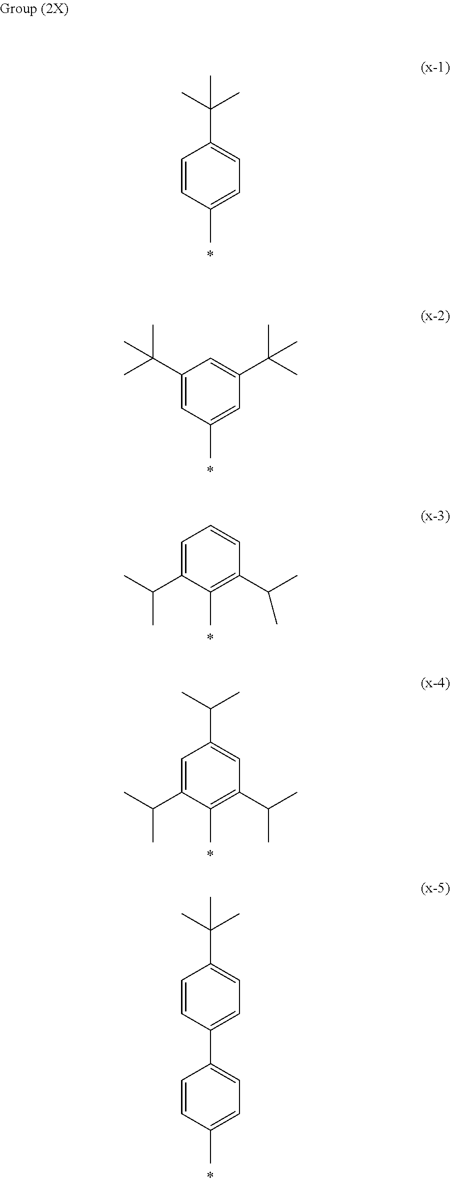

wherein * indicates a binding site, R^{1b} and R^{3b} may be a hydrogen atom or one of groups selected from Group (2X), R^{1c} and R^{3c} may be a hydrogen atom or one of the groups selected from Group (2X), R^{2b} and R^{4b} may be a hydrogen atom or any one of groups selected from Group (2X), and R^{2c} and R^{4c} may be a hydrogen atom or one of the other groups selected from Group (2X).

The compound represented by Formula (1) may have a molecular weight in a range of about 1000 g/mol to about 1400 g/mol. When the molecular weight exceeds 1400 g/mol, there is a risk of decomposition during deposition. The molecular weight may be 1380 or less, 1350 g/mol or less, preferably 1300 g/mol or less, and more preferably 1250 g/mol or less, and most preferably 1200 g/mol or less. In addition, the molecular weight of the compound represented by Formula (1) may exceed 1000 g/mol, 1010 g/mol or more, 1020 g/mol or more, preferably 1030 g/mol or more, and more preferably 1040 g/mol or more. In addition, the molecular weight is the total sum of the atomic weight of the atoms the constitute the compound represented by Formula (1). The preferred molecular weight of the compound of Formula (1) also applies to the compounds represented by Formulae (2), (3), and (4).

### Description of Molecular Length in Two-Axis Directions

The compound of Formula (1) according to the disclosure satisfies a specific relationship in the molecular length in two-axis directions. Specifically, the molecular length L₁ and the molecular length L₂ in two-axis directions of the compound of Formula (1) are defined as follows:

$$Molecular length {L}_{1} = ( longest end - to - end distance {L}_{1 x} between a carbon atom of substituent {R}^{1} and a carbon atom of substituent {R}^{3} ) + ( in the presence of substituent {R}^{1} ( hereinafter reffered to as substituent {R}^{1 p} ) other than substituent {R}^{1} used in calculation of longest end - to - end distance {L}_{1 x} , longest end - to - end distance {L}_{1 y} between a carbon atom binding to substituent {R}^{1 p} and a carbon atom of substituent {R}^{1 p} ) + ( in the presence of substituent {R}^{3} ( hereinafter reffered to as substituent {R}^{3 p} ) other than substituent {R}^{3} used in calculation of longest end - to - end distance {L}_{1 x} , longest end - to - end distance {L}_{1 z} between a carbon atom binding to substituent {R}^{3 p} and a carbon atom of substituent {R}^{3 p} ) \qquad Equation 1 A$$

$$Molecular length {L}_{2} = ( longest end - to - end distance {L}_{2 x} between a carbon atom of substituent {R}^{2} and a carbon atom of substituent {R}^{4} ) + ( in the presence of substituent {R}^{2} ( hereinafter reffered to as substituent {R}^{2 p} ) other than substituent {R}^{2} used in calculation of longest end - to - end distance {L}_{2 x} , longest end - to - end distance {L}_{2 y} between a carbon atom binding to substituent {R}^{2 p} and a carbon atom of substituent {R}^{2 p} ) + ( in the presence of substituent {R}^{4} ( hereinafter reffered to as substituent {R}^{4 p} ) other than substituent {R}^{4} used in calculation of longest end - to - end distance {L}_{2 x} , longest end - to - end distance {L}_{2 z} between a carbon atom binding to substituent {R}^{4 p} and a carbon atom of substituent {R}^{4 p} ) \qquad Equation 1 B$$

provided that, when each of substituents R^{1p} to R^{4p} exists in plural in the definition above, the longest end-to-end distance of each of substituents R^{1p} to R^{4p} existing in plural is added up to L_{1y}, L_{1z}, L_{2y}, and L_{2z}, respectively.

When calculated as described above, the molecular length L₁ and the molecular length L₂ may each independently be in a range of about 16 Å to about 38 Å, and a product of the molecular length L₁ and the molecular length L₂ may be in a range of about 490 Å² or about 1200 Å².

Here, the term ‘two-axis directions’ refers to two directions connecting R¹ to R³ (hereinafter referred to as direction D1) and R² to R⁴ (hereinafter referred to as direction D2) in the compound of Formula (1).

Hereinafter, the molecular length L₁ and the molecular length L₂ in an embodiment where the compound represented by Formula (1) is represented by Formula (4a) will be described:

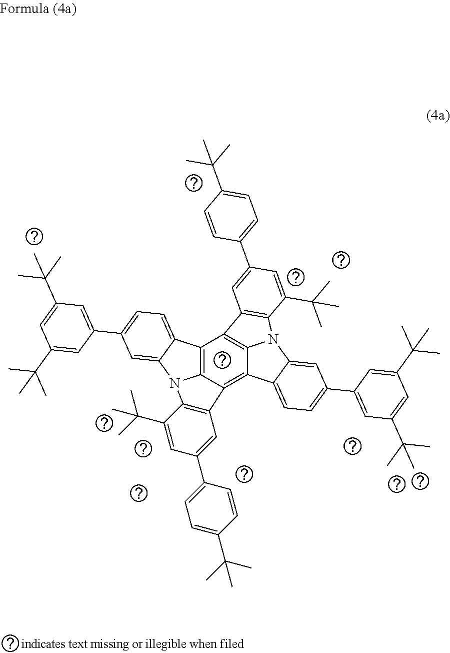 [SMILES: CC(C)(C)c1ccc(-c2cc(C(C)(C)C)c3c(c2)c2c4c5ccc(-c6cc(C(C)(C)C)cc(C(C)(C)C)c6)cc5n5c6c(C(C)(C)C)cc(-c7ccc(C(C)(C)C)cc7)cc6c(c6c7ccc(-c8cc(C(C)(C)C)cc(C(C)(C)C)c8)cc7n3c62)c45)cc1]

In the compound represented by Formula (4a), referring to Formula (1), n1 may be 2, R¹ may be a p-tert-butylphenyl group, ((x-1) of Group (2X)) and a tert-butyl group ((x-6) of Group (3X)), n2 may be 1, R² may be a 3,5-di-tert-butyl group ((x-2) of Group (2X)), n3 may be 2, R³ may be a p-tert-butylphenyl group ((x-1) of Group (2X)) and a tert-butyl group ((x-6) of Group (3X)), n4 may be 1, and R⁴ may be a 3,5-di-tert-butyl group ((x-2) of Group (2X)). In addition, in the compound represented by Formula (4a), referring to Formula (4), R^{1b} and R^{3b} may be a p-tert-butylphenyl group ((x-1) of Group (2X)), Rid and R^{3d} may be a tert-butyl group ((x-6) of Group (3X)), and R^{2b} and R^{4b} may be a 3,5-di-tert-butyl group ((x-2) of Group (2X)). When defining the molecular length L₁ and the molecular length L₂ in the compound of Formula (1), for convenience, the substituents in Formula (4) (i.e., R^{1b} and R^{3b}; R^{1d} and R^{3d}; and R^{2b} and R^{4b}) are used for explanation.

In the compound represented by Formula (4a), the molecular length L₁ in direction D1 is calculated first. For the ‘longest end-to-end distance L₁ₓ between a carbon atom of substituent R¹ and a carbon atom of substituent R³′ in the compound represented by Formula (4a), the distance between terminal carbon atoms of the p-tert-butylphenyl group ((x-1) of Group (2X)) in R^{1b} and R^{3b} is measured. Here, the p-tert-butylphenyl group ((x-1) of Group (2X)) includes a plurality of terminal carbon atoms, and in this regard, the longest distance between the terminal carbon atoms is defined as ‘the longest end-to-end distance L₁ₓ between a carbon atom of substituent R¹ and a carbon atom of substituent R³′ (wherein L₁ₓ in the compound of Formula (4a) is 23.1254 Å). None of the distance between a terminal carbon atom of R^{1d} (e.g., a tert-butyl group) and a terminal carbon atom of R^{3b} (e.g., a p-tert-butylphenyl group); the distance between a terminal carbon atom of R^{1b} (e.g., a p-tert-butylphenyl group) and a terminal carbon atom of R^{3d} (e.g., a tert-butyl group); and the distance between a terminal carbon atom of R^{1d} (e.g., a tert-butyl group) and a terminal carbon atom of R^{3d} (e.g., a tert-butyl group) reaches the longest distance between terminal carbon atoms, and therefore these distances do not correspond to ‘the longest end-to-end distance L₁ₓ between a carbon atom of substituent R¹ and a carbon atom of substituent R³’. For example, when the substituent (e.g., R¹ and R³) has two or more substituents and the same values are calculated as ‘the longest end-to-end distance L₁ₓ,’ one of the values is calculated and referred to as ‘the longest end-to-end distance L₁ₓ’, and the other is calculated and referred to as either ‘the longest end-to-end distance L_{1y}’ or ‘the longest end-to-end distance L_{1z}’. Likewise, regarding the molecular length L₂, when the longest end-to-end distance is the same for a plurality of terminal groups, the calculation is made as described above.

In the compound represented by Formula (4a), there may be R¹ (e.g., a tert-butyl group) other than the p-tert-butylphenyl group used in the calculation of the longest end-to-end distance L₁ₓ. That is, ‘in the presence of substituent R¹ (hereinafter referred to as substituent R^{1p}) other than substituent R¹ used in the calculation of the longest end-to-end distance L₁ₓ, the longest end-to-end distance Ly between a carbon atom binding to substituent R^{1p} and a carbon atom of substituent R^{1p}’ is calculated. As described above, since ‘the longest end-to-end distance between a terminal carbon atom of R^{1b} and a terminal carbon atom of R^{3b}’ is set as ‘the longest end-to-end distance L₁ₓ,’ substituent R^{1d} is excluded from the calculation of ‘the longest end-to-end distance L_{1y}’. In the compound represented by Formula (4a), ‘the longest end-to-end distance L₁y’ corresponds to ‘the longest end-to-end distance between a carbon atom binding to substituent R^{1d} (e.g., a tert-butyl group) and a carbon atom of substituent R^{1d} (e.g., a tert-butyl group)’ (wherein L₁y in the compound of Formula (4a) is 2.57896 Å). Next, in the compound represented by Formula (4a), there may be substituent R³ (e.g., a tert-butyl group) other than substituent R³ (e.g., a p-tert-butylphenyl group) used in the calculation of the longest end-to-end distance L₁ₓ. That is, ‘in the presence of substituent R³ (hereinafter referred to as substituent R^{3p}) other than substituent R³ used in the calculation of the longest end-to-end distance L₁ₓ, the longest end-to-end distance L_{1z} between a carbon atom binding to substituent R^{3p} and a carbon atom of substituent R^{3p}’ is calculated. Regarding substituent R^{3d}, since ‘the longest end-to-end distance between a terminal carbon atom of R^{1b} and a terminal carbon atom of R^{3b}’ is set as ‘the longest end-to-end distance L₁ₓ,’ substituent R^{3d} is excluded from the calculation of ‘the longest end-to-end distance L_{1z}’. In the compound represented by Formula (4a), ‘the longest end-to-end distance L_{1z}’ corresponds to ‘the longest end-to-end distance between a carbon atom of substituent R^{3d} and a carbon atom of substituent R^{3d}’ (wherein L_{1z} in the compound of Formula (4a) is 2.57888 Å).

As described above, ‘the longest end-to-end distance L₁ₓ,’ ‘the longest end-to-end distance L_{1y},’ and ‘the longest end-to-end distance L_{1z}’ are calculated, and these values are added up to calculate the molecular length L₁. For example, in the compound of Formula (4a), the molecular length L₁ is 28.283 Å by adding 23.125 Å, 2.579 Å, and 2.579 Å, and this sum value is rounded to 28.3 Å.

Next, in the compound represented by Formula (4a), the molecular length L₂ in direction D2 is calculated. For the ‘longest end-to-end distance Lex between a carbon atom of substituent R² and a carbon atom of substituent R⁴’ in the compound represented by Formula (4a), the distance between terminal carbon atoms of the tert-butyl group ((x-2) of Group (2X)) in R^{2b} and R^{4b} is measured. Here, the tert-butyl group ((x-2) of Group (2X)) includes a plurality of terminal carbon atoms, and in this regard, the longest distance between the terminal carbon atoms is defined as ‘the longest end-to-end distance L₂ₓ between a carbon atom of substituent R² and a carbon atom of substituent R⁴’ (wherein L₂ₓ in the compound of Formula (4a) is 22.971 Å).

In the compound represented by Formula (4a), R² other than substituent R² (e.g., a tert-butyl group) used in the calculation of the longest end-to-end distance Lex is a hydrogen atom. Therefore, ‘in the presence of substituent R² (hereinafter referred to as substituent R^{2p}) other than substituent R² used in the calculation of the longest end-to-end distance Lex, the longest end-to-end distance L₂y between a carbon atom of substituent R^{2p} and a carbon atom of substituent R^{2p}’ is 0. Likewise, in the compound represented by Formula (4a), R⁴ other than substituent R⁴ (e.g., a tert-butyl group) used in the calculation of the longest end-to-end distance Lax is a hydrogen atom. Therefore, ‘in the presence of substituent R⁴ (hereinafter referred to as substituent R^{4p}) other than substituent R⁴ used in the calculation of the longest end-to-end distance Lex, the longest end-to-end distance L₂z between a carbon atom of substituent R^{4p} and a carbon atom of substituent R^{4p}′ is 0.

As described above, ‘the longest end-to-end distance L₂x,’ ‘the longest end-to-end distance L_{2y},’ and ‘the longest end-to-end distance L₂₂’ are calculated, and these values are added up to calculate the molecular length L₂. For example, in the compound of Formula (4a), the molecular length L₂ is 22.971 Å by adding 22.971, 0, and 0, and this sum value is rounded to 23.0 Å.

In the compound of Formula (1) described herein, the calculated molecular length L₁ and the calculated molecular length L₂ may be 18 Å or more, may be 19 Å or more, or preferably 20 Å or more, such as 21 Å and 22 Å. The upper limit of the molecular length L₁ and the molecular length L₂ may preferably be 37 Å or less, 36 Å or less, or preferably 35 Å or less.

The disclosure is characterized not only by having the molecular length L₁ and the molecular length L₂ within specific ranges, but also by having the product of the molecular length L₁ and the molecular length L₂ within specific ranges. The product of the molecular length L₁ and the molecular length L₂ is a numerical value representing a technical detail, such as orientation (e.g., TDO). When this product is within a range of about 490 Å² to about 1200 Å², device efficiency may be improved due to high orientation.

When the product of the molecular length L₁ and the molecular length L₂ is in a range of about 490 Å² to about 1200 Å², the TDO may be in a range of about 90% to about 100%. Meanwhile, when the product of the molecular length L₁ and the molecular length L₂ is less than 490 Å2 or greater than 1200 Å², the TDO may be less than 90%. The product of the molecular length L₁ and the molecular length L₂ may preferably be in a range of about 500 Å² to about 1180 Å2, more preferably be in a range of about 520 Å² to about 1150 Å², even more preferably be in a range of about 550 Å² to about 1140 Å², particularly preferably be in a range of about 580 Å² to about 1135 Å², and most preferably be in a range of about 600 Å² to about 1130 Å².

According to an embodiment, the molecular length L₁ and the molecular length L₂ may be in a range of about 18 Å to about 38 Å, and the product of the molecular length L₁ and the molecular length L₂ may be in a range of about 500 Å² to about 1180 Å². In addition, according to an embodiment, the molecular length L₁ and the molecular length L₂ may be in a range of about 20 Å to about 38 Å, and the product of the molecular length L₁ and the molecular length L₂ may be in a range of about 520 Å² to about 1180 Å². According to an embodiment, the molecular length L₁ and the molecular length L₂ may be in a range of about 21 Å to about 31 Å, and the product of the molecular length L₁ and the molecular length L₂ may be in a range of about 490 Å² to about 650 Å².

In addition, when calculating the molecular length L₁ and the molecular length L₂ as described above, the structure of the compound of Formula (1) of the disclosure utilizes the most stable structure calculated by density functional theory (DFT) using a calculation software, Gaussian 16 (Gaussian Inc.). The molecular lengths are calculated using the function of GaussView for measuring the distance between atoms. Details of the most stable structure and calculation of the molecular lengths are as described in Examples below. In addition, after calculating the most stable structure by Gaussian 16 (Gaussian Inc.), the molecular lengths (L₁ and L₂) of the compound may be calculated using software such as Gauss View, Chem 3D, IQmol, and the like.

In an embodiment where the compound of Formula (1) in the disclosure is represented by Formula (2), the molecular length L₁ and the molecular length L₂ correspond to the molecular length L₃ and the molecular length L₄, respectively, and may be defined as follows. In addition, regarding the two-axis directions in the compound represented by Formula 2A and Formula 2B, respectively, direction D1 corresponds to the direction connecting substituent R^{a} to substituent R^{c}, and direction D2 corresponds to the direction connecting substituent R^{b} to substituent R^{d}.

$$Molecular length {L}_{3} = ( longest end - to - end distance {L}_{3 x} between a carbon atom of substituent {R}^{a} and a carbon atom of substituent {R}^{c} ) + ( in a case where substituent {X}^{1} is a group other than a hydrogen atom , longest end - to - end distance {L}_{3 y} between a carbon atom binding to substituent {X}^{1} and carbon atom of substituent {X}^{1} ) + ( in a case where substituent {X}^{3} is a group other than a hydrogen atom , longest end - to - end distance {L}_{3 z} between a carbon atom binding to substituent {X}^{3} and carbon atom of substituent {X}^{3} {L}_{3 z} ) ; \qquad Equation 2 A$$

$$Molecular length {L}_{4} = ( longest end - to - end distance {L}_{4 x} between a carbon atom of substituent {R}^{b} and a carbon atom of substituent {R}^{d} ) + ( in a case where substituent {X}^{2} is a group other than a hydrogen atom , longest end - to - end distance {L}_{4 y} between a carbon atom binding to substituent {X}^{2} and carbon atom of substituent {X}^{2} ) + ( in a case where substituent {X}^{4} is a group other than a hydrogen atom , longest end - to - end distance {L}_{4 z} between a carbon atom binding to substituent {X}^{4} and carbon atom of substituent {X}^{4} ) , \qquad Equation 2 B$$

provided that, when each of substituents R^{a} to R^{d} is a hydrogen atom in the definition above, carbon atoms of substituents A^{a} to A^{d} correspond to carbon atoms of substituents R^{a} to R^{d}, respectively, and when substituents X¹ to X⁴ are each a hydrogen atom, the longest end-to-end distances thereof, i.e., L_{3y}, L_{3z}, Lay, and Laz, are each 0.

In the compound represented by Formula (4a), referring to Formula (2), A^{a} to A^{d} may be benzene rings, one R^{a} may be a tert-butyl group, four R^{a}(s) may be hydrogen atoms, two R^{b}(s) may be tert-butyl groups, three R^{b}(s) may be hydrogen atoms, one R^{c} may be a tert-butyl group, four R^{c}(s) may be hydrogen atoms, two R^{d}(s) may be tert-butyl groups, three R^{d}(s) may be hydrogen atoms, one X¹ may be a tert-butyl group, two X¹ (s) may be hydrogen atoms, three X² (s) may be hydrogen atoms, one X³ may be a tert-butyl group, two X³ (s) may be hydrogen atoms, and three X⁴ (s) may be hydrogen atoms. When defining the molecular length L₃ and the molecular length La in the compound of Formula (2), for convenience, the substituents in Formula (4) (i.e., R^{1b} and R^{3b}; R^{1d} and R^{3d}; and R^{2b} and R^{4b}) are used for explanation.

In the compound represented by Formula (4a), the molecular length L₃ in direction D1 is calculated first. The ‘longest end-to-end distance L₃ₓ between a carbon atom of substituent R^{a} and a carbon atom of substituent R^{c}’ in the compound represented by Formula (4a) corresponds to the distance between terminal carbon atoms of the p-tert-butylphenyl group ((x-1) of Group (2X)) in R^{1b} and R^{3b}. As described above, the p-tert-butylphenyl group ((x-1) of Group (2X)) includes a plurality of terminal carbon atoms, and in this regard, the longest distance between the terminal carbon atoms is defined as ‘the longest end-to-end distance L₃ₓ between a carbon atom of substituent R^{a} and a carbon atom of substituent R^{c}’ (wherein L₃ₓ in the compound of Formula (4a) is 23.125 Å).

The compound represented by Formula (4a) may include, in addition to hydrogen atoms, substituent X¹ (e.g., a tert-butyl group). In this regard, subsequently, ‘in a case where substituent X¹ is a group other than a hydrogen atom, the longest end-to-end distance L_{3y} between a carbon atom binding to substituent X¹ and a carbon atom of substituent X¹’ is calculated. In the compound represented by Formula (4a), ‘the longest end-to-end distance L₃y’ corresponds to ‘the longest end-to-end distance between a carbon atom binding to substituent R^{1d} (e.g., a tert-butyl group) and a carbon atom of substituent R^{1d} (e.g., a tert-butyl group)’ (wherein L_{3y} in the compound of Formula (4a) is 2.579 Å). Likewise, the compound represented by Formula (4a) may include, in addition to hydrogen atoms, substituent X³ (e.g., a tert-butyl group). In this regard, subsequently, ‘in a case where substituent X³ is a group other than a hydrogen atom, the longest end-to-end distance L₃z between a carbon atom binding to substituent X³ and a carbon atom of substituent X³’ is calculated. In the compound represented by Formula (4a), ‘the longest end-to-end distance L₃z’ corresponds to ‘the longest end-to-end distance between a carbon atom of substituent R^{3d} and a carbon atom of substituent R^{3d}’ (wherein L₃z in the compound of Formula (4a) is 2.579 Å).

As described above, ‘the longest end-to-end distance L₃ₓ,’ ‘the longest end-to-end distance L_{3y},’ and ‘the longest end-to-end distance L₃₂’ are calculated, and these values are added up to calculate the molecular length L₃ (wherein the sum in the compound of Formula (4a) is 28.3 Å).

Next, in the compound represented by Formula (4a), the molecular length L₄ in direction D2 is calculated. The ‘longest end-to-end distance Lax between a carbon atom of substituent R^{b} and a carbon atom of substituent R^{d}′ in the compound represented by Formula (4a) corresponds to the distance between terminal carbon atoms of the tert-butyl group ((x-2) of Group (2X)) in R^{2b} and R^{4b}. As described above, the (x-2) of Group (2X) includes a plurality of terminal carbon atoms, and in this regard, the longest distance between the terminal carbon atoms is defined as ‘the longest end-to-end distance L₄ₓ between a carbon atom of substituent R_{b} and a carbon atom of substituent R^{d}′ (wherein Lax in the compound of Formula (4a) is 22.971 Å).

The compound represented by Formula (4a) may include, in addition to hydrogen atoms, substituents X² and X⁴. Therefore, ‘the longest end-to-end distance Lay between a carbon atom binding to substituent X² and a carbon atom of substituent X² in a case where substituent X² is a group other than a hydrogen atom’ and ‘the longest end-to-end distance L_{4z} between a carbon atom binding to substituent X⁴ and a carbon atom of substituent X⁴ in a case where substituent X⁴ is a group other than a hydrogen atom’ may be 0.

As described above, ‘the longest end-to-end distance L₄ₓ,’ ‘the longest end-to-end distance L_{4y},’ and ‘the longest end-to-end distance L_{4z}’ are calculated, and these values are added up to calculate the molecular length L₄ (wherein the sum in the compound of Formula (4a) is 23.0 Å).

In an embodiment where the compound of Formula (1) in the disclosure is represented by Formula (3), the molecular length L₁ and the molecular length L₂ correspond to the molecular length L₅ and the molecular length L₆, respectively, and may be defined as follows. In addition, regarding the two-axis directions in the compound represented by Formula 3A and Formula 3B, direction D1 corresponds to the direction connecting substituent R⁵ to substituent R⁷, and direction D2 corresponds to the direction connecting substituent R⁶ to substituent R⁸.

$$Molecular length {L}_{5} = ( longest end - to - end distance {L}_{5 x} between a carbon atom of substituent {R}^{5} and a carbon atom of substituent {R}^{7} ) + ( in a case where substituent {Y}^{1} is a group other than a hydrogen atom , longest end - to - end distance {L}_{5 y} between a carbon atom binding to substituent {Y}^{1} and carbon atom of substituent {Y}^{1} ) + ( in a case where substituent {Y}^{3} is a group other than a hydrogen atom , longest end - to - end distance {L}_{5 z} between a carbon atom binding to substituent {Y}^{3} and carbon atom of substituent {Y}^{3} ) , \qquad Equation 3 A$$

$$Molecular length {L}_{6} = ( longest end - to - end distance {L}_{6 x} between a carbon atom of substituent {R}^{6} and a carbon atom of substituent {R}^{8} ) + ( in a case where substituent {Y}^{2} is a group other than a hydrogen atom , longest end - to - end distance {L}_{6 y} between a carbon atom binding to substituent {Y}^{2} and carbon atom of substituent {Y}^{2} ) + ( in a case where substituent {Y}^{4} is a group other than a hydrogen atom , longest end - to - end distance {L}_{6 z} between a carbon atom binding to substituent {Y}^{4} and carbon atom of substituent {Y}^{4} ) , \qquad Equation 3 B$$

provided that, when each of substituents R⁵ to R⁸ is a hydrogen atom in the definition above, carbon atoms of a benzene ring including substituent R⁵ to R⁸ correspond to carbon atoms of substituent R⁵ to R⁸, respectively, and when substituents Y¹ to Y⁴ are each a hydrogen atom, the longest end-to-end distances thereof, i.e., L₅, L_{5z}, L_{6y}, and L_{6z} are each 0.

In the compound represented by Formula (4a), referring to Formulae (3A) and (3B), one R⁵ may be a tert-butyl group, four R⁵(s) may be hydrogen atoms, two R⁶(s) may be tert-butyl groups, three R⁶(s) may be hydrogen atoms, one R⁷ may be a tert-butyl group, four R⁷(s) may be hydrogen atoms, two R⁸(s) may be tert-butyl groups, three R⁸(s) may be hydrogen atoms, one Y¹ may be a tert-butyl group, two Y¹ (s) may be hydrogen atoms, three Y² (s) may be hydrogen atoms, one Y³ may be a tert-butyl group, two Y³ (s) may be hydrogen atoms, and three Y⁴ (s) may be hydrogen atoms. When defining the molecular length L₅ and the molecular length L₆ in the compound of Formula (3), for convenience, the substituents in Formula (4) (i.e., R^{1b} and R^{3b}; R^{1d} and R^{3d}; and R^{2b} and R^{4b}) are used for explanation.

In the compound represented by Formula (4a), the molecular length L₅ in direction D1 is calculated first. The ‘longest end-to-end distance Lox between a carbon atom of substituent R⁵ and a carbon atom of substituent R⁷’ in the compound represented by Formula (4a) corresponds to the distance between terminal carbon atoms of the p-tert-butylphenyl group ((x-1) of Group (2X)) in R^{1b} and R^{3b}. As described above, the p-tert-butylphenyl group ((x-1) of Group (2X)) includes a plurality of terminal carbon atoms, and in this regard, the longest distance between the terminal carbon atoms is defined as ‘the longest end-to-end distance L₅ₓ between a carbon atom of substituent R⁵ and a carbon atom of substituent R⁷’ (wherein L₅ₓ in the compound of Formula (4a) is 23.125 Å).

The compound represented by Formula (4a) may include, in addition to hydrogen atoms, substituent Y¹ (e.g., a tert-butyl group). In this regard, subsequently, ‘in a case where substituent Y¹ is a group other than a hydrogen atom, the longest end-to-end distance L₅y between a carbon atom binding to substituent Y¹ and a carbon atom of substituent Y¹’ is calculated. In the compound represented by Formula (4a), ‘the longest end-to-end distance L₅y’ corresponds to ‘the longest end-to-end distance between a carbon atom binding to substituent R^{1d} (e.g., a tert-butyl group) and a carbon atom of substituent R^{1d} (e.g., a tert-butyl group)’ (wherein L₅y in the compound of Formula (4a) is 2.57896 Å). Likewise, the compound represented by Formula (4a) may include substituent Y³ (e.g., a tert-butyl group). In this regard, subsequently, ‘in a case where substituent Y³ is a group other than a hydrogen atom, the longest end-to-end distance L₅z between a carbon atom binding to substituent Y³ and a carbon atom of substituent Y³’ is calculated. In the compound represented by Formula (4a), ‘the longest end-to-end distance L₅z’ corresponds to ‘the longest end-to-end distance between a carbon atom of substituent R^{3d} and a carbon atom of substituent R^{3d}’ (wherein L₃z in the compound of Formula (4a) is 2.579 Å).

As described above, ‘the longest end-to-end distance L₅ₓ,’ ‘the longest end-to-end distance L_{5y},’ and ‘the longest end-to-end distance L₅z’ are calculated, and these values are added up to calculate the molecular length L₅ (wherein the sum in the compound of Formula (4a) is 28.3 Å).

Next, in the compound represented by Formula (4a), the molecular length L₆ in direction D2 is calculated. The ‘longest end-to-end distance Lox between a carbon atom of substituent R⁶ and a carbon atom of substituent R⁸’ in the compound represented by Formula (4a) corresponds to the distance between terminal carbon atoms of the tert-butyl group ((x-2) of Group (2X)) in R²⁶ and R^{4b}. As described above, the (x-2) of Group (2X) includes a plurality of terminal carbon atoms, and in this regard, the longest distance between the terminal carbon atoms is defined as ‘the longest end-to-end distance Lox between a carbon atom of substituent R⁶ and a carbon atom of substituent R⁸’ (wherein Lex in the compound of Formula (4a) is 22.971 Å).

The compound represented by Formula (4a) may include, in addition to hydrogen atoms, substituents Y² and Y⁴. Therefore, ‘the longest end-to-end distance Ley between a carbon atom binding to substituent Y² and a carbon atom of substituent Y² in a case where substituent Y² is a group other than a hydrogen atom’ and ‘the longest end-to-end distance Loz between a carbon atom binding to substituent Y⁴ and a carbon atom of substituent Y⁴ in a case where substituent Y⁴ is a group other than a hydrogen atom’ may be 0.

As described above, ‘the longest end-to-end distance Lox,’ ‘the longest end-to-end distance Ley,’ and ‘the longest end-to-end distance Lez’ are calculated, and these values are added up to calculate the molecular length L₆ (wherein the sum in the compound of Formula (4a) is 23.0 Å).

The molecular length L₃ and the molecular length L₄; and the molecular length L₅ and the molecular length L₆; obtained as described above may preferably have the same relationship as the molecular length L₁ and the molecular length L₂. That is, the molecular length L₃ and the molecular length L₄; and the molecular length L₅ and the molecular length L₆ may be 18 Å or more, may be 19 Å or more, preferably may be 20 Å or more, such as 21 Å or more, and most preferably be 22 Å or more. The upper limit of the molecular length L₁ and the molecular length L₂ may preferably be 37 Å or less, 36 Å or less, and preferably be 35 Å or less.

In addition, the product of the molecular length L₃ and the molecular length L₄; and the product of the molecular length L₅ and the molecular length L₆ may preferably be in a range of about 500 Å² to about 1180 Å², more preferably be in a range of about 520 Å² to about 1150 Å², even more preferably be in a range of about 550 Å² to about 1140 Å², particularly preferably be in a range of about 580 Å² to about 1135 Å², and most preferably in a range of about 600 Å² to about 1130 Å².

According to an embodiment, the molecular length L₃ and the molecular length L₄ may be in a range of about 18 Å to about 38 Å, and the product of the molecular length L₃ and the molecular length L₄ may be in a range of about 500 Å² to about 1180 Å². In addition, according to an embodiment, the molecular length L₃ and the molecular length L₄ may be in a range of about 20 Å to about 38 Å, and the product of the molecular length L₃ and the molecular length La may be in a range of about 520 Å² to about 1180 Å². According to an embodiment, the molecular length L₃ and the molecular length La may be in a range of about 21 Å to about 31 Å, and the product of the molecular length L₃ and the molecular length La may be in a range of about 490 Å² to about 650 Å².

According to an embodiment, the molecular length L₅ and the molecular length L₆ may be in a range of about 18 Å to about 38 Å, and the product of the molecular length L₅ and the molecular length L₆ may be in a range of about 500 Å² to about 1180 Å². In addition, according to an embodiment, the molecular length L₅ and the molecular length L₆ may be in a range of about 20 Å to about 38 Å, and the product of the molecular length L₅ and the molecular length L₆ may be in a range of about 520 Å² to about 1180 Å². According to an embodiment, the molecular length L₅ and the molecular length L₆ may be in a range of about 21 Å to about 31 Å, and the product of the molecular length L₅ and the molecular length L₆ may be in a range of about 490 Å² to about 650 Å².

In addition, when calculating the molecular length L₃ and the molecular length L₄; and the molecular length L₅ and the molecular length L₆, the structure of the compound of Formula (2) or Formula (3) of the disclosure utilizes the most stable structure calculated by DFT using a calculation software, Gaussian 16 (Gaussian Inc.). In addition, after calculating the most stable structure by Gaussian 16 (Gaussian Inc.), the molecular lengths (L₃ and L₆) of the compound may be calculated using software such as Gauss View, Chem 3D, IQmol, and the like.

In addition, in an embodiment where the compound of Formula (1) of the disclosure is represented by Formula (4), the molecular length L₁ and the molecular length L₂ correspond to the molecular length L₇ and the molecular length L₈, respectively, as defined by Equations 4A and 4B, respectively.

$$Molecular length {L}_{5} = ( longest end - to - end distance {L}_{5 x} between a carbon atom of substituent {R}^{5} and a carbon atom of substituent {R}^{7} ) + ( in a case where substituent {Y}^{1} is a group other than a hydrogen atom , longest end - to - end distance {L}_{5 y} between a carbon atom binding to substituent {Y}^{1} and carbon atom of substituent {Y}^{1} ) + ( in a case where substituent {Y}^{3} is a group other than a hydrogen atom , longest end - to - end distance {L}_{5 z} between a carbon atom binding to substituent {Y}^{3} and carbon atom of substituent {Y}^{3} ) , \qquad Equation 4 A$$

$$Molecular length {L}_{6} = ( longest end - to - end distance {L}_{6 x} between a carbon atom of substituent {R}^{6} and a carbon atom of substituent {R}^{8} ) + ( in a case where substituent {Y}^{2} is a group other than a hydrogen atom , longest end - to - end distance {L}_{6 y} between a carbon atom binding to substituent {Y}^{2} and carbon atom of substituent {Y}^{2} ) + ( in a case where substituent {Y}^{4} is a group other than a hydrogen atom , longest end - to - end distance {L}_{6 z} between a carbon atom binding to substituent {Y}^{4} and carbon atom of substituent {Y}^{4} ) , \qquad Equation 4 B$$

provided that, when each of substituents R⁵ to R⁸ is a hydrogen atom in the definition above, carbon atoms of a benzene ring including substituent R⁵ to R⁸ correspond to carbon atoms of substituent R⁵ to R⁸, respectively, and when substituents Y¹ to Y⁴ are each a hydrogen atom, the longest end-to-end distances thereof, i.e., L₅, L_{5z}, Ley, and Lez are each 0.

Calculation methods for the molecular length L₇ and the molecular length L₈ may be referred to the calculation methods for the molecular length L₁ and the molecular length L₂.

In addition, when calculating the molecular length L₇ and the molecular length L₈ as described above, the structure of the compound of Formula (3) of the disclosure utilizes the most stable structure calculated by DFT using a calculation software, Gaussian 16 (Gaussian Inc.). In addition, after calculating the most stable structure by Gaussian 16 (Gaussian Inc.), the molecular lengths (L₇ and L₈) of the compound may be calculated using software such as Gauss View, Chem 3D, IQmol, and the like.

Regarding the two-axis directions in the compound represented by Formula (4), direction D1 corresponds to the direction connecting substituents R^{1a} to R^{1d} to substituents R^{3a} to R^{3d}, and direction D2 corresponds to the direction connecting substituents R^{2a} to R^{2d} to substituents R^{4a} to R^{4d}.

The molecular length L₇ and the molecular length L₈ may have the same relationship as the molecular length L₁ and the molecular length L₂. That is, the molecular length L₇ and the molecular length L₈ may be 18 Å or more, 19 Å or more, preferably be 20 Å or more such as 21 Å or more or 22 Å or more. The upper limit of the molecular length L₇ and the molecular length L₈ may preferably be 37 Å or less, 36 Å or less, and preferably be 35 Å or less.

In addition, the product of the molecular length L₇ and the molecular length L₈ may preferably be in a range of about 500 Å² to about 1180 Å², more preferably be in a range of about 520 Å² to about 1150 Å², even more preferably be in a range of about 550 Å² to about 1140 Å², particularly preferably be in a range of about 580 Å² to about 1135 Å², and most preferably be in a range of about 600 Å² to about 1130 Å².

According to an embodiment, the molecular length L₇ and the molecular length L₈ may be in a range of about 18 Å to about 38 Å, and the product of the molecular length L₇ and the molecular length L₈ may be in a range of about 500 Å² to about 1180 Å². In addition, according to an embodiment, the molecular length L₇ and the molecular length La may be in a range of about 20 Å to about 38 Å, and the product of the molecular length L₇ and the molecular length L₈ may be in a range of about 520 Å² to about 1180 Å². According to an embodiment, the molecular length L₇ and the molecular length L₈ may be in a range of about 21 Å to about 31 Å, and the product of the molecular length L₇ and the molecular length L₈ may be in a range of about 490 Å² to about 650 Å².

### Transition Dipole Moment Orientation (TDO)

In an embodiment, the TDO of the compound of the disclosure included in a thin film formed on a substrate may be in a range of about 90% to about 100%. When the TDO of the compound in a thin film is less than 90%, light extraction efficiency may decrease, resulting in a decrease in device efficiency. In addition, the upper limit of the TDO of the compound in a thin film is 100%, but when the TDO of the compound in a thin film is calculated using the relationship of the disclosure, the calculated TDO may exceed 100%. Here, the TDO of the compound is regarded as 100%. According to an embodiment, the TDO of the compound of the disclosure included in a thin film formed on a substrate may exceed 90%. In addition, the TDO of the compound of the disclosure included in a thin film formed on a substrate may be 91% or more, 92% or more, preferably be 93% or more, particularly, 94% or more or 95% or more. The upper limit of the TDO of the compound of the disclosure included in a thin film formed on a substrate is 100%, and may be 100% or less. According to an embodiment, the TDO of the compound of the disclosure included in a thin film formed on a substrate may be, for example, 99% or less or 98% or less. When the TDO of the compound of the disclosure included in a thin film formed on a substrate is within the ranges above, the light extraction efficiency may be further improved by an emission layer including the compound, thereby enabling an organic EL device with improved luminescence efficiency.

In this regard, the TDO of the compound represented by Formula (1) of the disclosure included in a thin film is a value calculated by measuring angle-resolved photoluminescence (PL) by the Luxol OLED analyzer of CoCoLink Corp. Specifically, based on the total mass (100 mass %) of the compound represented by Formula (1) and a host material, 1.5 mass % of the compound represented by Formula (1) and 98.5 mass % of a host may be co-deposited at a vacuum degree of 10.5 Pa on a substrate (e.g., a quartz substrate). Then, for a thin film formed on the substrate at a thickness of 50 nm, angle-resolved PL may be measured at room temperature (25° C.) using the Luxol OLED analyzer. As the host material, Compound H-H1 and Compound H-E1 may be used at a mass ratio of 60:40 (Compound H-H1: Compound H-E1=60:40). Accordingly, the thin film in which the compound represented by Formula (1) is dispersed in the host materials, i.e., Compound H-H1 and Compound H-E1 may be also referred to as a ‘host dispersion film’. That is, the TDO of the compound of Formula (1) is a value representing the orientation state of the compound of Formula (1) in the host dispersion film.

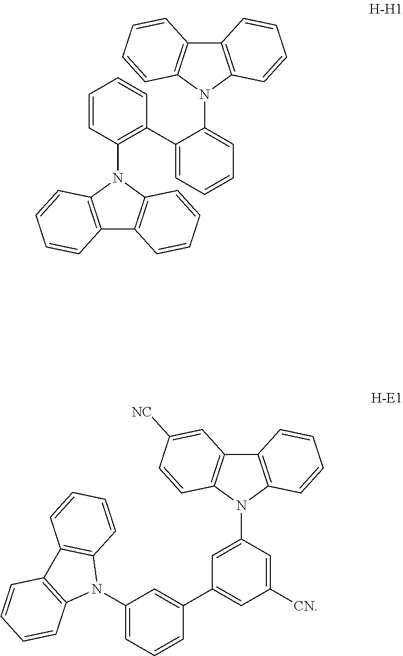 [SMILES: c1ccc(-n2c3ccccc3c3ccccc32)c(-c2ccccc2-n2c3ccccc3c3ccccc32)c1 ; N#Cc1cc(-c2cccc(-n3c4ccccc4c4ccccc43)c2)cc(-n2c3ccccc3c3cc(C#N)ccc32)c1]

The TDO of the compound in the thin film, calculated by measuring angle-resolved PL, may be defined by Equation (i):

$$TDO = ( Px - Py ) / ( Px + Py + Pz ) \qquad ( i )$$

wherein Px, Py, and Pz refer to angle-resolved moment components of the transition dipole moments of the compound included in the thin film, being resolved with respect to the x, y, and z axes, respectively.

Regarding Equation (i), when the transition dipole moment of the compound included in the thin film formed on the substrate is angle-resolved in the x-axis and y-axis directions, which are the plane direction of the substrate, and in the z-axis, which is perpendicular to the substrate, and the moment components each corresponding to the x-axis, y-axis, and z-axis are denoted as Px, Py, and Pz, the sum of squares of these moment components may be derived according to Equation (i). In addition, a detailed description of Equation (i) may be referred to the PHYS. REV. APPLIED 8, 037001 (2017).

When the TDO of the compound included the thin film, calculated according to Equation (i), is 67%, it indicates that the compounds are randomly arranged, and when the TDO of the compound included in the thin film is 100%, it indicates that the compounds are horizontally oriented with respect to the substrate.

### Relationship Between Molecular Length in Two-Axis Directions and TDO

According to the disclosure, compounds having high TDO may be designed and synthesized by calculating the molecular length of compounds from simulation results using the DFT calculation. The inventors of the disclosure have found that the molecular length of the compound represented by Formula (1) correlates with the TDO of the compound (hereinafter referred to as ‘relationship of the disclosure’). In addition, the molecular lengths of the compounds represented by Formula (2) and Formula (3) also correlate with the TDO of the same compounds (i.e., the ‘relationship of the disclosure’ has been shown). In other words, it has been found that, when designing molecules to obtain high-efficiency compounds, compounds with desired TDO may be set by changing the molecular length of the compounds (i.e., the relationship of the disclosure has been shown). Accordingly, by appropriately selecting the molecular length of a compound (depending on types of substituents and substitution positions of substituents) in the compound represented by Formula (1), the TDO may be controlled. As a result, compounds having peak wavelengths in blue wavelength region in the emission spectrum and capable of exhibiting high-efficiency luminescence may optionally be obtained.

Calculation methods for the molecular length L₁ and the molecular length L₂ in the compound of Formula (1) in the relationship of disclosure, the molecular length L₃ and the molecular length L₄ in the compound of Formula (2) in the relationship of disclosure, the molecular length L₅ and the molecular length L₆ in the compound of Formula (3) in the relationship of disclosure, and the molecular length L₇ and the molecular length L₈ in the compound of Formula (4) in the relationship of disclosure are as described above.

According to the correlation of the disclosure based on the calculated molecular lengths L₁ and L₂; the calculated molecular lengths L₃ and L₄; or the calculated molecular lengths L₅ and L₆, the TDO of the compound may be calculated. In detail, based on the product (L₁×L₂) of L₁ and L₂, the product (L₃×L₄) of L₃ and L₄, the product (L₅×L₆) of L₅ and L₆, or the product (L₇×L₈) L₇ and L₈, the predicted TDO (%) may be calculated by comparing the relationship (i.e., the relationship of the disclosure) between the molecular length of the compound and the TDO of the compound. In addition, determining the correlation (relationship of the disclosure) between the molecular length of the compound and the TDO of the compound may be also described. This correlation may be obtained by performing preliminary experiments, in which the molecular length of a compound of interest is varied with respect to TDO of the compound to obtain compounds with various molecular lengths, and then using known regression analysis methods, e.g., ordinary least squares (OLS). Here, the specific expression of the term ‘relation of the disclosure’ obtained by the regression analysis method known in the art is not particularly limited, but this term may be, for example, referred to as linear approximation (linear regression) or polynomial approximation (polynomial regression). In addition, the degree of polynomial approximation (polynomial regression) is not particularly limited, but may be 2 to 5, and preferably be 3 or 4. Such linear approximation and polynomial approximation curve may be obtained by using the ‘Linear approximation’ or ‘Polynomial approximation’ function under the ‘Formatting polynomial approximation’ in the Microsoft Excel (by Microsoft Corporation). In addition, if the ‘relationship of the disclosure’ obtained separately in accordance with these methods is available, it is also possible to implement a manufacturing method according to an embodiment. Here, the manufacturing method according to an embodiment does not include determining the ‘relationship of the disclosure’. The TDO of a target compound may be appropriately set within a range of about 90% to about 100%. For example, the TDO of a target compound may be in a range of about 90% to about 100%.

According to an embodiment, provided is a compound represented by Formula (1):

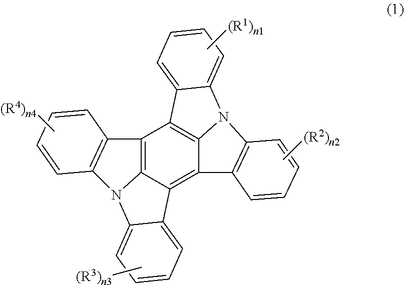

wherein, in Formula (1),
R¹ to R⁴ may each independently be one of the following groups of (1a) to (1d):
(1a) a substituted or unsubstituted C1-C20 alkyl group;
(1b) a substituted or unsubstituted C1-C20 alkoxy group;
(1c) a substituted or unsubstituted aromatic hydrocarbon group; or
(1d) a substituted or unsubstituted heterocyclic group,
n1 to n4 may each independently be 1, 2, 3, or 4, provided that, when n1 is 2 or more, each R¹ may be identical to or different from the others, when n2 is 2 or more, each R² may be identical to or different from the others, when n3 is 2 or more, each R³ may be identical to or different from the others, and when n4 is 2 or more, each R⁴ may be identical to or different from the others, and
the TDO of the compound in a thin film may be in a range of about 90% to about 100%, as calculated by the following equation:

$$TDO = ( Px - Py ) / ( Px + Py + Pz ) \qquad ( i )$$

wherein Px, Py, and Pz refer to angle-resolved moment components of the transition dipole moments of the compound included in the thin film, being resolved with respect to the x, y, and z axes, respectively.

For example, a thin film having a thickness of 50 nm formed on the substrate, by which 1.5 mass % of the compound represented by Formula (1) and 98.5 mass % of the host, based on the total mass of the compound represented by Formula (1) and the host material, are co-deposited at a vacuum degree of 10⁻⁵ Pa on the substrate. For use as the host material, Compound H-H1 and Compound H-E1 may be used at a mass ratio of 60:40 (Compound H-H1: Compound H-E1=60:40).

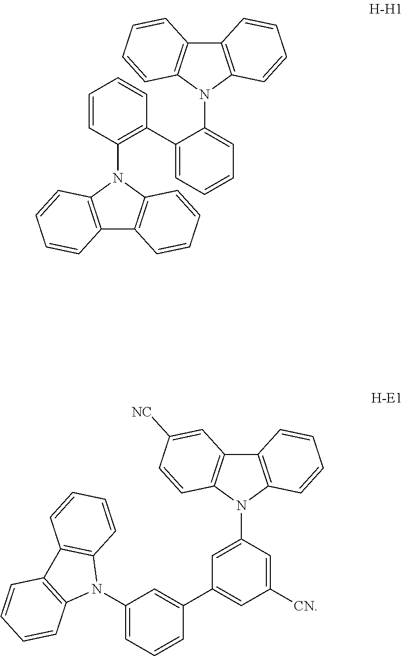 [SMILES: c1ccc(-n2c3ccccc3c3ccccc32)c(-c2ccccc2-n2c3ccccc3c3ccccc32)c1 ; N#Cc1cc(-c2cccc(-n3c4ccccc4c4ccccc43)c2)cc(-n2c3ccccc3c3cc(C#N)ccc32)c1]

In addition, according to an embodiment, provided is a compound represented by Formula (2):

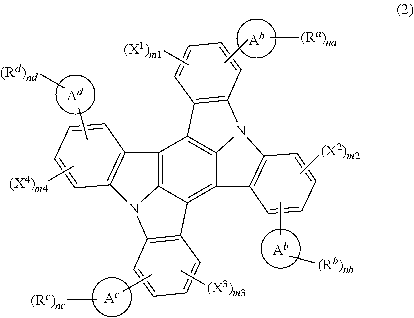

wherein, in Formula (2),
A^{a} to A^{d} may each independently be a benzene ring or a heterocyclic ring,
R^{a} to R^{d} may each independently be a hydrogen atom, an unsubstituted C1-C20 alkyl group, an unsubstituted C1-C20 alkoxy group, an unsubstituted C6-C20 arylamino group, a substituted or unsubstituted aromatic hydrocarbon group, or a substituted or unsubstituted aromatic heterocyclic group,
when A^{a} is a benzene ring, na is 5, and when A^{a} is a heterocyclic ring, na is an upper limit of possible number of substitution with A^{a},
when A^{b} is a benzene ring, nb is 5, and when A^{b} is a heterocyclic ring, nb is an upper limit of possible number of substitution with A^{b},
when A^{c} is a benzene ring, nc is 5, and when A^{c} is a heterocyclic ring, nc is an upper limit of possible number of substitution with A^{c},
when A^{d} is a benzene ring, nd is 5, and when A^{d} is a heterocyclic ring, nd is an upper limit of possible number of substitution with A^{d},
X¹ to X⁴ may each independently be a hydrogen atom, an unsubstituted C1-C20 alkyl group, an unsubstituted C1-C20 alkoxy group, or a substituted or unsubstituted aromatic hydrocarbon group,
m1 to m4 may be 3, and
the TDO of the compound in a thin film may be in a range of about 90% to about 100%, as calculated by the following equation:

$$TDO = ( Px - Py ) / ( Px + Py + Pz ) \qquad ( i )$$

wherein Px, Py, and Pz refer to angle-resolved moment components of the transition dipole moments of the compound included in the thin film, being resolved with respect to the x, y, and z axes, respectively.

For example, a thin film having a thickness of 50 nm formed on the substrate, by which 1.5 mass % of the compound represented by Formula (2) and 98.5 mass % of the host, based on the total mass of the compound represented by Formula (2) and the host material, are co-deposited at a vacuum degree of 10⁻⁵ Pa on the substrate. For use as the host material, Compound H-H1 and Compound H-E1 may be used at a mass ratio of 60:40 (Compound H-H1: Compound H-E1=60:40).

In addition, according to an embodiment, provided is a compound represented by Formula (3):

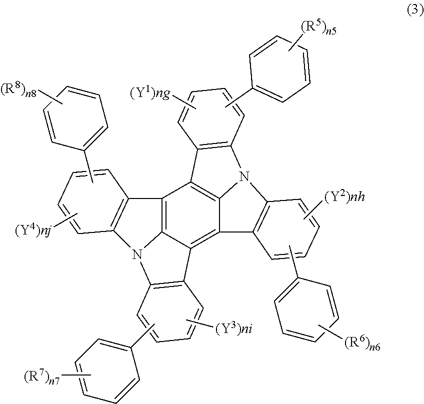

wherein, in Formula (3),
R⁵ to R⁸ may each independently be a hydrogen atom, an unsubstituted C1-C20 alkyl group, an unsubstituted C1-C20 alkoxy group, a substituted or unsubstituted aromatic hydrocarbon group, or a substituted or unsubstituted aromatic heterocyclic group,
n5 to n8 may be 5,
Y¹ to Y⁴ may each independently be a hydrogen atom, an unsubstituted C1-C20 alkyl group, an unsubstituted C1-C20 alkoxy group, or a substituted or unsubstituted aromatic hydrocarbon group,
ng to nj may be 3, and
the TDO of the compound in a thin film may be in a range of about 90% to about 100%, as calculated by the following equation:

$$TDO = ( Px - Py ) / ( Px + Py + Pz ) \qquad ( i )$$

wherein Px, Py, and Pz refer to angle-resolved moment components of the transition dipole moments of the compound included in the thin film, being resolved with respect to the x, y, and z axes, respectively.

For example, a thin film having a thickness of 50 nm formed on the substrate, by which 1.5 mass % of the compound represented by Formula (3) and 98.5 mass % of the host, based on the total mass of the compound represented by Formula (3) and the host material, are co-deposited at a vacuum degree of 10⁻⁵ Pa on the substrate. For use as the host material, Compound H-H1 and Compound H-E1 may be used at a mass ratio of 60:40 (Compound H-H1: Compound H-E1=60:40).

In addition, according to an embodiment, provided is a compound represented by Formula (4):

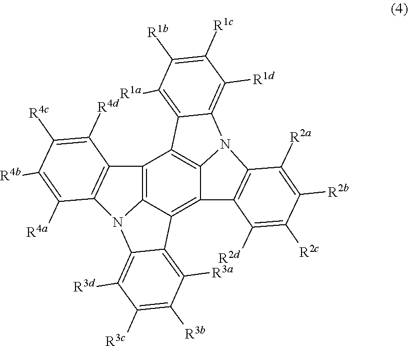

wherein, in Formula (4),
R^{1a} to R^{1d}, R^{2a} to R^{2d}, R^{3a} to R^{3d}, and R^{4a} to R^{4d} may each independently be a hydrogen atom or a group selected from Group (1X):

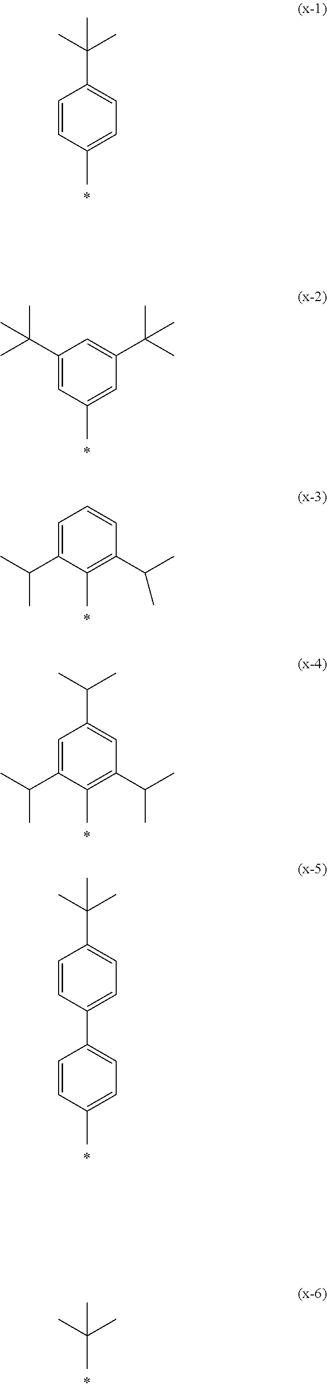

wherein at least one of R^{1a} to R^{1d}, at least one of R^{2a} to R^{2d}, at least one of R^{3a} to R^{3d}, and at least one of R^{4a} to R^{4d} may be groups selected from Group (1X) (in addition, * in Group (1X) indicates a binding site), and
the TDO of the compound in a thin film may be in a range of about 90% to about 100%, as calculated by the following equation:

$$TDO = ( Px - Py ) / ( Px + Py + Pz ) \qquad ( i )$$

wherein Px, Py, and Pz refer to angle-resolved moment components of the transition dipole moments of the compound included in the thin film, being resolved with respect to the x, y, and z axes, respectively.

For example, a thin film having a thickness of 50 nm formed on the substrate, by which 1.5 mass % of the compound represented by Formula (4) and 98.5 mass % of the host, based on the total mass of the compound represented by Formula (4) and the host material, are co-deposited at a vacuum degree of 10⁻⁵ Pa on the substrate. For use as the host material, Compound H-H1 and Compound H-E1 may be used at a mass ratio of 60:40 (Compound H-H1: Compound H-E1=60:40).

Hereinafter, the compound of Formula (1) 1 according to an embodiment may be exemplified as follows, but the disclosure is not limited thereto. For example, the compound of Formula (1) according to an embodiment may include Compounds (101) to (141):

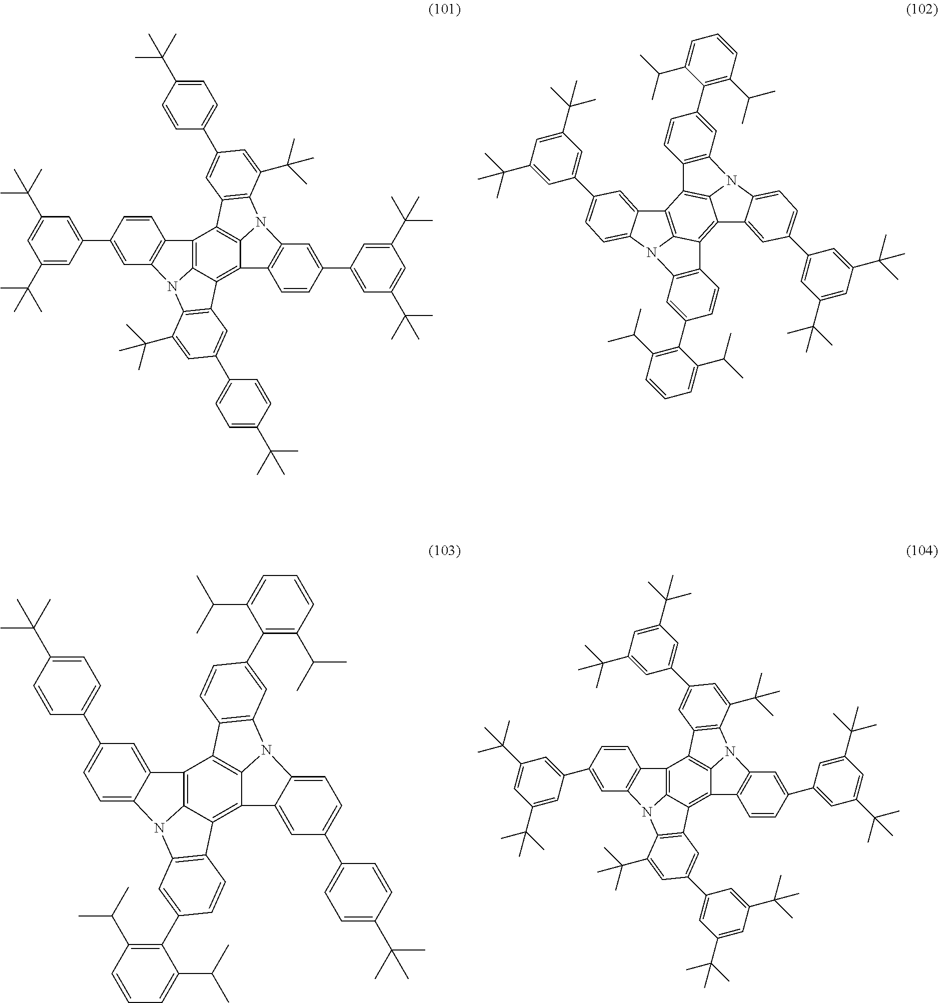

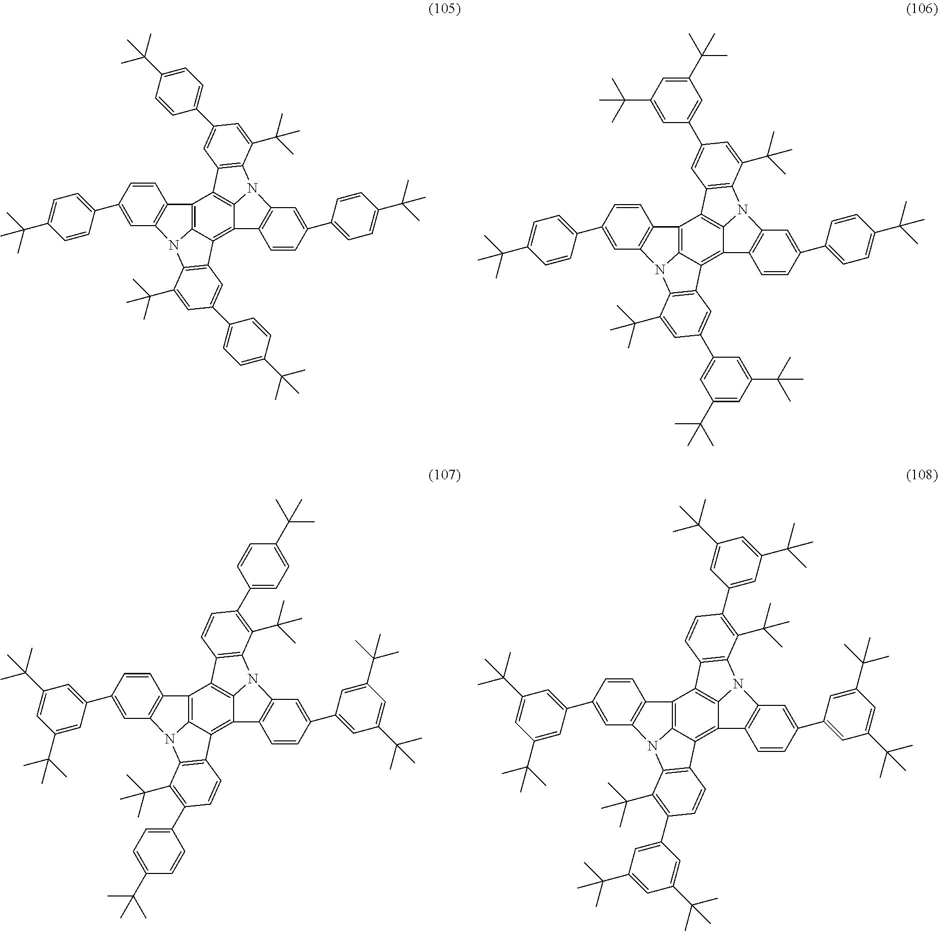

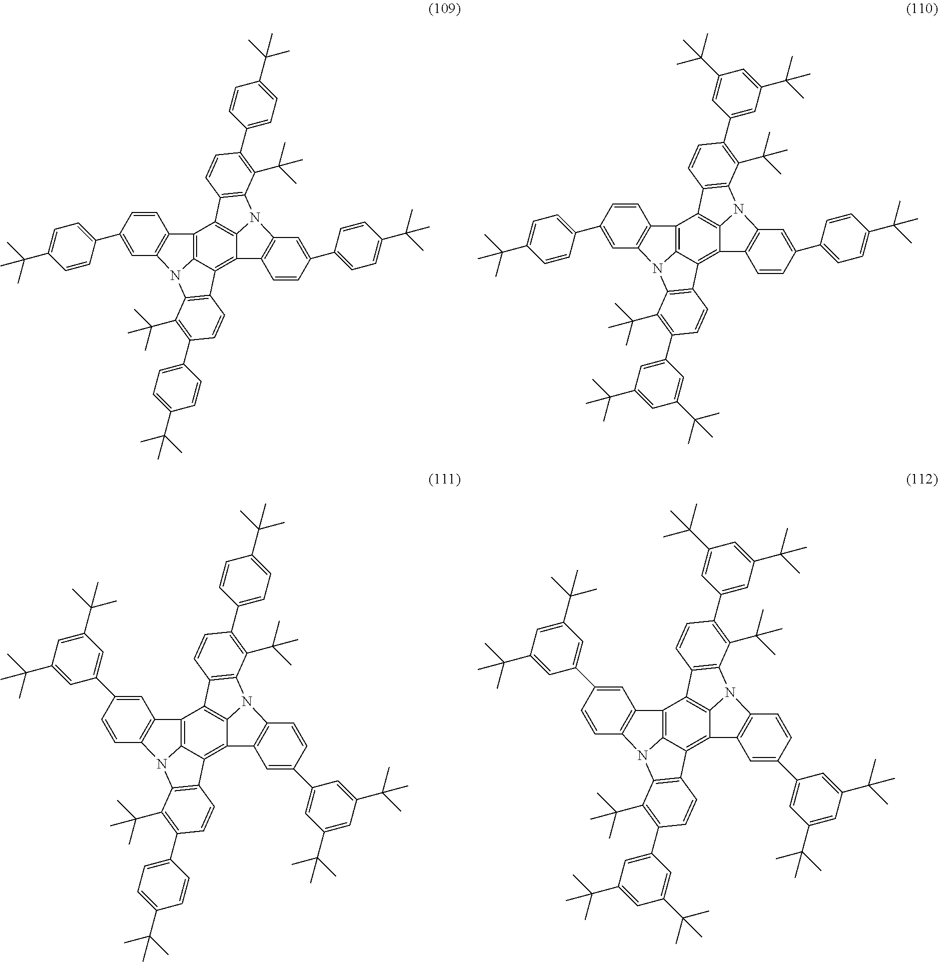

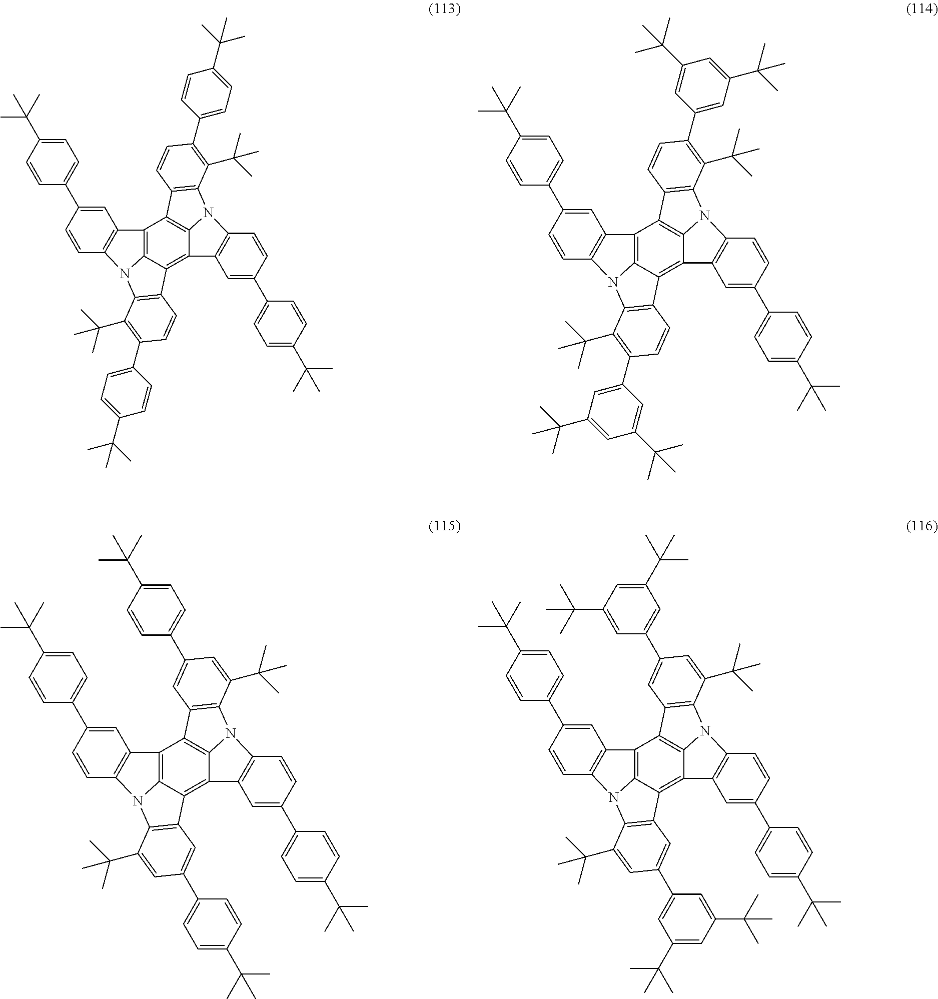

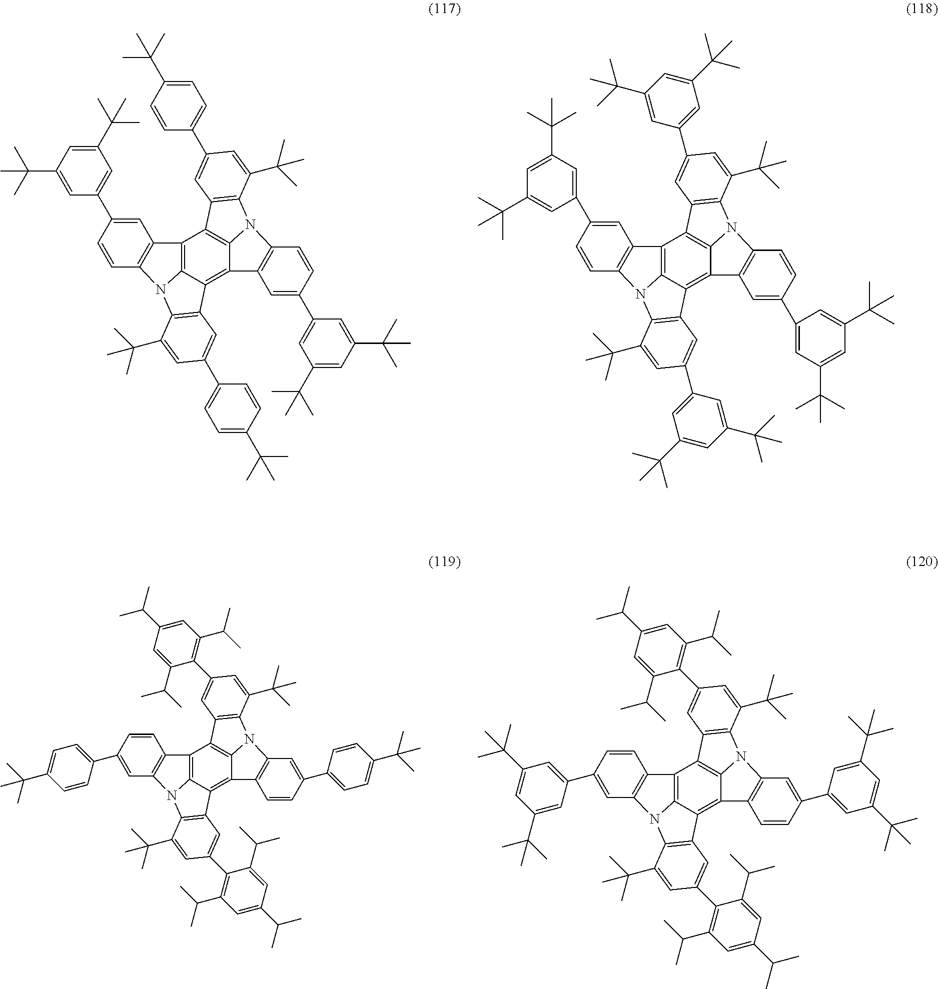

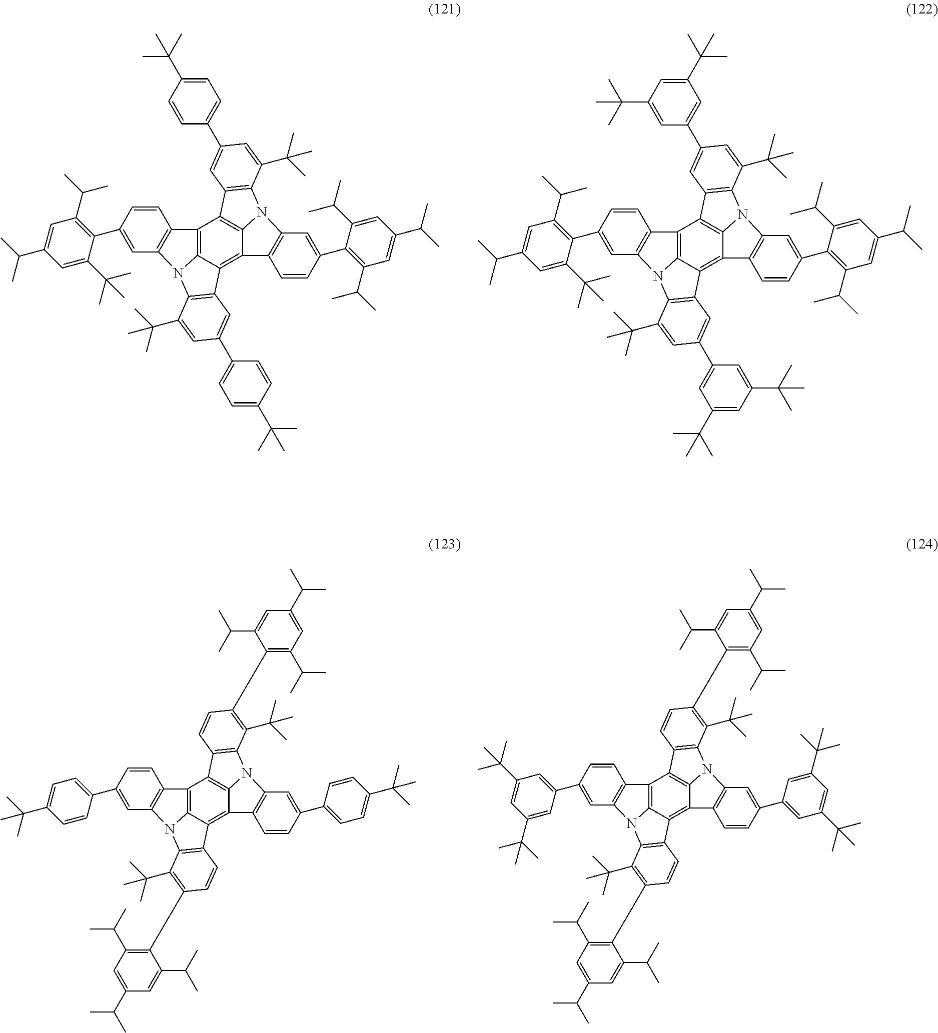

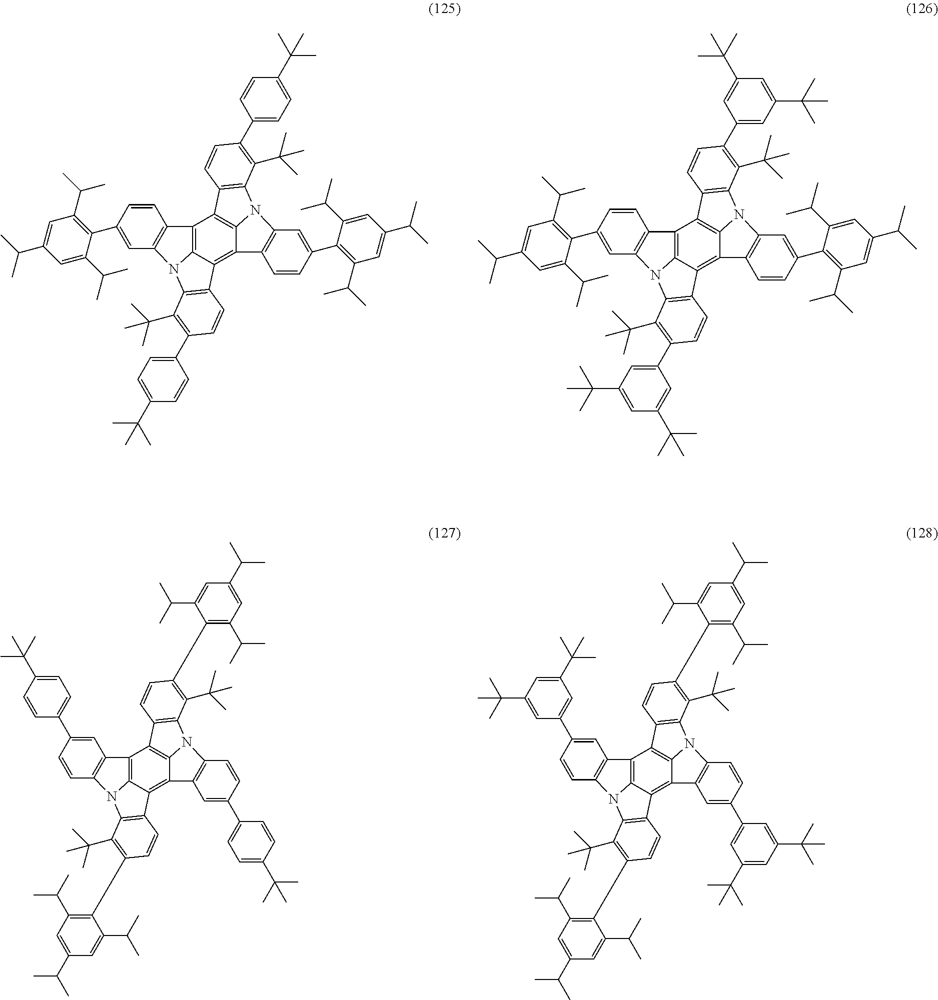

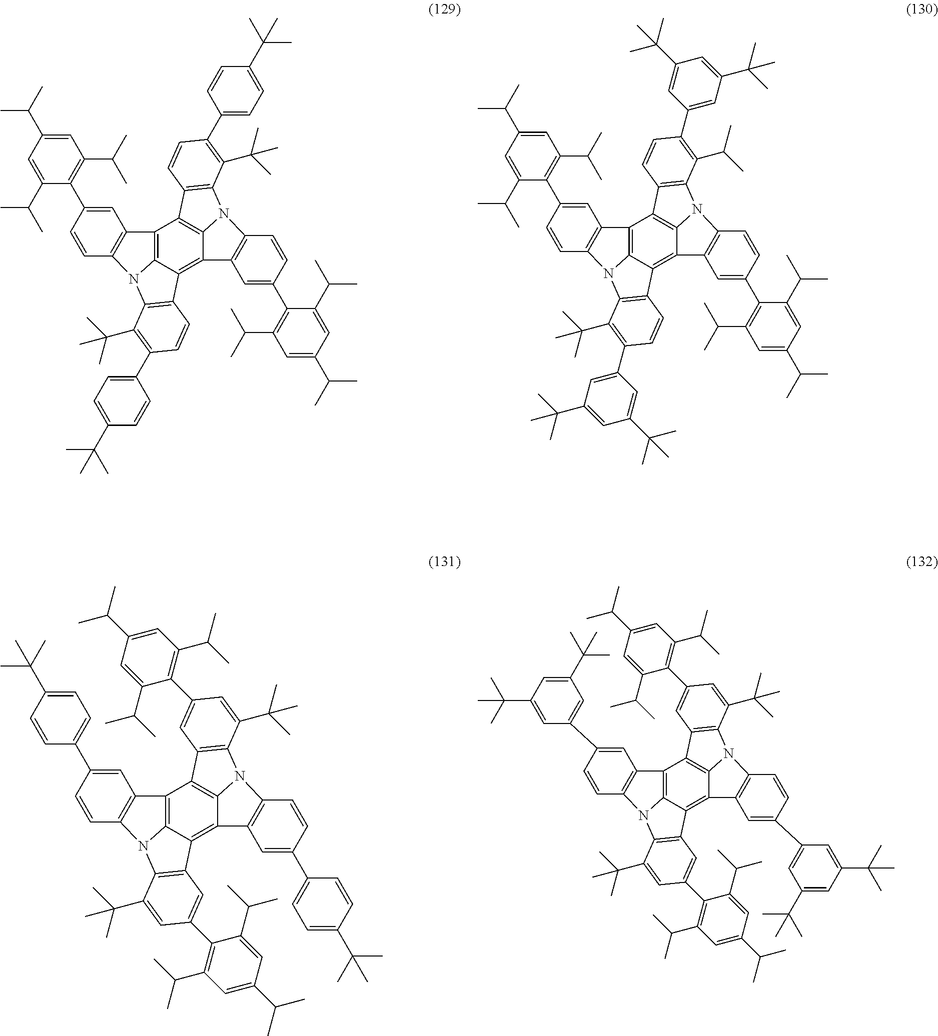

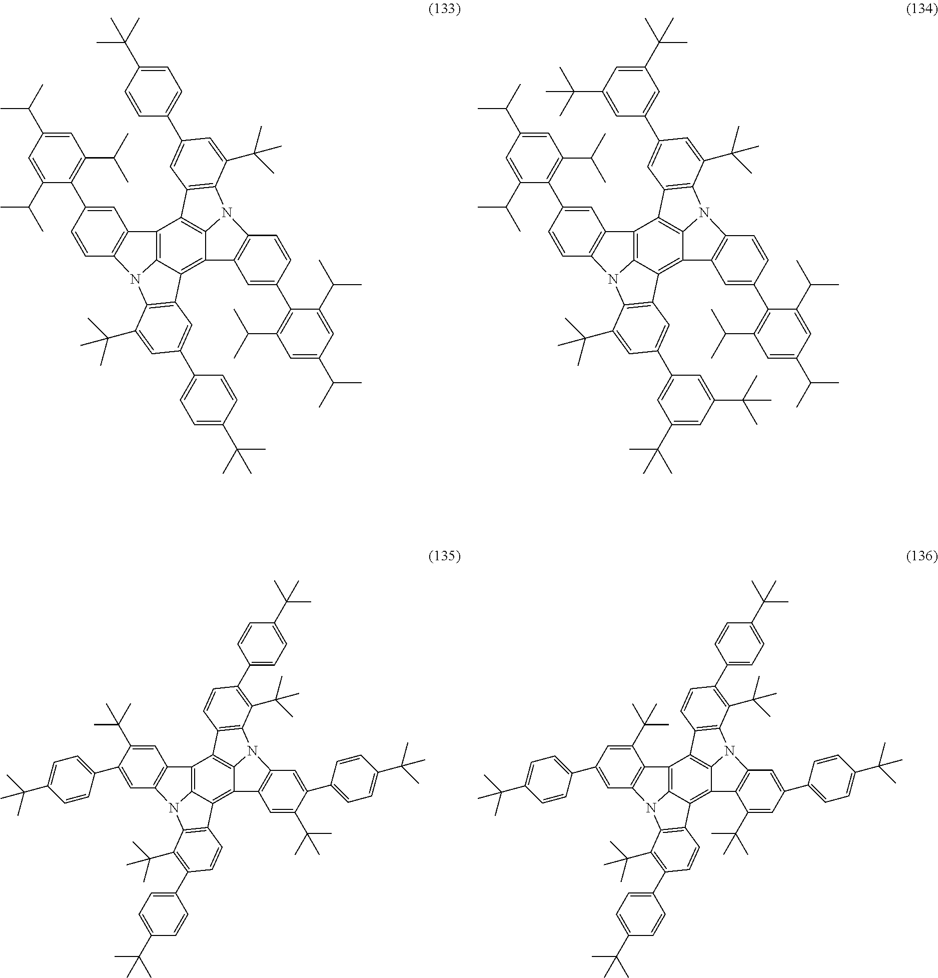

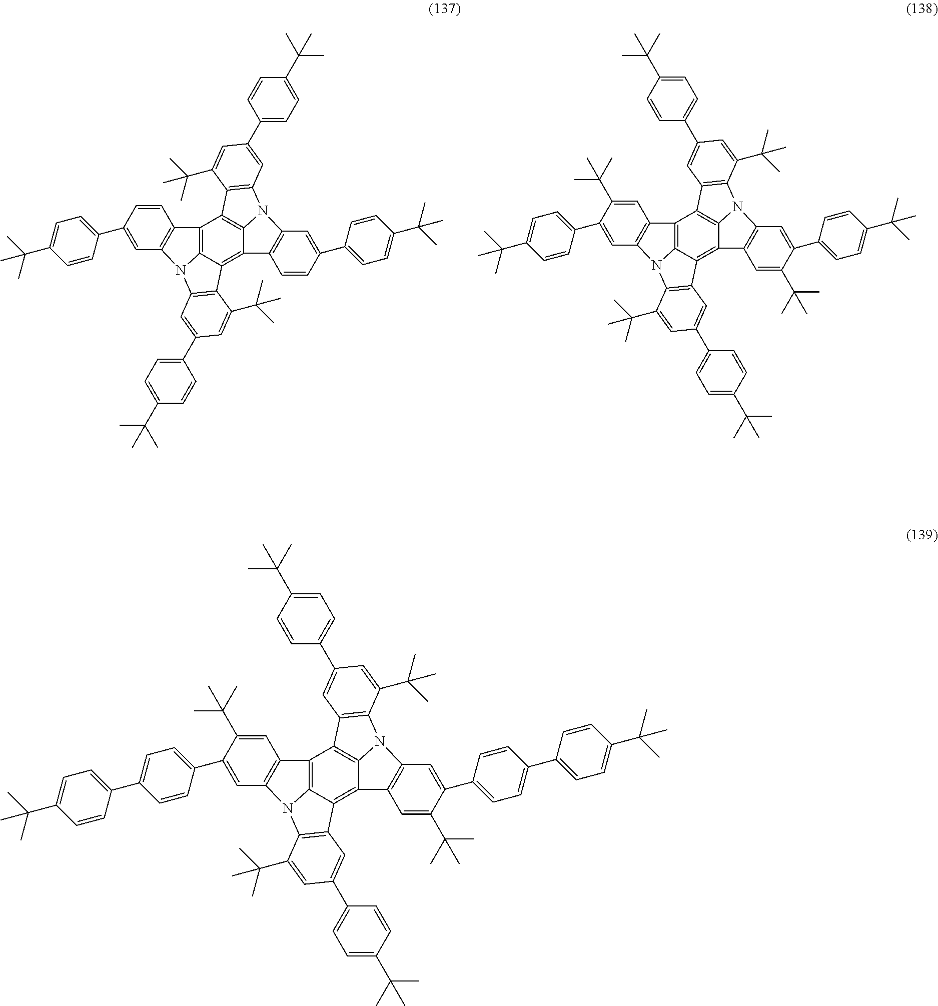

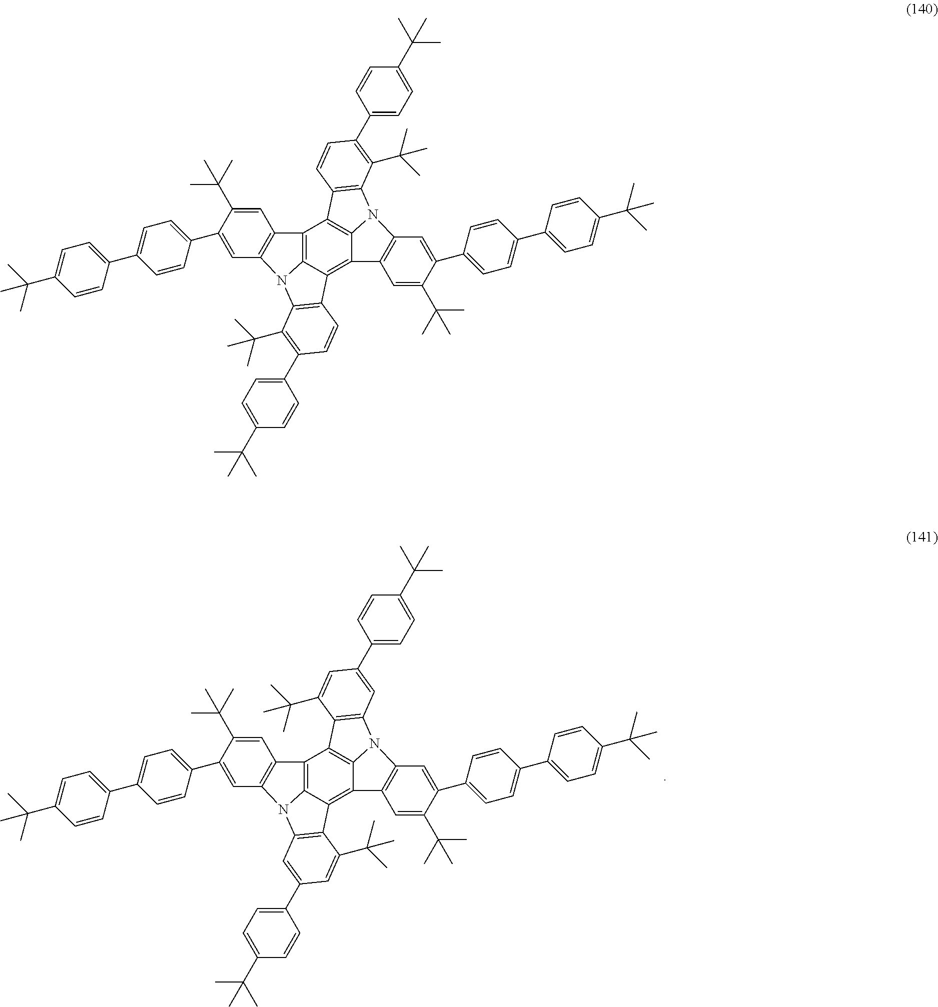

Preferred compound may include, for example, Compounds 101, 105, 110, 119, 135, 136, 140, and the like.

### Luminescence Characteristics

The compound of formula (1) according to an embodiment may implement luminescence in which a peak wavelength in an emission spectrum is within a blue wavelength region and which is high-purity. In addition, the term “blue wavelength region” used in the present specification refers to the wavelength in a range of about 400 nm to about 500 nm. A peak wavelength of luminescence in PL of the compound of Formula (1) in the disclosure is not particularly limited, but may preferably be in a range of about 440 nm to about 480 nm. In addition, the peak wavelength of light emitted may have a peak preferably in a wavelength region of about 445 nm to about 470 nm, in a wavelength region of about 450 nm to about 470 nm, and preferably in a wavelength region of about 450 nm to about 465 nm. When the peak wavelength is within the above range, excellent luminescence, particularly, excellent blue luminescence may be obtained. In addition, the peak wavelength of luminescence in PL may be measured using the F-7000 spectrophotometer manufactured by Hitach High-Tech, Ltd. More specifically, a thin film, which is formed using a toluene solution containing the compound of Formula (1) at a concentration of 1×10⁻⁵M (=mol/dm³, mol/L) or formed by deposition of the compound of Formula (1) and a host molecule according to methods described Examples below, may be evaluated by measuring at room temperature using a spectrophotometer with an excitation wavelength of 360 nm.

### Manufacturing Method

Synthesis methods of the compound of Formula (1) in the disclosure are not particularly limited, and may be achieved based on known synthetic methods. For example, the compound may be synthesized by methods described in Examples below or methods similar to the methods described in Examples below. For example, synthesis may be achieved by modifying raw materials or reaction conditions from those described in Examples, adding or omitting certain steps, or appropriately combining known synthesis methods.

A method of confirming the structure of the compound of Formula (1) in the disclosure is not particularly limited. The structure of the compound of Formula (1) in the disclosure may be, for example, confirmed by known methods (e.g., NMR, LC-MS, etc.).

### Materials for Organic EL Device

According to another embodiment, a material for an organic EL device includes the compound of Formula (1). The material may preferably be a material for an emission layer.

The material for an organic EL device according to an embodiment may preferably include the compound of Formula (1) and other materials used in an organic EL device. The other materials used in an organic EL device are not particularly limited, but may preferably be a phosphorescent material or a host material, and more preferably be a phosphorescent complex and a host material. Here, it is preferable to use the compound of Formula (1) as a dopant material and the phosphorescent complex as an auxiliary dopant material. When the compound of Formula (1) is used together with a phosphorescent material or a host material (preferably, a phosphorescent complex and a host material), the luminescence efficiency may be significantly improved, and the reasons for this are presumed as follows. When the material for an organic EL device includes a host material, a phosphorescent material may receive energy from the host material. Then, the phosphorescent material may transfer energy to the compound of Formula (1) via a fluorescence resonance energy transfer (FRET) mechanism. As a result, high-efficiency energy transfer to the compound of Formula (1) occurs in the phosphorescent material. In addition, the other materials used in an organic EL device may be materials known in the art other than the present field of the disclosure.

An amount of the compound of Formula (1) with respect to the total mass of the material for an organic EL device (particularly, a material for an emission layer) is not particularly limited, but may preferably be 0.05 mass % or more. In addition, the amount may more preferably be 0.1 mass % or more, and even more preferably be 0.2 mass % or more. Within the ranges above, an organic EL device having excellent color purity of luminescence and according having high luminescence efficiency may be obtained. In addition, the amount of the compound of Formula (1) with respect to the total mass of the material for an organic EL device (particularly, a material for an emission layer) is not particularly limited, but may preferably be 50 mass % or less. In addition, the amount may more preferably be 30 mass % or less, and even more preferably be 25 mass % or less. Within the ranges above, an organic EL device having excellent color purity of luminescence and according having high luminescence efficiency may be obtained. In addition, in an emission layer of an organic EL device described below, the preferable amount of the compound of Formula (1) with respect to the emission layer may be the same as described above.

### Phosphorescent Complex

The material for an organic EL device according to an embodiment may preferably include a phosphorescent complex in addition to the compound of Formula (1). The inclusion of the phosphorescent complex may significantly improve the luminescence efficiency. The use of the compound of Formula (1) and the phosphorescent complex together may significantly improve the luminescence efficiency. The phosphorescent material may transfer energy to the compound of Formula (1) via a fluorescence resonance energy transfer (FRET) mechanism. As a result, high-efficiency energy transfer to the phosphorescent complex to the nitrogen-containing condensed compound occurs. As such, it is presumed that the effect is exhibited because the phosphorescent complex enables high efficiency energy transfer to the compound of Formula (1).

The phosphorescent complex is not particularly limited, but may preferably be a metal complex in terms of luminescence efficiency. From the same perspective, the metal complex may preferably be a platinum complex or a palladium complex, and more preferably a platinum complex. Therefore, a material for an organic EL device according to an embodiment may be, for example, the phosphorescent complex or the platinum complex.

The phosphorescent complex is not particularly limited, but may preferably be a compound having a structure of Formula (5) in terms of color purity of luminescence and luminescence efficiency:

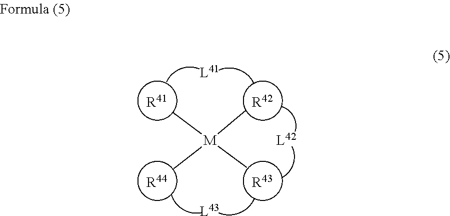

wherein, in Formula (5), M is a metal ion with a valence of 4,
R⁴¹, R⁴², R⁴³, and R⁴⁴ may each independently be a substituted or unsubstituted cyclic hydrocarbon group or a substituted or unsubstituted heterocyclic group,
L⁴¹ may be a linking group linking R⁴¹ and R⁴²
L⁴² may be a linking group linking R⁴² and R⁴³, and
L⁴³ may be a linking group linking R⁴³ and R⁴⁴.

In Formula (5), the cyclic hydrocarbon group refers to a group derived from one or more hydrocarbon rings. When the cyclic hydrocarbon group includes two or more hydrocarbon rings, these rings may be bonded or condensed to each other via single bonds in part or in whole. In addition, when the cyclic hydrocarbon group includes two or more hydrocarbon rings, one atom may also serve as a ring-forming atom of any of these rings.

In Formula (5), except for the fact that the valence may be different, the heterocyclic group may be the same as the monovalent heterocyclic group described in the group of (1d) in Formula (1).

A substituent substituting the cyclic hydrocarbon group or the heterocyclic group in Formula (5) is not particularly limited, but may preferably be a substituent substituting the groups of (1a) to (1d) in Formula (1).

In Formula (5), M may preferably be a platinum (Pt) ion or a palladium (Pd) ion, and more preferably be a platinum (Pt) ion.

For use as the phosphorescent complex, a compound known in the art may be used. For example, the platinum complex described in ‘Tyler Fleetham et al., ‘Efficient “Pure” Blue OLEDs Employing Tetradentate Pt Complexes with a Narrow Spectral Bandwidth’, Advanced Materials, 2014, 26, 7116-7121’, the platinum complex described in the specification of EP 3670520, the platinum complex and the palladium complex described in JP 2019-029500, and the platinum complex described in the specification of US 2015/0162552 may be used.

Hereinafter, the phosphorescent complex according to an embodiment may be exemplified as follows, but the disclosure is not limited thereto:

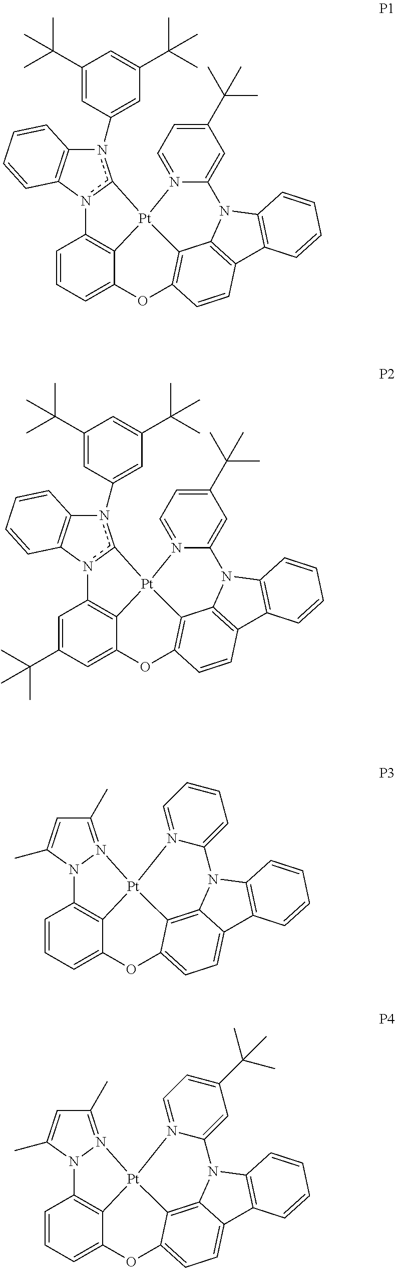

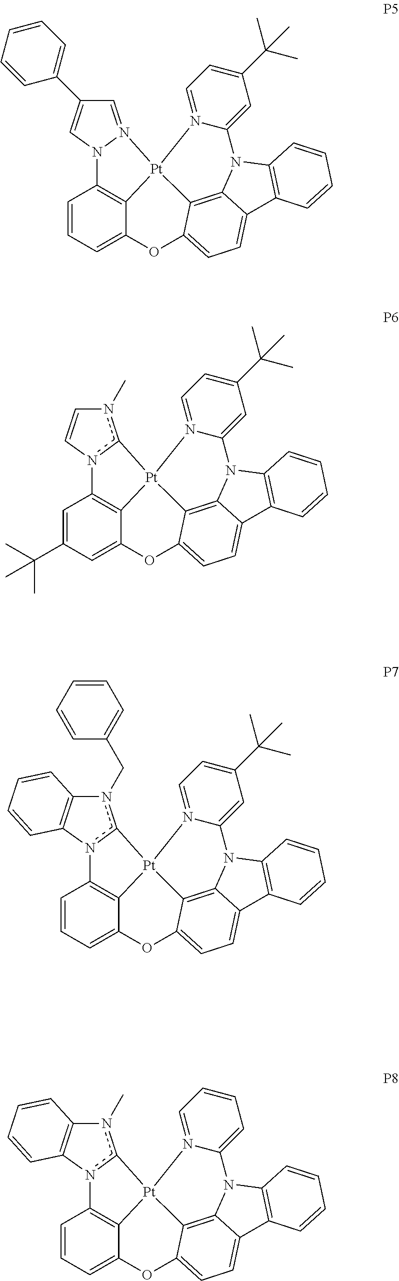

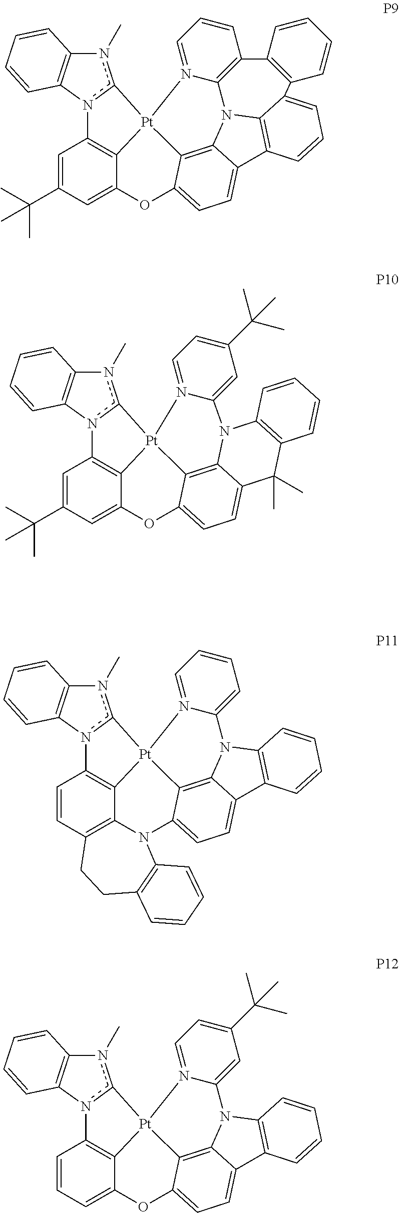

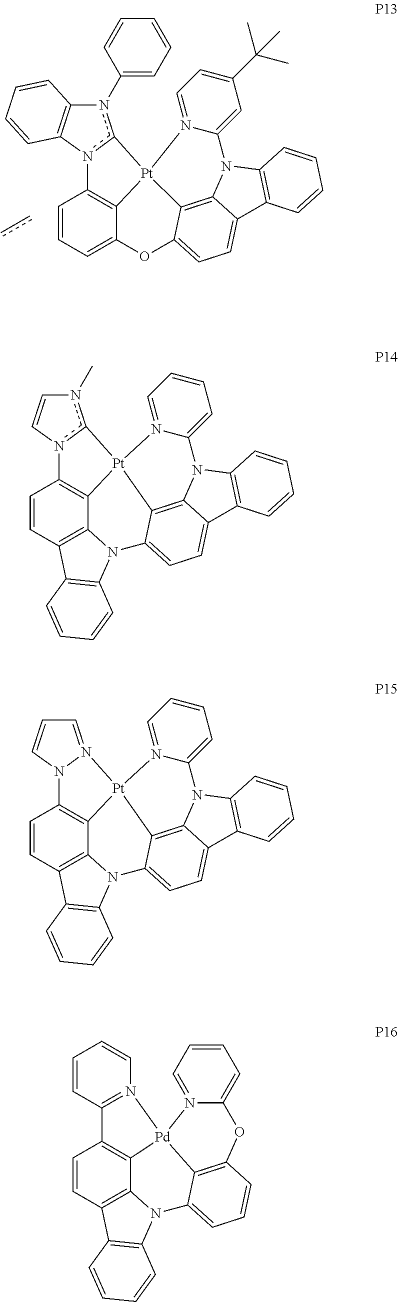

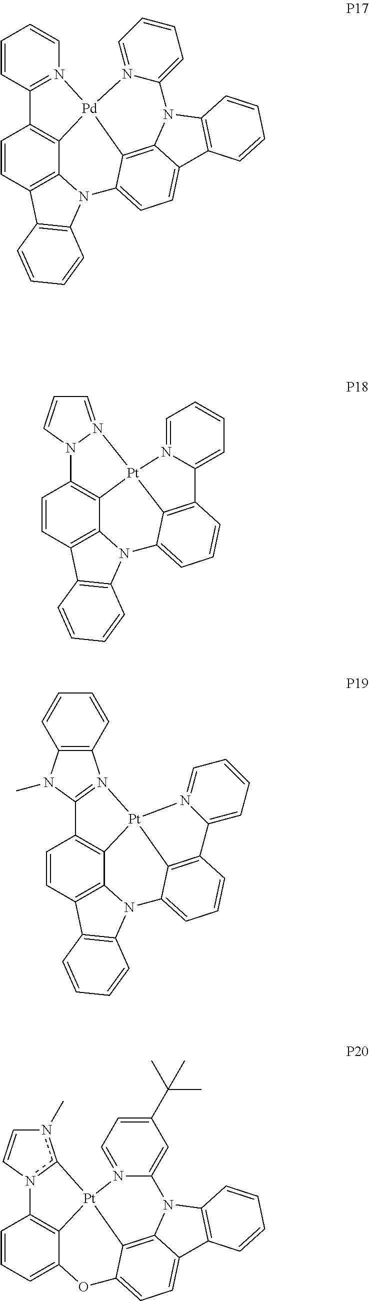

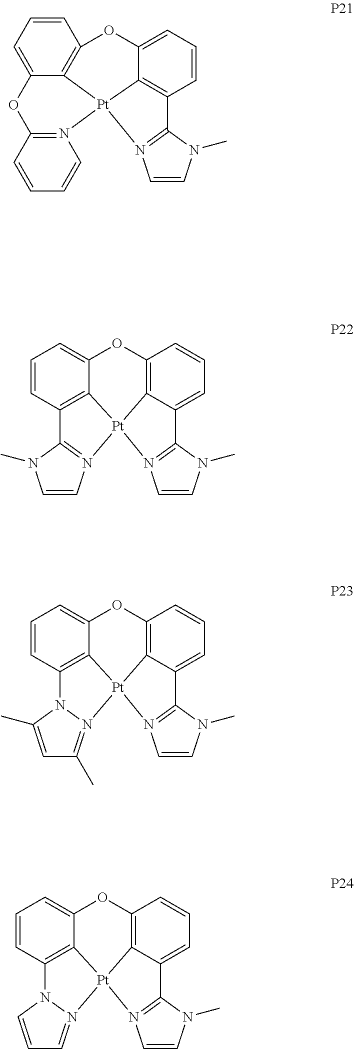

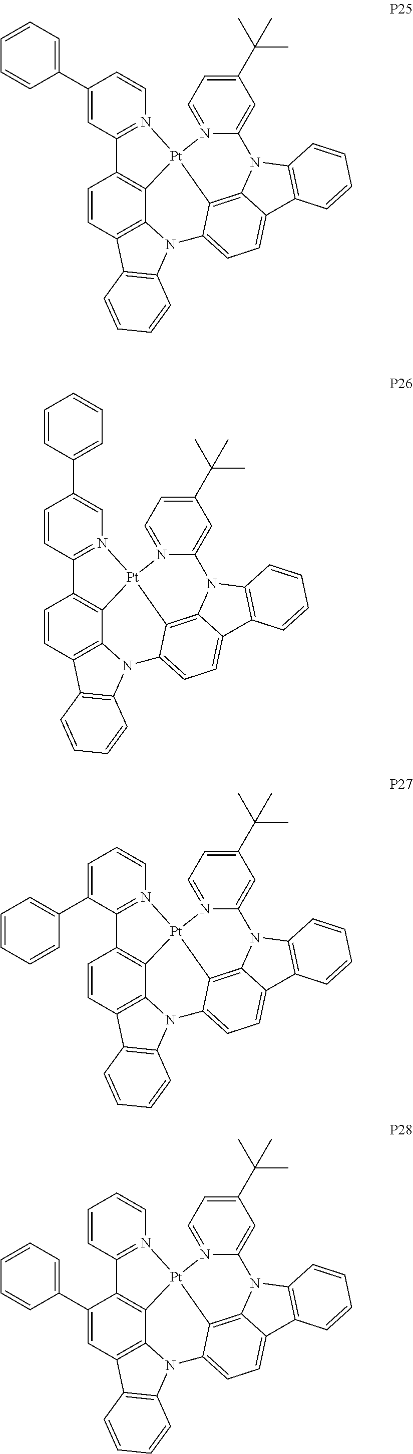

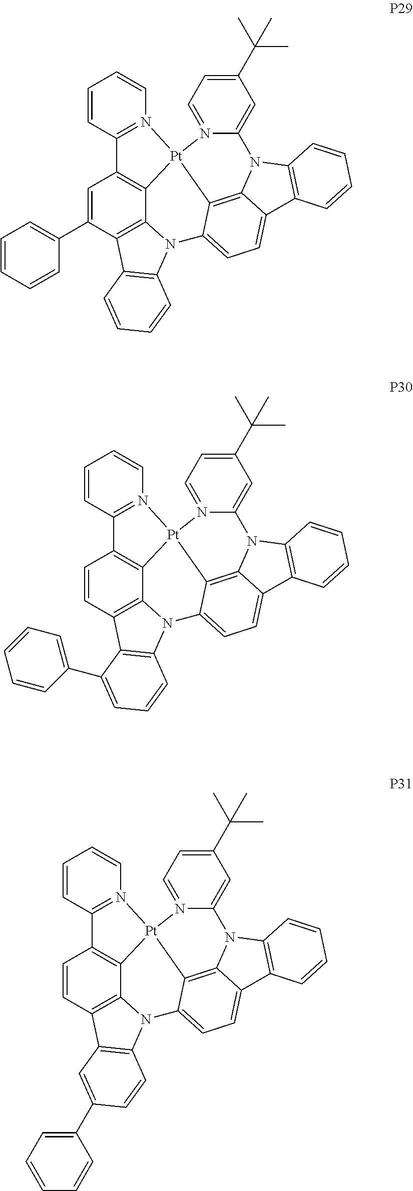

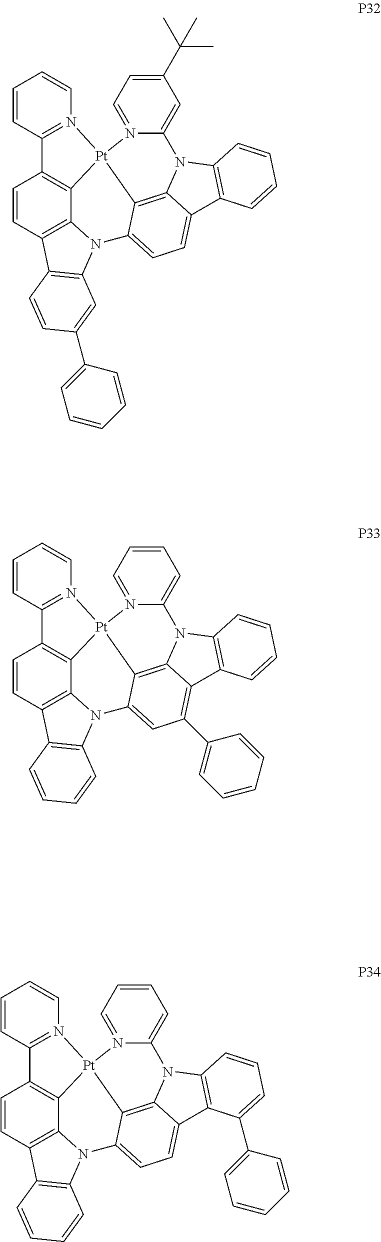

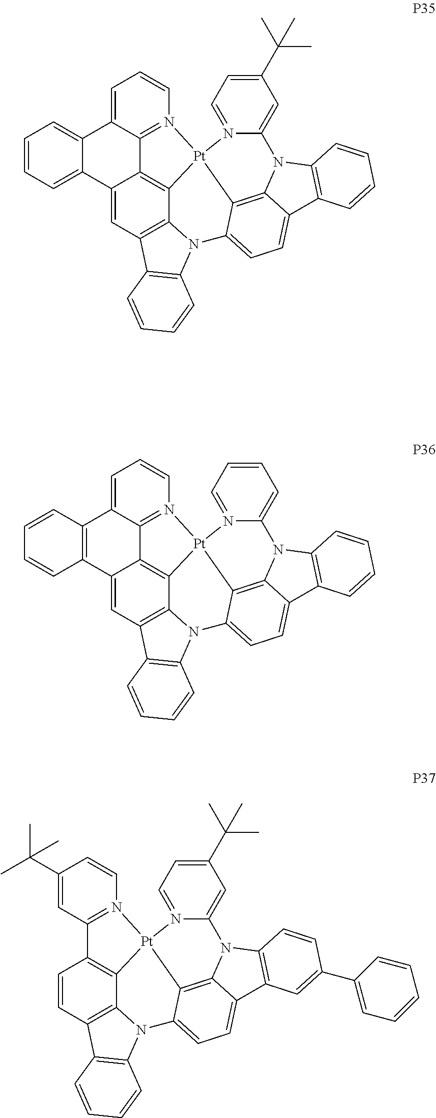

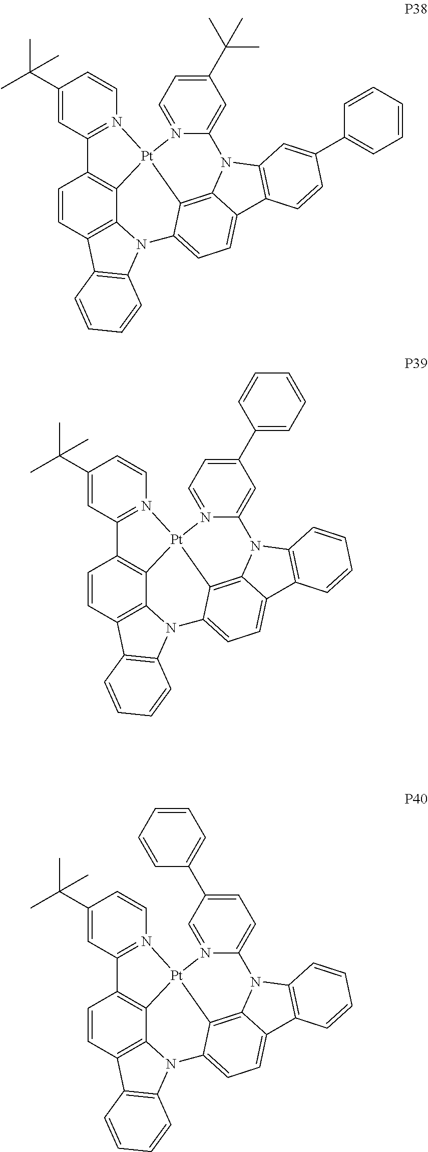

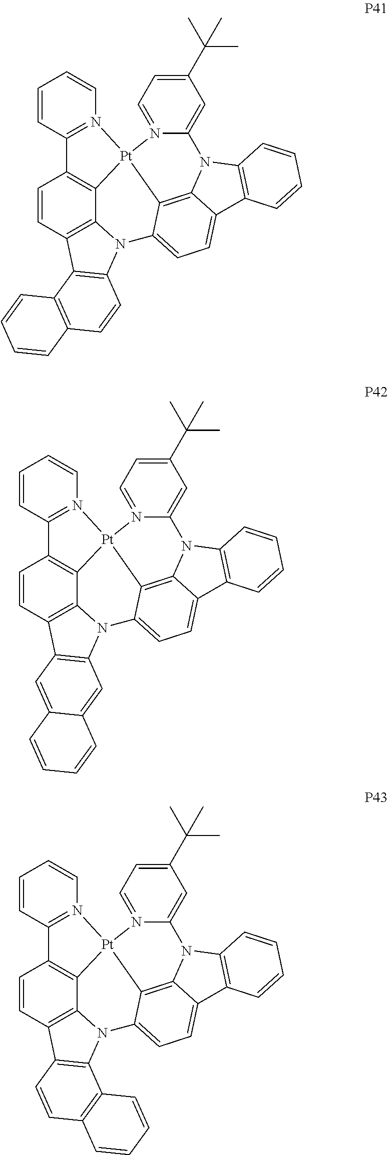

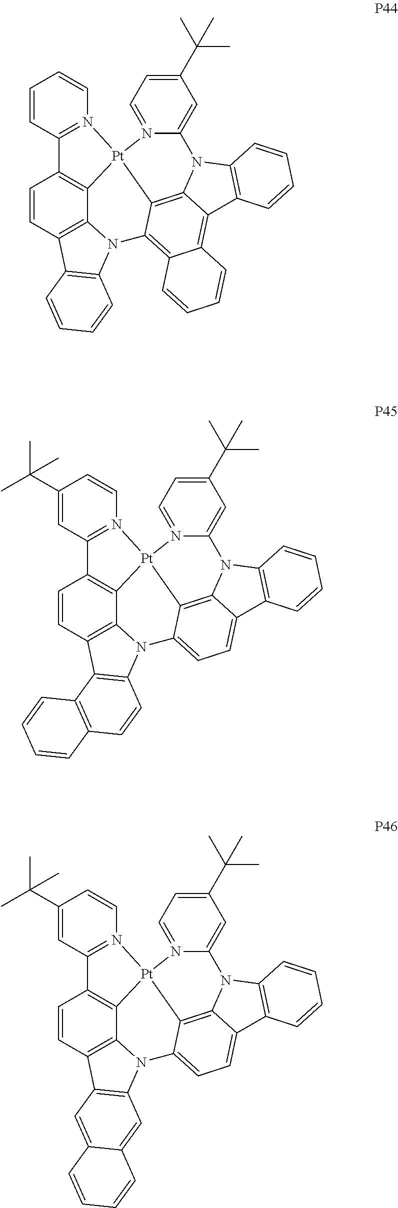

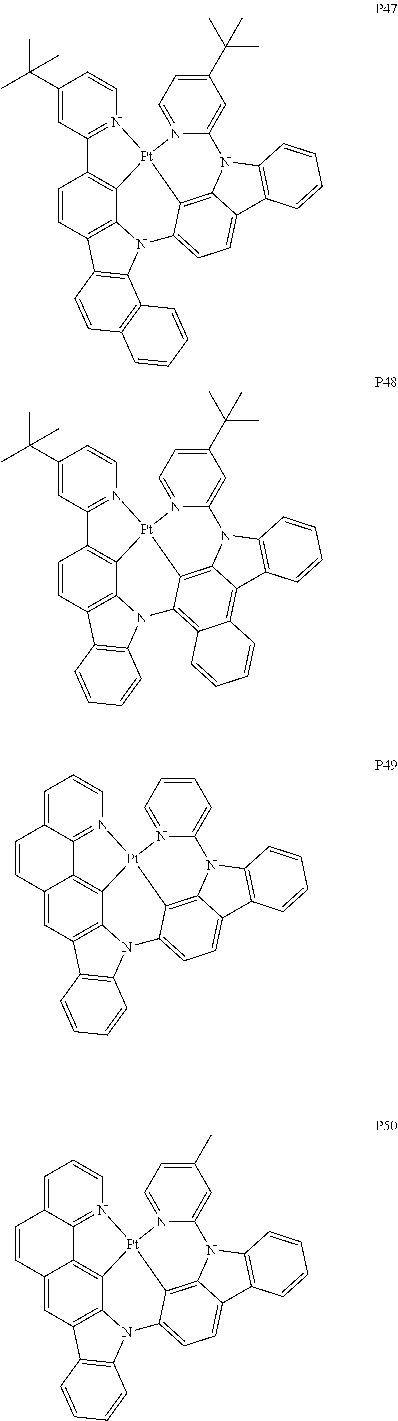

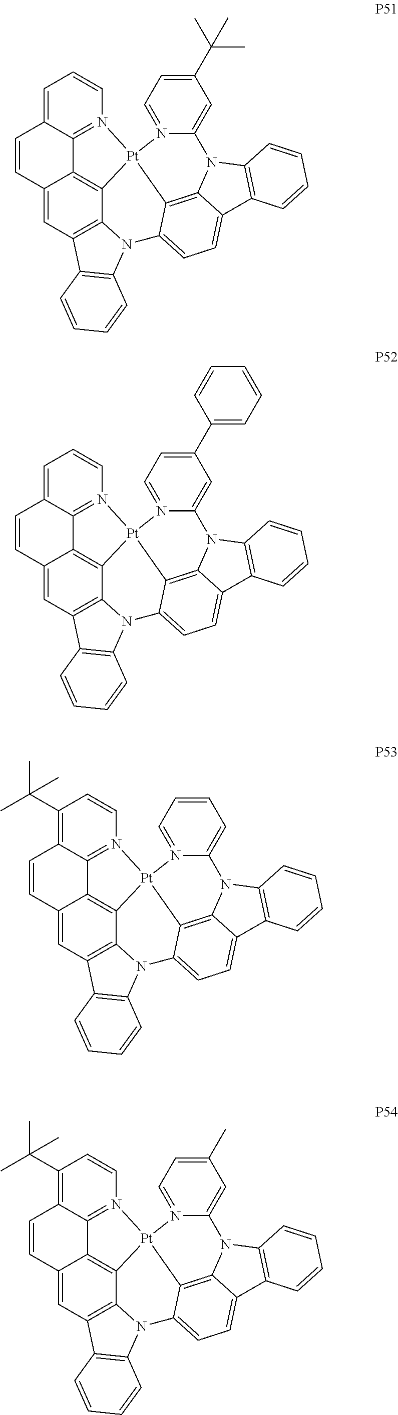

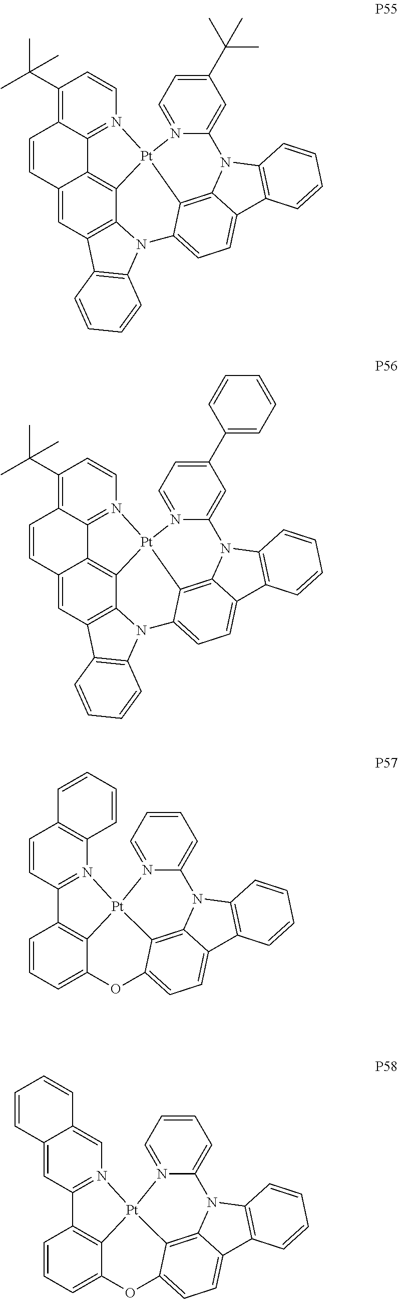

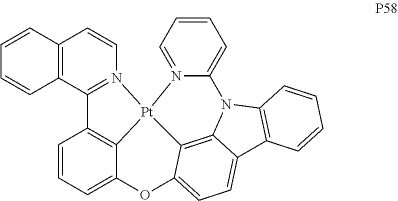

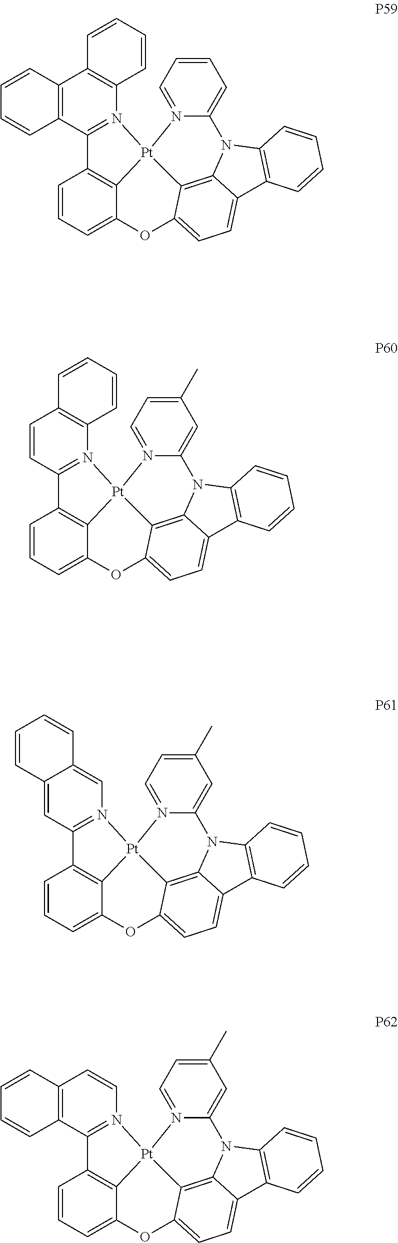

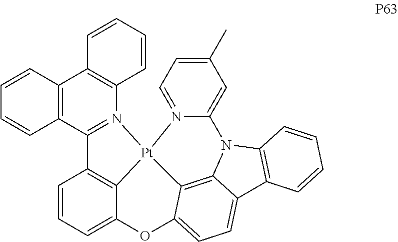

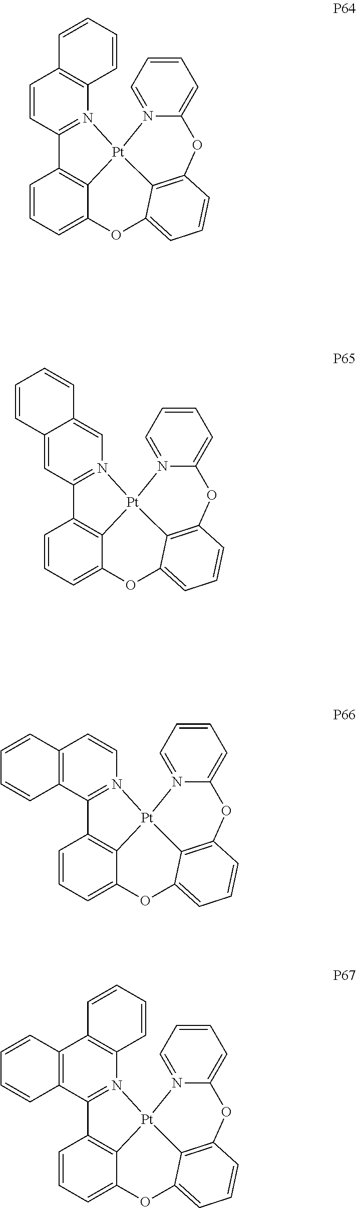

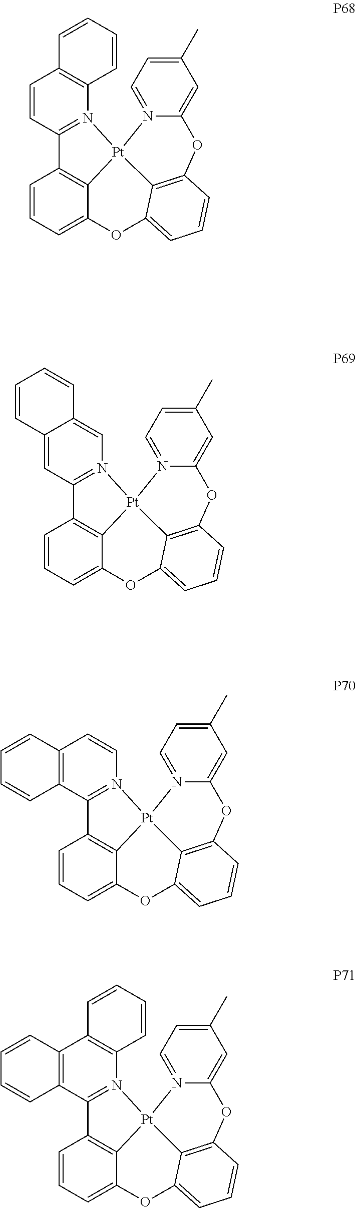

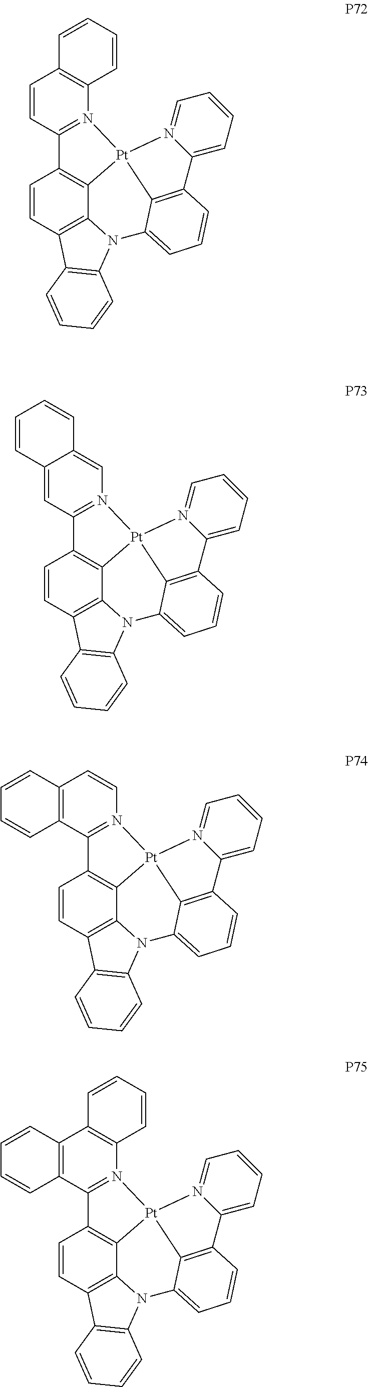

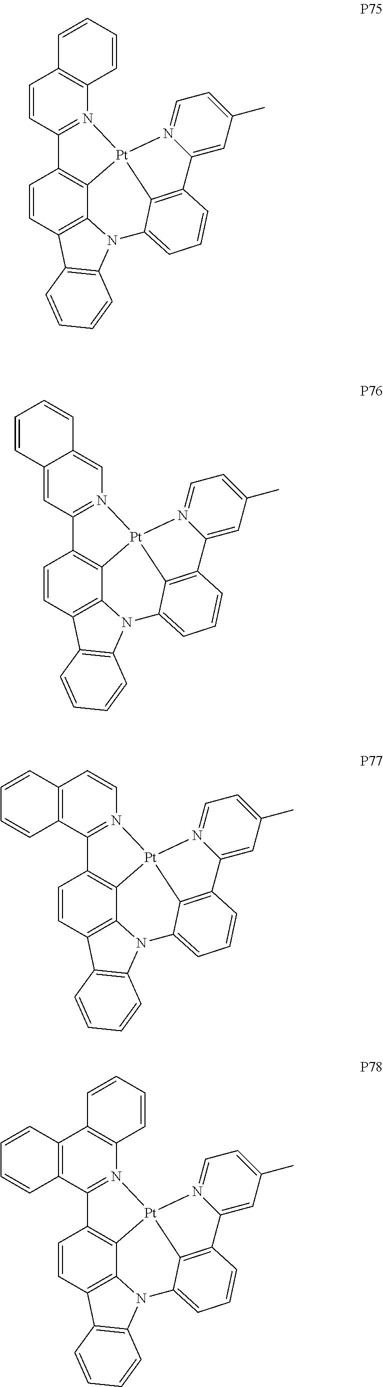

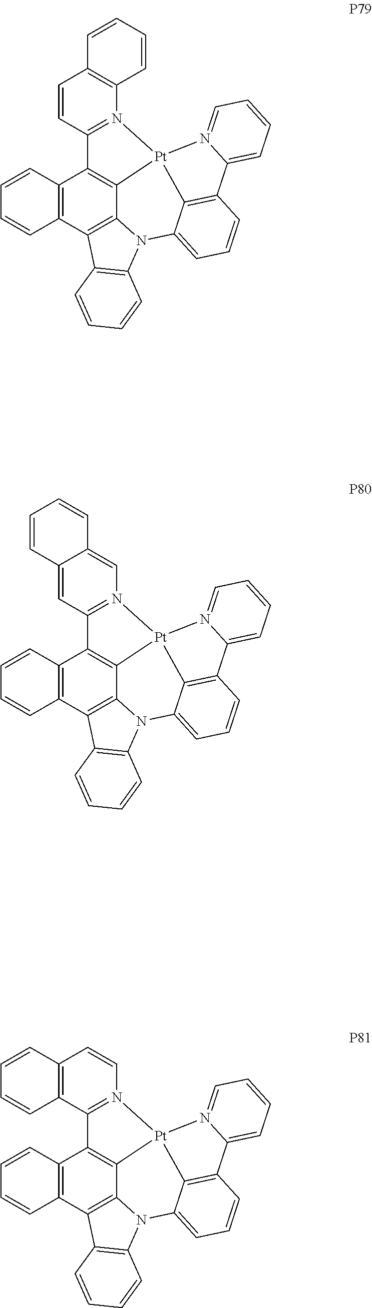

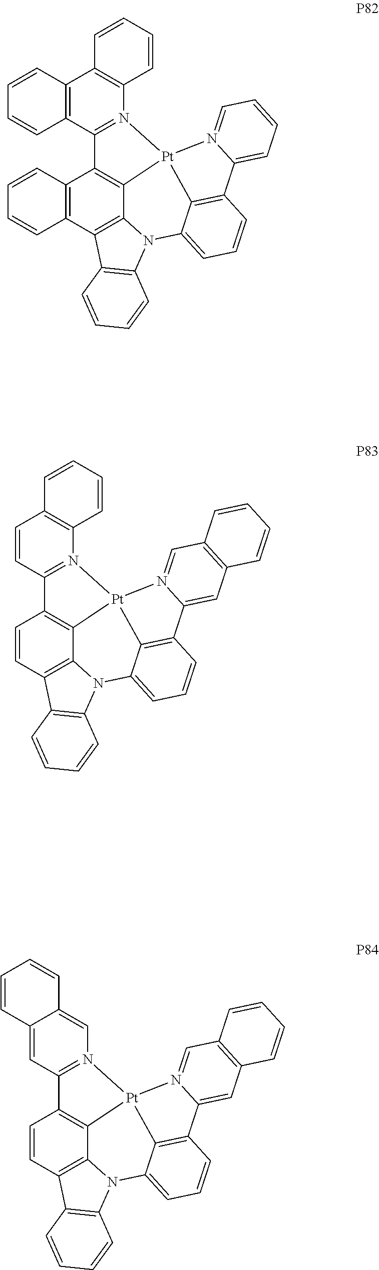

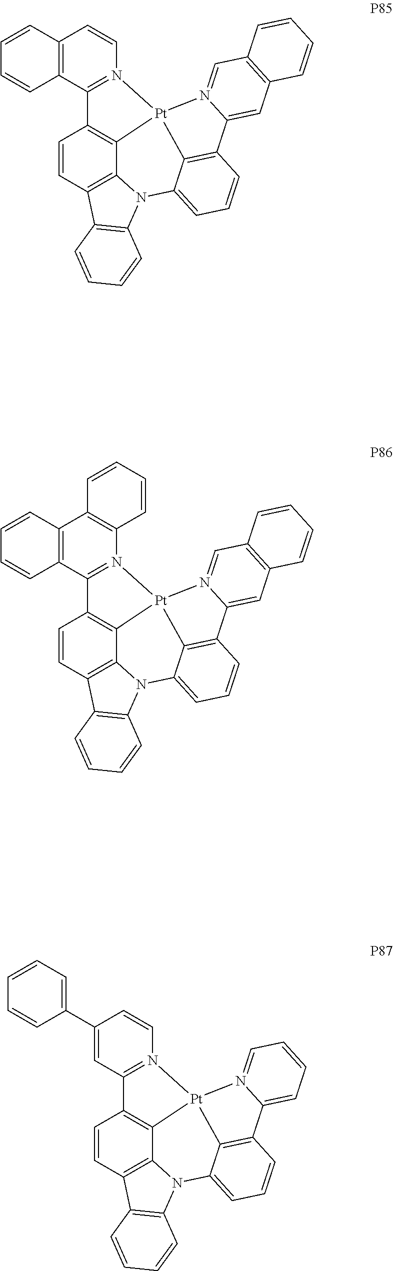

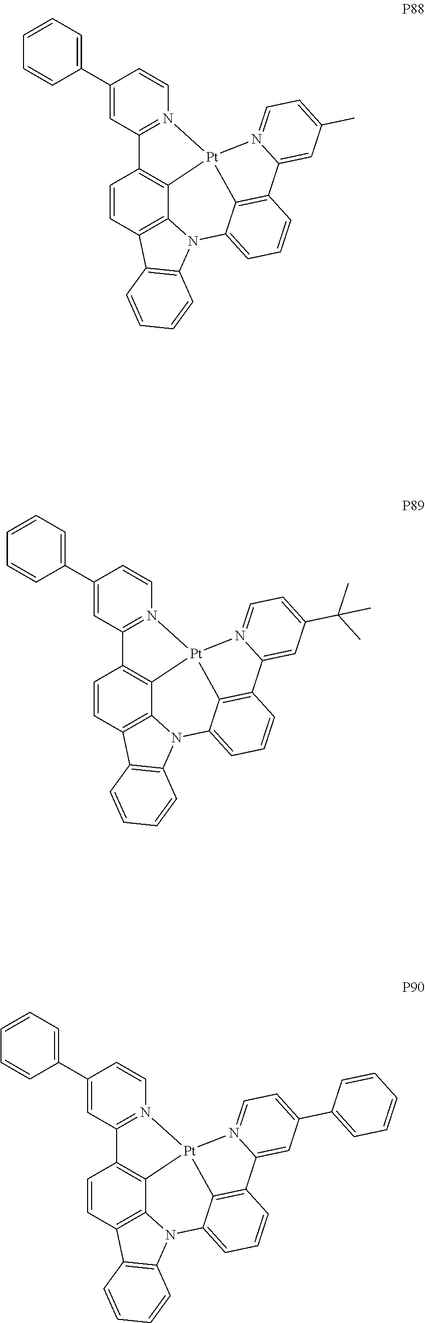

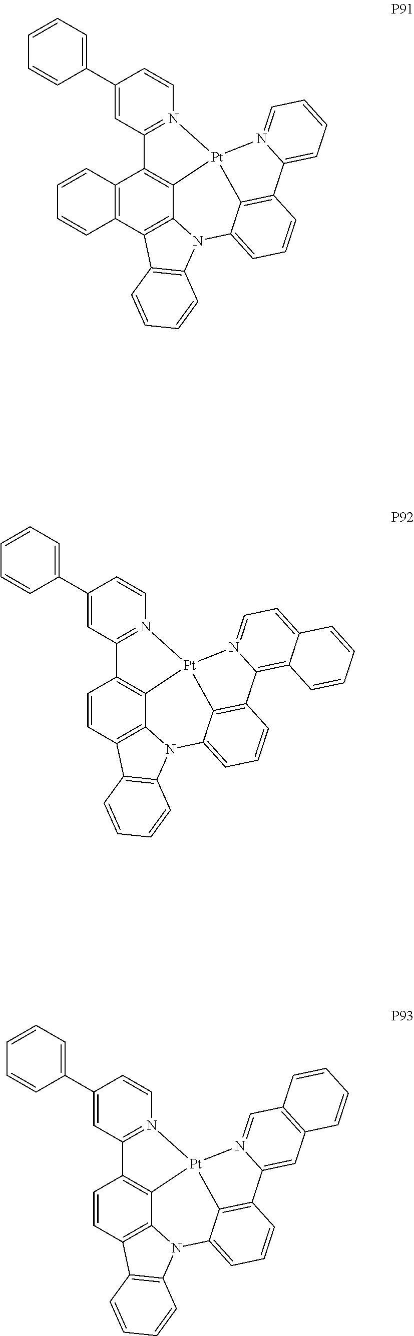

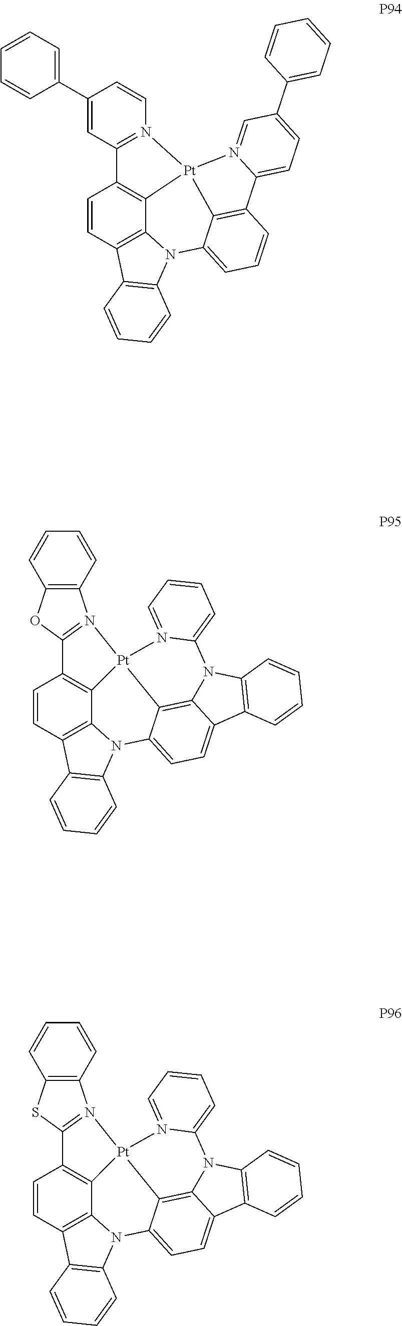

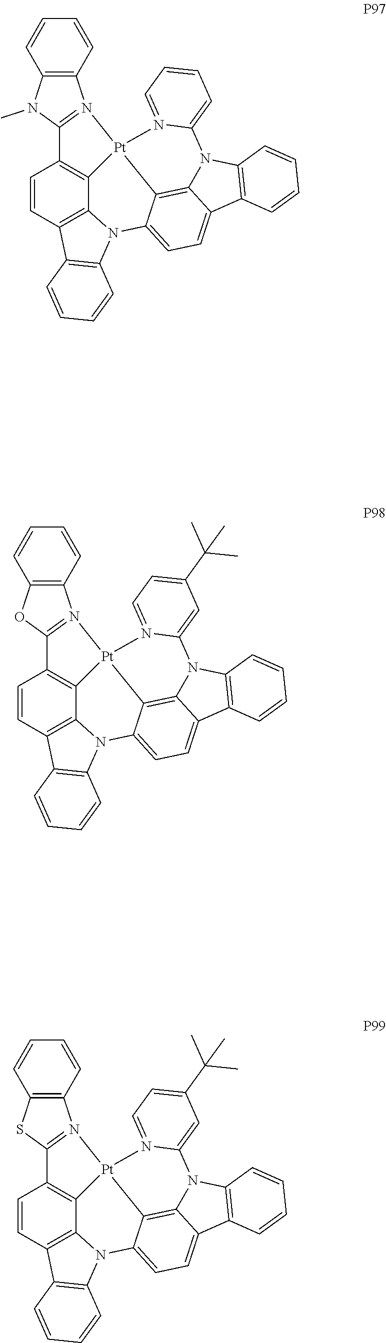

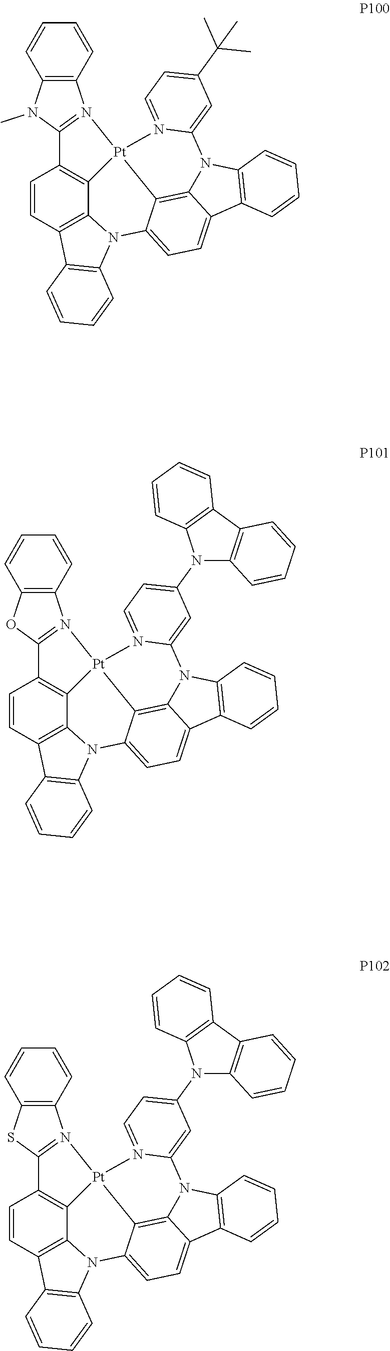

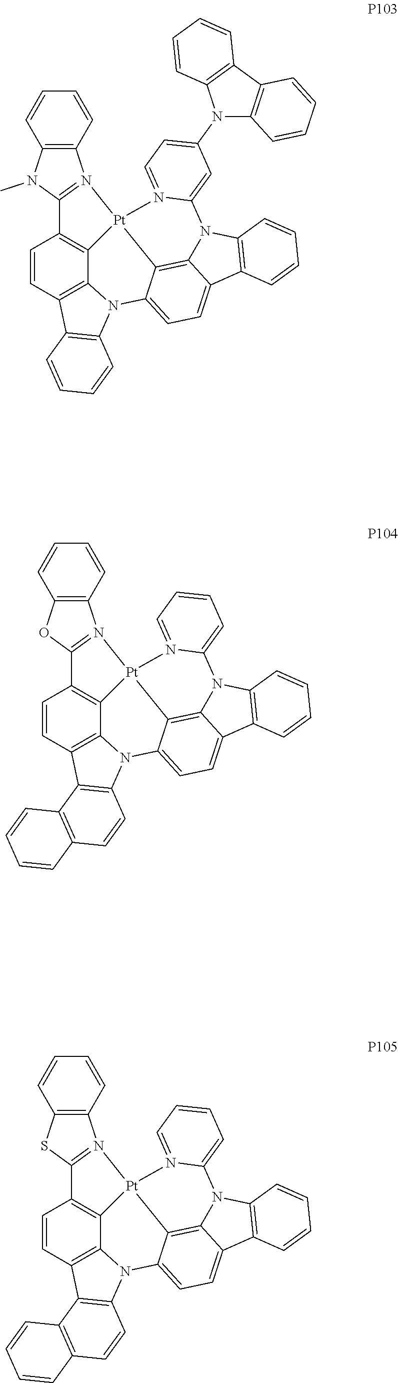

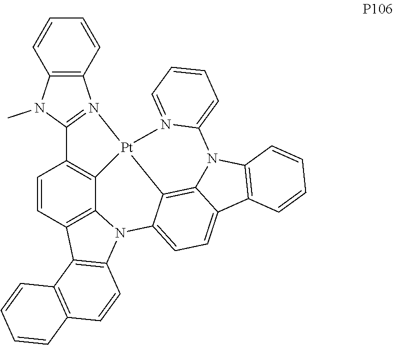

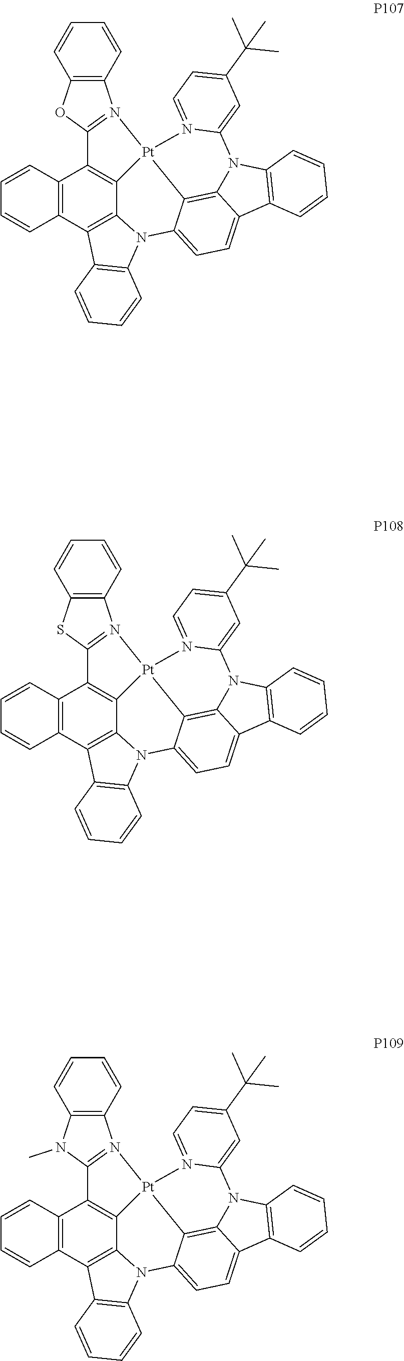

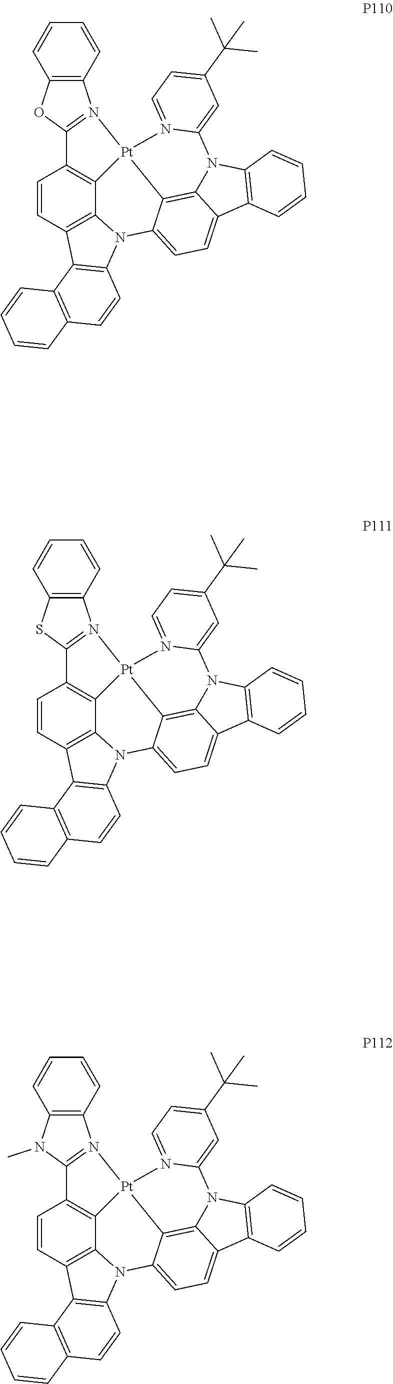

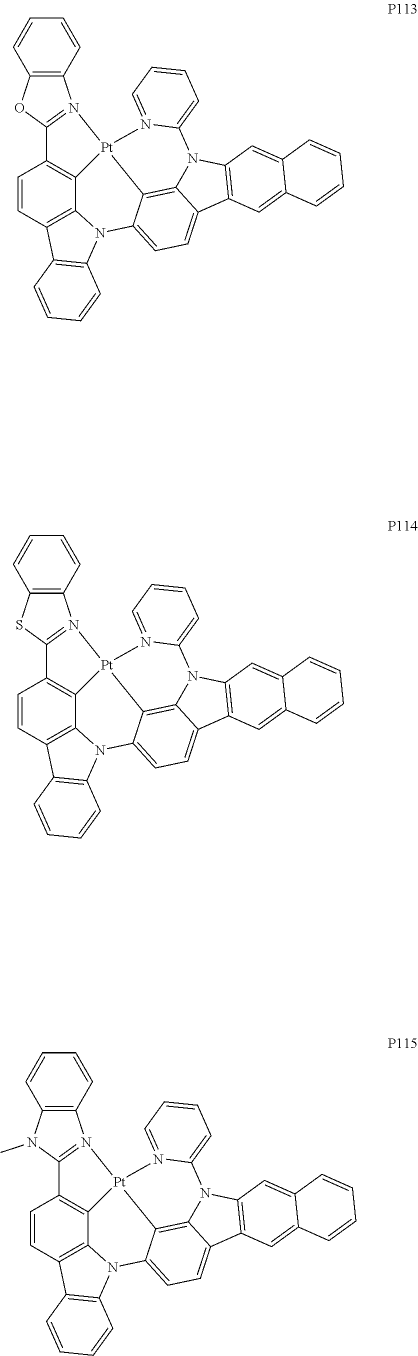

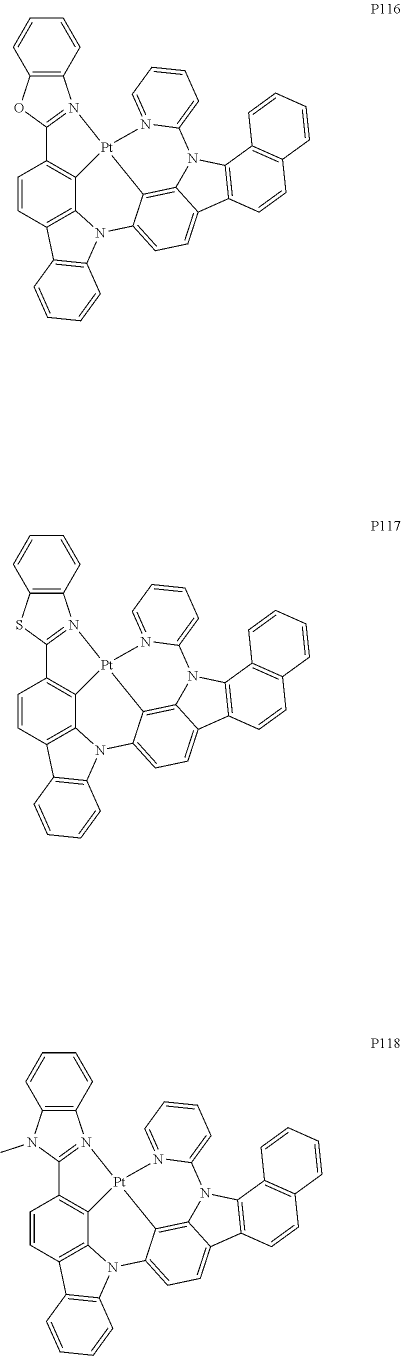

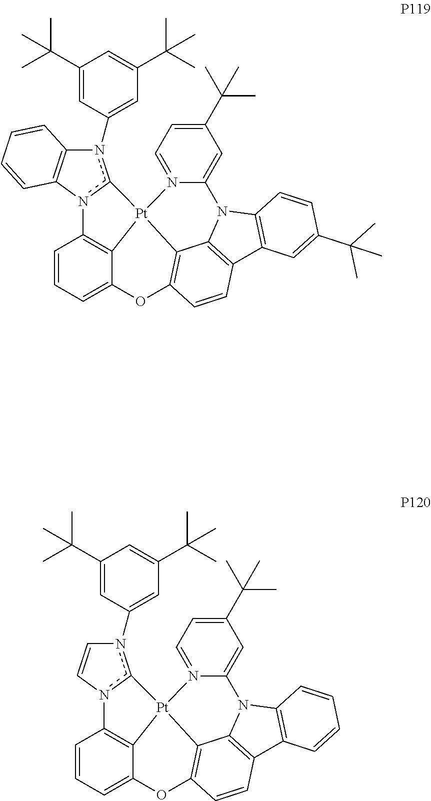

An amount of the phosphorescent complex with respect to the total mass of the material for an organic EL device (particularly, a material for an emission layer) is not particularly limited, but may preferably be 0.1 mass % or more, or may be 0.2 mass % or more. In addition, the amount may be 0.5 mass % or more, and preferably be 1 mass % or more. In addition, the amount may be 3 mass % or more, and 5 mass % or less. Within the ranges above, an organic EL device having excellent color purity of luminescence and according having high luminescence efficiency may be obtained. In addition, the amount of the phosphorescent complex with respect to the total mass of the material for an organic EL device (particularly, a material for an emission layer) is not particularly limited, but may be 50 mass % or less. In addition, the amount may be 40 mass % or less, and preferably be 30 mass % or less. Within the ranges above, an organic EL device having excellent color purity of luminescence and according having high luminescence efficiency may be obtained. In addition, in an emission layer of an organic EL device described below, the preferable amount of the phosphorescent complex with respect to the emission layer may be the same as described above.

When the material for an organic EL device (particularly, a material of an emission layer) includes the phosphorescent complex, the amount of the phosphorescent complex may preferably be 100 parts by mass or more with respect to 100 parts by mass of the compound of Formula (1). In addition, the amount of the phosphorescent complex may be 150 parts by mass or more, and preferably be 200 parts by mass or more, with respect to 100 parts by mass of the compound of Formula (1). Within the ranges above, an organic EL device having excellent color purity of luminescence and according having high luminescence efficiency may be obtained.

In addition, the amount of the phosphorescent complex is not particularly limited, but may preferably be 10000 parts by mass or less with respect to 100 parts by mass of the compound of Formula (1). In addition, the amount of the phosphorescent complex may be 7500 parts by mass or less, or preferably be 5000 parts by mass or less, with respect to 100 parts by mass of the compound of Formula (1). Within the ranges above, an organic EL device having excellent color purity of luminescence and according having high luminescence efficiency may be obtained. In addition, in an emission layer of an organic EL device described below, the preferable amount (parts by mass) of the phosphorescent complex with respect to 100 parts by mass of the compound of Formula (1) may be the same as described above.

### Host Material

The material for an organic EL device according to an embodiment may more preferably include a host material in addition to the compound of Formula (1). When the compound of Formula (1) is used as both a dopant material and a host material, an organic EL device including the compound of Formula (1) may implement excellent luminescence efficiency.

The host material is not particularly limited, but may use a known host material. Examples of the known host material are an anthracene derivative, a pyrene derivative, a fluoranthene derivative, a chrysene derivative, a dihydrobenzo anthracene derivative, or a triphenylene derivative. The anthracene derivative may preferably be 9-(1-naphthyl)-10-(2-naphthyl) anthracene (corresponding to Compound HT4).

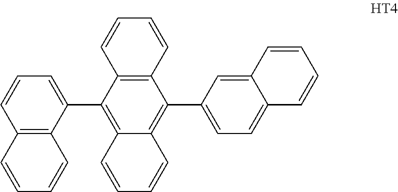 [SMILES: c1ccc2cc(-c3c4ccccc4c(-c4cccc5ccccc45)c4ccccc34)ccc2c1]

The host material may preferably be: (1) a compound having a carbazole ring structure (exclusive of a compound of Formula (1)); (2) a compound having a ring structure in which at least one of ring-forming carbon atoms of the carbazole ring structure is substituted with a nitrogen atom (exclusive of a compound of Formula (1) and a host compound (1)); or a compound having a triazine ring structure (exclusive of a compound represented by Formula (1), a host compound (1), and a host compound (2)). Among these examples, the host material may be the compound having a carbazole ring structure. When these compounds are used as the host material, efficient energy transfer within an emission layer may be promoted. In addition, the balance in carrier mobility of electrons and holes may be further improved. In addition, in the carbazole ring structure, the ring structure in which at least one of ring-forming carbon atoms of the carbazole ring is substituent with a nitrogen atom, and the triazine ring structure of these compounds, a hydrogen atom binding to ring-forming atoms constituting these rings may be substituted with other atoms or substituents. In addition, two or more substituents may form a ring structure.

The host compound (2) having the carbazole ring structure or the compound having a ring structure in which at least one of ring-forming carbon atoms of the carbazole ring is substituent with a nitrogen atom is not particularly limited, but may preferably be a compound having a structure represented by Formula (6):

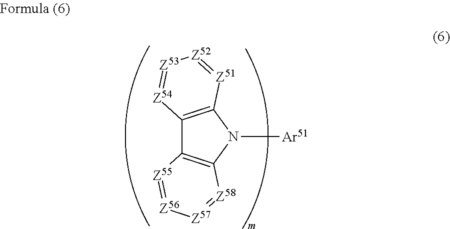

wherein, in Formula (6),
Z⁵¹ may be CH, CR⁵¹, or N,
Z⁵² may be CH, CR⁵², or N,
Z⁵³ may be CH, CR⁵³, or N,
Z⁵⁴ may be CH, CR⁵⁴, or N,
Z⁵⁵ may be CH, CR⁵⁵, or N,
Z⁵⁶ may be CH, CR⁵⁶, or N,
Z⁵⁷ may be CH, CR⁵⁷, or N,
Z⁵⁸ may be CH, CR⁵⁸, or N,
R⁵¹ to R⁵⁸ may each independently be one of the following groups of (6a) to (6h):
(6a) a cyano group (—CN group),
(6b) a substituted or unsubstituted C1-C20 alkyl group,
(6c) a substituted or unsubstituted C1-C20 alkoxy group,
(6d) a substituted or unsubstituted C6-C20 arylamino group,
(6e) a substituted or unsubstituted phosphoryl group (—POH₂ group),
(6f) a substituted or unsubstituted silyl group (—SiH₃ group),
(6g) a substituted or unsubstituted monovalent aromatic hydrocarbon group, and
(6h) a substituted or unsubstituted monovalent heterocyclic group,
Ar⁵¹ may be a group including at least one of an aromatic hydrocarbon group and a heterocyclic group,
m may be 1, 2, 3, 4, 5, or 6, and
R⁵¹ and R⁵²; R⁵² and R⁵³; R⁵³ and R⁵⁴; R⁵⁵ and R⁵⁶; R⁵⁶ and R⁵⁷; or R⁵⁷ and R⁵⁸ may optionally be bonded together to form an aliphatic hydrocarbon ring, an aromatic hydrocarbon ring, an aromatic hydrocarbon ring, or a heterocyclic ring, each including a carbon atom of each substituent of each substituent pair, the carbon atom positioned at which substituents of each substituent pair are bonded to each other.

In Formula (6), descriptions of the groups of (6b), (6c), (6g), and the (6h) may be the same as those of the groups of (1a) to (1d) in Formula (1), respectively. In addition, in Formula (6), a description of the group of (6d) may be the same as a description of the arylamino group as the substituent that R¹ to R⁴ in Formula (1).

The aromatic hydrocarbon group in Ar⁵¹ may be the same as the aromatic hydrocarbon group described in the description of the group of (1c) in Formula (1), except that the valence may be different.

In addition, except for the fact that the valence may be different, the heterocyclic group in A⁵¹ may be the same as the heterocyclic group described in the group of (1d) in Formula (1).

In Formula (6), it is preferable that none of Z⁵¹ to Z⁵⁸ may be N or one of Z⁵¹ to Z⁵⁸ may be N. In addition, it is preferable that none of Z⁵¹ to Z⁵⁸ may be N.

In Formula (6), when the groups of (6b) to (6h) are substituted with other substituents, the other substituents are not particularly limited. For example the other substituents may be the groups of (6a) to (6h). Examples of the other substituents are not particularly limited, but may include a cyano group, an unsubstituted C1-C20 alkyl group, a C1-C20 alkoxy group substituted with a C6-C30 aromatic hydrocarbon group that is further substituted with an unsubstituted C2-C30 alkenyl group, a substituted or unsubstituted C6-C20 arylamino group, an unsubstituted C6-C30 aromatic hydrocarbon group, a C6-C30 aromatic hydrocarbon group substituted with a cyano group, a C6-C30 aromatic hydrocarbon group substituted with an unsubstituted C2-C30 alkenyl group, a C6-C30 aromatic hydrocarbon group substituted with an unsubstituted C6-C20 arylamino group, an unsubstituted aromatic C6-C30 hydrocarbon group, and a heterocyclic group with a ring-forming atom number of 3 to 30 substituted with an unsubstituted C6-C30 aromatic hydrocarbon group.

In Formula (6), Ar⁵¹ is not particularly limited as long as it includes at least one of an aromatic hydrocarbon group and a heterocyclic group. For example, Ar⁵¹ may be a substituted or unsubstituted aromatic hydrocarbon group, a substituted or unsubstituted heterocyclic group, a group in which at least one of the substituted or unsubstituted aromatic hydrocarbon group and at least one of the substituted or unsubstituted heterocyclic group are bonded to each other via a single bond, a group in which at least two of the substituted or unsubstituted aromatic hydrocarbon group or the substituted or unsubstituted heterocyclic group is bonded through a linking group other than the aforementioned group.

Here, regarding the at least two of the substituted or unsubstituted aromatic hydrocarbon group or the group in which a substituted or unsubstituted heterocyclic group is bonded to a group other than the aforementioned group via a linking group, the linking group is not particularly limited. Examples of the linking group are a Si group, a N group, a P═O group, a S(═O)═O group, a C═O group, and the like.

In Formula (6), when the group constituting Ar⁵¹ is substituted with other substituents, the other substituents are not particularly limited. For example, the other substituents may be the groups of (6a) to (6h). Examples of the other substituents are not particularly limited, but may include a cyano group, an unsubstituted C1-C20 alkyl group, a monovalent heterocyclic group with a ring-forming atom number of 3 to 30 substituted with an unsubstituted C1-C20 alkyl group.

Here, descriptions of the groups of (6b) to (6h) or the substituents constituting Ar⁵¹, such as a C1-C20 alkyl group, a C1-C20 alkoxy group, a C6-C30 aromatic hydrocarbon group, a C6-C30 aromatic hydrocarbon group, and a heterocyclic group with a ring-forming atom number of 3 to 30 may be the same as the descriptions of the groups of (1a) to (1d) in Formula (1). In addition, the substituents of the groups of (6b) to (6h) or the substituents constituting Ar⁵¹, such as a C6-C20 arylamino group, may be the same as a description of the arylamino group as the substituent that R¹ to R⁴ in Formula (1).

In addition, the substituents of the groups of (6c) to (6h) or the substituents constituting Ar⁵¹, such as a C2-C30 alkenyl group, are not particularly limited, and may be linear, branched, or cyclic. Examples of the alkenyl group are not particularly limited, but may include, for example, a vinyl group, a 2-prophenyl group, a 2-butenyl group, a 3-butenyl group, a 1-methyl-2-prophenyl group, a 2-methyl-2-prophenyl group, a 2-cyclopentenyl group, a 3-cyclopentenyl group, a 4-cyclopentenyl group, a 1-methyl-2-butenyl group, a 2-methyl-2-butenyl group, a 3-methyl-2-butenyl group, a 1-methyl-3-butenyl group, a 2-methyl-3-butenyl group, a 3-methyl-3-butenyl group, a 1,1-dimethyl-2-prophenyl group, a 1,2-dimethyl-2-prophenyl group, a 1-ethyl-2-prophenyl group, and the like.
m may preferably be 1, 2, 3, or 4, and may more preferably be 2.

Hereinafter, as the host material according to an embodiment, the compound having a carbazole ring structure and the compound having a ring structure in which at least one of ring-forming carbon atoms of the carbazole ring is substituted with a nitrogen atom will be described in detail, but the disclosure is not limited thereto.

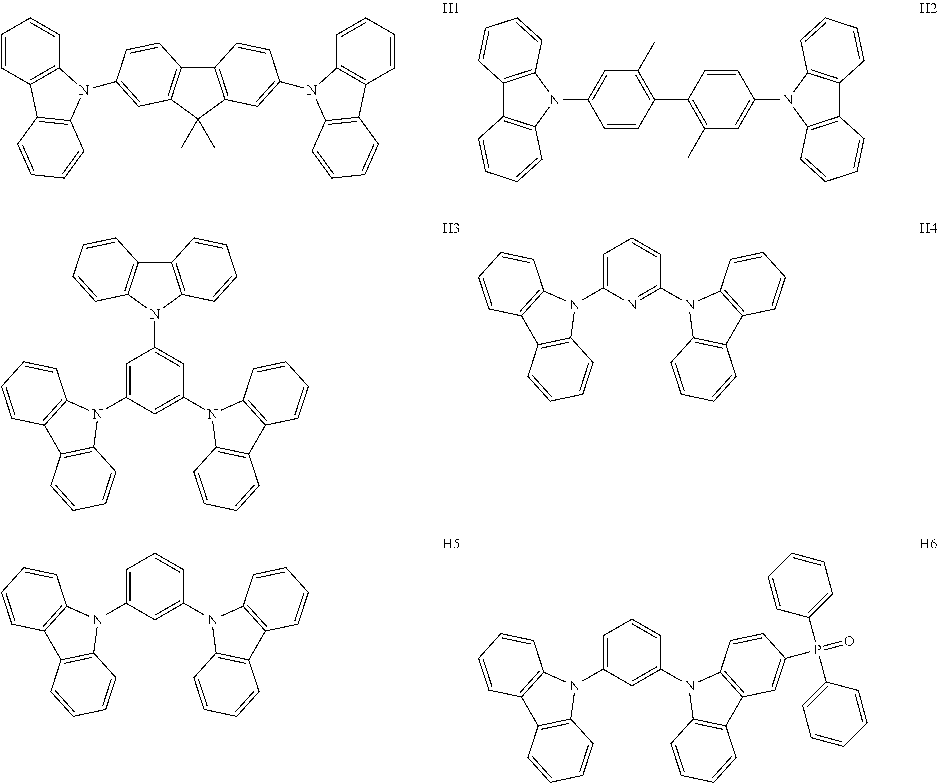 [SMILES: CC1(C)c2cc(-n3c4ccccc4c4ccccc43)ccc2-c2ccc(-n3c4ccccc4c4ccccc43)cc21 ; Cc1cc(-n2c3ccccc3c3ccccc32)ccc1-c1ccc(-n2c3ccccc3c3ccccc32)cc1C ; c1ccc2c(c1)c1ccccc1n2-c1cc(-n2c3ccccc3c3ccccc32)cc(-n2c3ccccc3c3ccccc32)c1 ; c1cc(-n2c3ccccc3c3ccccc32)nc(-n2c3ccccc3c3ccccc32)c1 ; c1cc(-n2c3ccccc3c3ccccc32)cc(-n2c3ccccc3c3ccccc32)c1 ; O=P(c1ccccc1)(c1ccccc1)c1ccc2c(c1)c1ccccc1n2-c1cccc(-n2c3ccccc3c3ccccc32)c1]

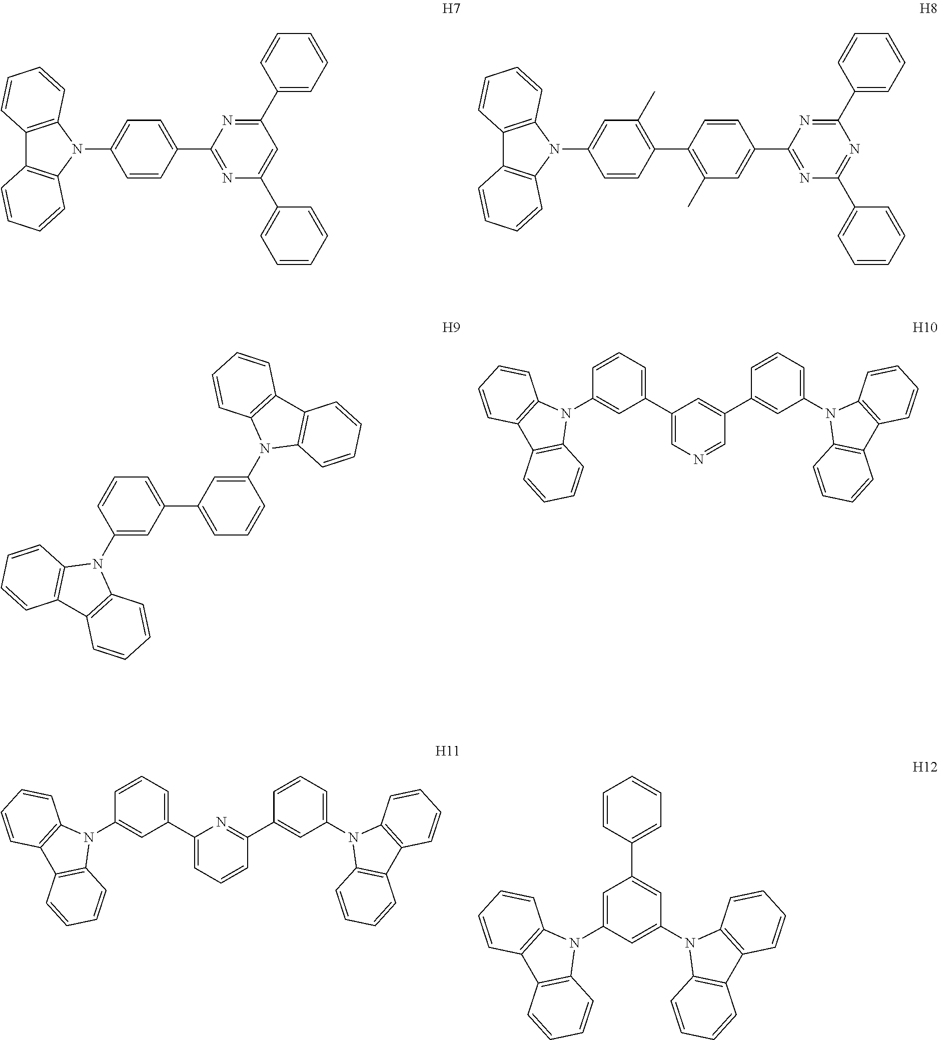 [SMILES: c1ccc(-c2cc(-c3ccccc3)nc(-c3ccc(-n4c5ccccc5c5ccccc54)cc3)n2)cc1 ; Cc1cc(-c2nc(-c3ccccc3)nc(-c3ccccc3)n2)ccc1-c1ccc(-n2c3ccccc3c3ccccc32)cc1C ; c1cc(-c2cccc(-n3c4ccccc4c4ccccc43)c2)cc(-n2c3ccccc3c3ccccc32)c1 ; c1cc(-c2cncc(-c3cccc(-n4c5ccccc5c5ccccc54)c3)c2)cc(-n2c3ccccc3c3ccccc32)c1 ; c1cc(-c2cccc(-c3cccc(-n4c5ccccc5c5ccccc54)c3)n2)cc(-n2c3ccccc3c3ccccc32)c1 ; c1ccc(-c2cc(-n3c4ccccc4c4ccccc43)cc(-n3c4ccccc4c4ccccc43)c2)cc1]

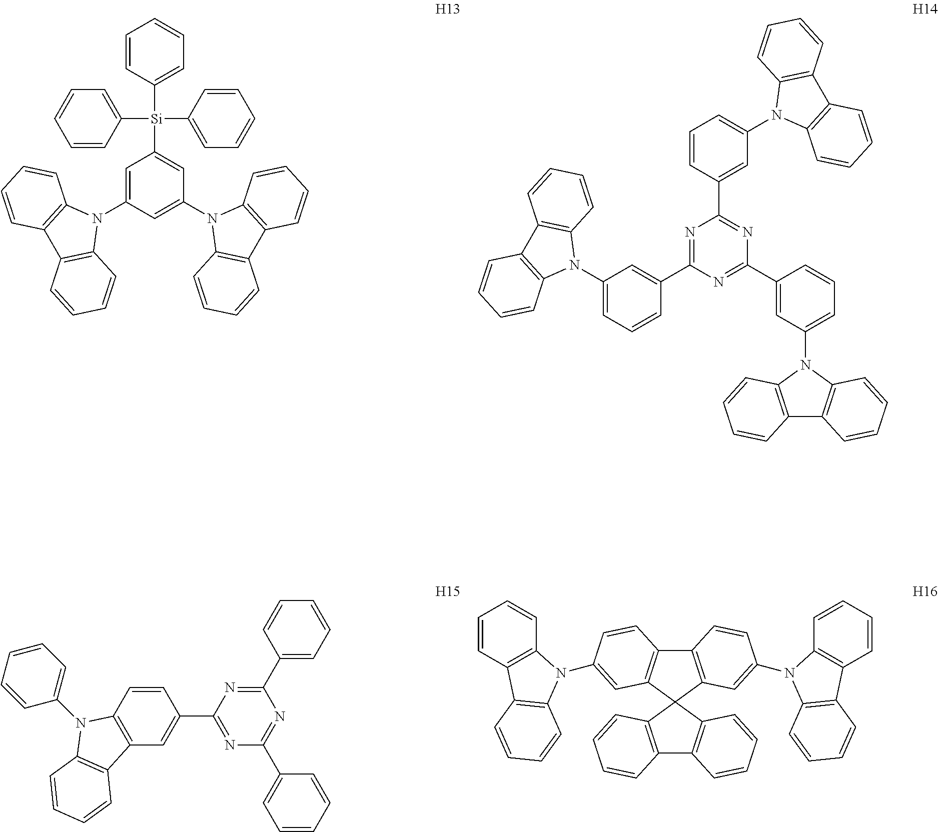 [SMILES: c1ccc([Si](c2ccccc2)(c2ccccc2)c2cc(-n3c4ccccc4c4ccccc43)cc(-n3c4ccccc4c4ccccc43)c2)cc1 ; c1cc(-c2nc(-c3cccc(-n4c5ccccc5c5ccccc54)c3)nc(-c3cccc(-n4c5ccccc5c5ccccc54)c3)n2)cc(-n2c3ccccc3c3ccccc32)c1 ; c1ccc(-c2nc(-c3ccccc3)nc(-c3ccc4c(c3)c3ccccc3n4-c3ccccc3)n2)cc1 ; c1ccc2c(c1)-c1ccccc1C21c2cc(-n3c4ccccc4c4ccccc43)ccc2-c2ccc(-n3c4ccccc4c4ccccc43)cc21]

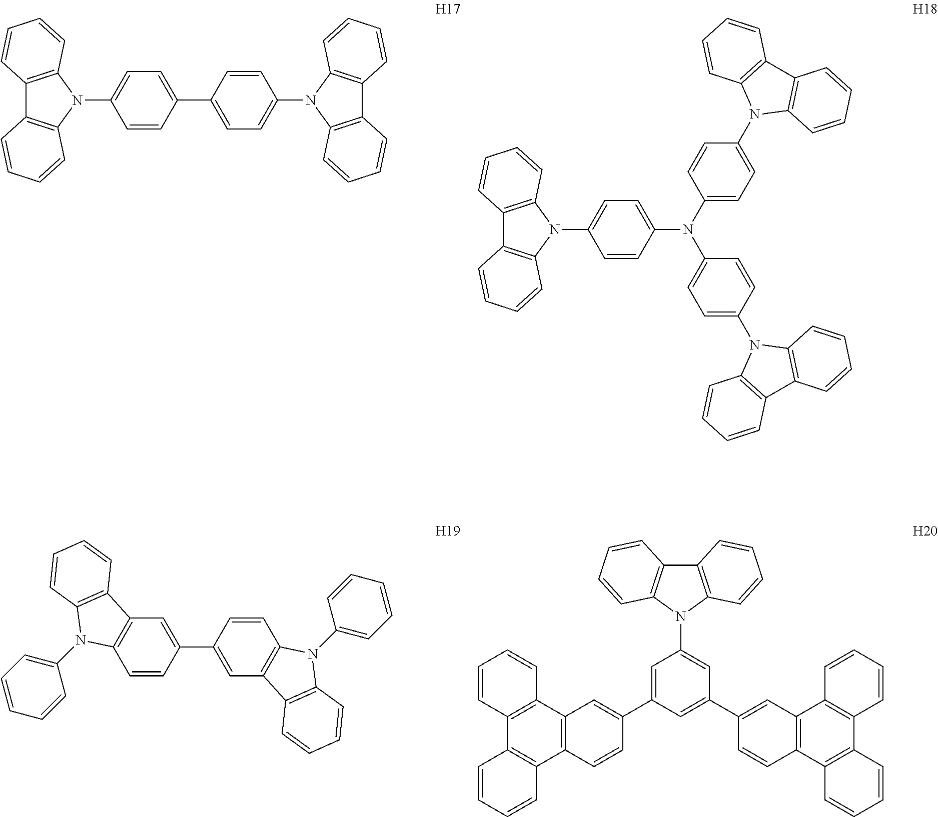 [SMILES: c1ccc2c(c1)c1ccccc1n2-c1ccc(-c2ccc(-n3c4ccccc4c4ccccc43)cc2)cc1 ; c1ccc2c(c1)c1ccccc1n2-c1ccc(N(c2ccc(-n3c4ccccc4c4ccccc43)cc2)c2ccc(-n3c4ccccc4c4ccccc43)cc2)cc1 ; c1ccc(-n2c3ccccc3c3cc(-c4ccc5c(c4)c4ccccc4n5-c4ccccc4)ccc32)cc1 ; c1ccc2c(c1)c1ccccc1c1cc(-c3cc(-c4ccc5c6ccccc6c6ccccc6c5c4)cc(-n4c5ccccc5c5ccccc54)c3)ccc21]

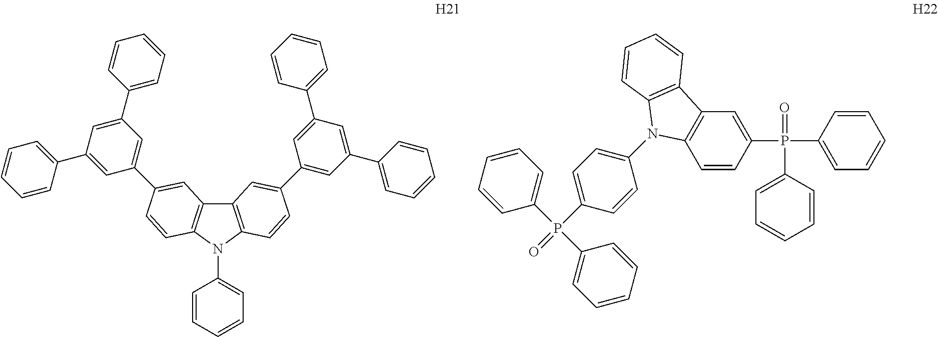 [SMILES: c1ccc(-c2cc(-c3ccccc3)cc(-c3ccc4c(c3)c3cc(-c5cc(-c6ccccc6)cc(-c6ccccc6)c5)ccc3n4-c3ccccc3)c2)cc1 ; O=P(c1ccccc1)(c1ccccc1)c1ccc(-n2c3ccccc3c3cc(P(=O)(c4ccccc4)c4ccccc4)ccc32)cc1]

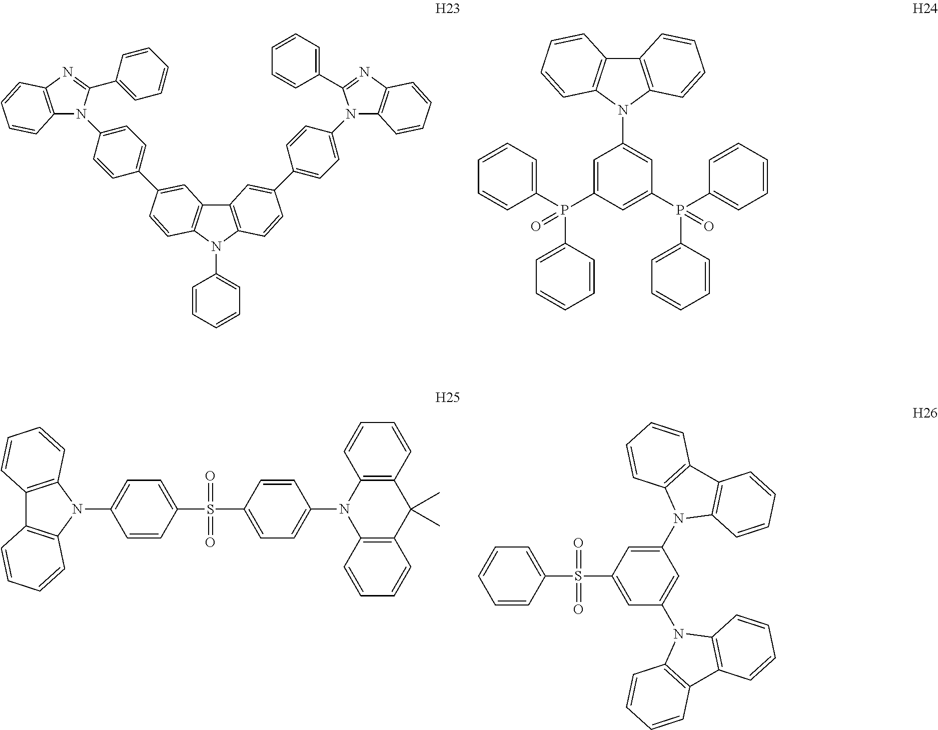 [SMILES: c1ccc(-c2nc3ccccc3n2-c2ccc(-c3ccc4c(c3)c3cc(-c5ccc(-n6c(-c7ccccc7)nc7ccccc76)cc5)ccc3n4-c3ccccc3)cc2)cc1 ; O=P(c1ccccc1)(c1ccccc1)c1cc(-n2c3ccccc3c3ccccc32)cc(P(=O)(c2ccccc2)c2ccccc2)c1 ; CC1(C)c2ccccc2N(c2ccc(S(=O)(=O)c3ccc(-n4c5ccccc5c5ccccc54)cc3)cc2)c2ccccc21 ; O=S(=O)(c1ccccc1)c1cc(-n2c3ccccc3c3ccccc32)cc(-n2c3ccccc3c3ccccc32)c1]

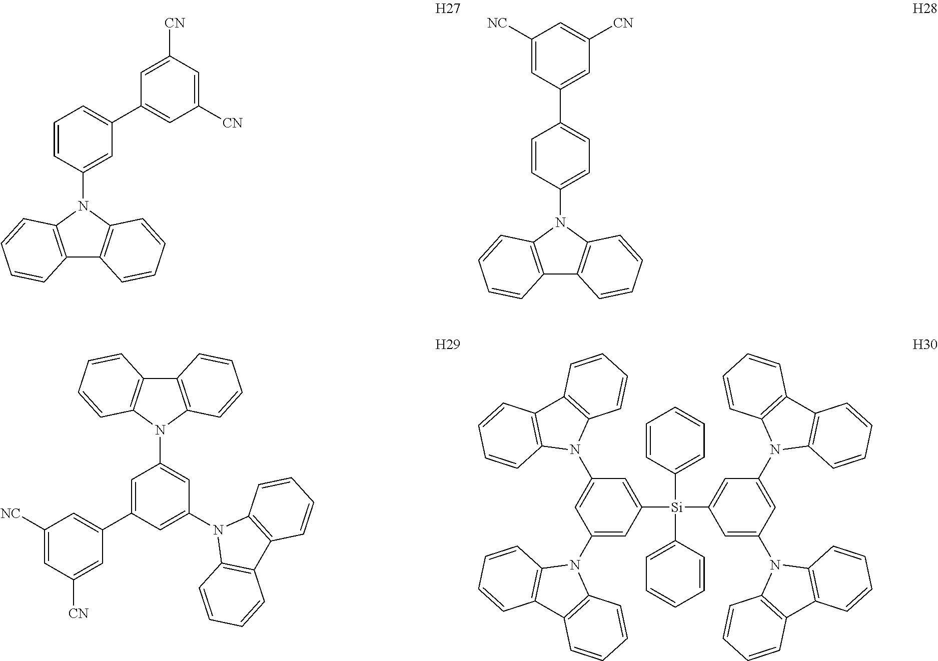 [SMILES: N#Cc1cc(C#N)cc(-c2cccc(-n3c4ccccc4c4ccccc43)c2)c1 ; N#Cc1cc(C#N)cc(-c2ccc(-n3c4ccccc4c4ccccc43)cc2)c1 ; N#Cc1cc(C#N)cc(-c2cc(-n3c4ccccc4c4ccccc43)cc(-n3c4ccccc4c4ccccc43)c2)c1 ; c1ccc([Si](c2ccccc2)(c2cc(-n3c4ccccc4c4ccccc43)cc(-n3c4ccccc4c4ccccc43)c2)c2cc(-n3c4ccccc4c4ccccc43)cc(-n3c4ccccc4c4ccccc43)c2)cc1]

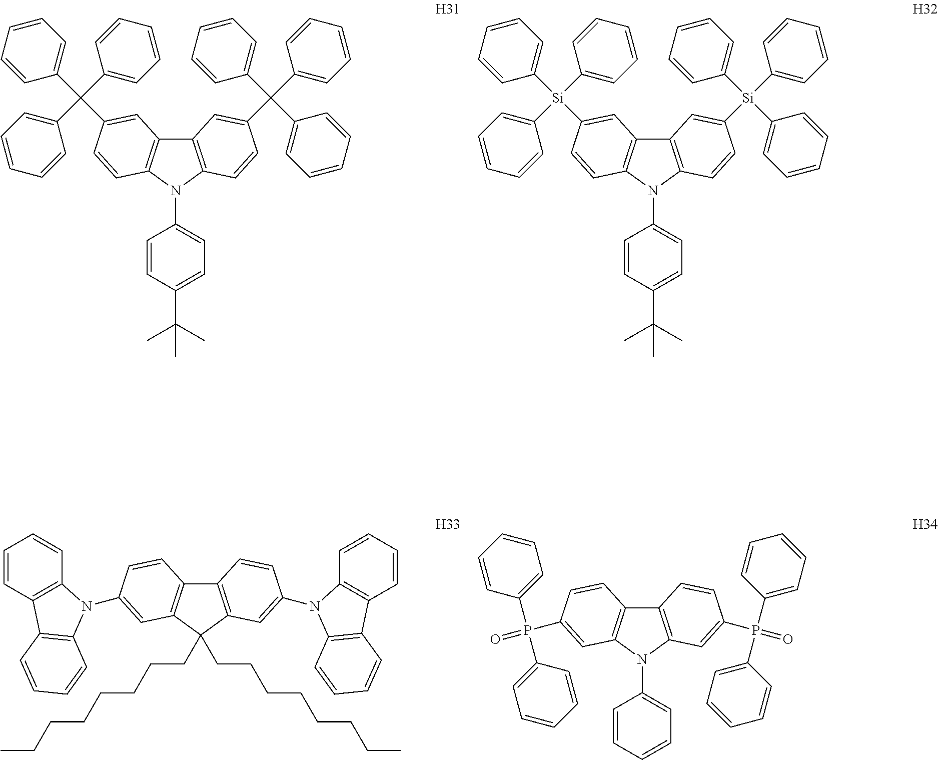 [SMILES: CC(C)(C)c1ccc(-n2c3ccc(C(c4ccccc4)(c4ccccc4)c4ccccc4)cc3c3cc(C(c4ccccc4)(c4ccccc4)c4ccccc4)ccc32)cc1 ; CC(C)(C)c1ccc(-n2c3ccc([Si](c4ccccc4)(c4ccccc4)c4ccccc4)cc3c3cc([Si](c4ccccc4)(c4ccccc4)c4ccccc4)ccc32)cc1 ; CCCCCCCCC1(CCCCCCCC)c2cc(-n3c4ccccc4c4ccccc43)ccc2-c2ccc(-n3c4ccccc4c4ccccc43)cc21 ; O=P(c1ccccc1)(c1ccccc1)c1ccc2c3ccc(P(=O)(c4ccccc4)c4ccccc4)cc3n(-c3ccccc3)c2c1]

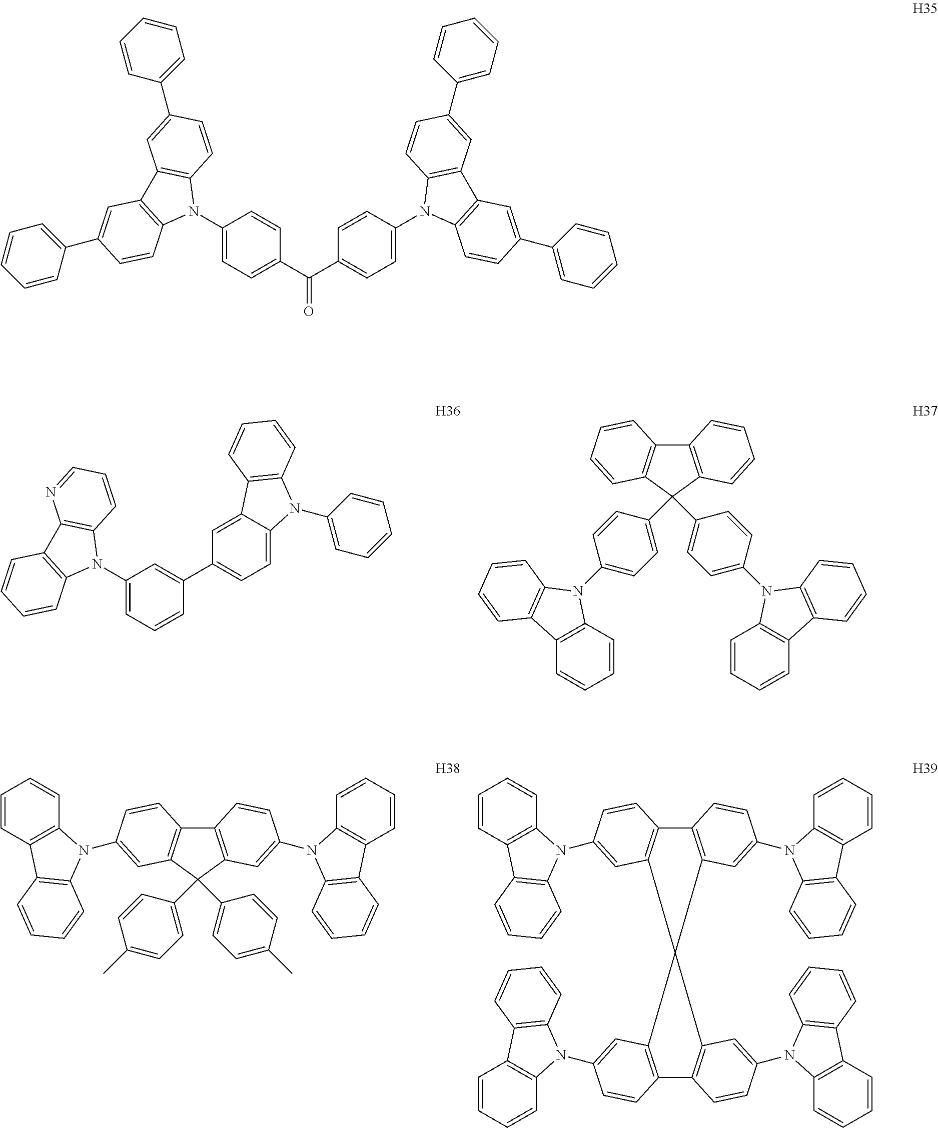 [SMILES: O=C(c1ccc(-n2c3ccc(-c4ccccc4)cc3c3cc(-c4ccccc4)ccc32)cc1)c1ccc(-n2c3ccc(-c4ccccc4)cc3c3cc(-c4ccccc4)ccc32)cc1 ; c1ccc(-n2c3ccccc3c3cc(-c4cccc(-n5c6ccccc6c6ncccc65)c4)ccc32)cc1 ; c1ccc2c(c1)-c1ccccc1C2(c1ccc(-n2c3ccccc3c3ccccc32)cc1)c1ccc(-n2c3ccccc3c3ccccc32)cc1 ; Cc1ccc(C2(c3ccc(C)cc3)c3cc(-n4c5ccccc5c5ccccc54)ccc3-c3ccc(-n4c5ccccc5c5ccccc54)cc32)cc1 ; c1ccc2c(c1)c1ccccc1n2-c1ccc2c(c1)C1(c3cc(-n4c5ccccc5c5ccccc54)ccc3-2)c2cc(-n3c4ccccc4c4ccccc43)ccc2-c2ccc(-n3c4ccccc4c4ccccc43)cc21]

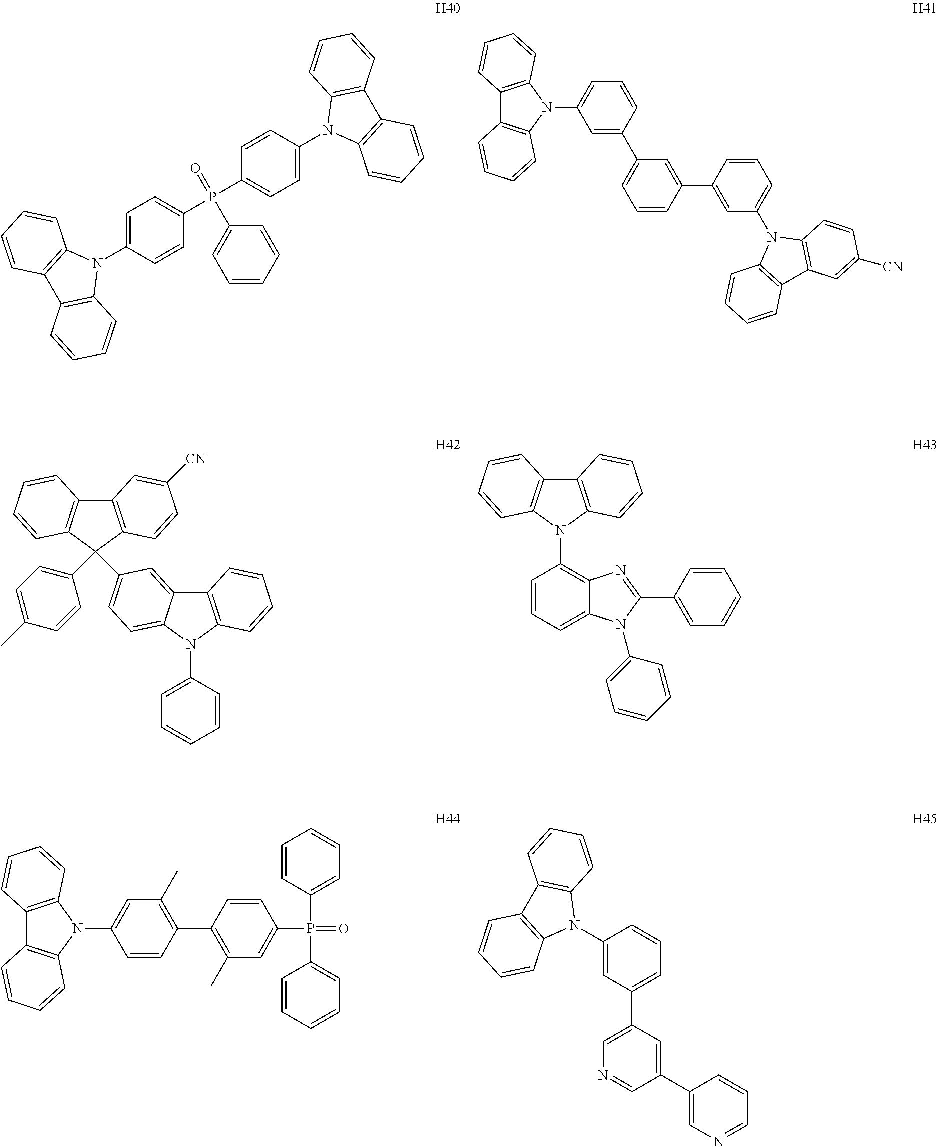 [SMILES: O=P(c1ccccc1)(c1ccc(-n2c3ccccc3c3ccccc32)cc1)c1ccc(-n2c3ccccc3c3ccccc32)cc1 ; N#Cc1ccc2c(c1)c1ccccc1n2-c1cccc(-c2cccc(-c3cccc(-n4c5ccccc5c5ccccc54)c3)c2)c1 ; Cc1ccc(C2(c3ccc4c(c3)c3ccccc3n4-c3ccccc3)c3ccccc3-c3cc(C#N)ccc32)cc1 ; c1ccc(-c2nc3c(-n4c5ccccc5c5ccccc54)cccc3n2-c2ccccc2)cc1 ; Cc1cc(-n2c3ccccc3c3ccccc32)ccc1-c1ccc(P(=O)(c2ccccc2)c2ccccc2)cc1C ; c1cncc(-c2cncc(-c3cccc(-n4c5ccccc5c5ccccc54)c3)c2)c1]

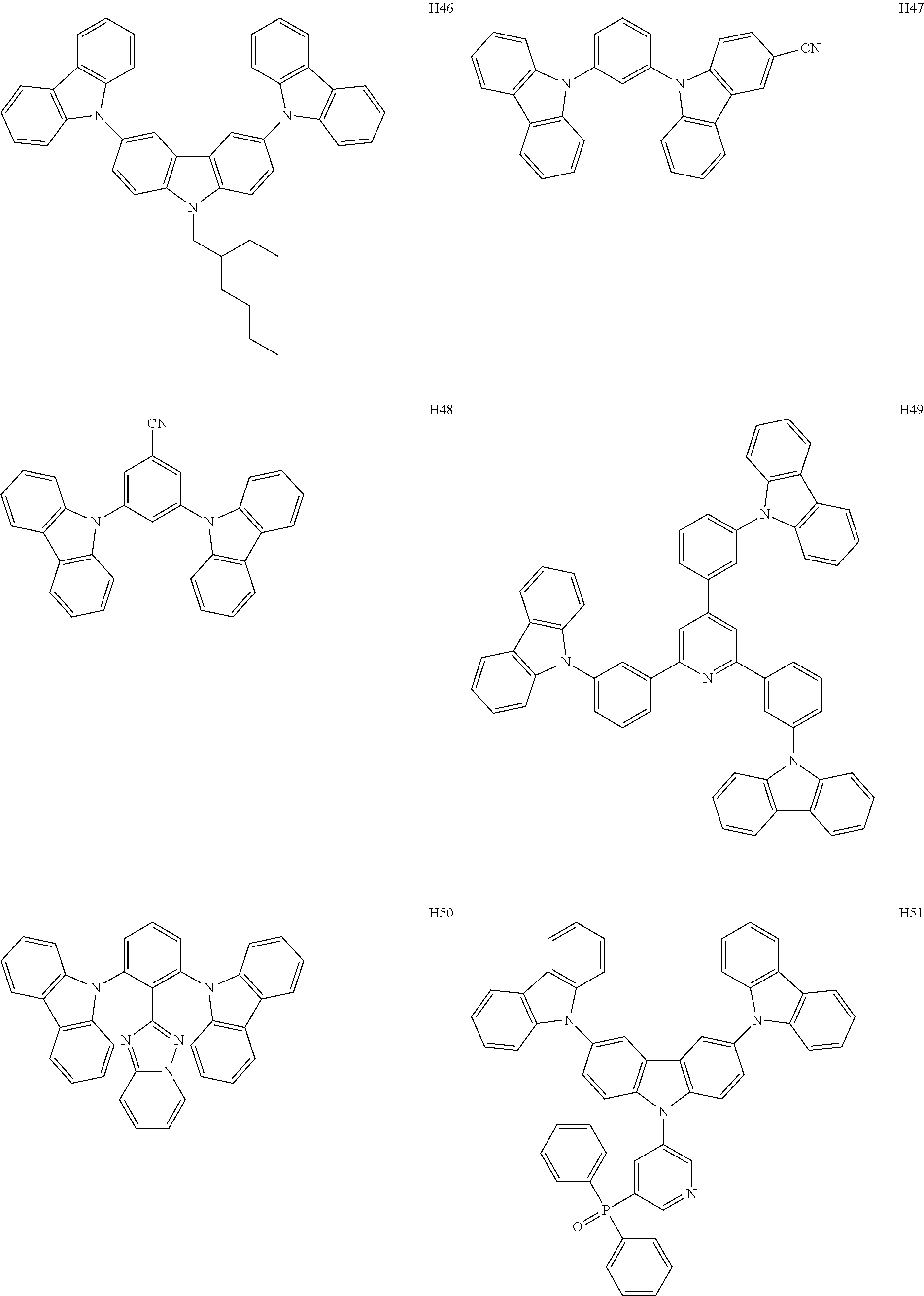 [SMILES: CCCCC(CC)Cn1c2ccc(-n3c4ccccc4c4ccccc43)cc2c2cc(-n3c4ccccc4c4ccccc43)ccc21 ; N#Cc1ccc2c(c1)c1ccccc1n2-c1cccc(-n2c3ccccc3c3ccccc32)c1 ; N#Cc1cc(-n2c3ccccc3c3ccccc32)cc(-n2c3ccccc3c3ccccc32)c1 ; c1cc(-c2cc(-c3cccc(-n4c5ccccc5c5ccccc54)c3)nc(-c3cccc(-n4c5ccccc5c5ccccc54)c3)c2)cc(-n2c3ccccc3c3ccccc32)c1 ; c1cc(-n2c3ccccc3c3ccccc32)c(-c2nc3ccccn3n2)c(-n2c3ccccc3c3ccccc32)c1 ; O=P(c1ccccc1)(c1ccccc1)c1cncc(-n2c3ccc(-n4c5ccccc5c5ccccc54)cc3c3cc(-n4c5ccccc5c5ccccc54)ccc32)c1]

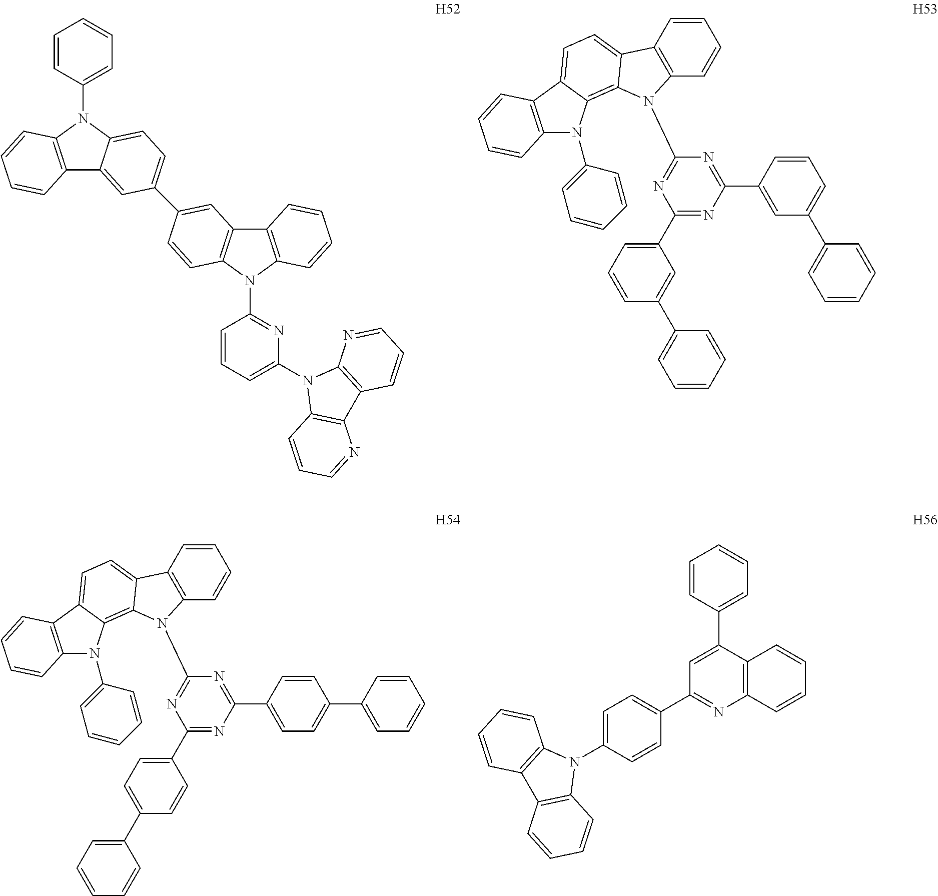 [SMILES: c1ccc(-n2c3ccccc3c3cc(-c4ccc5c(c4)c4ccccc4n5-c4cccc(-n5c6cccnc6c6cccnc65)n4)ccc32)cc1 ; c1ccc(-c2cccc(-c3nc(-c4cccc(-c5ccccc5)c4)nc(-n4c5ccccc5c5ccc6c7ccccc7n(-c7ccccc7)c6c54)n3)c2)cc1 ; c1ccc(-c2ccc(-c3nc(-c4ccc(-c5ccccc5)cc4)nc(-n4c5ccccc5c5ccc6c7ccccc7n(-c7ccccc7)c6c54)n3)cc2)cc1 ; c1ccc(-c2cc(-c3ccc(-n4c5ccccc5c5ccccc54)cc3)nc3ccccc23)cc1]

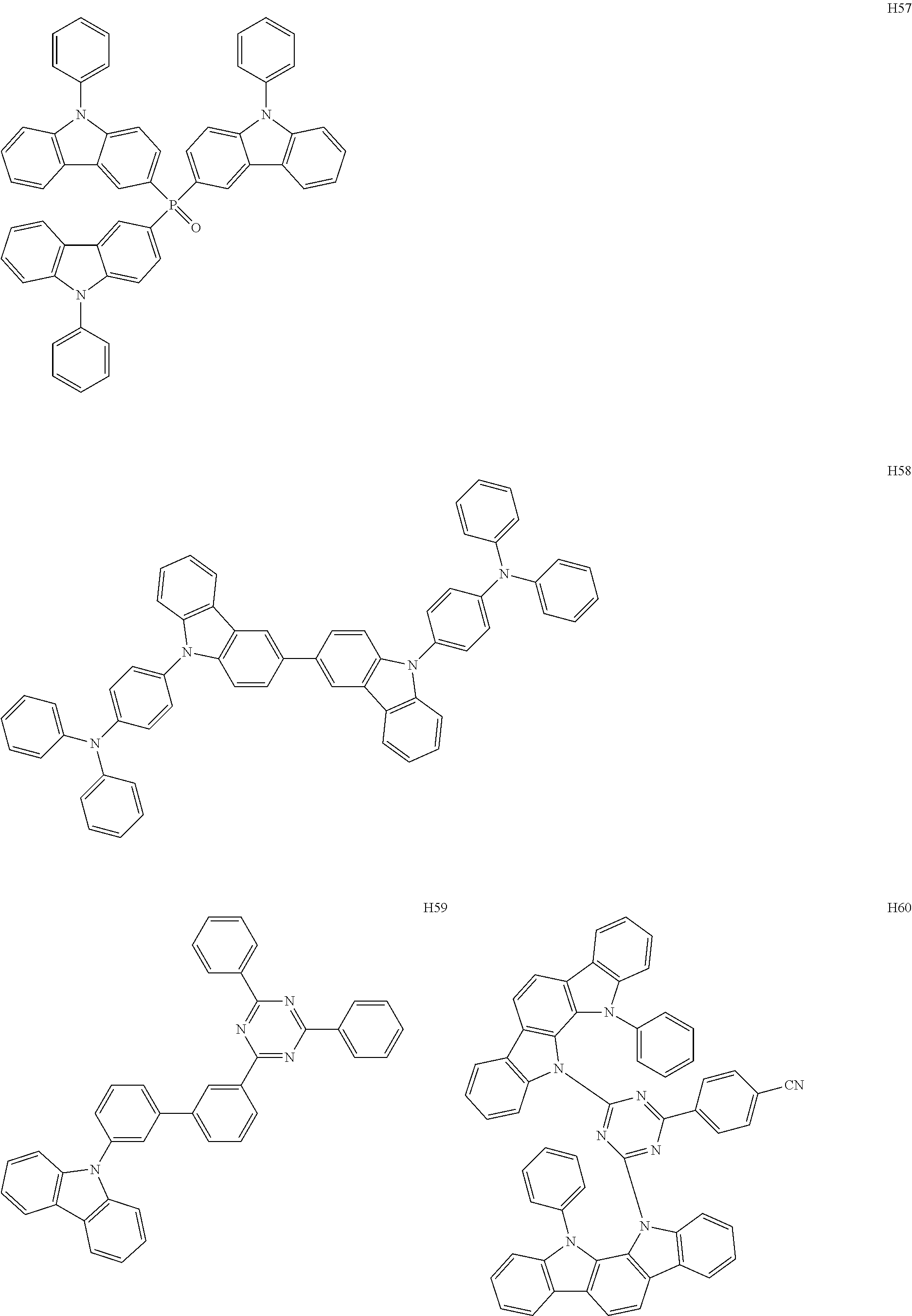 [SMILES: O=P(c1ccc2c(c1)c1ccccc1n2-c1ccccc1)(c1ccc2c(c1)c1ccccc1n2-c1ccccc1)c1ccc2c(c1)c1ccccc1n2-c1ccccc1 ; c1ccc(N(c2ccccc2)c2ccc(-n3c4ccccc4c4cc(-c5ccc6c(c5)c5ccccc5n6-c5ccc(N(c6ccccc6)c6ccccc6)cc5)ccc43)cc2)cc1 ; c1ccc(-c2nc(-c3ccccc3)nc(-c3cccc(-c4cccc(-n5c6ccccc6c6ccccc65)c4)c3)n2)cc1 ; N#Cc1ccc(-c2nc(-n3c4ccccc4c4ccc5c6ccccc6n(-c6ccccc6)c5c43)nc(-n3c4ccccc4c4ccc5c6ccccc6n(-c6ccccc6)c5c43)n2)cc1]

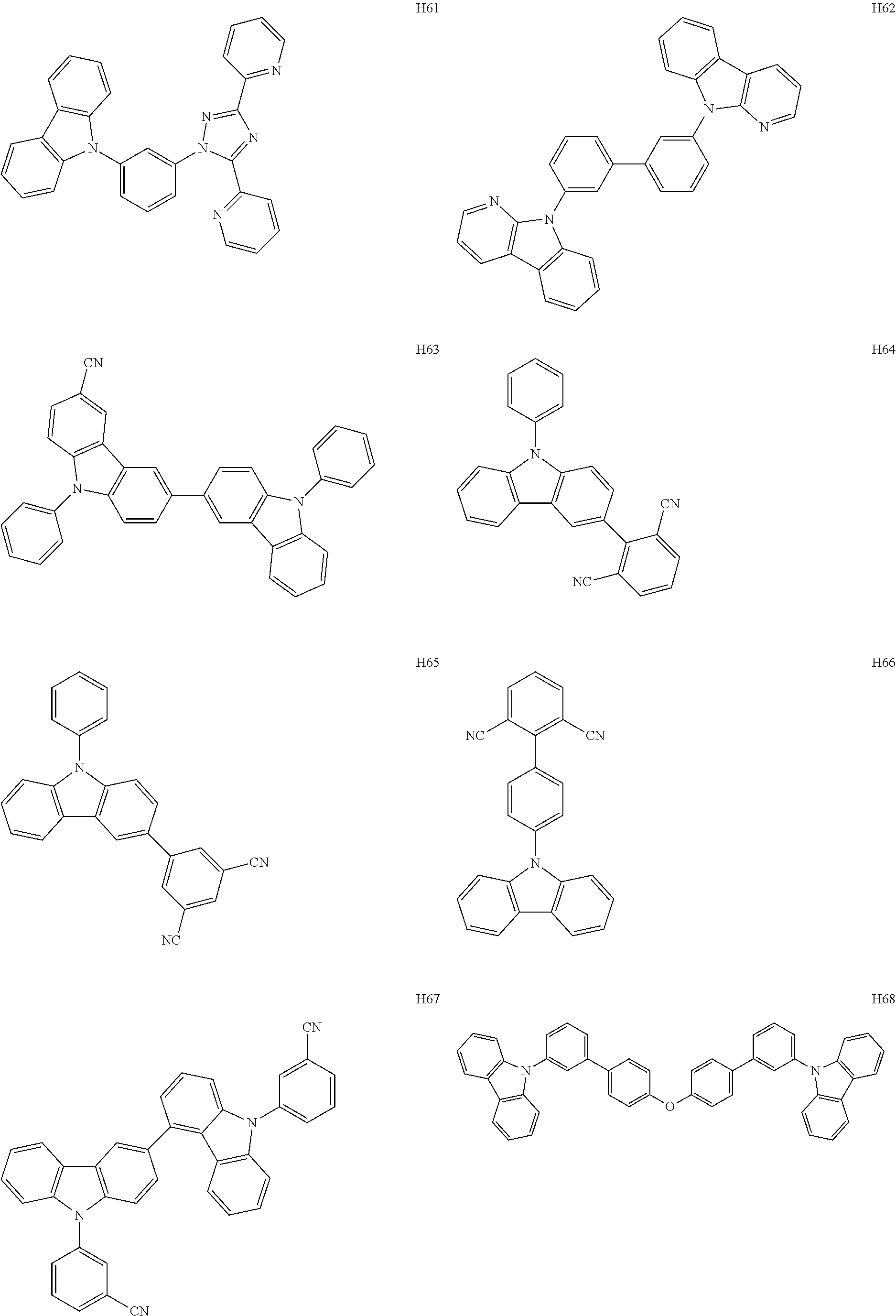

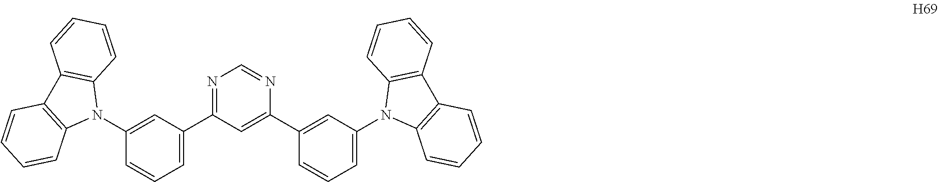 [SMILES: c1cc(-c2cc(-c3cccc(-n4c5ccccc5c5ccccc54)c3)ncn2)cc(-n2c3ccccc3c3ccccc32)c1]

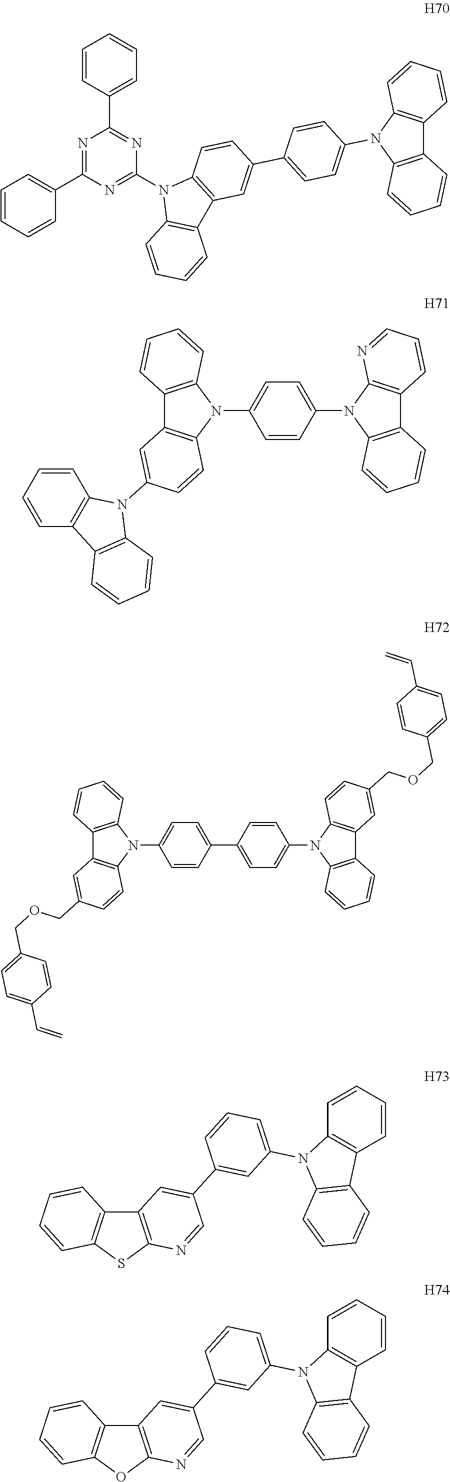 [SMILES: c1ccc(-c2nc(-c3ccccc3)nc(-n3c4ccccc4c4cc(-c5ccc(-n6c7ccccc7c7ccccc76)cc5)ccc43)n2)cc1 ; c1ccc2c(c1)c1ccccc1n2-c1ccc2c(c1)c1ccccc1n2-c1ccc(-n2c3ccccc3c3cccnc32)cc1 ; C=Cc1ccc(COCc2ccc3c(c2)c2ccccc2n3-c2ccc(-c3ccc(-n4c5ccccc5c5cc(COCc6ccc(C=C)cc6)ccc54)cc3)cc2)cc1 ; c1cc(-c2cnc3sc4ccccc4c3c2)cc(-n2c3ccccc3c3ccccc32)c1 ; c1cc(-c2cnc3oc4ccccc4c3c2)cc(-n2c3ccccc3c3ccccc32)c1]

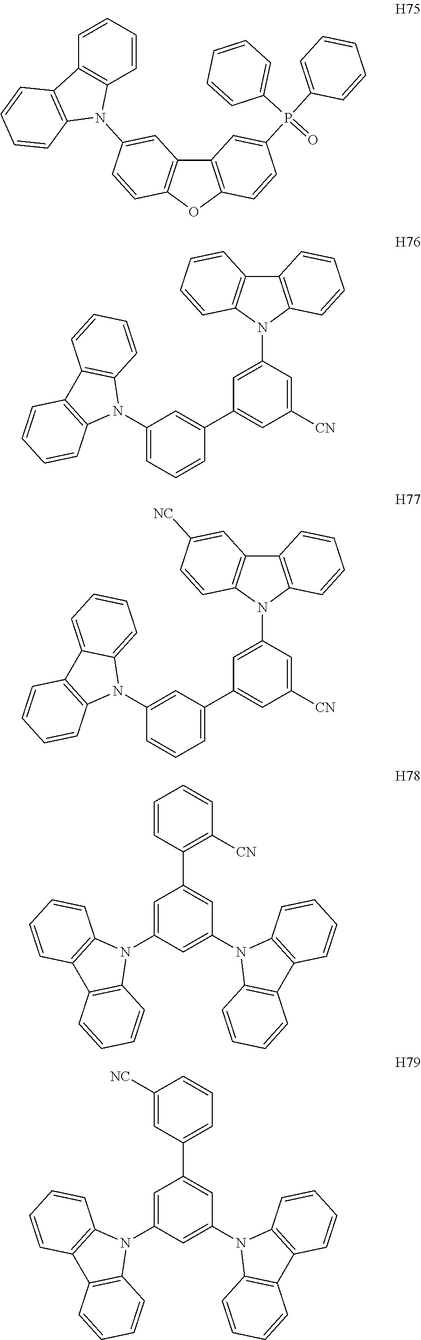

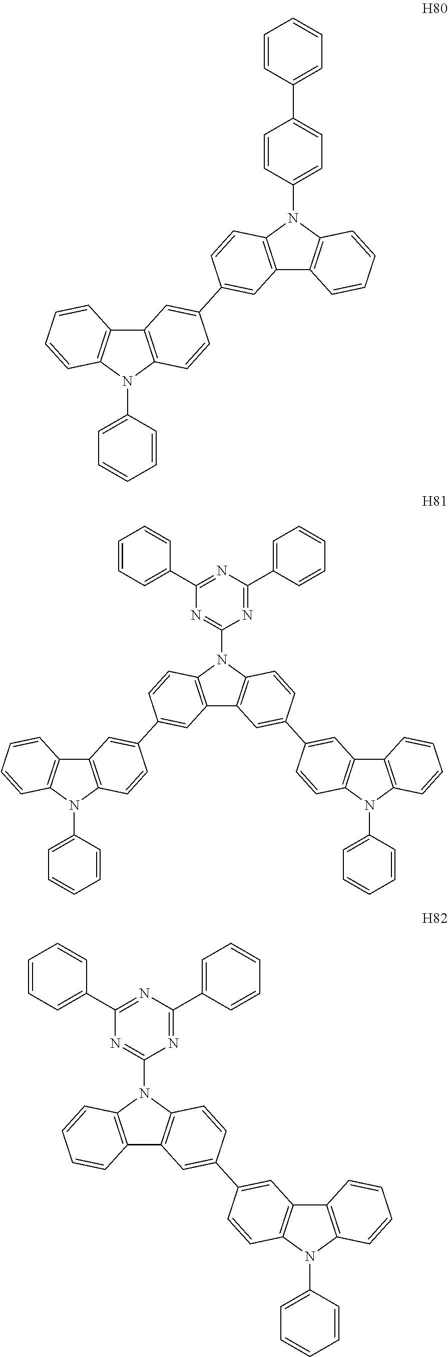 [SMILES: c1ccc(-c2ccc(-n3c4ccccc4c4cc(-c5ccc6c(c5)c5ccccc5n6-c5ccccc5)ccc43)cc2)cc1 ; c1ccc(-c2nc(-c3ccccc3)nc(-n3c4ccc(-c5ccc6c(c5)c5ccccc5n6-c5ccccc5)cc4c4cc(-c5ccc6c(c5)c5ccccc5n6-c5ccccc5)ccc43)n2)cc1 ; c1ccc(-c2nc(-c3ccccc3)nc(-n3c4ccccc4c4cc(-c5ccc6c(c5)c5ccccc5n6-c5ccccc5)ccc43)n2)cc1]

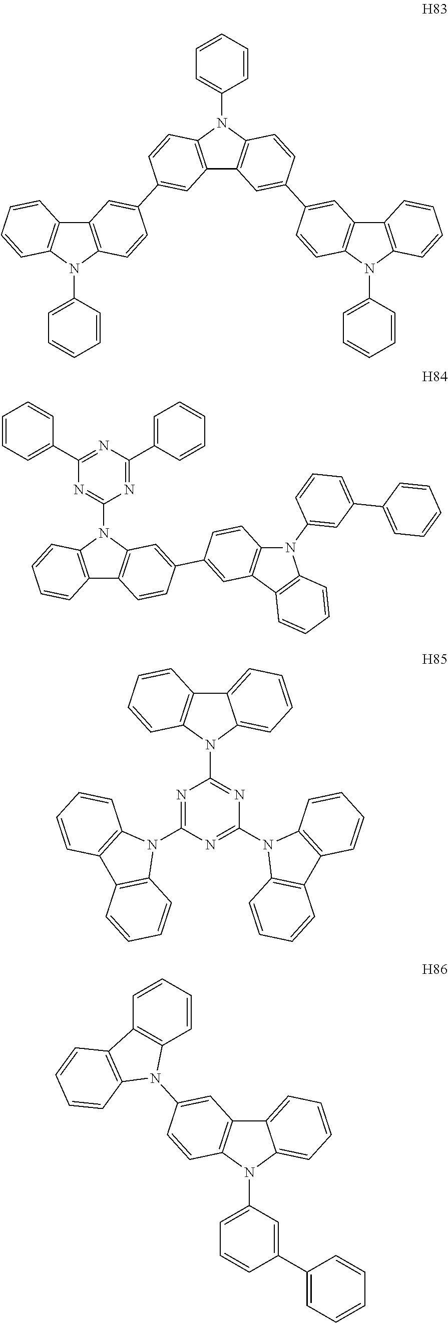 [SMILES: c1ccc(-n2c3ccccc3c3cc(-c4ccc5c(c4)c4cc(-c6ccc7c(c6)c6ccccc6n7-c6ccccc6)ccc4n5-c4ccccc4)ccc32)cc1 ; c1ccc(-c2cccc(-n3c4ccccc4c4cc(-c5ccc6c7ccccc7n(-c7nc(-c8ccccc8)nc(-c8ccccc8)n7)c6c5)ccc43)c2)cc1 ; c1ccc2c(c1)c1ccccc1n2-c1nc(-n2c3ccccc3c3ccccc32)nc(-n2c3ccccc3c3ccccc32)n1 ; c1ccc(-c2cccc(-n3c4ccccc4c4cc(-n5c6ccccc6c6ccccc65)ccc43)c2)cc1]

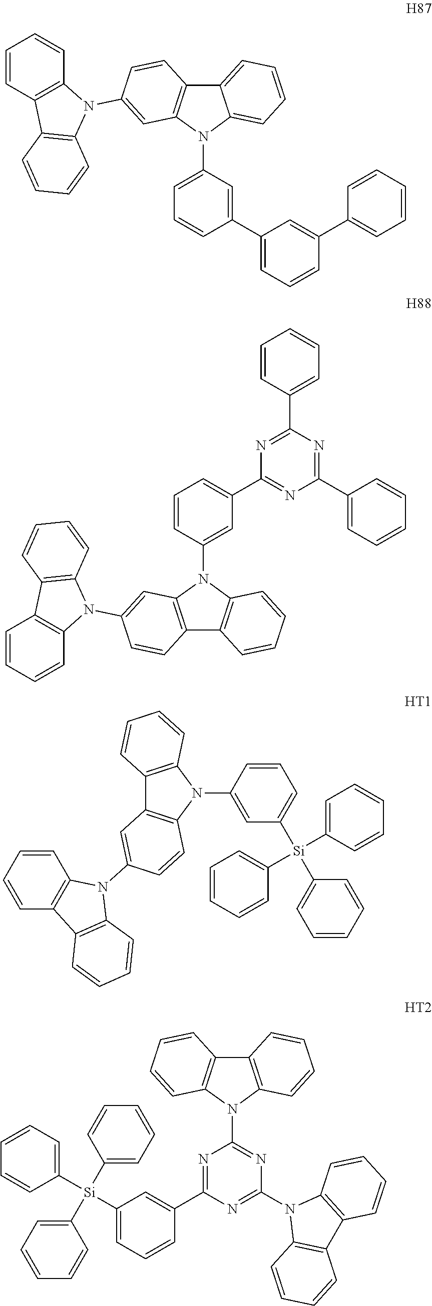

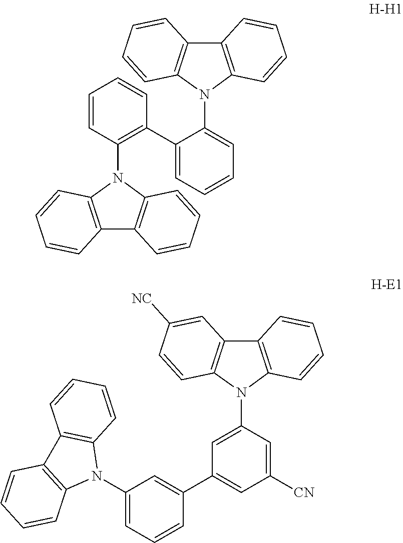

Accordingly, the material for an organic EL device according to an embodiment may include the compound of Formula (1), the phosphorescent complex, and the host material, wherein the host material may include the compound having a structure represented by Formula (6). In addition, the material for an organic EL device according to an embodiment may include the compound of Formula (1) and the host material, wherein the host material may include the compound having a structure represented by Formula (6). The material for an organic EL device according to an embodiment may include the compound of Formula (1), the phosphorescent complex, and the host material, wherein the host material may include at least two types of the compound having a structure represented by Formula (6). Here, for example, the compound having a structure represented by Formula (6) may preferably include Compounds HT-1 and HT-2.

The compound having a triazine ring structure is not particularly limited, but may preferably be a compound having a structure represented by Formula (7):

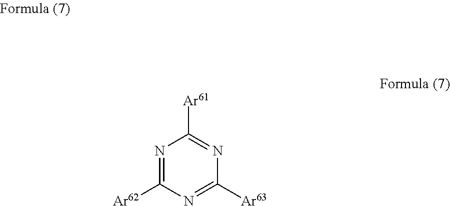

wherein, in Formula (7),
Ar⁶¹ to Ar⁶³ may each independently be a substituted or unsubstituted aromatic hydrocarbon group or a substituted or unsubstituted heterocyclic group.

In Formula (7), a description of the substituted or unsubstituted aromatic hydrocarbon group may be the same as the description of the group of (1c) in Formula (1). In addition, a description of the substituted or unsubstituted heterocyclic group may be the same as the description of the group of (1d) in Formula (1).

A substituent substituting the aromatic hydrocarbon group or the heterocyclic group in Formula (7) is not particularly limited, but may preferably be a substituent substituting the groups of (1a) to (1d) in Formula (1). In addition, the unsubstituted aromatic hydrocarbon group may preferably be a substituted silyl group. In addition, a description of the unsubstituted aromatic hydrocarbon group may be the same as the description of the unsubstituted group in the group of (1c).

The compound having a triazine ring structure may be a compound including a silyl group (i.e., a compound having a triazine ring structure with a silyl group).

In addition, the compound having a triazine ring structure may be used in combination with the compound having a carbazole ring structure or with a compound having a ring structure in which at least one of ring-forming carbon atoms of the carbazole ring is substituted with a nitrogen atom.

Hereinafter, as the host material according to an embodiment, a compound having a triazine ring structure will be described in detail, but the disclosure is not limited thereto.

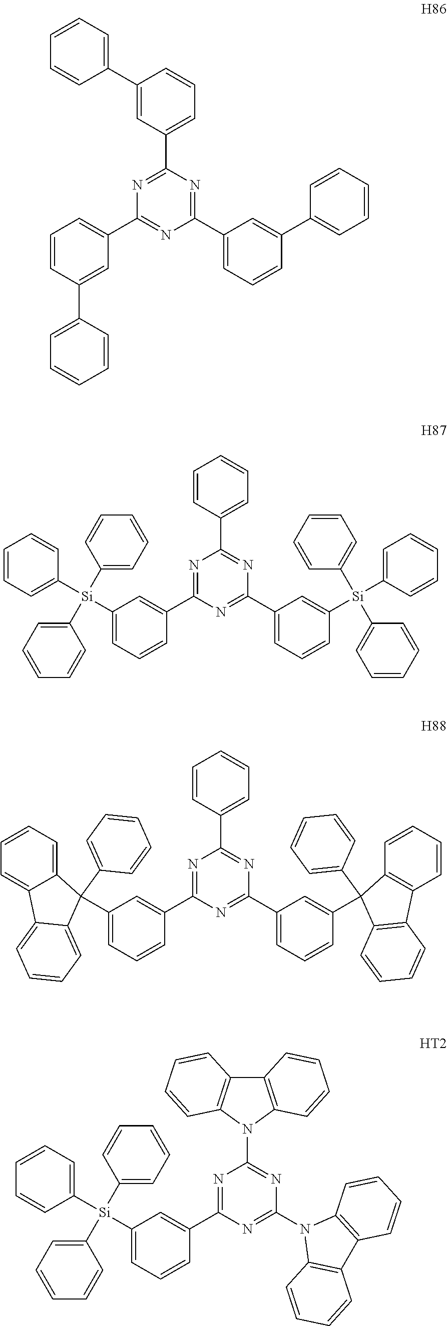 [SMILES: c1ccc(-c2cccc(-c3nc(-c4cccc(-c5ccccc5)c4)nc(-c4cccc(-c5ccccc5)c4)n3)c2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; c1ccc(-c2nc(-c3cccc(C4(c5ccccc5)c5ccccc5-c5ccccc54)c3)nc(-c3cccc(C4(c5ccccc5)c5ccccc5-c5ccccc54)c3)n2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1]

Accordingly, the material for an organic EL device according to an embodiment may include the compound of Formula (1), the phosphorescent complex, and the host material, wherein the host material may include the compound having a structure represented by Formula (6). In addition, the material for an organic EL device according to an embodiment may include the compound of Formula (1), the phosphorescent complex, and the host material, wherein the host material may include the compound having a structure represented by Formula (6) and the compound having a structure represented by Formula (7). In addition, the material for an organic EL device according to an embodiment may include the compound of Formula (1) and the host material, wherein the host material may include the compound having a structure represented by Formula (6). In addition, the material for an organic EL device according to an embodiment may include the compound of Formula (1) and the host material, wherein the host material may include the compound having a structure represented by Formula (6) and the compound having a structure represented by Formula (7).

An amount of the host material with respect to the total mass of the material for an organic EL device (particularly, a material for an emission layer) is not particularly limited, but may be 5 mass % or more. In addition, the amount may more be 10 mass % or more, may be 20 mass % or more, may be 40 mass % or more, or may be 40 mass % or more. Within the ranges above, an organic EL device having excellent color purity of luminescence and according having high luminescence efficiency may be obtained. In addition, the amount of the host material with respect to the total mass of the material for an organic EL device (particularly, a material for an emission layer) is not particularly limited, but may be 99 mass % or less. In addition, the amount may more preferably be 98 mass % or less, and even more preferably be 95 mass % or less. Within the ranges above, an organic EL device having excellent color purity of luminescence and according having high luminescence efficiency may be obtained. In addition, in an emission layer of an organic EL device described below, the preferable amount of the host material with respect to the emission layer may be the same as described above.

When the material for an organic EL device includes the host material, the amount of the host material may be 1000 parts by mass or more with respect to 100 parts by mass of the compound of Formula (1). In addition, the amount of the phosphorescent complex may be 150 parts by mass or more, and even more preferably be 200 parts by mass or more, with respect to 100 parts by mass of the compound of Formula (1). Within the ranges above, an organic EL device having excellent color purity of luminescence and according having high luminescence efficiency may be obtained. In addition, the amount of the host material is not particularly limited, but may be 200,000 parts by mass or less with respect to 100 parts by mass of the compound of Formula (1). In addition, the amount of the host material may be 150000 parts by mass or less, and even be 100,000 parts by mass or less, with respect to 100 parts by mass of the compound of Formula (1). Within the ranges above, an organic EL device having excellent color purity of luminescence and according having high luminescence efficiency may be obtained. In addition, in an emission layer of an organic EL device described below, the amount (parts by mass) of the host material with respect to 100 parts by mass of the compound of Formula (1) may be the same as described above.

### Organic EL Device

Another aspect of the disclosure provides an organic EL device including an emission layer that includes the compound of Formula (1). In addition, in the organic EL device, the emission layer may include the compound of Formula (1), the phosphorescent complex, and the host material in addition to the compound of Formula (1) and the phosphorescent complex. Here, the phosphorescent complex may preferably be a platinum complex.

In addition, another aspect of the disclosure provides an organic EL device including the material for an organic EL device. In addition, in the organic EL device, the material for an organic EL device may further include the host material. In addition, in the organic EL device, the phosphorescent complex included therein may preferably be a platinum complex.

In the organic EL device, the host material included therein may preferably include the compound having a carbazole ring structure, the compound having a ring structure in which at least one of ring-forming carbon atoms of the carbazole ring is substituted with a nitrogen atom, or the compound having a triazine ring structure. In addition, in the organic EL device, the host material included therein may include the compound having a structure of Formula (6). In addition, in the organic EL device, the host material included therein may include the compound having a structure of Formula (7). In addition, in the organic EL device, the host material included therein may preferably include the compound having a structure of Formula (6) and the compound having a structure of Formula (7).

In addition, in the organic EL device, the phosphorescent complex included therein may preferably include the compound having a structure of Formula (5).

The organic EL device according to an embodiment is not particularly limited, and for example, may include a first electrode, a second electrode, and a single or a plurality of organic layers. The second electrode may be arranged on the first electrode.

The organic EL device according to an embodiment may include a first electrode, a second electrode, and a single or a plurality of layers arranged between the first electrode and the second electrode. Here, the layer may include at least one organic layer, wherein the at least one organic layer may include the compound of Formula (1) or the material for an organic EL device. The at least one organic layer including the compound of Formula (1) or the material for an organic EL device may preferably include an emission layer. According to the aforementioned organic EL devices, high-purity luminescence may be implemented.

As such, the emission layer may preferably include at least one of the compound of Formula (1).

The emission layer may be a single layer consisting of a plurality of different materials. In addition, the emission layer may have a multiple-layer structure including a plurality of layers consisting of a plurality of different materials.

The emission layer is not particularly limited, but for example, may include a host material and a dopant material. The compound of Formula (1) may be used as a host material or a dopant material, but may preferably be used as a dopant material.

Accordingly, in an embodiment, the organic EL device may include the emission layer, and the emission layer may include the compound of Formula (1) or the material for an organic EL device. In addition, the emission layer may preferably include the material for an organic EL device. In terms of a peak wavelength in an emission spectrum, color purity of luminescence, and luminescence efficiency, the material for an organic EL device may preferably include the host material in addition to the compound of Formula (1). From the same perspective, the material for an organic EL device may preferably include a phosphorescent complex and a host material in addition to the compound of Formula (1). In addition, the preferred ranges of the amount or amount ratio of the compound of Formula (1), the phosphorescent complex, and the host material in the emission layer may be the same as the preferred amount or amount ratio of the material for an organic EL device.

A thickness of the emission layer is not particularly limited, but may preferable be in range of about 1 nm to about 100 nm, and more preferably be in a range of about 10 nm to about 50 nm.

A method of forming the emission layer is not particularly limited, but for example, may include known methods of forming the emission layer, such as a vacuum deposition method, a spin coating method, a Langmuir-Blodgett (LB) method, an inkjet printing method, a laser printing method, a laser induced thermal imaging (LITI) method, and the like.

The luminescence wavelength of the organic EL device is not particularly limited. A preferable range of the luminescence wavelength of the organic EL device may be, for example, the same as the peak wavelength of luminescence in PL of the compound of Formula (1). Among these ranges, regarding the characteristics of currently commercialized products, for blue light luminescence, light having a peak in the wavelength region of about 445 nm to about 470 nm, light having a peak in the wavelength region of about 450 nm to about 470 nm may be preferable, and light having a peak in the wavelength region of about 450 nm to about 465 nm may be most preferable.

Hereinafter, with reference to the attached drawings, an embodiment where the organic EL device according to an embodiment incudes an organic layer in addition to the emission layer will be described in detail. In addition, the same elements in the description of drawings will be denoted by the same reference numerals, and thus redundant description thereof will be omitted. In addition, the dimension ratio of the drawings may be exaggerated for convenience of explanation, and thus may differ from the actual ratio.

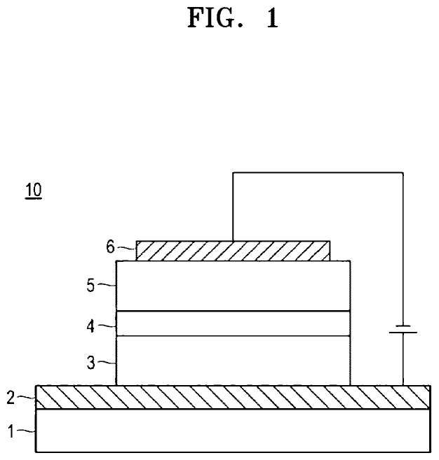

FIGS. 1 to 3 are each a schematic cross-sectional view of an organic EL device according to an embodiment. However, the structure of the organic EL device described herein is not limited to the forms shown in FIGS. 1 to 3.

FIG. 1 is a schematic cross-sectional view of an organic EL device 10 according to an embodiment. The organic EL device 10 according to an embodiment includes a substrate 1, a first electrode 2, a hole transport region 3, an emission layer 4, an electron transport region 5, and a second electrode 6 that are stacked in the stated order.

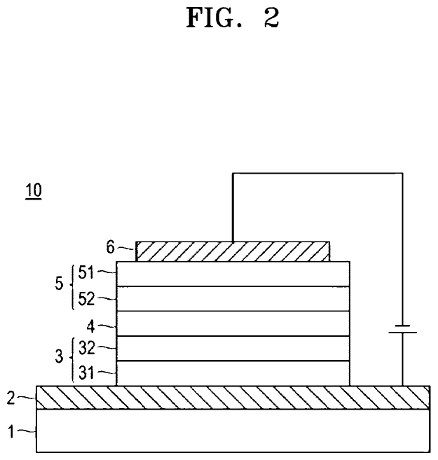

FIG. 2 is a schematic cross-sectional view of the organic EL device according to another embodiment. The organic EL device 10 according to an embodiment includes a substrate 1, a first electrode 2, a hole transport region 3, an emission layer 4, an electron transport region 5, and a second electrode 6 that are stacked in the stated order. In FIG. 2, the hole transport region 3 includes a hole injection layer 31 and a hole transport layer 32 that are stacked in the stated order. In addition, as shown in FIG. 2, the electron transport region 5 includes an electron transport layer 52 and an electron injection layer 51 that are stacked in the stated order.

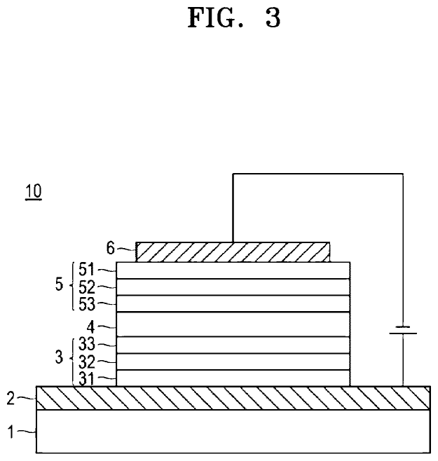

FIG. 3 is a schematic cross-sectional view of the organic EL device 10 according to other embodiments. The organic EL device 10 according to an embodiment includes a substrate 1, a first electrode 2, a hole transport region 3, an emission layer 4, an electron transport region 5, and a second electrode 6 that are stacked in the stated order. In FIG. 3, the hole transport region 3 includes a hole injection layer 31, a hole transport layer 32, and an electron-blocking layer 33 that are stacked in the stated order. In addition, as shown in FIG. 3, the electron transport region 5 includes a hole-blocking layer 53, an electron transport layer 52, and an electron injection layer 51 that are stacked in the stated order.

Hereinafter, the substrate, each region, and each layer will be described in detail.

The organic EL device 10 may include the substrate (1). The substrate 1 may be a substrate used in a general organic EL device. For example, the substrate 1 may be a glass substrate, a semiconductor substrate such as a silicon substrate, or a transparent plastic substrate.

The first electrode 2 may have conductivity. In the organic EL device according to an embodiment, the first electrode 2 may preferably be a positive electrode. In addition, the first electrode 2 may preferably be a pixel electrode. In addition, the first electrode 2 may preferably be a transmissive electrode, a transflective electrode, or a reflective electrode.

A material for the first electrode 2 is not particularly limited, but for example, may include a metal, a metal alloy, or a conductive compound. When the first electrode 2 is a transmissive electrode, the first electrode 2 may include a transparent metal oxide, such as indium tin oxide (ITO), indium zinc oxide (IZO), zinc oxide (ZnO), indium tin zinc oxide (ITZO), and the like. When the first electrode 2 is a transflective electrode or a reflective electrode, the first electrode 2 may include Ag, Mg, Cu, Al, Pt, Pd, Au, Ni, Nd, Ir, Cr, Li, Ca, LiF/Ca, LiF/Al, Mo, Ti, or a compound or mixture thereof (for example, a mixture of Ag and Mg).

The first electrode 2 may be a single layer consisting of a single material, or may be a single layer consisting of a plurality of different materials. In addition, the first electrode 2 may have a multiple-layer structure including a plurality of layers consisting of a plurality of different materials.

A thickness of the first electrode 2 is not particularly limited, but may preferably be in a range of about 10 nm to about 1000 nm, and more preferably be in a range of about 50 nm to about 300 nm.

The hole transport region 3 may be provided on the first electrode 2. The hole transport region 3 may include at least one of a hole injection layer 31, a hole transport layer 32, a hole buffer layer (not shown), and an electron-blocking layer 33.

The hole transport region 3 may be a single layer consisting of a single material, or may be a single layer consisting of a plurality of different materials. In addition, the hole transport region 3 may have a multiple-layer structure including a plurality of layers consisting of a plurality of different materials.

For example, the hole transport region 3 may have a single layer structure with the hole injection layer 31 or the hole transport layer 32. In addition, for example, the hole transport region 3 may have a single layer structure formed by using a hole-injecting material and a hole-transporting material. In addition, for example, the hole transport region 3 may have a hole injection layer 31/hole transport layer 32 structure, wherein the constituent layers are stacked from the first electrode 2. In addition, for example, the hole transport region 3 may have a hole injection layer 31/hole transport layer 32/hole buffer layer (not shown) structure. In addition, for example, the hole transport region 3 may have a hole injection layer 31/hole buffer layer (not shown) structure, wherein the constituent layers are stacked from the first electrode 2. In addition, for example, the hole transport region 3 may have a hole transport layer 32/hole buffer layer (not shown) structure, wherein the constituent layers are stacked from the first electrode 2. In addition, for example, the hole transport region 3 may have a hole injection layer 31/hole transport layer 32/electron-blocking layer 33 structure, wherein the constituent layers are stacked from the first electrode 2. However, the structure of the hole transport region 3 is not limited thereto.

The hole injection layer 31 or other layers constituting the hole transport region 3 are not particularly limited, but for example, may include a known hole-injecting material. Examples of the hole-injecting material are a phthalocyanine compound, such as copper phthalocyanine, N,N′-diphenyl-N,N′-bis-[4-(phenyl-m-tolyl-amino)-phenyl]-biphenyl-4,4′-diamine (DNTPD), 4,4′,4″-tris(3-methylphenylphenylamino)triphenylamine (m-MTDATA), 4,4′,4″-tris(N,N-diphenylamino)triphenylamine (TDATA), 4,4′,4″-tris {N,-(2-naphthyl)-N-phenylamino}-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphorsulfonic acid (PANI/CSA), polyaniline/poly(4-styrenesulfonate) (PANI/PSS), N,N′-di(naphthalen-1-yl)-N,N′-diphenyl-benzidine (NPB), polyetherketone (TPAPEK) including triphenylamine, 4-isopropyl-4′-methyldiphenyliodonium tetrakis(pentafluorophenyl) borate, dipyrazino[2,3-f: 2,3′-h]quinoxalin-2,3,6,7,10,11-hexacarbonitrile (HAT-CN), 1,3,4,5,7,8-hexafluorotetracyano-2,6-naphthoquinodimethane (F6-TCNNQ), and the like.

In addition, the hole injection layer 32 or other layers constituting the hole transport region 3 are not particularly limited, but for example, may include a known hole-transporting material. Examples of the hole-transporting material are a carbazole-based derivative, such as N-phenylcarbazole, polyvinylcarbazole, etc., a fluorene-based derivative, a triphenylamine-based derivative, such as N,N′-bis(3-methylphenyl)-N,N′-diphenyl-[1,1-biphenyl]-4,4′-diamine (TPD), 4,4′,4″-tris(N-carbazolyl)triphenylamine (TCTA), etc., N,N′-do (naphthalen-1-yl)-N,N′-diphenyl-benzidine (NPB), 4,4′-cyclohexylidenbis[N,N-bis(4-methylphenyl)benzeneamine] (TAPC), 4,4′-bis[N,N′-(3-tolyl)amino]-3,3′-dimethylbiphenyl (HMTPD), 1,3-bis(N-carbazolyl)benzene (mCP), Compound HTM1, Compound HTM2, Compound HT1, and the like:

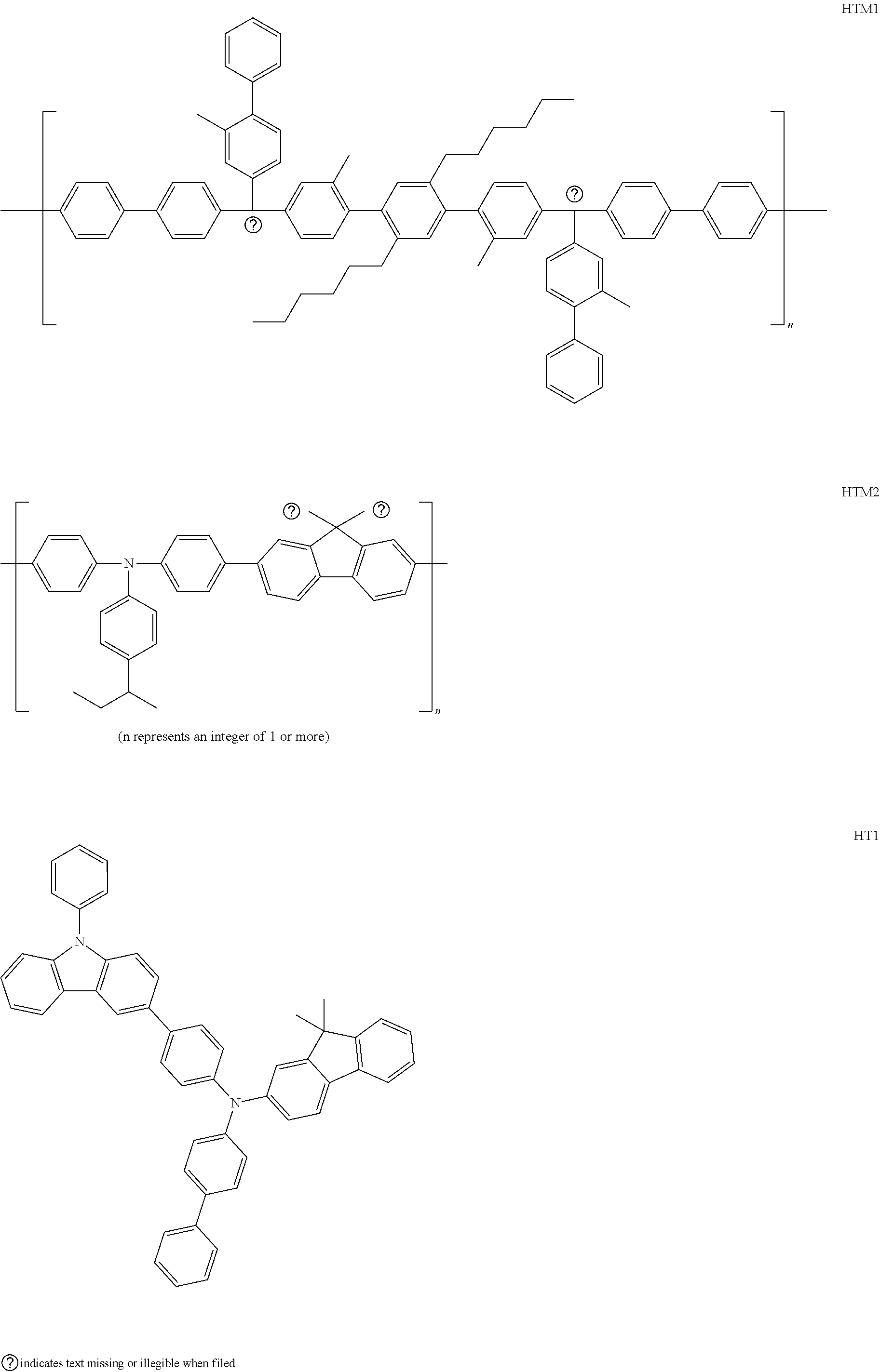

The hole transport region 3 may further include, in addition to the hole-injecting material or the hole-transporting material, a charge generation material to improve conductivity. The charge generation material may be homogeneously or non-homogeneously dispersed in the hole transport region 3 or each layer thereof. The charge generation material is not particularly limited, and an example thereof may be a known charge generation material. An example of the charge generation material may be a p-dopant. Examples of the p-dopant may include a quinone derivative as such tetracyanoquinonedimethane (TCNQ) or 2,3,5,6-tetrafluoro-tetracyanoquinodimethane (F4-TCNQ), a metal oxide such as tungsten oxide or molybdenum oxide, a cyano group-containing compound, and the like.

The hole buffer layer (not shown) compensates for the resonance distance caused by the wavelength of light emitted from the emission layer 4, thereby increasing light extraction efficiency. Materials included in the hole buffer layer (not shown) are not particularly limited, and may include any material used in the hole buffer layer (not shown). For example, the compounds that may be included in the hole transport region 3 may be used.

The electron-blocking layer 33 is a layer that prevents injection of electrons from the electron transport region 5 to the hole transport region 3. Materials included in the electron-blocking layer 33 are not particularly limited, and may include any material used in the electron-blocking layer 33. For example, host materials included in the emission layer (as the material for an organic EL device) may be used, and examples thereof are Compounds H55, H86, and H87 and the like.

A thickness of the hole transport region 3 is not particularly limited, but may be in a range of about 1 nm to about 1000 nm, or in a range of about 10 nm to about 500 nm. In addition, for each layer constituting the hole transport region 3, a thickness of the hole injection layer 31 is not particularly limited, but may be in a range of about 3 nm to about 200 nm. A thickness of the hole transport layer 32 is not particularly limited, but may be in a range of about 3 nm to about 200 nm. A thickness of the electron-blocking layer 33 is not particularly limited, but may be in a range of about 1 nm to about 100 nm. In addition, a thickness of the hole buffer layer (not shown) is not particularly limited as long as the thickness is within a range that allows the hole buffer layer to function without interfering with the function of the organic EL device. When the thickness of the hole transport region 3, the hole injection layer 31, the hole transport layer 32, or the electron-blocking layer 33 is within the ranges above, satisfactory hole transporting characteristics may be obtained while suppressing a substantial increase in driving voltage.

Methods of forming the hole transport region 3 or each layer constituting the hole transport region 3 are not particularly limited, but for example, may include a vacuum deposition method, a spin coating method, an LB method, an inkjet printing method, a laser-printing method, an LITI method, and the like.

The emission layer 4 may be arranged on the hole transport region 3. Details of the emission layer 4 may be the same as described above.

The electron transport region 5 is arranged on the emission layer 4. The electron transport region 5 may include at least one of an electron injection layer 51, an electron transport layer 52, and a hole-blocking layer 53, but embodiments are not limited thereto.

The electron transport region 5 may be a single layer consisting of a single material, or may be a single layer consisting of a plurality of different materials. In addition, the electron transport region 5 may have a multiple-layer structure including a plurality of layers consisting of a plurality of different materials. For example, the electron transport region 5 may have a single layer structure with the electron injection layer 51 or the electron transport layer 52. In addition, for example, the electron transport region 5 may have a single layer structure formed by using an electron-injecting material and an electron-transporting material. In addition, for example, the electron transport region 5 may have an electron transport layer 52/electron injection layer 51 structure, wherein constituent layers are stacked from the emission layer 4. In addition, for example, the electron transport region 5 may have a hole-blocking layer 53/electron transport layer 52/electron injection layer 51 structure, wherein constituent layers are stacked from the emission layer 4. However, the structure of the electron transport region 5 is not limited to the above examples.

The electron injection layer 51 or other layers constituting the electron transport region 5 are not particularly limited, but for example, may include a known electron-injecting material. Examples of the electron-injecting material are LiF, lithium quinolate (LiQ), Li₂O, BaO, NaCl, CsF, a lanthanide metal such as Yb, a halogenated metal such as RbCl, and the like. The electron injection layer 51 is not particularly limited, but for example, may include an electron-transporting material which will be described below and an insulating organic metal salt. The organic metal salt is not particularly limited, but for example, may be a material having an energy band gap of 4 eV or more. Examples of the organic metal salt are a metal salt of acetic acid, a metal salt of benzoic acid, a metal salt of acetoacetic acid, a metal salt of acetylacetonate, a metal salt of stearic acid, and the like.

The electron transport layer 52 or other layers constituting the electron transport region are not particularly limited, but for example, may include a known electron-transporting material. Examples of the electron-transporting material are an anthracene-based compound, tris(8-hydroxyquinolinolato)aluminum (Alq₃), 1,3,5-tri[(3-pyridyl)-phen-3-yl]benzene, 2,4,6-tris(3′-pyridin-3-yl) biphenyl-3-yl)-1,3,5-triazine, 2-(4-(N-phenylbenzoimidazolyl-1-ylphenyl)-9,10-dinaphthylanthracene, 1,3,5-tri (1-phenyl-1H-benzo[d]imidazol-2-yl)phenyl(TPBi), 2,9-dimethyl-4,7-diphenyl-1,10-phenanthroline (BCP), 4,7-diphenyl-1,10-phenanthroline (Bphen), 3-(4-biphenyl)-4-phenyl-5-tert-butylphenyl-1,2,4-triazole (TAZ), 4-(naphthalen-1-yl)-3,5-diphenyl-4H-1,2,4-triazole (NTAZ), tBu-PBD (2-(4-biphenyl)-5-(4-tert-butylphenyl)-1,3,4-oxadiazole), bis(2-methyl-8-quinolinolato-N1,O8)-(1,1′-biphenyl-4-ollato)aluminum (BAlq), berylliumbis(benzoquinolin-10-olato (Bebq₂), 9,10-di(naphthalen-2-yl) anthracene (ADN), lithium quinolate (LiQ), Compound ET1, Compound H91, and the like. In addition, TRE314 (manufactured by Toray, electron-transporting material) may be used.

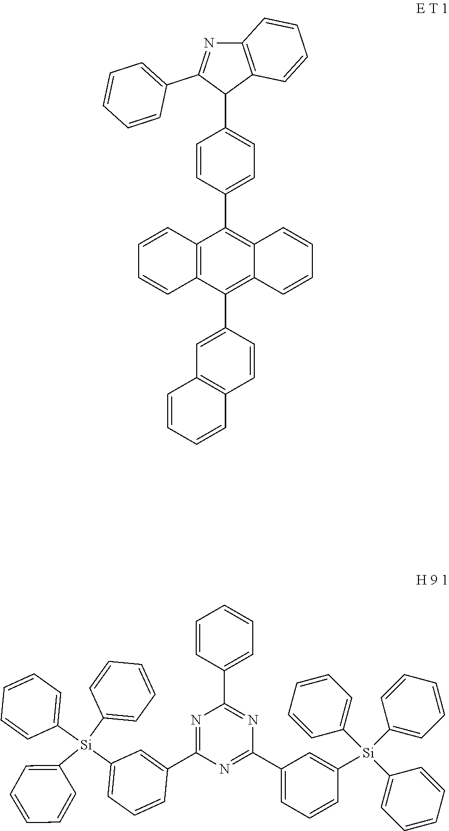 [SMILES: c1ccc(C2=Nc3ccccc3C2c2ccc(-c3c4ccccc4c(-c4ccc5ccccc5c4)c4ccccc34)cc2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1]

The hole-blocking layer 53 is a layer that prevents injection of holes from the hole transport region 3 to the electron transport region 5. Materials included in the hole-blocking layer 53 are not particularly limited, and materials used in a known hole-blocking layer may be used. The hole-blocking layer 53 may include, for example, a known hole-blocking material. Examples of the hole-blocking material are 2,9-dimethyl-4,7-diphenyl-1,10-phenanthroline (BCP), 4,7-diphenyl-1,10-phenanthroline (BPhen), and the like. In addition, for example, host materials included in the emission layer (as the material for an organic EL device) may be used, and examples thereof are Compounds H77 and H87 and the like.

A thickness of the electron transport region 5 is not particularly limited, but may be in a range of about 0.1 nm to about 200 nm, or may be in a range of about 30 nm to about 150 nm. In addition, for each layer constituting the electron transport region 5, a thickness of the electron transport layer 52 is not particularly limited, but may be in a range of about 10 nm to about 100 nm, or may be in a range of about 15 nm to about 50 nm. A thickness of the hole-blocking layer 53 is not particularly limited, but may be in a range of about 1 nm to about 100 nm, or may be in a range of about 5 nm to about 30 nm. A thickness of the electron injection layer 51 is not particularly limited, but may be in a range of about 0.1 nm to about 10 nm, or may be in a range of about 0.3 nm to about 9 nm. When the thickness of the electron injection layer 51 is within the ranges above, satisfactory electron injection characteristics may be obtained while suppressing a substantial increase in driving voltage. In addition, when the thickness of the electron transport region 5, the electron injection layer 51, the electron transport layer 52, or the hole-blocking layer 53 is within the above ranges, satisfactory electron transport characteristics may be obtained while suppressing a substantial increase in driving voltage.

Methods of forming the electron transport region 5 or each layer constituting the electron transport region 5 are not particularly limited, but for example, may include a vacuum deposition method, a spin coating method, an LB method, an inkjet printing method, a laser-printing method, an LITI method, and the like.

The second electrode 6 is arranged on the electron transport region 5. The second electrode 6 may have conductivity. In the organic EL device according to an embodiment, the second electrode 6 may preferably be a common electrode or a negative electrode. In addition, the second electrode 6 may preferably be a transmissive electrode, a transflective electrode, or a reflective electrode.

A material for the second electrode 6 is not particularly limited, but for example, may include a metal, a metal alloy, or a conductive compound. When the second electrode 6 is a transmissive electrode, the second electrode 6 may preferably include a transparent metal oxide, such as ITO, IZO, ZnO, ITZO, etc. When the second electrode 6 is a transflective electrode or a reflective electrode, the second electrode 6 may preferably include Ag, Mg, Cu, Al, Pt, Pd, Au, Ni, Nd, Ir, Cr, Li, Ca, LiF/Ca, LiF/Al, Mo, Ti, or a compound or mixture including the same (e.g., a mixture of Ag and Mg).

The second electrode 6 may be a single layer consisting of a single material, or may be a single layer consisting of a plurality of different materials. In addition, the second electrode 6 may have a multiple-layer structure including a plurality of layers consisting of a plurality of different materials.

A thickness of the second electrode 6 is not particularly limited, but may be in a range of about 10 nm to about 1000 nm.

The second electrode 6 may be connected to an auxiliary electrode (not shown). By connecting the second electrode 6 to the auxiliary electrode, the resistance of the second electrode 6 may be further reduced.

In addition, a capping layer (not shown) may be further arranged on the second electrode 6. The capping layer (not shown) is not particularly limited, but for example, may be a layer including α-NPD, NPB, TPD, m-MTDATA, Alq₃, CuPc, N4,N4,N4′,N4′-tetra(biphenyl-4-yl) biphenyl-4,4′-diamine (TPD15), 4,4′,4″-tri-9-carbazolyltriphenylamine (TCTA), N,N′-bis(naphthalen-1-yl), and the like.

In addition, the materials constituting each layer and each electrode may be used alone or in combination with two or more types.

In the organic EL device 10 of FIGS. 1 to 3, the compound of Formula (1) or the material for an organic EL device may preferably be included in the emission layer 4, but may also be included in the organic layer other than the emission layer 4. In addition, the compound of Formula (1) or the material for an organic EL device may also be included in the emission layer 4 and the organic layer other than the emission layer 4.

In the organic EL device 10 of FIGS. 1 to 3, when voltage is applied to each of the first electrode 2 and the second electrode 6, holes injected from the first electrode 2 may move toward the emission layer 4 through the hole transport region 3, and electrons injected from the second electrode 6 may move toward the emission layer 4 through the electron transport region 5. The holes and the electrons may then recombine in the emission layer 4 to produce excitons, and these excitons may transition from an excited state to a ground state, thereby generating light.

The embodiments of the disclosure have been described in detail, but are provided for illustrative and exemplary purposes only and are not intended to be limited thereto. Accordingly, the scope of the disclosure should be defined by the following claims.

The disclosure includes the following embodiments and forms:
[1] A compound represented by Formula (1):

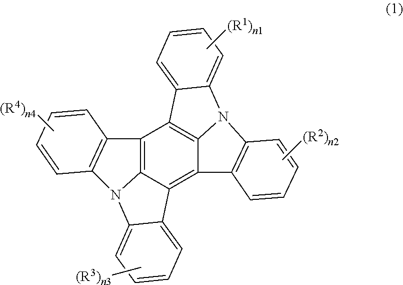

wherein, in Formula (1),
wherein R¹ to R⁴ may each independently be
one of the following groups of (1a) to (1d):
(1a) a substituted or unsubstituted C1-C20 alkyl group;
(1b) a substituted or unsubstituted C1-C20 alkoxy group;
(1c) a substituted or unsubstituted aromatic hydrocarbon group; or
(1d) a substituted or unsubstituted heterocyclic group,
n1 to n4 may each independently be 1, 2, 3, or 4, provided that, when n1 is 2 or more, each R¹ may be identical to or different from the others, when n2 is 2 or more, each R² may be identical to or different from the others, when n3 is 2 or more, each R³ may be identical to or different from the others, and when n4 is 2 or more, each R⁴ may be identical to or different from the others,
wherein the compound may have a molecular weight in a range of about 1000 g/mol to about 1400 g/mol,
a molecular length L₁ and a molecular length L₂ in two-axis directions of the compound may each independently be, as defined by the Equation 1A and Equation 1B, respectively, in a range of about 16 Å to about 38 Å, and
a product of the molecular length L₁ and the molecular length L₂ may be in a range of about 490 Å² or about 1200 Å²:

$$Molecular length {L}_{1} = ( longest end - to - end distance {L}_{1 x} between a carbon atom of substituent {R}^{1} and a carbon atom of substituent {R}^{3} ) + ( in the presence of substituent {R}^{1} ( hereinafter reffered to as substituent {R}^{1 p} ) other than substituent {R}^{1} used in calculation of longest end - to - end distance {L}_{1 x} , longest end - to - end distance {L}_{1 y} between a carbon atom binding to substituent {R}^{1 p} and a carbon atom of substituent {R}^{1 p} ) + ( in the presence of substituent {R}^{3} ( hereinafter reffered to as substituent {R}^{3 p} ) other than substituent {R}^{3} used in calculation of longest end - to - end distance {L}_{1 x} , longest end - to - end distance {L}_{1 z} between a carbon atom binding to substituent {R}^{3 p} and a carbon atom of substituent {R}^{3 p} ) \qquad Equation 1 A$$

$$Molecular length {L}_{2} = ( longest end - to - end distance {L}_{2 x} between a carbon atom of substituent {R}^{2} and a carbon atom of substituent {R}^{4} ) + ( in the presence of substituent {R}^{2} ( hereinafter reffered to as substituent {R}^{2 p} ) other than substituent {R}^{2} used in calculation of longest end - to - end distance {L}_{2 x} , longest end - to - end distance {L}_{2 y} between a carbon atom binding to substituent {R}^{2 p} and a carbon atom of substituent {R}^{2 p} ) + ( in the presence of substituent {R}^{4} ( hereinafter reffered to as substituent {R}^{4 p} ) other than substituent {R}^{4} used in calculation of longest end - to - end distance {L}_{2 x} , longest end - to - end distance {L}_{2 z} between a carbon atom binding to substituent {R}^{4 p} and a carbon atom of substituent {R}^{4 p} ) , \qquad Equation 1 B$$

provided that, when each of substituents R^{1p} to R^{4p} exists in plural in the definition above, the longest end-to-end distance of each of substituents R^{1p} to R^{4p} existing in plural is added up to L_{1y}, L_{1z}, L_{2y}, and L_{2z}, respectively.
[2] A compound represented by Formula (2) by referring to the compound represented by Formula (1):

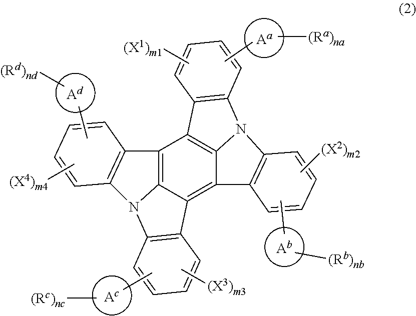

wherein, in Formula (2),
A^{a} to A^{d} may each independently be a benzene ring or a heterocyclic ring,
R^{a} to R^{d} may each independently be a hydrogen atom, an unsubstituted C1-C20 alkyl group, an unsubstituted C1-C20 alkoxy group, an unsubstituted C6-C20 arylamino group, a substituted or unsubstituted aromatic hydrocarbon group, or a substituted or unsubstituted aromatic heterocyclic group,
when A^{a} is a benzene ring, na is 5, and when A^{a} is a heterocyclic ring, na is an upper limit of possible number of substitution with A^{a},
when A^{b} is a benzene ring, nb is 5, and when A^{b} is a heterocyclic ring, nb is an upper limit of possible number of substitution with A^{b},
when A^{c} is a benzene ring, nc is 5, and when A^{c} is a heterocyclic ring, nc is an upper limit of possible number of substitution with A^{c},
when A^{d} is a benzene ring, nd is 5, and when A^{d} is a heterocyclic ring, nd is an upper limit of possible number of substitution with A^{d},
X¹ to X⁴ may each independently be a hydrogen atom, an unsubstituted C1-C20 alkyl group, an unsubstituted C1-C20 alkoxy group, or a substituted or unsubstituted aromatic hydrocarbon group, and
m1 to m4 may be 3,
wherein the compound may have a molecular weight in a range of about 1000 g/mol to about 1400 g/mol,
a molecular length L₁ and a molecular length L₂ in two-axis directions of the compound may each independently be, as defined by the Equation 2A and Equation 2B, respectively, in a range of about 16 Å to about 38 Å, and
a product of the molecular length L₁ and the molecular length L₂ may be in a range of about 490 Å² or about 1200 Å²:

$$Molecular length {L}_{3} = ( longest end - to - end distance {L}_{3 x} between a carbon atom of substituent {R}^{a} and a carbon atom of substituent {R}^{c} ) + ( in a case where substituent {X}^{1} is a group other than a hydrogen atom , longest end - to - end distance {L}_{3 y} between a carbon atom binding to substituent {X}^{1} and carbon atom of substituent {X}^{1} ) + ( in a case where substituent {X}^{3} is a group other than a hydrogen atom , longest end - to - end distance {L}_{3 z} between a carbon atom binding to substituent {X}^{3} and carbon atom of substituent {X}^{3} {L}_{3 z} ) ; \qquad Equation 2 A$$

$$Molecular length {L}_{4} = ( longest end - to - end distance {L}_{4 x} between a carbon atom of substituent {R}^{b} and a carbon atom of substituent {R}^{d} ) + ( in a case where substituent {X}^{2} is a group other than a hydrogen atom , longest end - to - end distance {L}_{4 y} between a carbon atom binding to substituent {X}^{2} and carbon atom of substituent {X}^{2} ) + ( in a case where substituent {X}^{4} is a group other than a hydrogen atom , longest end - to - end distance {L}_{4 z} between a carbon atom binding to substituent {X}^{4} and carbon atom of substituent {X}^{4} ) , \qquad Equation 2 B$$

Provided that, when each of substituents R^{a} to R^{d} is a hydrogen atom in the definition above, carbon atoms of substituents A^{a} to A^{d} correspond to carbon atoms of substituents R^{a} to R^{d}, respectively, and when substituents X¹ to X⁴ are each a hydrogen atom, the longest end-to-end distances thereof, i.e., L_{3y}, L_{3z}, L_{4y}, and L_{4z}, are each 0.
[3] A compound represented by Formula (3) by referring to the compound described in [1] or [2] above:

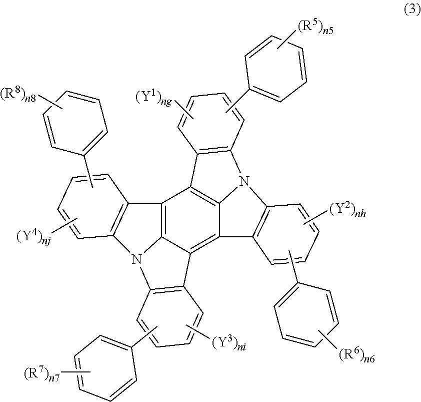

wherein, in Formula (3),
R⁵ to R⁸ may each independently be a hydrogen atom, an unsubstituted C1-C20 alkyl group, an unsubstituted C1-C20 alkoxy group, a substituted or unsubstituted aromatic hydrocarbon group, or a substituted or unsubstituted aromatic heterocyclic group,
n5 to n8 may be 5,
Y¹ to Y⁴ may each independently be a hydrogen atom, an unsubstituted C1-C20 alkyl group, an unsubstituted C1-C20 alkoxy group, or a substituted or unsubstituted aromatic hydrocarbon group,
ng to nj may be 3, and
wherein the compound may have a molecular weight in a range of about 1000 g/mol to about 1400 g/mol, a molecular length L₁ and a molecular length L₂ in two-axis directions of the compound may each independently be, as defined by the Equation 3A and Equation 3B, respectively, in a range of about 16 Å to about 38 Å, and a product of the molecular length L₁ and the molecular length L₂ may be in a range of about 490 Å² or about 1200 Å²:

$$Molecular length {L}_{5} = ( longest end - to - end distance {L}_{5 x} between a carbon atom of substituent {R}^{5} and a carbon atom of substituent {R}^{7} ) + ( in a case where substituent {Y}^{1} is a group other than a hydrogen atom , longest end - to - end distance {L}_{5 y} between a carbon atom binding to substituent {Y}^{1} and carbon atom of substituent {Y}^{1} ) + ( in a case where substituent {Y}^{3} is a group other than a hydrogen atom , longest end - to - end distance {L}_{5 z} between a carbon atom binding to substituent {Y}^{3} and carbon atom of substituent {Y}^{3} ) ; \qquad Equation 3 A$$

$$Molecular length {L}_{6} = ( longest end - to - end distance {L}_{6 x} between a carbon atom of substituent {R}^{6} and a carbon atom of substituent {R}^{8} ) + ( in a case where substituent {Y}^{2} is a group other than a hydrogen atom , longest end - to - end distance {L}_{6 y} between a carbon atom binding to substituent {Y}^{2} and carbon atom of substituent {Y}^{2} ) + ( in a case where substituent {Y}^{4} is a group other than a hydrogen atom , longest end - to - end distance {L}_{6 z} between a carbon atom binding to substituent {Y}^{4} and carbon atom of substituent {Y}^{4} ) , \qquad Equation 3 B$$

provided that, when each of substituents R⁵ to R⁸ is a hydrogen atom in the definition above, carbon atoms of a benzene ring including substituent R⁵ to R⁸ correspond to carbon atoms of substituent R⁵ to R⁸, respectively, and when substituents Y¹ to Y⁴ are each a hydrogen atom, the longest end-to-end distances thereof, i.e., L₅, L_{5z}, Ley, and Loz are each 0.
[4] Provided is an organic EL device including an emission layer that includes any one of the compounds of [1] to [3].
[5] Provided is the organic EL device of [4], wherein the emission layer further includes a phosphorescent complex.
[6] Provided is the organic EL device of [5], wherein the phosphorescent complex is a platinum complex.
[7] Provided is the organic EL device of any one of [4] to [6], wherein the emission layer further includes a host material.
[8] Provided is the organic EL device of [7], wherein the host material includes a compound having a triphenylsilyl group.
[9] Provided is the organic EL device of [7], wherein the host material includes a compound having an anthracene ring structure.

### EXAMPLES

Hereinafter, the disclosure will be described in more detail with reference to the following examples and comparative examples, but the technical scope of the disclosure is not limited thereto.

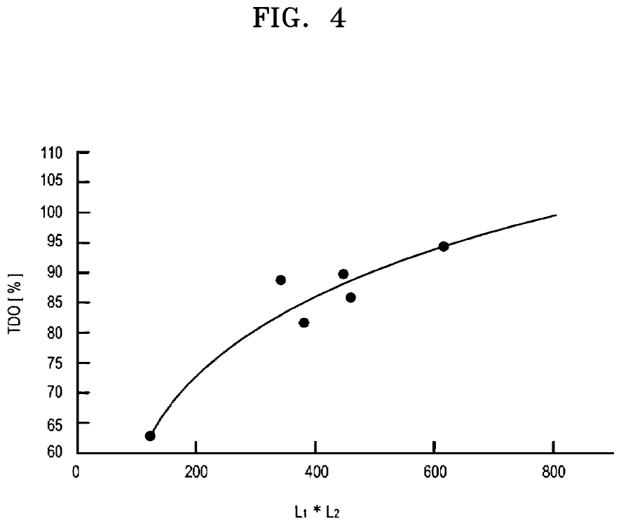

The structure of the compound was derived from simulation results using DFT calculations for the following compounds, and based on this structure, molecular lengths (L₁ and L₂) of the compound were calculated. Moreover, by using the relationship as described, transition dipole moment (TDO) of each compound was calculated based on the value obtained by multiplying the molecular lengths (L₁ and L₂) of the compound. A relationship was determined by reading the TDO corresponding to the value (x-axis) obtained by multiplying the molecular lengths (L₁ and L₂) calculated using a graph (see FIG. 4) showing the correlation between the pre-calculated molecular lengths and TDO, and plotting the values on the graph curve. The TDO obtained using such a relationship is referred to as the expected TDO. The values obtained by multiplying the molecular lengths (L₁ and L₂) of the compound and the expected TDO results are shown in Tables 1A/1B to 7A/7B (collectively, referred to as Table 1). In the compounds of Table 1, Compounds A¹ to A³⁸ are represented by Formula (1), and Comparative Compounds C1 to C3 are not represented by Formula (1). The measured TDO values are also provided for Comparative Compounds C1 to C3. In addition, the expected TDO values calculated based on the values obtained by multiplying the molecular lengths (L₁ and L₂) of Compound 1 used in the following examples and the measured TDO values are also provided in Tables 1 to 7.

Here, calculations using density functional theory (DFT) were performed using Gaussian 16 (Gaussian Inc.) as the calculation software, following the calculation method described in (I) below:
(I) S0 calculation method: Structural optimization calculation by functional B3LYP, basis function 6-31G(d, p), and DFT.

TABLE 1A

| No. | A1 | A2 | A3 |
|---|---|---|---|
| Structural formula | 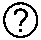 | 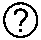 | 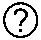 |
| Expected | 95% | 96% | 96% |
| TDO | | | |
| L₁ | 26.8 | 27.7 | 29.3 |
| L₂ | 23.0 | 24.2 | 22.8 |
| L₁*L₂ | 616 | 670 | 668 |
| Mol. Wt. | 1269.94 | 1157.73 | 1157.73 |

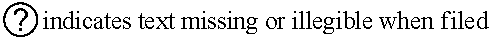

TABLE 1B

| No. | A4 | A5 | A6 |
|---|---|---|---|
| Structural Formula | 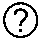 | 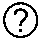 | 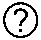 |
| Expected | 96% | 97% | 96% |
| TDO | | | |
| L₁ | 28.5 | 28.3 | 28.8 |
| L₂ | 23.5 | 24.2 | 22.6 |
| L₁*L₂ | 670 | 685 | 651 |
| Mol. Wt | 1269.9 | 1157.7 | 1157.7 |

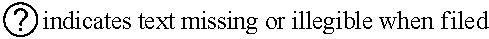

TABLE 2A

| No. | A7 | A8 | A9 |
|---|---|---|---|
| Structural formula | 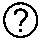 | 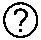 | 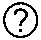 |
| Expected | 96% | 96% | 96% |
| TDO | | | |
| L₁ | 28.9 | 29.4 | 28.5 |
| L₂ | 22.5 | 22.8 | 23.2 |
| L₁*L₂ | 650 | 670 | 661 |
| Mol. Wt. | 1269.94 | 1045.51 | 1142.69 |

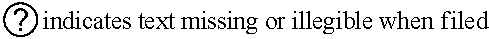

TABLE 2B

| No. | A10 | A11 | A12 |
|---|---|---|---|
| Structural formula | 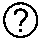 | 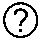 | 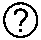 |
| Expected | 96% | 95% | 95% |
| TDO | | | |
| L₁ | 28.2 | 27.3 | 28.3 |
| L₂ | 23.2 | 23.2 | 22.6 |
| L₁*L₂ | 654 | 633 | 640 |
| Mol. Wt. | 1045.5 | 1157.7 | 1157.7 |

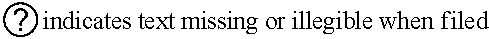

TABLE 3A

| No. | A13 | A14 | A15 |
|---|---|---|---|
| Structural formula | 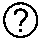 | 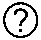 | 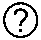 |
| Expected | 95% | 97% | 96% |
| TDO | | | |
| L₁ | 27.9 | 28.4 | 28.4 |
| L₂ | 22.6 | 24.2 | 23.5 |
| L₁*L₂ | 630 | 687 | 667 |
| Molecular | 1269.9 | 1185.8 | 1298.0 |
| weight | | | |

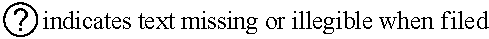

TABLE 3B

| No. | A16 | A17 | A18 |
|---|---|---|---|
| Structural formula | 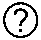 | 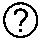 | 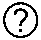 |
| Expected | 97% | 96% | 97% |
| TDO | | | |
| L₁ | 28.3 | 27.7 | 29.6 |
| L₂ | 24.2 | 24.2 | 24.2 |
| L₁*L₂ | 685 | 670 | 716 |
| Molecular | 1199.8 | 1312.0 | 1185.8 |
| weight | | | |

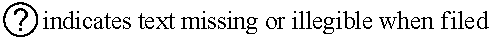

TABLE 4A

| No. | A19 | A20 | A21 |
|---|---|---|---|
| Structural formula | 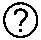 | 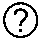 | 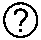 |
| Expected | 96% | 97% | 96% |
| TDO | | | |
| L₁ | 29.5 | 29.3 | 27.2 |
| L₂ | 22.5 | 23.8 | 24.2 |
| L₁*L₂ | 664 | 697 | 658 |
| Mol. Wt. | 1298.0 | 1185.8 | 1298.0 |

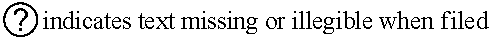

TABLE 4B

| No. | A22 | A23 | A24 |
|---|---|---|---|
| Structural formula | 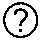 | 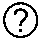 | 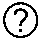 |
| Expected | 97% | 96% | 96% |
| TDO | | | |
| L₁ | 29.5 | 29.5 | 29.3 |
| L₂ | 23.2 | 22.5 | 23.2 |
| L₁*L₂ | 684 | 664 | 680 |
| Mol. Wt. | 1185.8 | 1298.0 | 1185.8 |

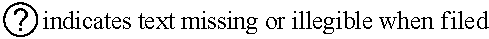

TABLE 5A

| No. | A25 | A26 | A27 |
|---|---|---|---|
| Structural formula | 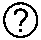 | 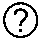 | 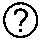 |
| Expected | 96% | 96% | 95% |
| TDO | | | |
| L₁ | 28.6 | 28.4 | 28.4 |
| L₂ | 23.2 | 23.2 | 22.5 |
| L₁*L₂ | 664 | 659 | 639 |
| Mol/ Wt. | 1284.0 | 1185.8 | 1298.0 |

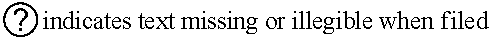

TABLE 5B

| No. | A28 | A29 | A30 |
|---|---|---|---|
| Structural formula | 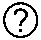 | 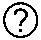 | 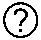 |
| Expected | 96% | 96% | 97% |
| TDO | | | |
| L₁ | 28.3 | 27.9 | 28.3 |
| L₂ | 23.3 | 23.3 | 24.1 |
| L₁*L₂ | 659 | 650 | 692 |
| Mol. Wt. | 1185.8 | 1298.0 | 1445.5 |

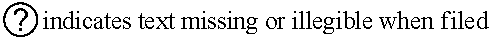

TABLE 6A

| No. | A31 | A32 | A33 |
|---|---|---|---|
| Structural formula | 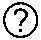 | 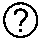 | 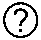 |
| Expected | | | |
| TDO | 100% | 97% | 98% |
| L₁ | 28.3 | 29.3 | 25.5 |
| L₂ | 29.2 | 23.9 | 29.3 |
| L₁*L₂ | 826 | 700 | 747 |
| Mol. Wt. | 1157.73 | 1045.51 | 1157.73 |

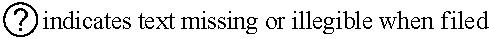

TABLE 6B

| No. | A34 | A35 | A36 |
|---|---|---|---|
| Structural formula | 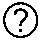 | 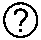 | 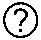 |
| Expected | 104% | 106% | 98% |
| TDO | | | |
| L₁ | 27.6 | 29.4 | 24.4 |
| L₂ | 37.6 | 37.6 | 29.5 |
| L₁*L₂ | 1038 | 1105 | 719 |
| Mol. Wt. | 1309.92 | 1309.92 | 1045.51 |

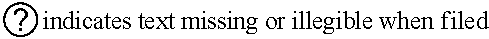

TABLE 7A

| No. | A37 | A38 | C1 |
|---|---|---|---|
| Structural formula | 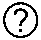 | 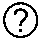 | 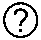 |
| Measured | | | 63% |
| TDO | | | |
| Expected | 97% | 105% | 64% |
| TDO | | | |
| L₁ | 29.5 | 29.2 | 11.1 |
| L₂ | 24.2 | 36.6 | 11.1 |
| L₁*L₂ | 714 | 1069 | 123 |
| Mol. Wt. | 1045.51 | 1309.92 | 404 |

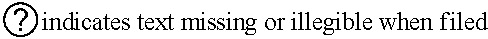

TABLE 7B

| No. | C2 | C3 | Compound 1 |
|---|---|---|---|
| Structural formula | 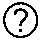 | 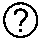 | 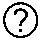 |
| Measured | 82% | 86% | 95% |
| TDO | | | |
| Expected | 85% | 89% | 93% |
| TDO | | | |
| L₁ | 16.1 | 19.6 | 28.3 |
| L₂ | 23.6 | 23.4 | 21.7 |
| L₁*L₂ | 380 | 459 | 614 |
| Mol. Wt | 933 | 1101 | 1157.73 |

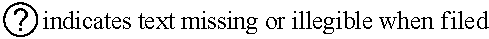

### Compound Synthesis

Compound 1 was synthesized according to the following synthesis for use in the manufacture of an organic electroluminescence device. Compound 1 is represented by Formula (1). Comparative Compound C1 was prepared for use in the manufacture of an organic electroluminescence device for comparison.

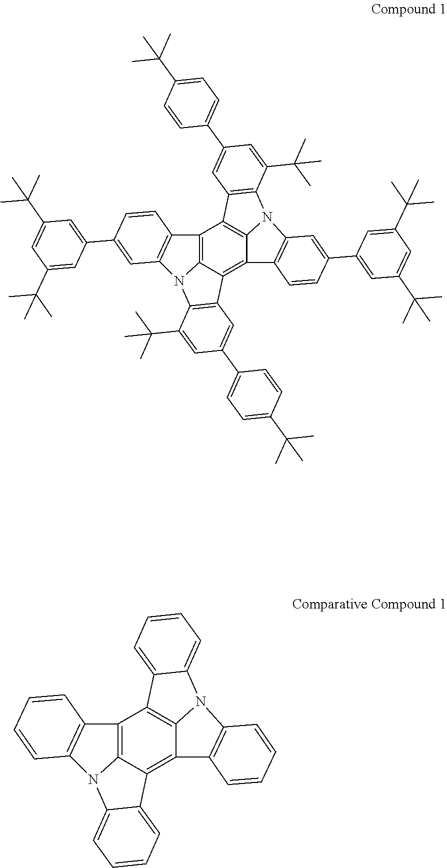 [SMILES: CC(C)(C)c1ccc(-c2cc(C(C)(C)C)c3c(c2)c2c4c5ccc(-c6cc(C(C)(C)C)cc(C(C)(C)C)c6)cc5n5c6c(C(C)(C)C)cc(-c7ccc(C(C)(C)C)cc7)cc6c(c6c7ccc(-c8cc(C(C)(C)C)cc(C(C)(C)C)c8)cc7n3c62)c45)cc1 ; c1ccc2c(c1)c1c3c4ccccc4n4c5ccccc5c(c5c6ccccc6n2c15)c34]

### Synthesis Example 1

Compound 1 was synthesized according to the following scheme.

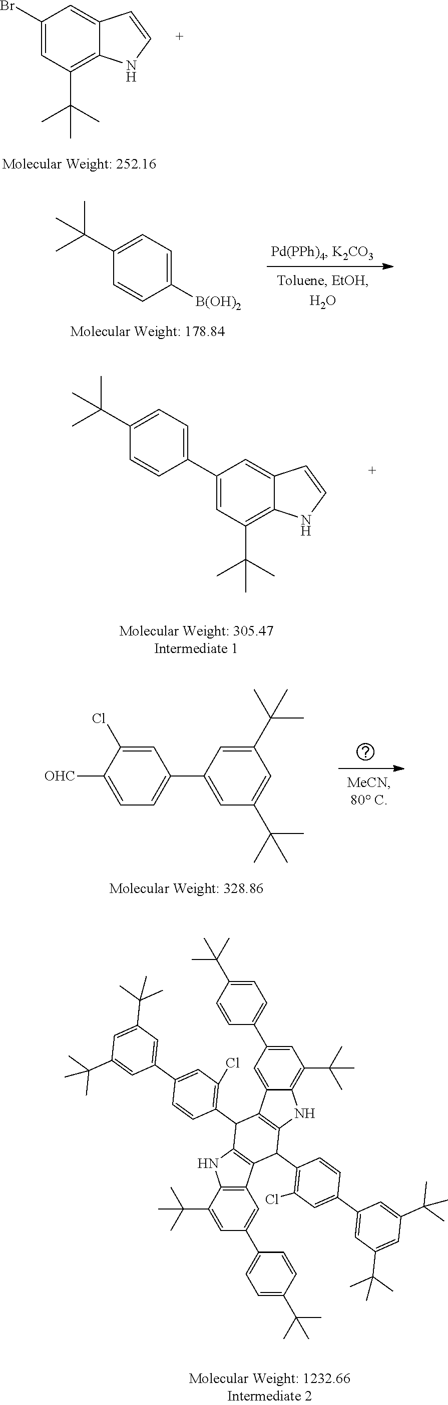 [SMILES: CC(C)(C)c1cc(Br)cc2cc[nH]c12 ; CC(C)(C)c1ccc(B(O)O)cc1 ; CC(C)(C)c1ccc(-c2cc(C(C)(C)C)c3[nH]ccc3c2)cc1 ; CC(C)(C)c1cc(-c2ccc(C=O)c(Cl)c2)cc(C(C)(C)C)c1 ; CC(C)(C)c1ccc(-c2cc(C(C)(C)C)c3[nH]c4c(c3c2)C(c2ccc(-c3cc(C(C)(C)C)cc(C(C)(C)C)c3)cc2Cl)c2[nH]c3c(C(C)(C)C)cc(-c5ccc(C(C)(C)C)cc5)cc3c2C4c2ccc(-c3cc(C(C)(C)C)cc(C(C)(C)C)c3)cc2Cl)cc1]

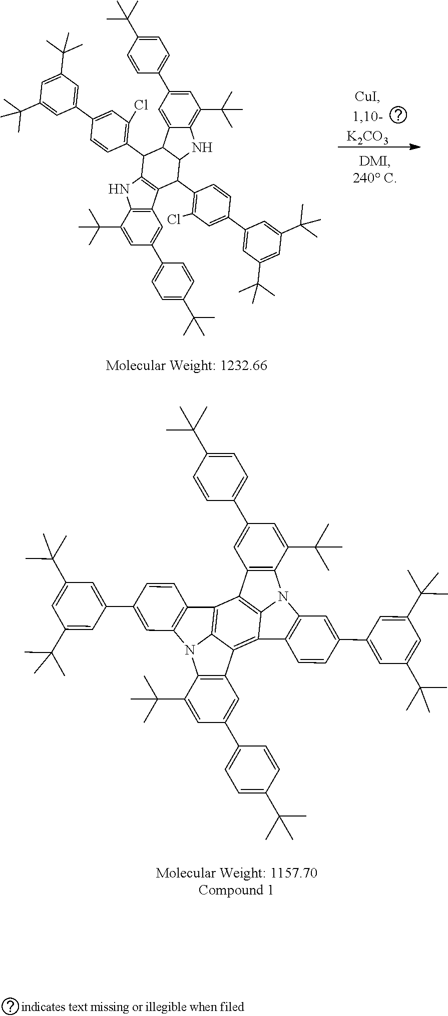

### Synthesis of Intermediate 1

In a nitrogen atmosphere, 5-bromo-7-(tert-butyl)-1H-indole (1.0 g, 4.0 mmol), 4-tert-butylphenyl boronic acid (1.3 g, 7.1 mmol), tetrakis(triphenylphosphine) palladium (0) (0.2 g, 0.2 mmol), potassium carbonate (1.1 g, 7.9 mmol), 20 mL of toluene, 10 mL of ethanol, and 10 mL of water were added to a 100 mL three-neck flask. The reaction solution was heated under reflux for 2 hours. The resulting reaction solution was cooled to room temperature, the ethanol was removed by distillation under reduced pressure, and toluene and water were added for purification and extraction processes. An organic layer thus obtained was dried with magnesium sulphate and isolated, and the solvent was removed by distillation under reduced pressure. A solid thus obtained was purified with methanol to obtain Intermediate 1 as a white powder. 0.5 g (Yield: 45%).

### Synthesis of Intermediate 2

In a nitrogen atmosphere, 3′,5′-di-tert-butyl-3-chloro-[1,1′-biphenyl]-4-carbaldehyde (6.8 g, 20.6 mmol), Intermediate 1 (6.3 g, 20.6 mmol), and 100 mL of acetonitrile were added to a 100 mL three-neck flask. The reaction solution was heated to 80° C., and 57 mass % of hydroiodic acid (0.58 mL, 4.1 mmol) was added thereto and stirred for 2 hours. After cooling the resulting reaction solution to room temperature, the precipitated solid was separated, and the solid thus obtained was washed with cooled acetonitrile to obtain Intermediate 2 as a white powder. 8.0 g (Yield: 63%).

### Synthesis of Compound 1

In a nitrogen atmosphere, Intermediate 2 (3.0 g, 2.4 mmol), potassium carbonate (3.4 g, 24.3 mmol), copper (I) iodide (4.6 g, 24.3 mmol), 1,10-phenanthroline (4.4 g, 24.3 mmol), and 12 ml of 1,3-dimethyl-2-imidazolidinone were added to a 100 mL three-neck flask, and the reaction solution was stirred while heating at 240° C. for 2 hours. Next, the resulting reaction solution was cooled to room temperature, and the precipitated solid was isolated. In a 500 mL triangular flask, the separated solid, 200 mL of methanol, and 50 mL of ethylenediamine were added and stirred, and then the solid was extracted by filtration. The solid thus obtained was recrystallized using THF-acetonitrile to obtain Compound 1 as a white solid. 1.7 g (Yield: 60%) LC-MS: 1158 ([M+H]⁺).

### Compound Data (Identification Data) for Compound 1

The structure of Compound 1 thus obtained was identified by nuclear magnetic resonance device (1H-NMR) as follows: NMR data (300 MHz, CD2Cl2) (ppm) 1.49 (9H, s), 1.57 (18H, s), 2.09 (9H, s), 7.59 (1H, s), 7.70 (2H, d, J=8.4 Hz), 7.80 (2H, s), 7.94-7.97 (3H, m), 8.04 (1H, s), 8.89-8.97 (3H, m).

### Emission Spectrum of Solution

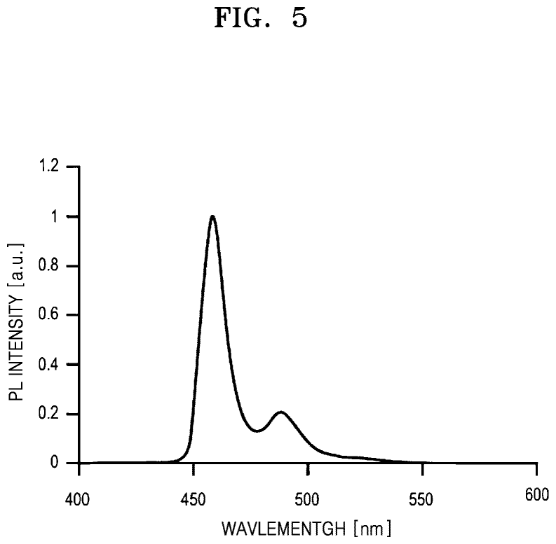

For Compound 1 contained at a concentration of 1×10⁻⁷M (=mol/dm³, mol/L) in a toluene solution, the emission spectrum (photoluminescence, PL) was measured at room temperature using a fluorescence spectrophotometer F-7000 produced by Hitachi High-Tech Products, Co., Ltd. with an excitation wavelength of 320 nm. The emission spectrum of Compound 1 in the toluene solution measured by the method above is shown in FIG. 5. The emission wavelength of Compound 1 of the disclosure was 458 nm, exhibiting blue emission.

### Thin Film Properties

A thin film having a thickness of 50 nm was manufactured on a quartz substrate by which 1.5 mass % of the compound represented by Formula (1), or a compound to be measured, and 98.5 mass % of a host material, with the total mass (100 mass %) of the compound represented by Formula (1) and the host materials, were co-deposited under a vacuum of 10⁻⁵ Pa. In addition, for use as the host material, Compound H-H1 and Compound H-E1 were used at a mass ratio of 60:40 (Compound H-H1: Compound H-E1=60:40). The structures of Compound H-H1 and Compound H-E1 are as follows.

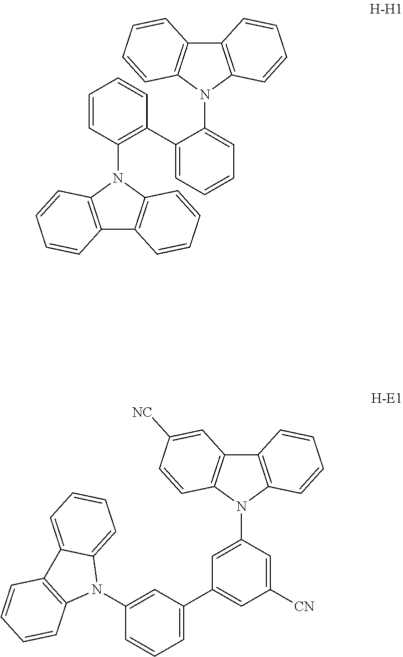 [SMILES: c1ccc(-n2c3ccccc3c3ccccc32)c(-c2ccccc2-n2c3ccccc3c3ccccc32)c1 ; N#Cc1cc(-c2cccc(-n3c4ccccc4c4ccccc43)c2)cc(-n2c3ccccc3c3cc(C#N)ccc32)c1]

### Measurement of Angle-Resolved PL

The angle-resolved PL at room temperature of the prepared thin films was measured using a Luxol OLED analyzer of CoCoLink Corp. with excitation light set to 365 nm. The results obtained by the evaluation are shown in Table 8.

TABLE 8
TDO of Compound in Thin film

| | Compound | TDO |
|---|---|---|
| Example | Compound 1 | 93% |
| Comparative Ex. | Comparative | 63% |
| | Compound C1 | |

The TDO of Compound 1 was 93% in the host dispersion state. Compound 1 has, compared to Comparative Compound C1, a newly introduced structure including a tert-butylphenyl group and a di-tert-butylphenyl group as the main skeleton, and as a result, the molecular length of Compound 1 is elongated, increasing the TDO. Meanwhile, in Comparative Compound C1, the TDO was relatively small at 63%. From these results, it was confirmed that molecules of Compound 1 were oriented parallel to the plane, whereas molecules of Comparative Compound C1 were oriented randomly in the plane. Compound 1 was able to obtain higher light extraction efficiency, and the compound was found to be excellent as a light-emitting dopant.

### Evaluation of OLED

### Manufacture of Organic EL Device: Preparation of Material for Forming Each Layer

For use as a material for forming each layer in an organic EL device, the following materials were prepared in addition to Compound 1 and Comparative Compound C1.

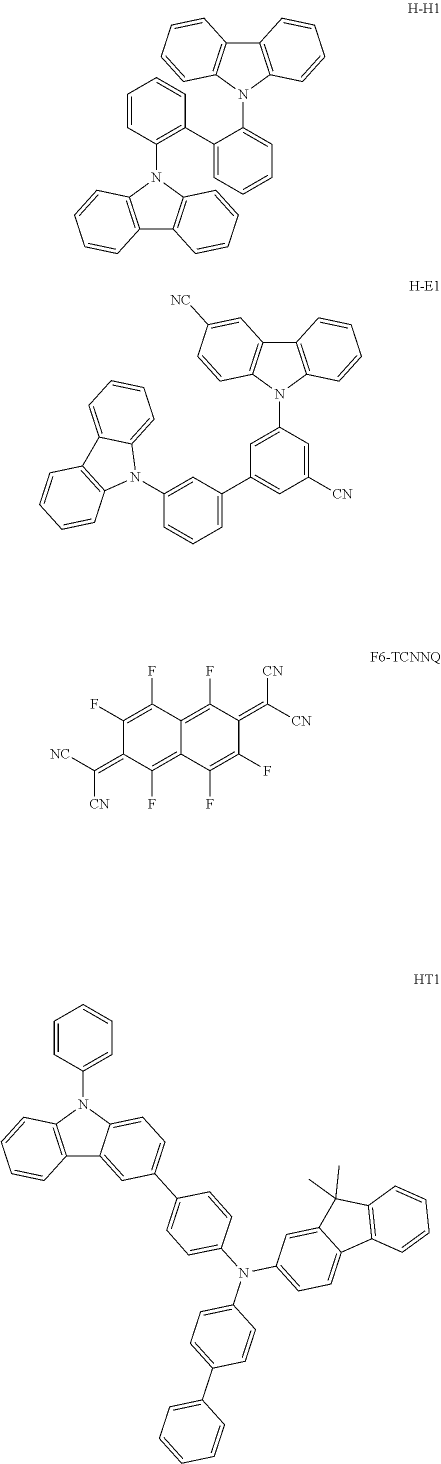 [SMILES: c1ccc(-n2c3ccccc3c3ccccc32)c(-c2ccccc2-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#CC(C#N)=c1c(F)c(F)c2c(F)c(=C(C#N)C#N)c(F)c(F)c2c1F ; CC1(C)c2ccccc2-c2ccc(N(c3ccc(-c4ccccc4)cc3)c3ccc(-c4ccc5c(c4)c4ccccc4n5-c4ccccc4)cc3)cc21]

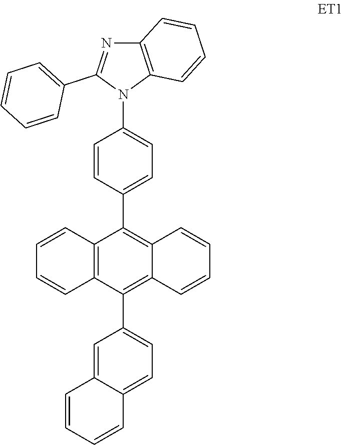 [SMILES: c1ccc(-c2nc3ccccc3n2-c2ccc(-c3c4ccccc4c(-c4ccc5ccccc5c4)c4ccccc34)cc2)cc1]

### Example 1

An ITO glass substrate with an electrode pattern completed was cut to a size of 50 mm×50 mm×0.7 mm, sonicated with acetone, isopropyl alcohol, and pure water in the stated order, for 15 minutes each, and then cleaned by OV ozone for 30 minutes. Then, the following layers were deposited on the ITO electrode (positive electrode) on the glass substrate using a vacuum deposition device.

F6-TCNNQ was deposited on the ITO electrode to form a hole injection layer having a film thickness of 10 nm. Compound HT1 was deposited on the hole injection layer to form a hole transport layer having a film thickness of 140 nm. Compound H-H1 was deposited on the hole transport layer to form an electron-blocking layer having a film thickness of 5 nm. Accordingly, a hole transport region was formed.

Compound H-H1, Compound H-E1, and Compound 1 obtained above were co-deposited on the hole transport region to form an emission layer having a film thickness of 40 nm. Here, in the formation of the emission layer, a mass ratio of Compound H-H1 to Compound H-E1 (Compound H-H1: Compound H-E1) in the emission layer was set to be 60:40. Moreover, a concentration of Compound 1 in the emission layer was set to be 1.5 mass % relative to the total mass (i.e., total mass of the emission layer) of Compound H-H1, Compound H-E1, and Compound 1. In addition, Compound H-H1 and Compound H-E1 were host materials.

Compound H-E1 was vacuum-deposited on the emission layer to form a hole-blocking layer having a thickness of 5 nm. Compound ET1 and LiQ were co-deposited at a mass ratio of 5:5 (Compound ET1: LiQ=5:5 (unit: parts by mass) to form an electron transport layer having a thickness of 30 nm. LiQ was deposited on the electron transport layer to form an electron injection layer having a thickness of 1 nm. Accordingly, an electron transport region was formed.

An organic EL device was manufactured by which Al (negative electrode) was deposited to a film thickness of 100 nm on the electron injection layer.

Afterwards, in a glove box in a nitrogen atmosphere with a moisture concentration of 1 ppm or less and an oxygen concentration of 1 ppm or less, an organic EL device manufactured above was sealed using a glass bag with a desiccant attached and a UV-curable resin (produced by MORESCO, product name: WB90US).

### Comparative Example 1

Organic EL device (2) was manufactured in the same manner as in Example 1 with the exception for replacing Compound 1 in the emission layer with Comparative Compound C1, and then sealed as above, thereby completing the manufacture of the organic EL device.

### Manufacture 2 of Organic EL Device

### Example 2

Organic EL device (3) was manufactured in the same manner as in Example 1 with the exception for changing the method of forming the emission layer as follows in the formation of the emission layer, and then sealed, thereby completing the manufacture of the organic EL device. The method of forming the emission layer, Compound H-H1, Compound H-E1, phosphorescent complex P1, and Compound 1 obtained above were co-deposited on the hole transport region obtained in Example 1 to form an emission layer having a film thickness of 40 nm. Here, in the formation of the emission layer, a mass ratio of Compound H-H1, Compound H-E1, and phosphorescent complex P1 (Compound H-H1: Compound H-E1: phosphorescent complex P1) in the emission layer was set to be 60:40:13. In addition, in the formation of the emission layer, a concentration of Compound 1 in the emission layer was set to be 0.4 mass % relative to the total mass (i.e., total mass of the emission layer) of Compound H-H1, Compound H-E1, phosphorescent complex P1, and Compound 1. In addition, Compound H-H1 and Compound H-E1 were host materials.

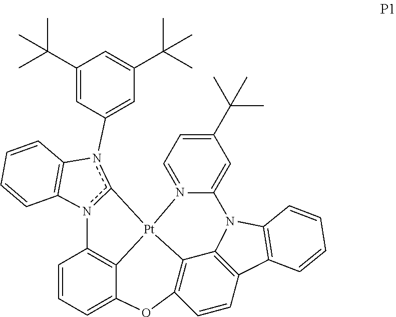

### Comparative Example 2

Except for replacing Compound 1 in the emission layer with Comparative Compound C1 in the formation of the emission layer, Organic EL device (4) was manufactured in the same manner as in Example 2, and then sealed as above, thereby completing the manufacture of the organic EL device.

### Evaluation of Organic EL Device: External Quantum Efficiency

Results of evaluating external quantum efficiency at luminance of 1,000 cd/m² according to the following method are shown in Table 3.

The organic EL device was induced to emit light by varying the applied voltage using a direct current-constant voltage power supply (produced by KEITHLEY, source meter model 2400). Here, the luminance, emission spectrum, and emission intensity were measured using a luminance measurement device (produced by Topcon, SR-3).

Here, the external quantum efficiency was calculated from the emission spectrum, luminance, and current value at the time of measurement. The external quantum efficiency at a luminance of 1,000 cd/m² was defined as EQE[%], and the external quantum efficiency at a current density of 0.1 mA/cm² was defined as MaxEQE[%].

Results of evaluating OLEDs are shown in Table 9. The OLEDs manufactured using Compound 1 of the disclosure as a luminescent material had higher external quantum yield than the OLEDs manufactured using Comparative Compound 1 as a luminescent material. That is, it is understood that the light extraction efficiency improved by high TDO according to the disclosure clearly contributes to high efficiency of the device, and it is confirmed that the compound is excellent as a luminescent dopant.

TABLE 9
OLED device results

| | | Compound | EQE | Max EQE |
|---|---|---|---|---|
| Manufacture 1 | Example 1 | Compound 1 | 2.2 | 2.3 |
| of organic | Comp. | Comp. | 1.0 | 1.0 |
| EL device | Ex. 1 | Compound C1 | | |
| Manufacture 2 | Example 2 | Compound 1 | 4.7 | 4.8 |
| of organic | Comp. | Comp. | 1.0 | 1.0 |
| EL device | Ex. 2 | Compound C1 | | |

As shown in Table 9, the OLEDs manufactured using Compound 1 of the disclosure as a luminescent material had higher external quantum yields than the OLEDs manufactured using Comparative Compound C1 as a luminescent material. Accordingly, it is understood that the light extraction efficiency improved by high TDO according to the disclosure clearly contributes to high efficiency of the device, and it is confirmed that the compound of the disclosure is excellent as a luminescent dopant.

According to an embodiment of the disclosure, a compound that has a peak wavelength in a blue wavelength region of an emission spectrum and enables high-efficiency luminescence may be provided. In addition, according to another embodiment, an organic electroluminescence device including the compound may be provided. In addition, according to another embodiment, a means for achieving high-efficiency luminescence by the organic electroluminescence device in which a peak wavelength is in a blue wavelength region of an emission spectrum may be provided.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A compound represented by Formula (1): 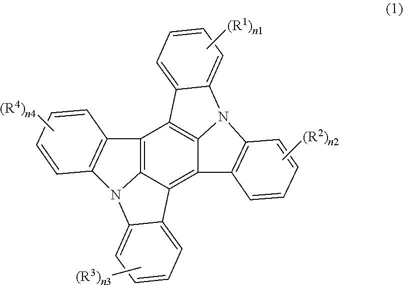
wherein, in Formula (1),
R¹ to R⁴ are each independently one of the following groups of (1a) to (1d):
(1a) a substituted or unsubstituted C1-C20 alkyl group;
(1b) a substituted or unsubstituted C1-C20 alkoxy group;
(1c) a substituted or unsubstituted aromatic hydrocarbon group; or
(1d) a substituted or unsubstituted heterocyclic group;
n1 to n4 are each independently 1, 2, 3, or 4, provided that, when n1 is 2 or more, each R¹ is identical to or different from the others, when n2 is 2 or more, each R² is identical to or different from the others, when n3 is 2 or more, each R³ is identical to or different from the others, and when n4 is 2 or more, each R⁴ is identical to or different from the others,
a molecular weight of the compound is in a range of about 1000 to about 1400,
a molecular length L₁ and a molecular length L₂ in two-axis directions of the compound are, as defined by the following equations, in a range of about 16 Å to about 38 Å,
a product of the molecular length L₁ and the molecular length L₂ is in a range of about 490 Å² or about 1200 Å², and
the molecular length L₁ and the molecular length L₂ are calculated by Equation 1A and Equation 1B, respectively:
$$Molecular length {L}_{1} = ( longest end - to - end distance {L}_{1 x} between a carbon atom of substituent {R}^{1} and a carbon atom of substituent {R}^{3} ) + ( in the presence of substituent {R}^{1} ( hereinafter reffered to as substituent {R}^{1 p} ) other than substituent {R}^{1} used in calculation of longest end - to - end distance {L}_{1 x} , longest end - to - end distance {L}_{1 y} between a carbon atom binding to substituent {R}^{1 p} and a carbon atom of substituent {R}^{1 p} ) + ( in the presence of substituent {R}^{3} ( hereinafter reffered to as substituent {R}^{3 p} ) other than substituent {R}^{3} used in calculation of longest end - to - end distance {L}_{1 x} , longest end - to - end distance {L}_{1 z} between a carbon atom binding to substituent {R}^{3 p} and a carbon atom of substituent {R}^{3 p} ) ; \qquad Equation 1 A$$
$$Molecular length {L}_{2} = ( longest end - to - end distance {L}_{2 x} between a carbon atom of substituent {R}^{2} and a carbon atom of substituent {R}^{4} ) + ( in the presence of substituent {R}^{2} ( hereinafter reffered to as substituent {R}^{2 p} ) other than substituent {R}^{2} used in calculation of longest end - to - end distance {L}_{2 x} , longest end - to - end distance {L}_{2 y} between a carbon atom binding to substituent {R}^{2 p} and a carbon atom of substituent {R}^{2 p} ) + ( in the presence of substituent {R}^{4} ( hereinafter reffered to as substituent {R}^{4 p} ) other than substituent {R}^{4} used in calculation of longest end - to - end distance {L}_{2 x} , longest end - to - end distance {L}_{2 z} between a carbon atom binding to substituent {R}^{4 p} and a carbon atom of substituent {R}^{4 p} ) , \qquad Equation 1 B$$
provided that, when each of substituents R^{1p} to R^{4p} exists in plural in the definition above, the longest end-to-end distance of each of substituents R^{1p} to R^{4p} existing in plural is added up to determine L_{1y}, L_{1z}, L_{2y}, and L_{2z}, respectively.

2. The compound of claim 1, wherein R¹ to R⁴ are each independently one of the following groups of (1a) or (1c).

3. The compound of claim 1, wherein R¹ to R⁴ each independently include at least one group selected from Group (2X): 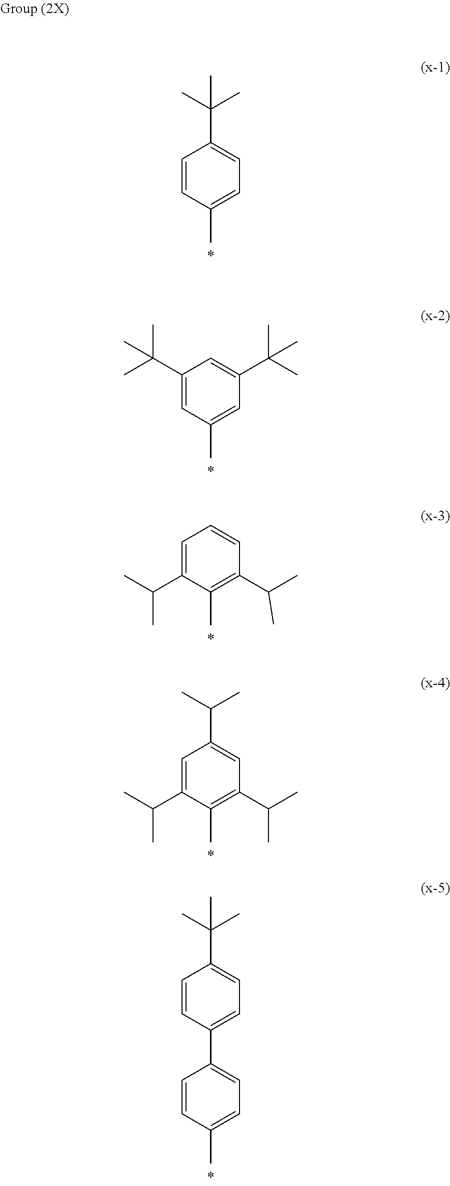
wherein * in Group (2X) indicates a binding site.

4. The compound of claim 1, wherein the compound represented by Formula (1) is represented by Formula (2): 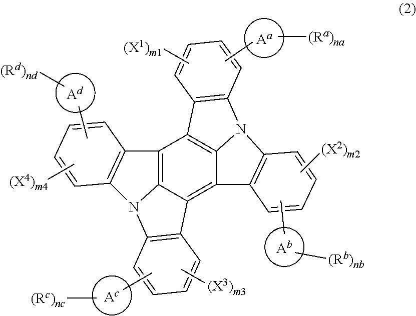
wherein, in Formula (2),
A^{a} to A^{d} are each independently a benzene ring or a heterocyclic ring,
R^{a} to R^{d} are each independently a hydrogen atom, an unsubstituted C1-C20 alkyl group, an unsubstituted C1-C20 alkoxy group, an unsubstituted C6-C20 arylamino group, a substituted or unsubstituted aromatic hydrocarbon group, or a substituted or unsubstituted aromatic heterocyclic group,
wherein;
when A^{a} is a benzene ring, na is 5, and when A^{a} is a heterocyclic ring, na is an upper limit of possible number of substitution with A^{a},
when A^{b} is a benzene ring, nb is 5, and when A^{b} is a heterocyclic ring, nb is an upper limit of possible number of substitution with A^{b},
when A^{c} is a benzene ring, nc is 5, and when A^{c} is a heterocyclic ring, nc is an upper limit of possible number of substitution with A^{c}, or
when A^{d} is a benzene ring, nd is 5, and when A^{d} is a heterocyclic ring, nd is an upper limit of possible number of substitution with A^{d},
X¹ to X⁴ are each independently a hydrogen atom, an unsubstituted C1-C20 alkyl group, an unsubstituted C1-C20 alkoxy group, or a substituted or unsubstituted aromatic hydrocarbon group,
m¹ to m⁴ are 3,
a molecular weight of the compound is in a range of about 1000 g/mol to about 1400 g/mol,
a molecular length L₃ and a molecular length L₄ in two-axis directions of the compound are, as defined by the following equations, in a range of about 16 Å to about 38 Å,
a product of the molecular length L₃ and the molecular length L₄ is in a range of about 490 Å² or about 1200 Å², and
the molecular length L₃ and the molecular length La are calculated by Equation 2A and Equation 2B, respectively:
$$Molecular length {L}_{3} = ( longest end - to - end distance {L}_{3 x} between a carbon atom of substituent {R}^{a} and a carbon atom of substituent {R}^{c} ) + ( in a case where substituent {X}^{1} is a group other than a hydrogen atom , longest end - to - end distance {L}_{3 y} between a carbon atom binding to substituent {X}^{1} and carbon atom of substituent {X}^{1} ) + ( in a case where substituent {X}^{3} is a group other than a hydrogen atom , longest end - to - end distance {L}_{3 z} between a carbon atom binding to substituent {X}^{3} and carbon atom of substituent {X}^{3} {L}_{3 z} ) ; \qquad Equation 2 A$$
$$Molecular length {L}_{4} = ( longest end - to - end distance {L}_{4 x} between a carbon atom of substituent {R}^{b} and a carbon atom of substituent {R}^{d} ) + ( in a case where substituent {X}^{2} is a group other than a hydrogen atom , longest end - to - end distance {L}_{4 y} between a carbon atom binding to substituent {X}^{2} and carbon atom of substituent {X}^{2} ) + ( in a case where substituent {X}^{4} is a group other than a hydrogen atom , longest end - to - end distance {L}_{4 z} between a carbon atom binding to substituent {X}^{4} and carbon atom of substituent {X}^{4} ) , \qquad Equation 2 B$$
provided that, when each of substituents R^{a} to R^{d} is a hydrogen atom in the definition above, carbon atoms of substituents A^{a} to A^{d} correspond to carbon atoms of substituents R^{a} to R^{d}, respectively, and when substituents X¹ to X⁴ are each a hydrogen atom, the longest end-to-end distances thereof, i.e., L_{3y}, L_{3z}, L_{4y}, and L_{4z}, are each 0.

5. The compound of claim 1, wherein the compound represented by Formula (1) is represented by Formula (3): 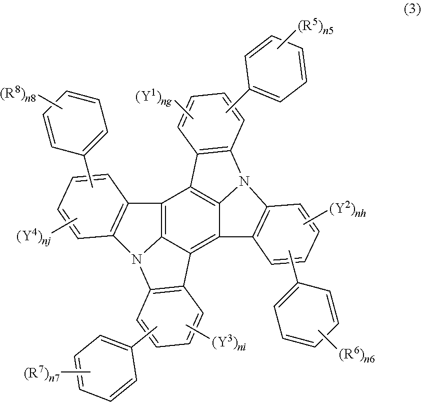
wherein, in Formula (3),
R⁵ to R⁸ are each independently a hydrogen atom, an unsubstituted C1-C20 alkyl group, an unsubstituted C1-C20 alkoxy group, a substituted or unsubstituted aromatic hydrocarbon group, or a substituted or unsubstituted aromatic heterocyclic group,
n5 to n8 are 5,
Y¹ to Y⁴ are each independently a hydrogen atom, an unsubstituted C1-C20 alkyl group, an unsubstituted C1-C20 alkoxy group, or a substituted or unsubstituted aromatic hydrocarbon group,
ng to nj are 3,
a molecular weight of the compound is in a range of about 1000 to about 1400,
a molecular length L₅ and a molecular length L₆ in two-axis directions of the compound are, as defined by the following equations, in a range of about 16 Å to about 38 Å,
a product of the molecular length L₅ and the molecular length L₆ is in a range of about 490 Å² or about 1200 Å², and
the molecular length L₁ and the molecular length L₂ are calculated by Equation 3A and Equation 3B, respectively:
$$Molecular length {L}_{5} = ( longest end - to - end distance {L}_{5 x} between a carbon atom of substituent {R}^{5} and a carbon atom of substituent {R}^{7} ) + ( in a case where substituent {Y}^{1} is a group other than a hydrogen atom , longest end - to - end distance {L}_{5 y} between a carbon atom binding to substituent {Y}^{1} and carbon atom of substituent {Y}^{1} ) + ( in a case where substituent {Y}^{3} is a group other than a hydrogen atom , longest end - to - end distance {L}_{5 z} between a carbon atom binding to substituent {Y}^{3} and carbon atom of substituent {Y}^{3} ) ; \qquad Equation 3 A$$
$$Molecular length {L}_{6} = ( longest end - to - end distance {L}_{6 x} between a carbon atom of substituent {R}^{6} and a carbon atom of substituent {R}^{8} ) + ( in a case where substituent {Y}^{2} is a group other than a hydrogen atom , longest end - to - end distance {L}_{6 y} between a carbon atom binding to substituent {Y}^{2} and carbon atom of substituent {Y}^{2} ) + ( in a case where substituent {Y}^{4} is a group other than a hydrogen atom , longest end - to - end distance {L}_{6 z} between a carbon atom binding to substituent {Y}^{4} and carbon atom of substituent {Y}^{4} ) , \qquad Equation 3 B$$
provided that, when each of substituents R⁵ to R⁸ is a hydrogen atom in the definition above, carbon atoms of a benzene ring including substituent R⁵ to R⁸ correspond to carbon atoms of substituent R⁵ to R⁸, respectively, and when substituents Y¹ to Y⁴ are each a hydrogen atom, the longest end-to-end distances thereof, i.e., L₅, L_{5z}, L_{6y}, and L_{6z} are each 0.

6. The compound of claim 1, wherein the compound represented by Formula (1) is represented by Formula (4): 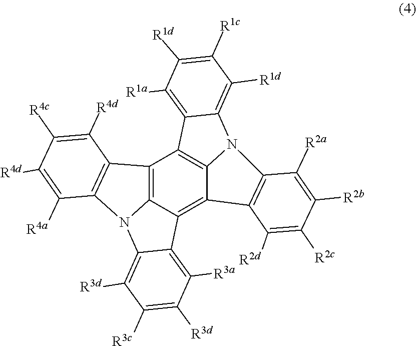
wherein, in Formula (4),
R^{1a} to R^{1d}, R^{2a} to R^{2d}, R^{3a} to R^{3d}, and R^{4a} to R^{4d} are each independently a hydrogen atom or a group selected from Group (1X): 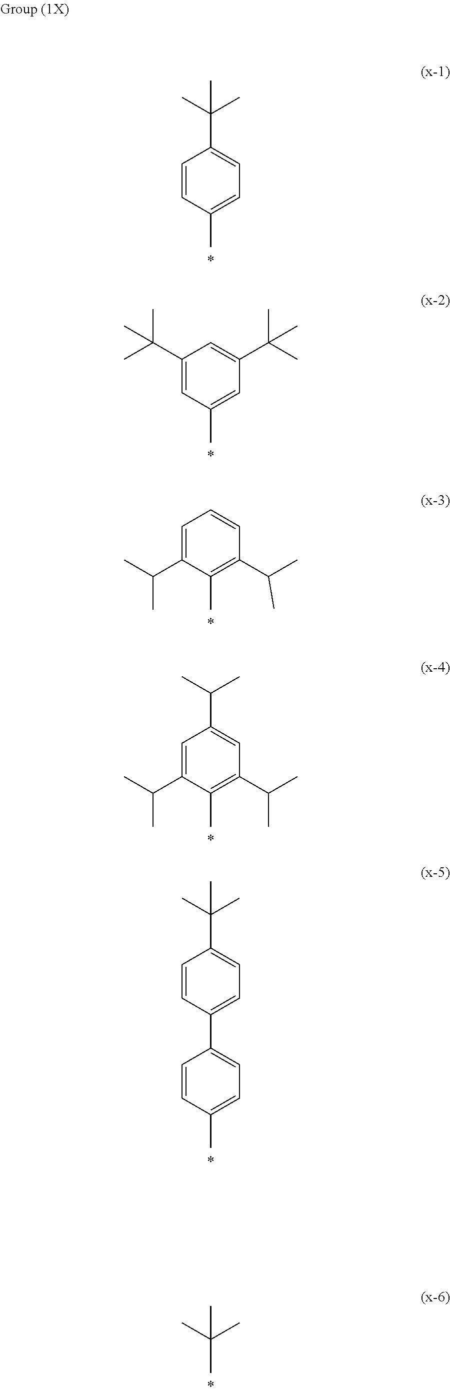
at least one of R^{1a} to R^{1d}, at least one of R^{2a} to R^{2d}, at least one of R^{3a} to R^{3d}, and at least one of R^{4a} to R^{4d} are groups selected from Group (1X), and
wherein * in Group (1X) indicates a binding site.

7. The compound of claim 6, wherein at least one of R^{1a} to R^{1d}, at least one of R^{2a} to R^{2d}, at least one of R^{3a} to R^{3d}, and at least one of R^{4a} to R^{4d} are groups selected from Group (2X): 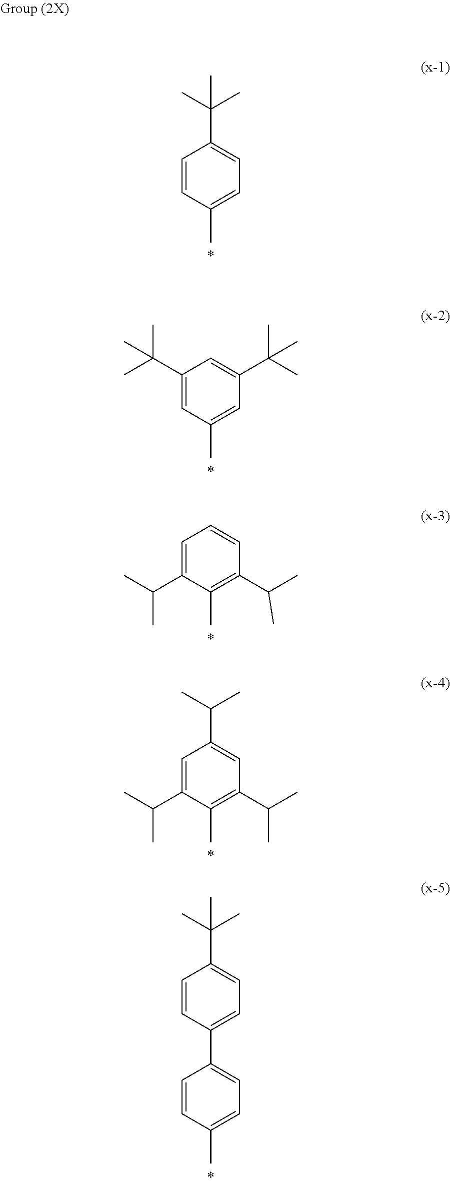
wherein * in Group (2X) indicates a binding site.

8. The compound of claim 6, wherein a group of at least one combination selected from R^{1b} and R^{3b}; and R^{1c} and R^{3c}, and a group of at least one combination selected from R^{2b} and R^{4b}; and R^{2c} and R^{4c}, are each independently a group selected from Group (2X).

9. The compound of claim 1, wherein the compound represented by Formula (1) is one of Compounds (101) to (141):

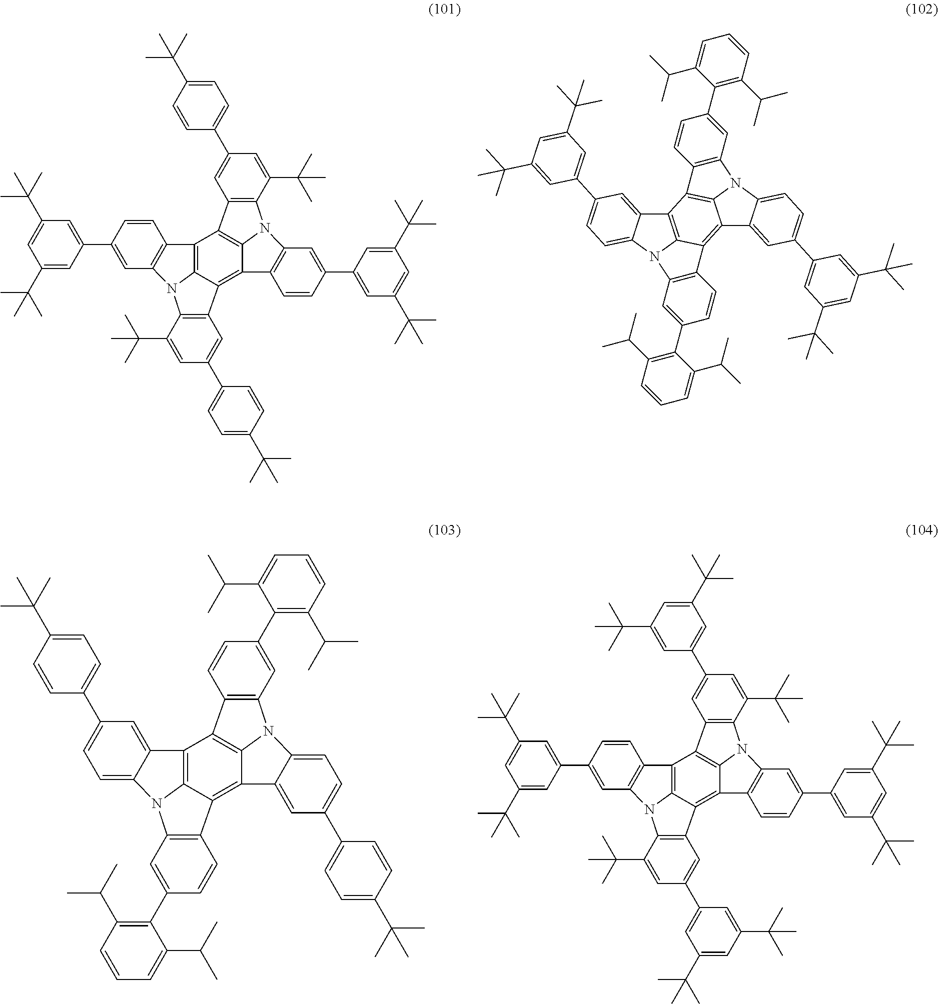

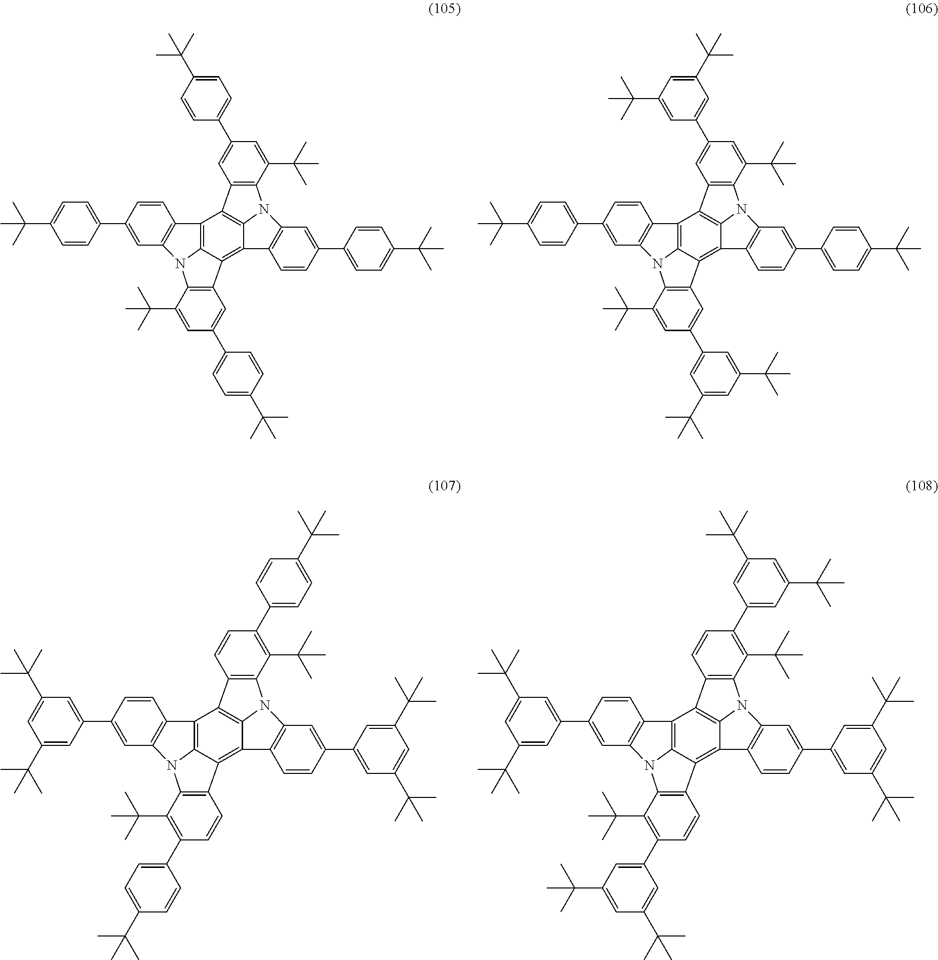

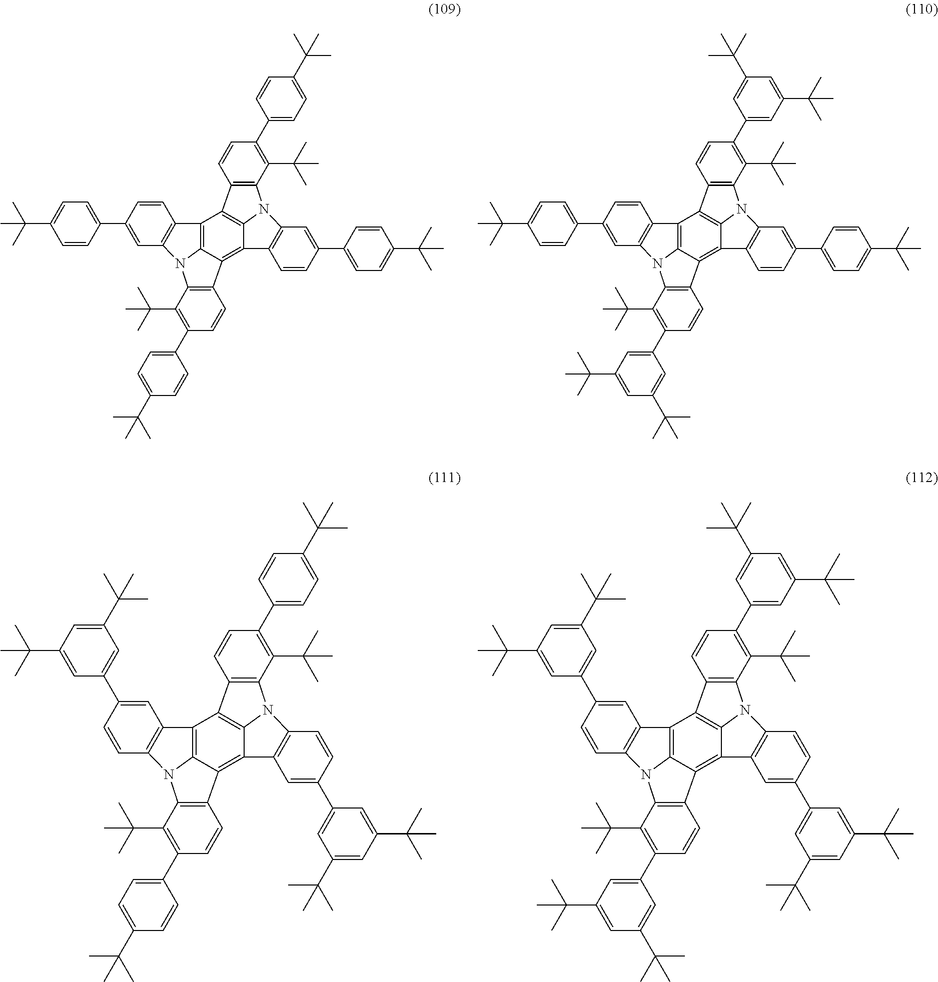

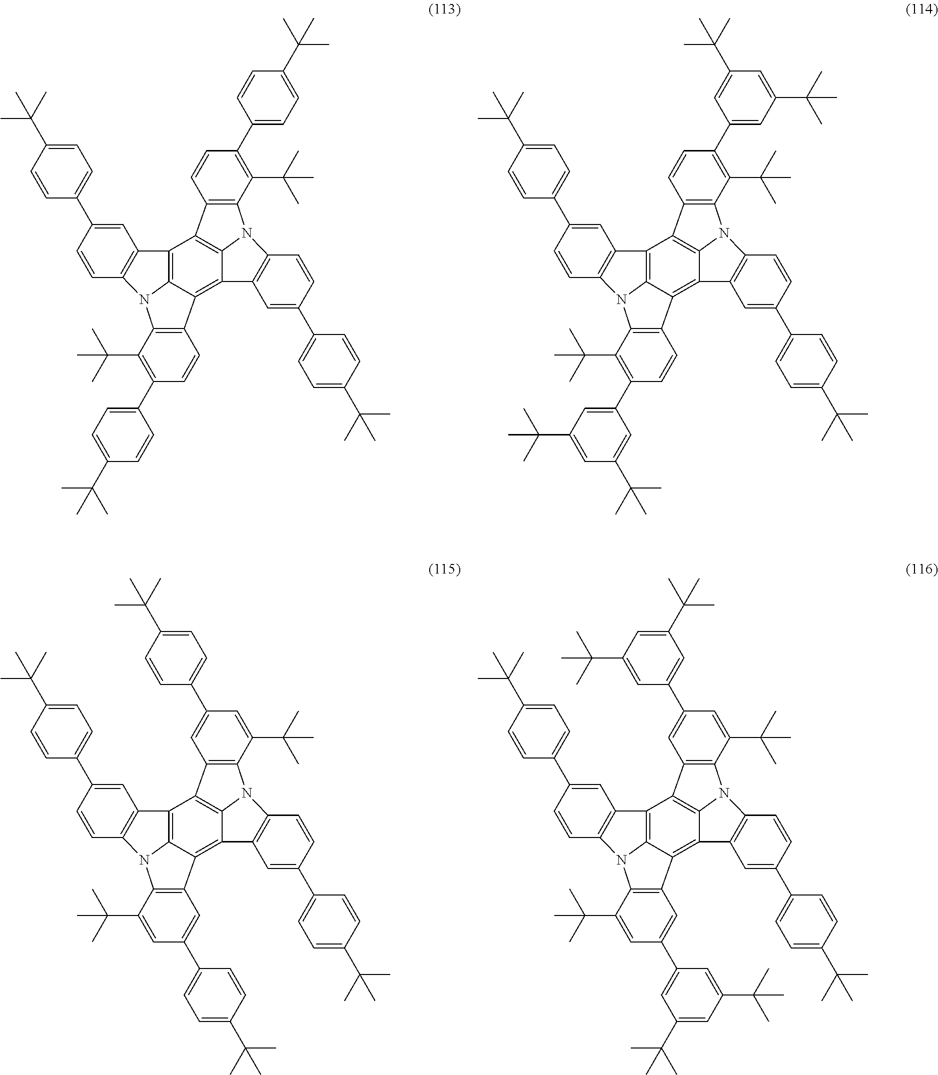

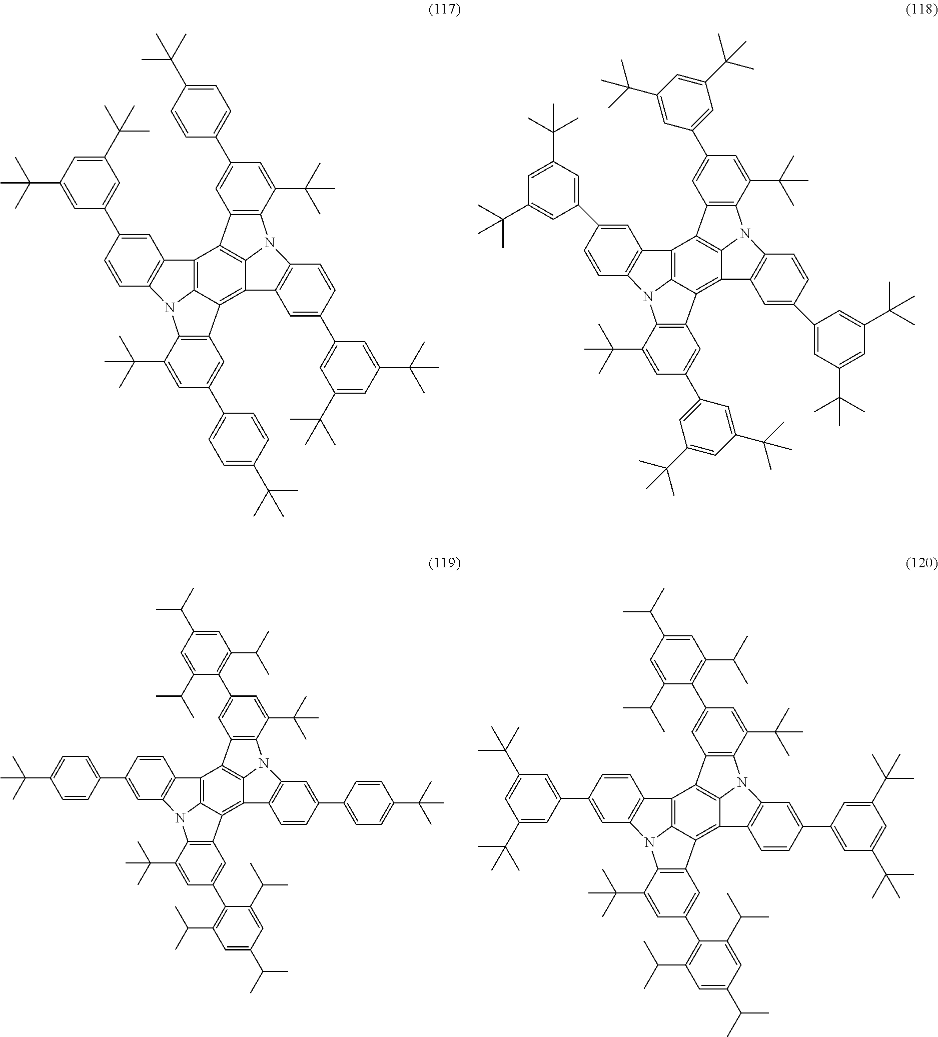

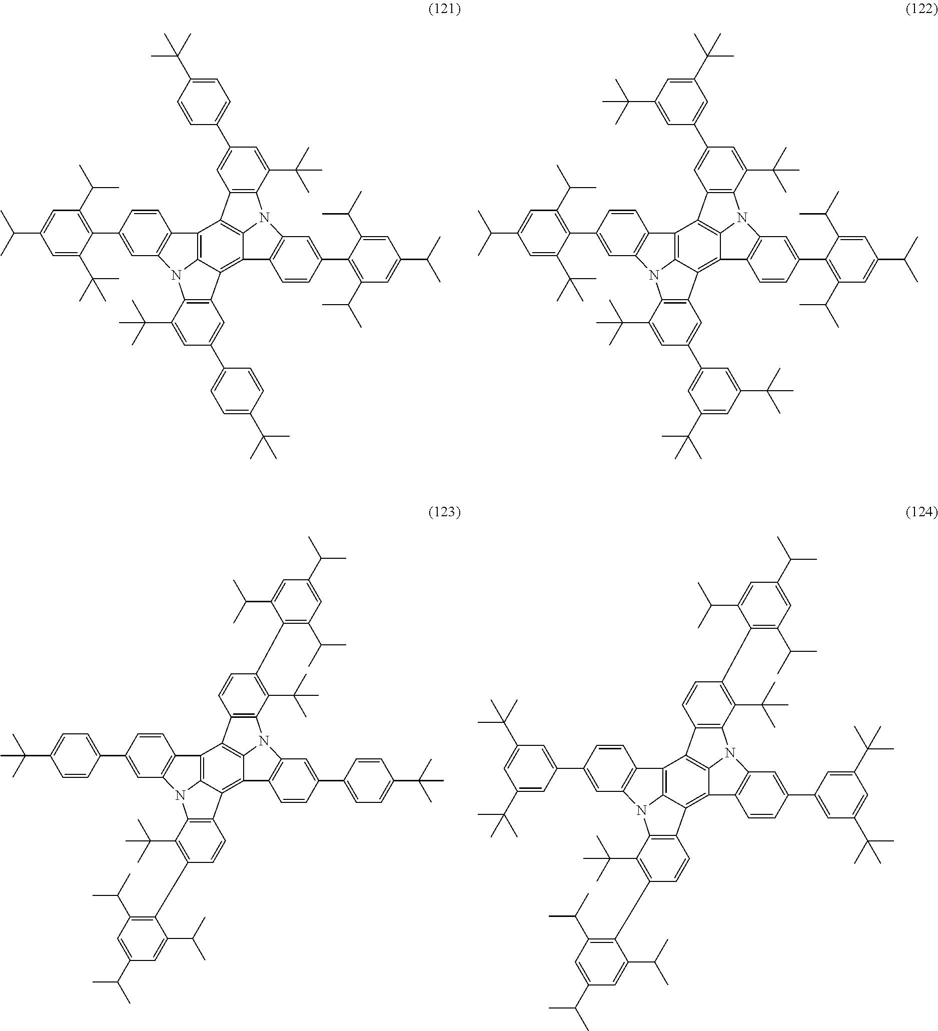

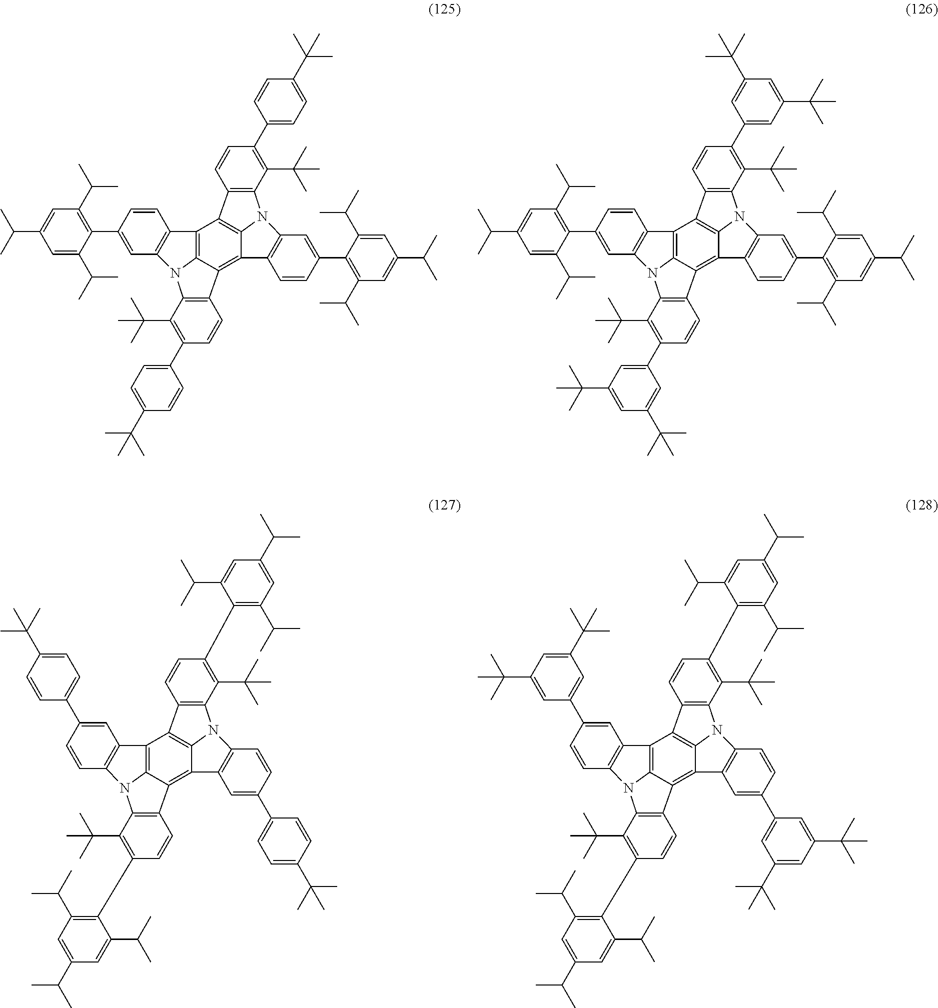

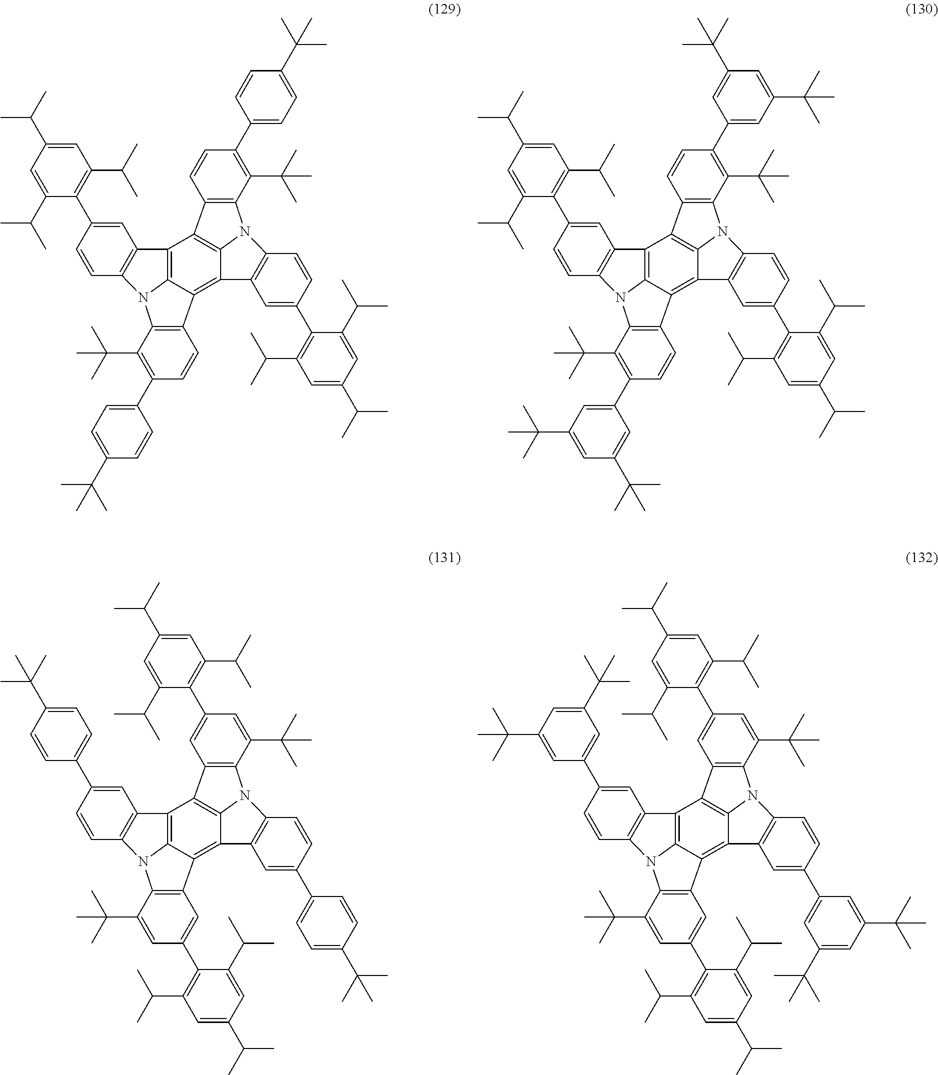

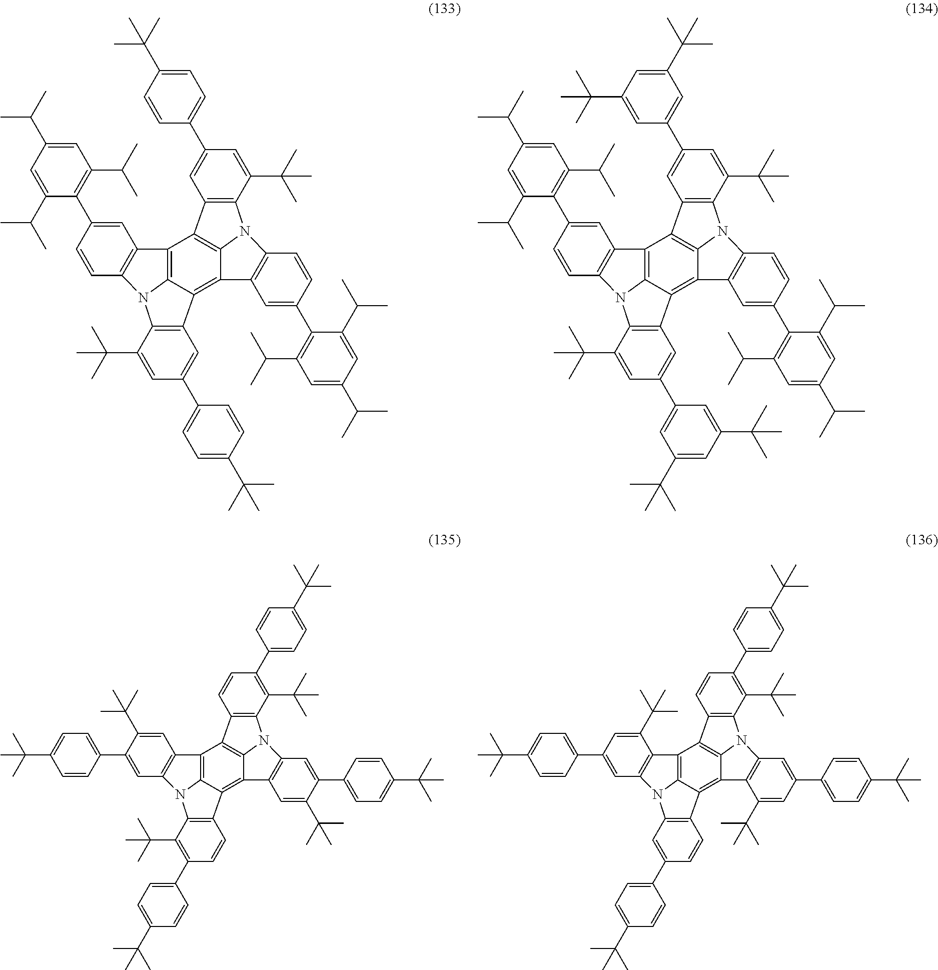

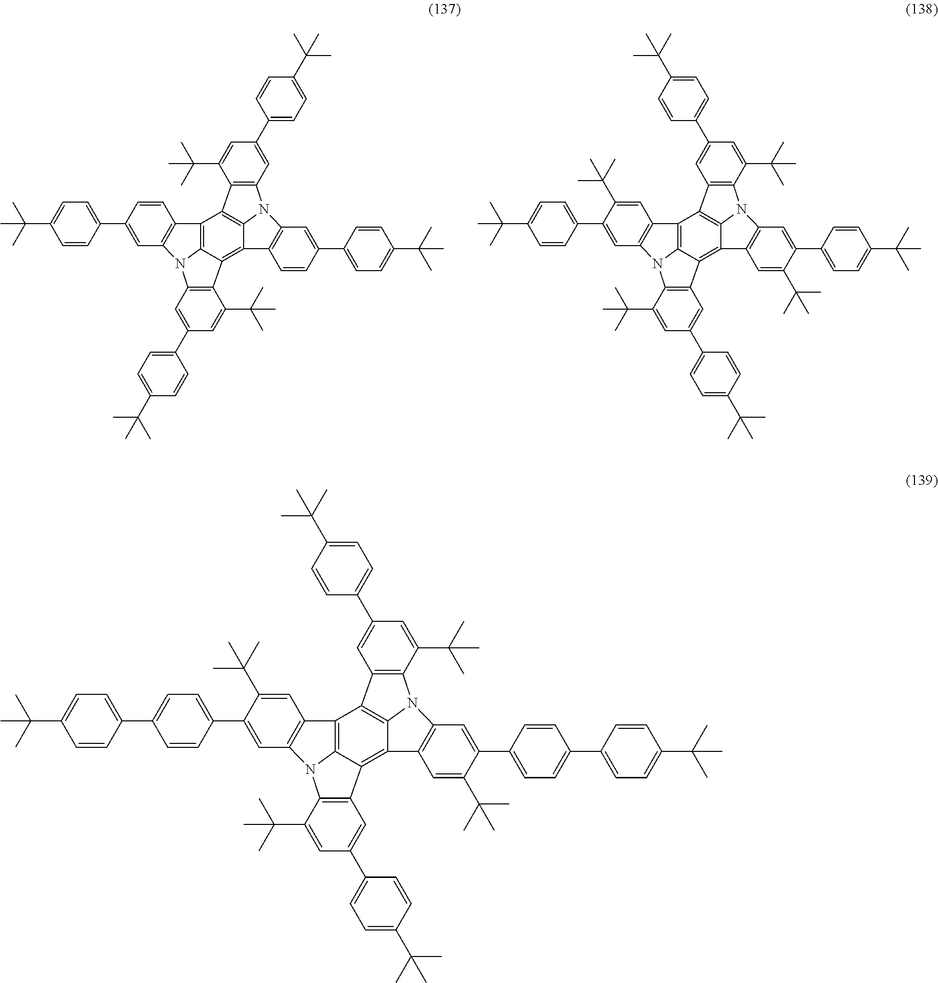

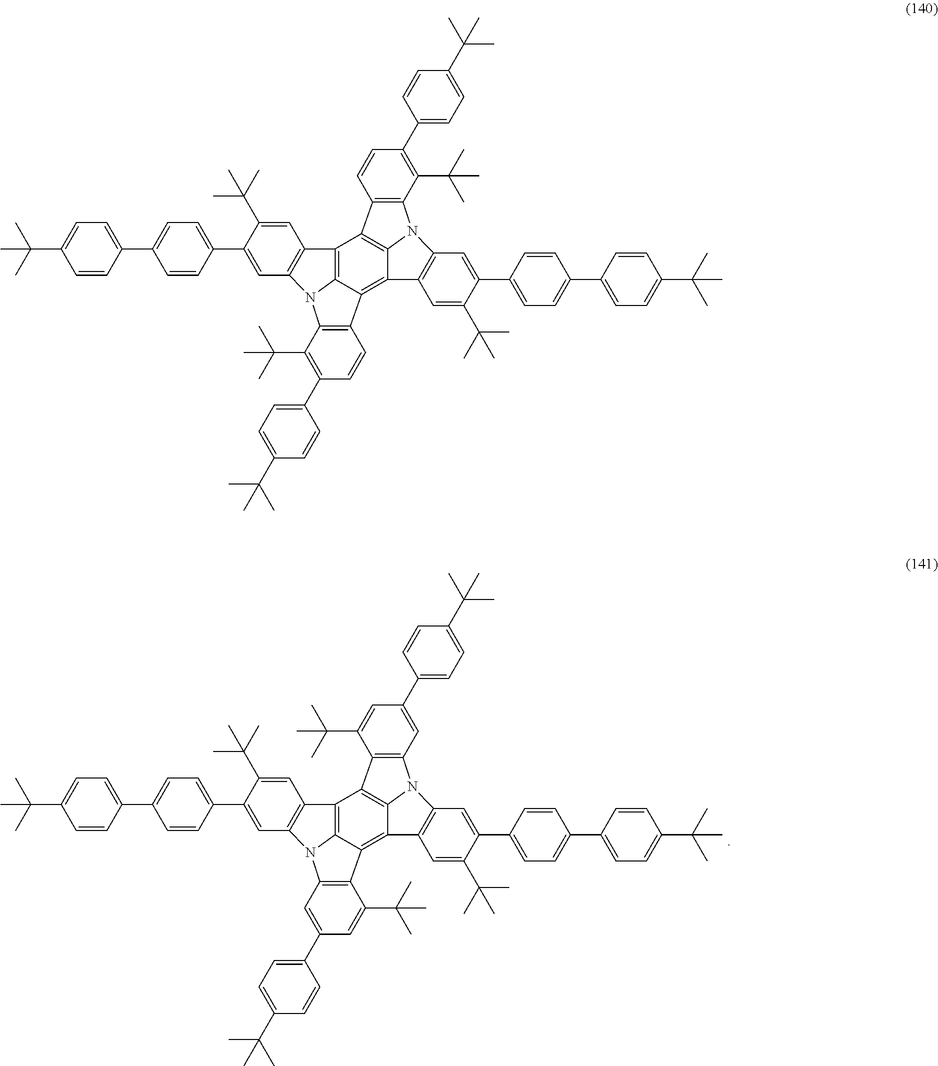

10. The compound of claim 1, wherein a peak wavelength of an emission spectrum of the compound is in a range of about 400 nm to about 500 nm.

11. An organic electroluminescence device comprising an emission layer that includes the compound of claim 1.

12. The organic electroluminescence device of claim 11, wherein the emission layer further includes a phosphorescent complex.

13. The organic luminescence device of claim 12, wherein the phosphorescent complex is a platinum complex.

14. The organic luminescence device of claim 12, wherein the phosphorescent complex is one of Compounds P1 to P120:

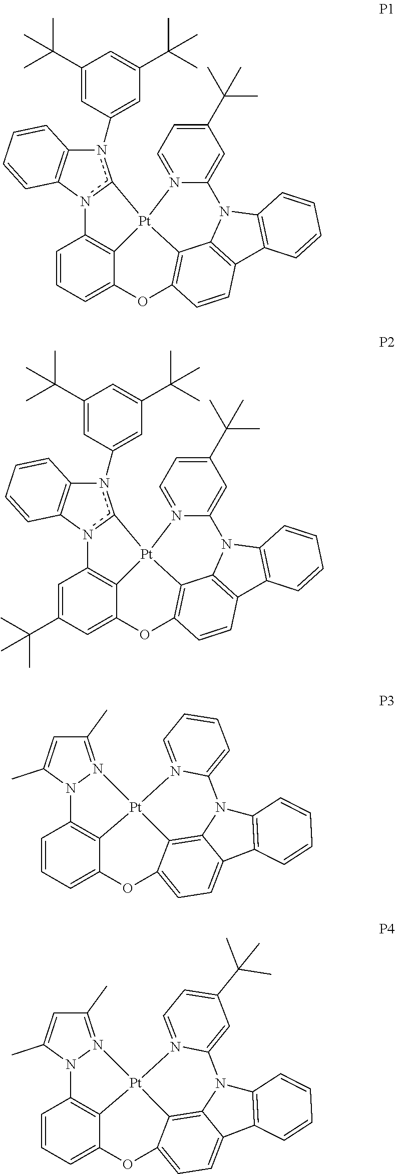

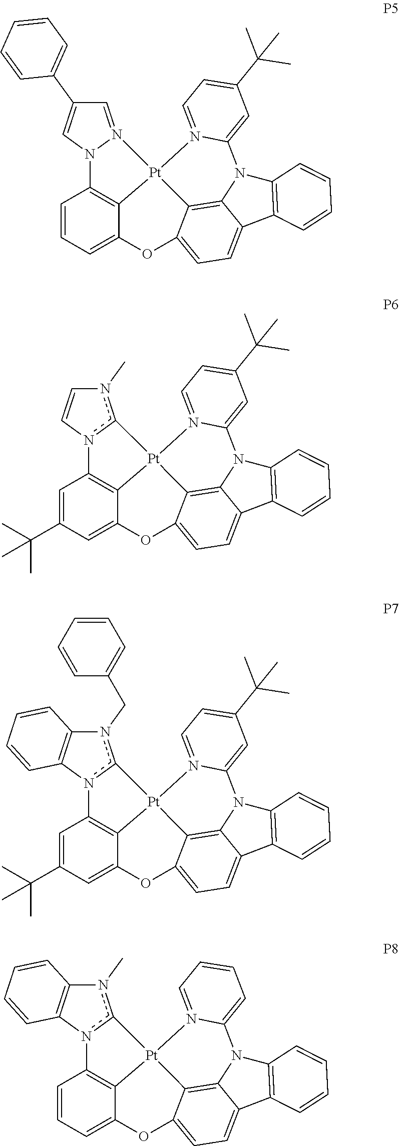

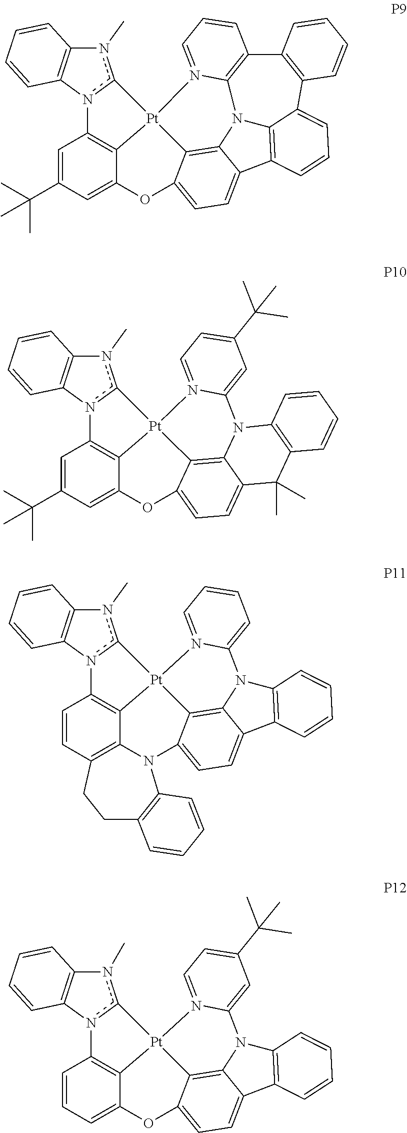

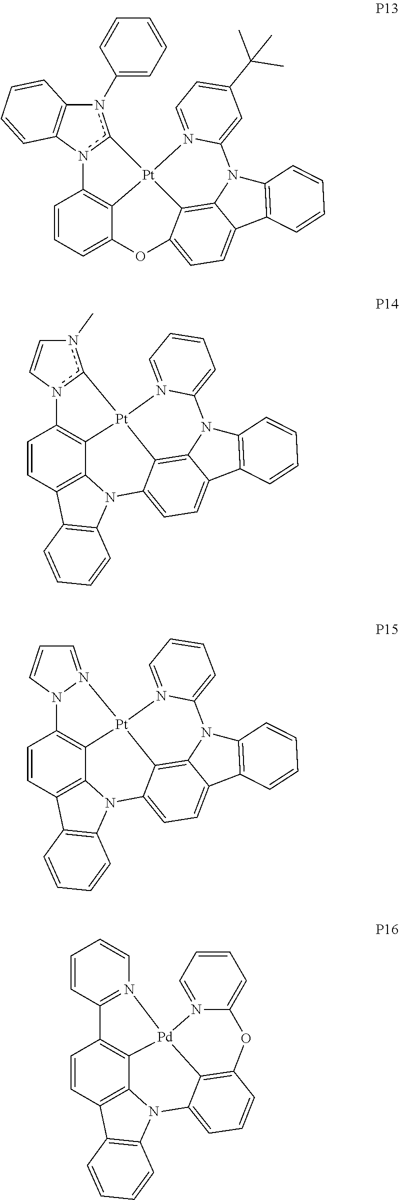

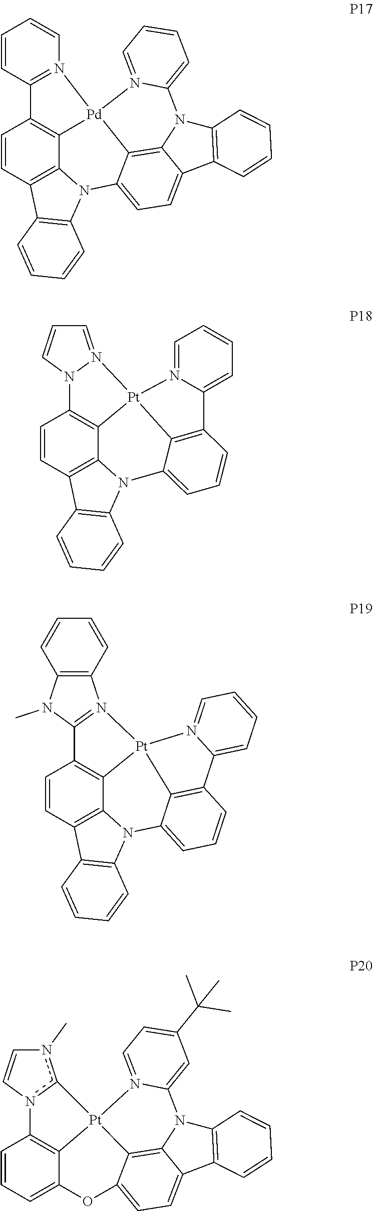

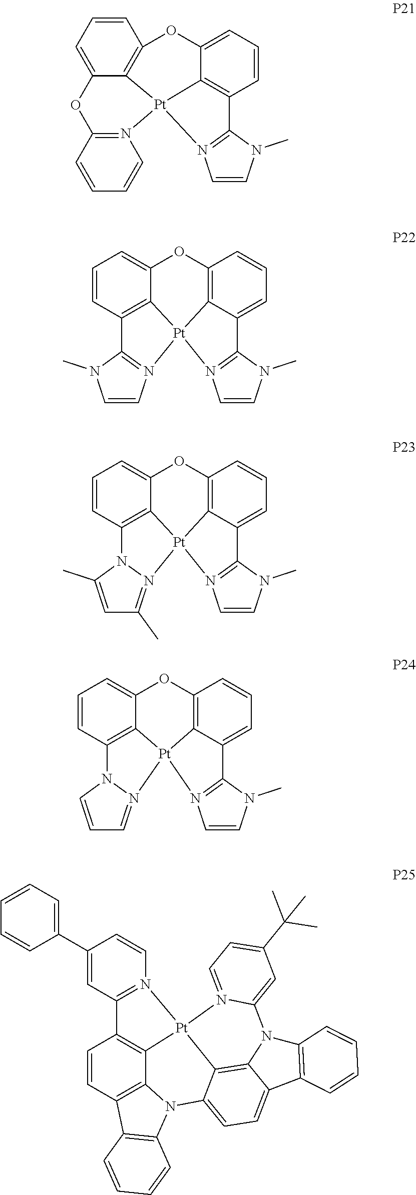

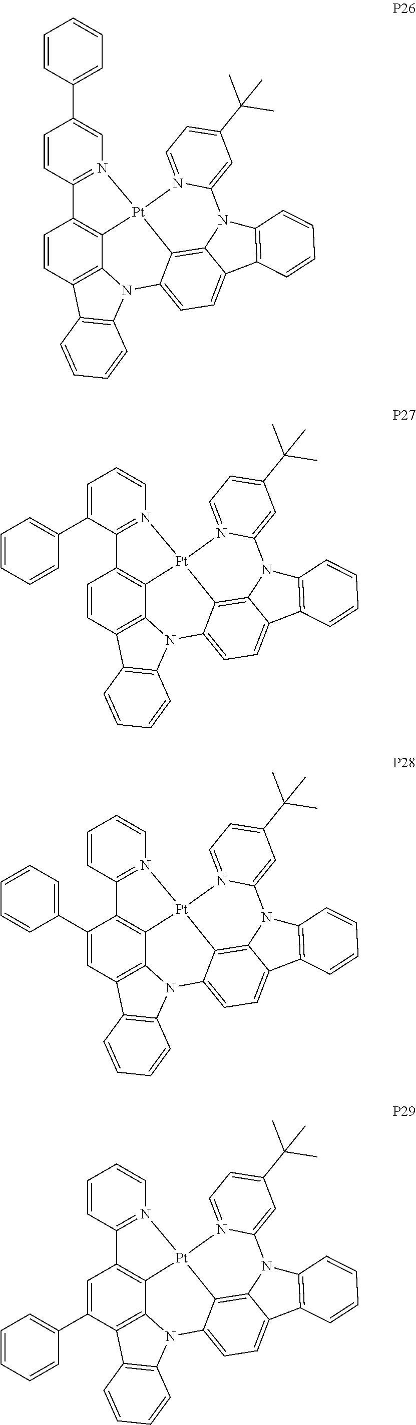

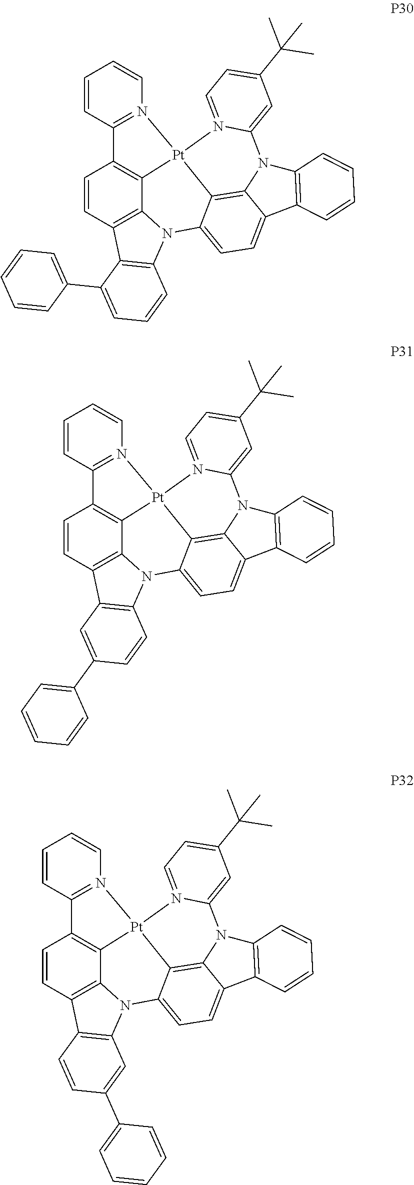

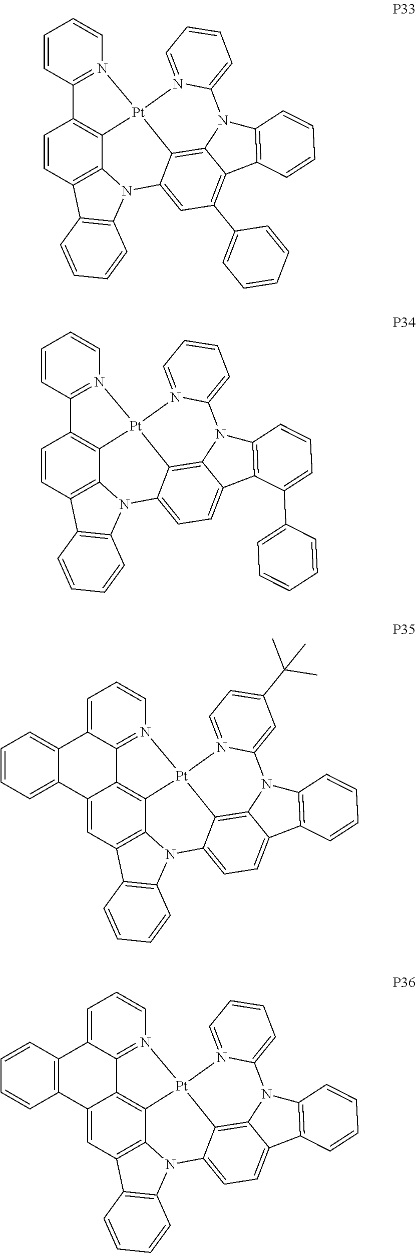

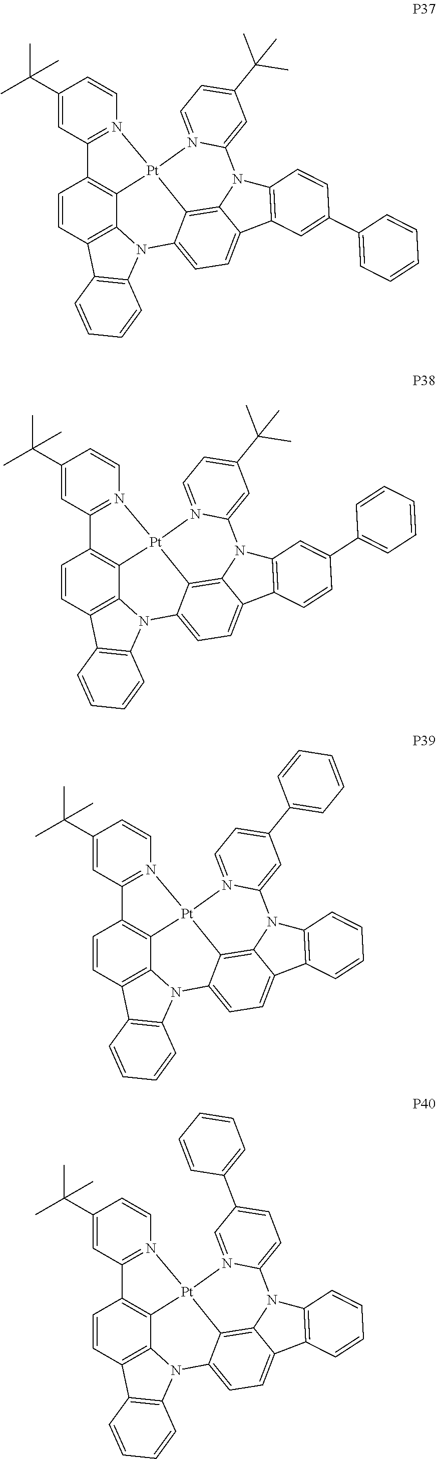

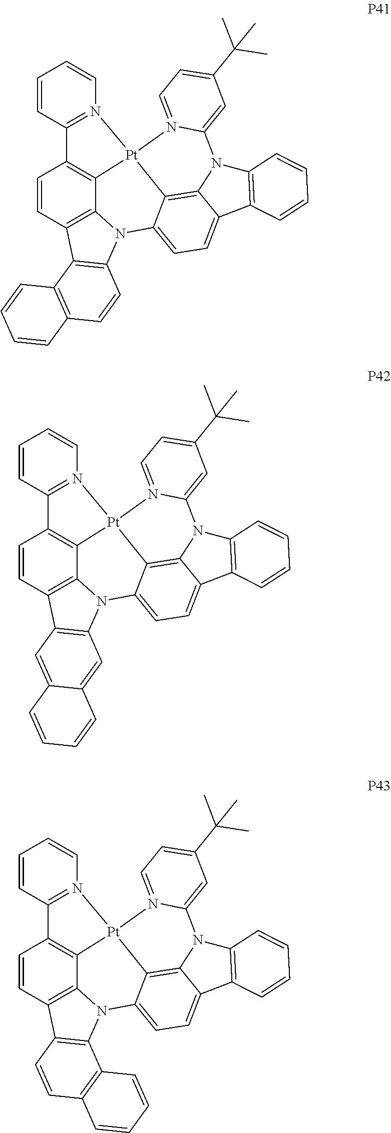

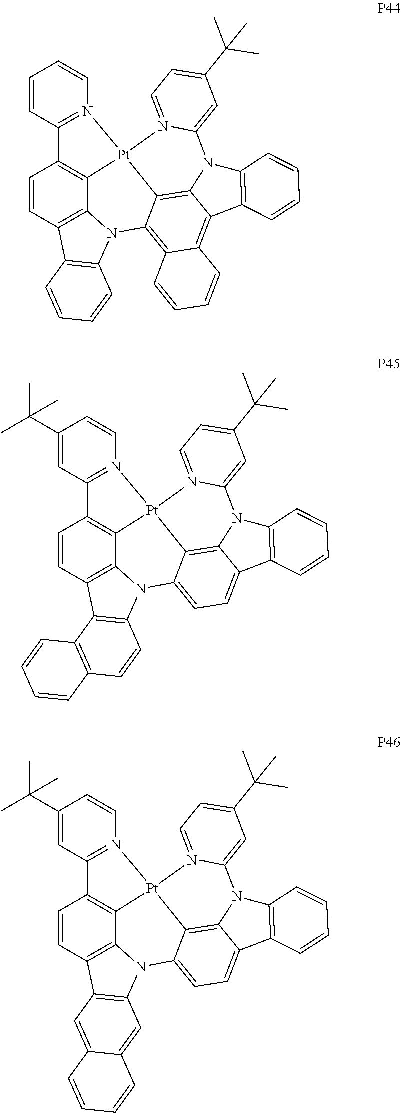

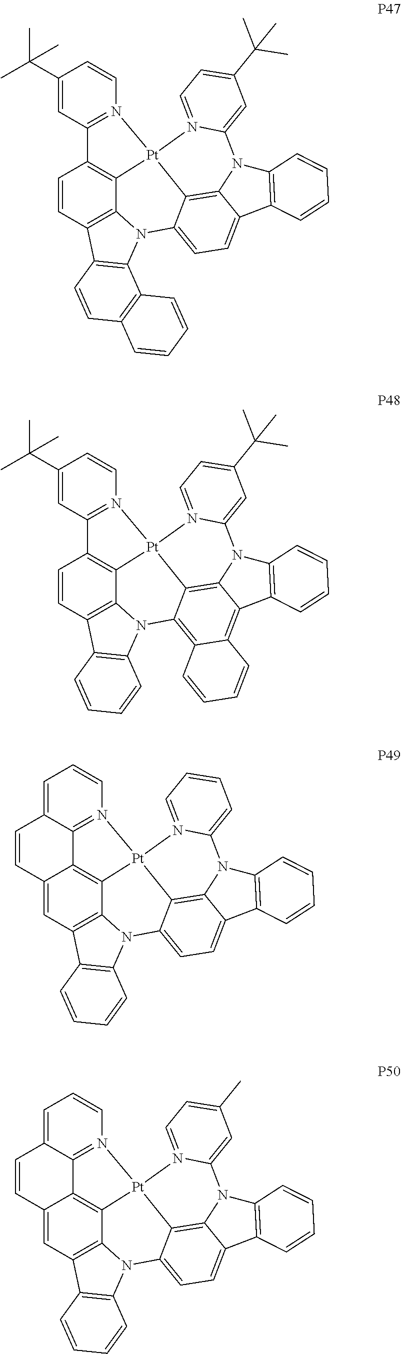

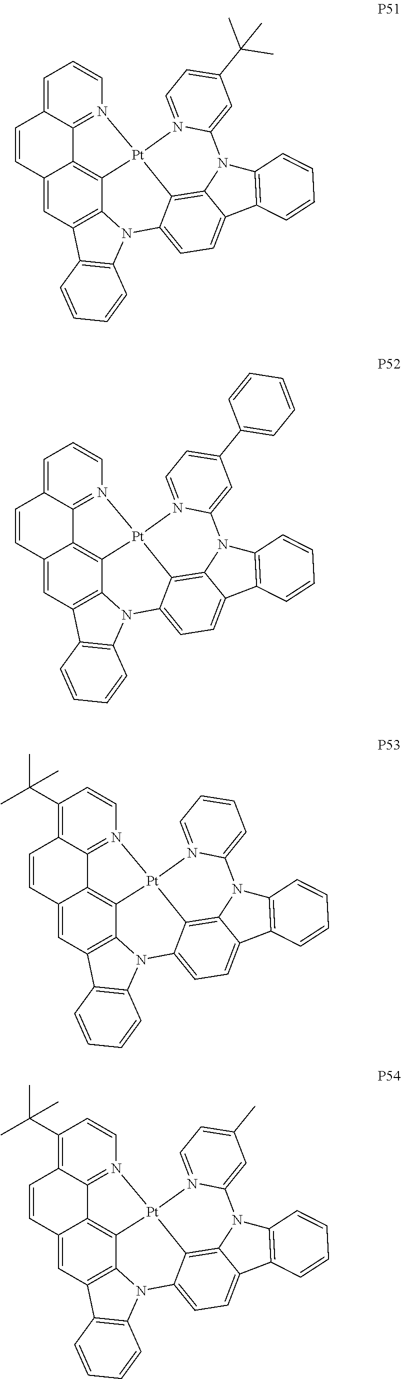

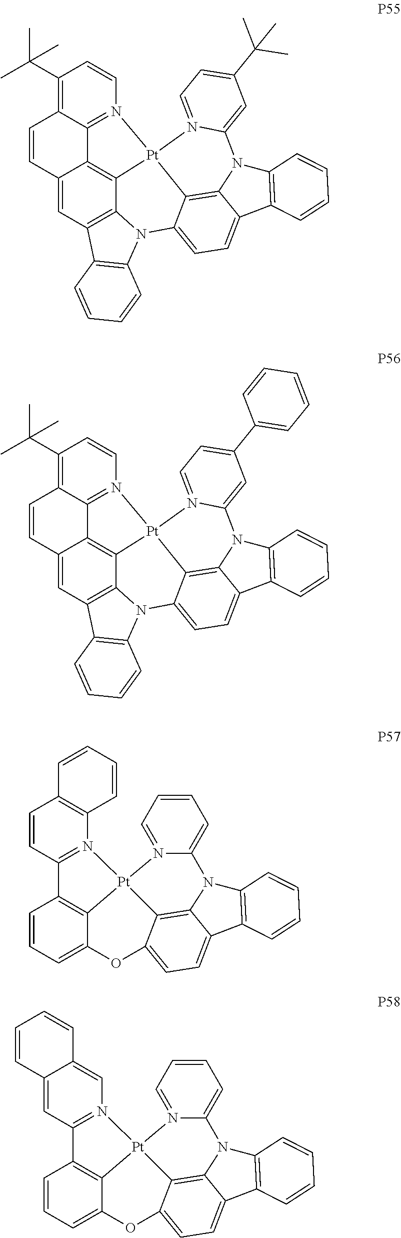

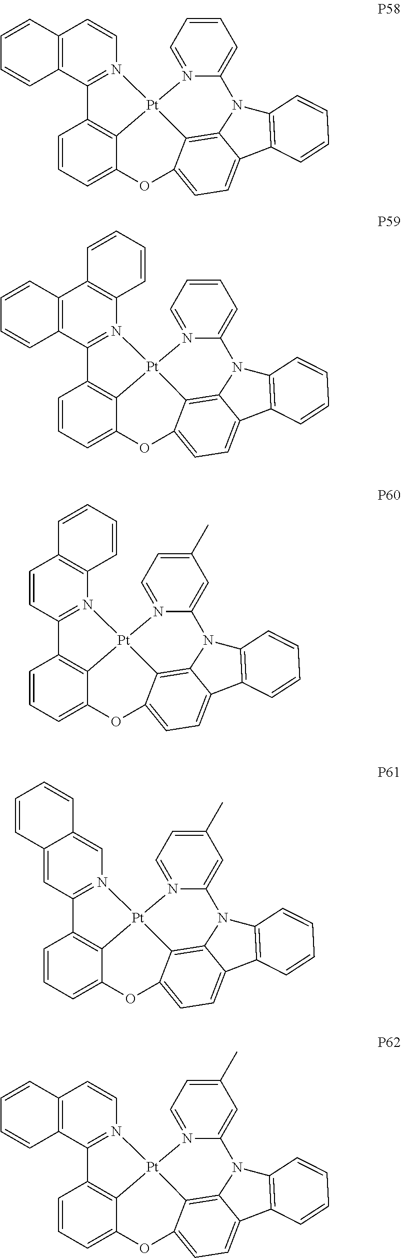

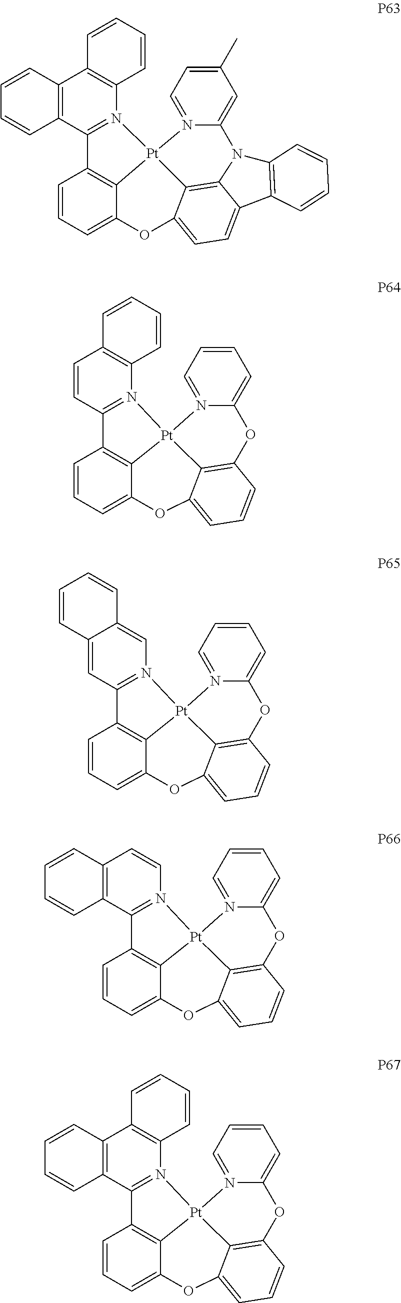

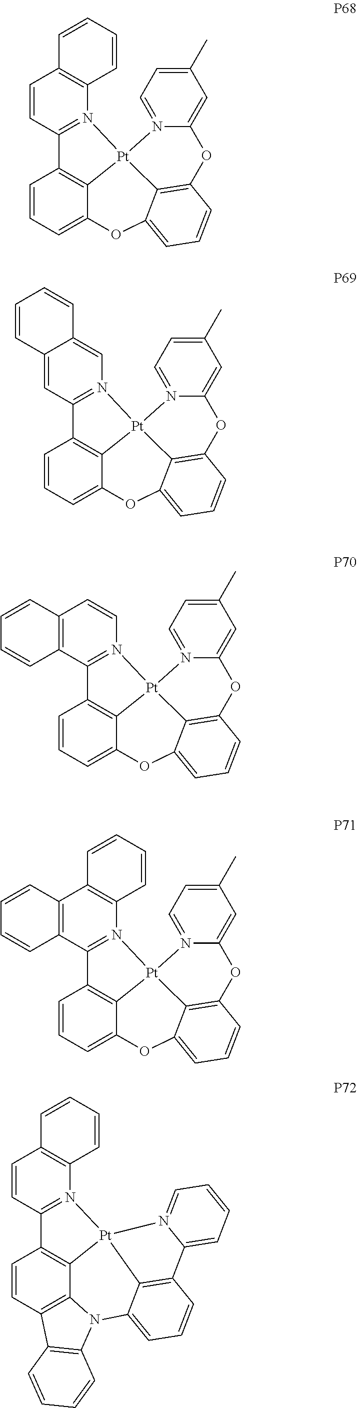

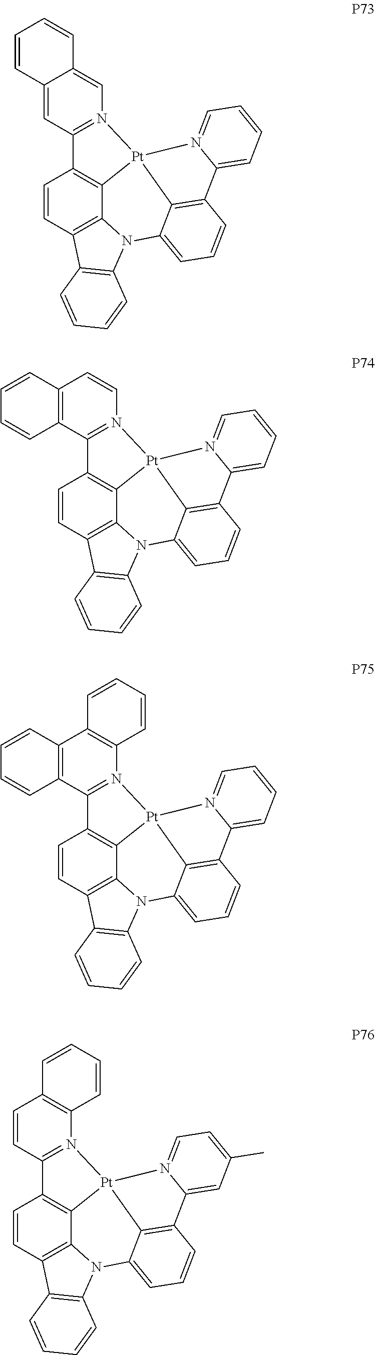

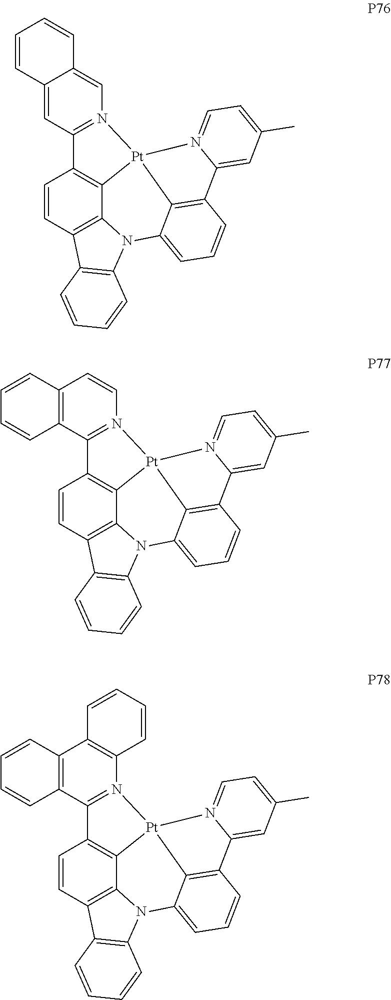

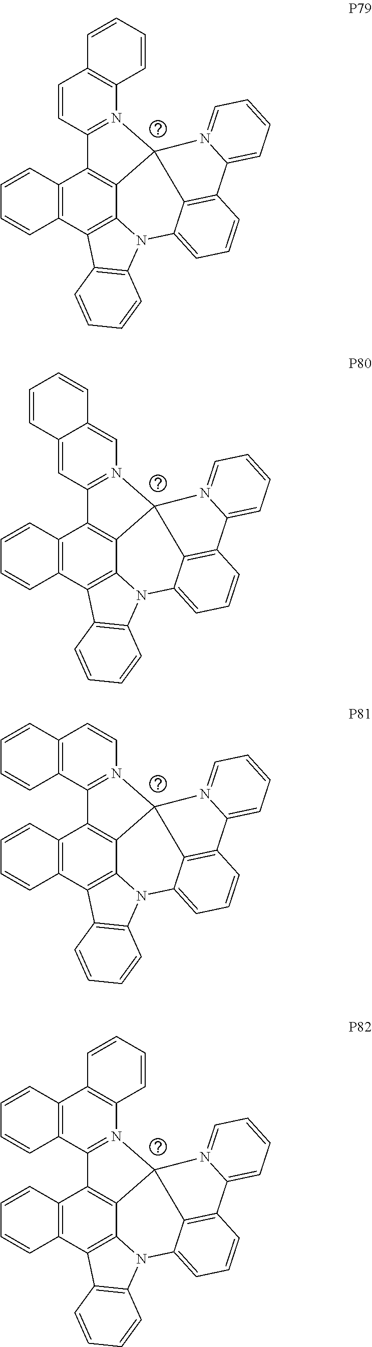

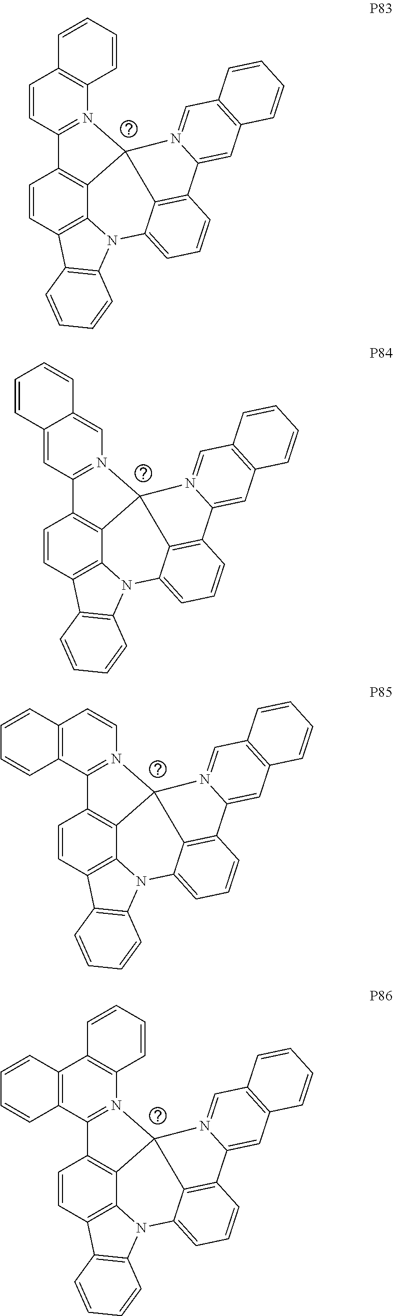

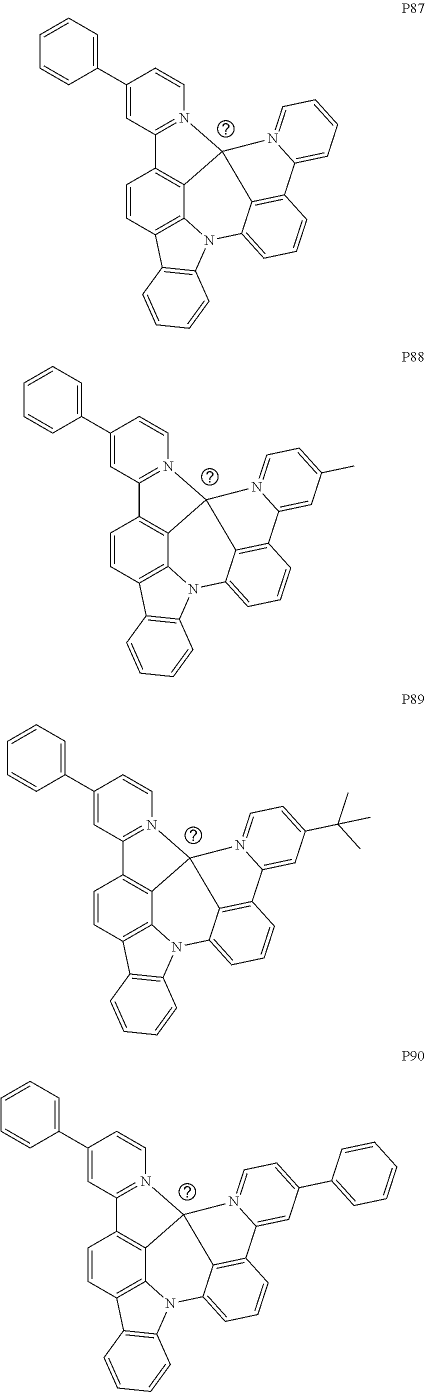

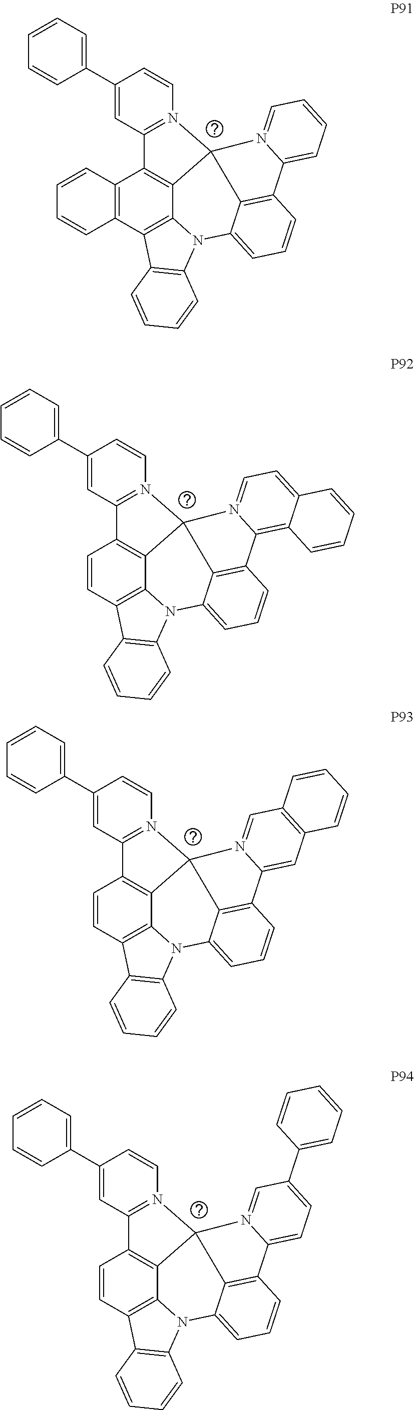

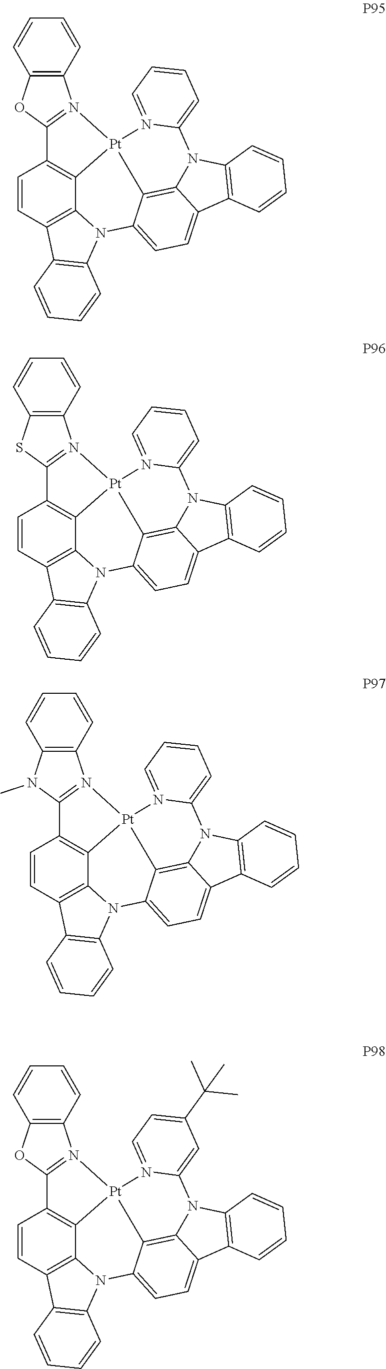

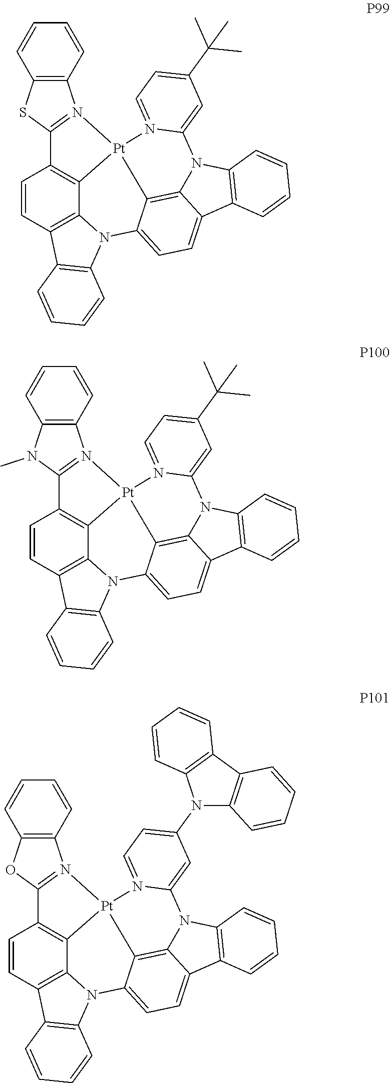

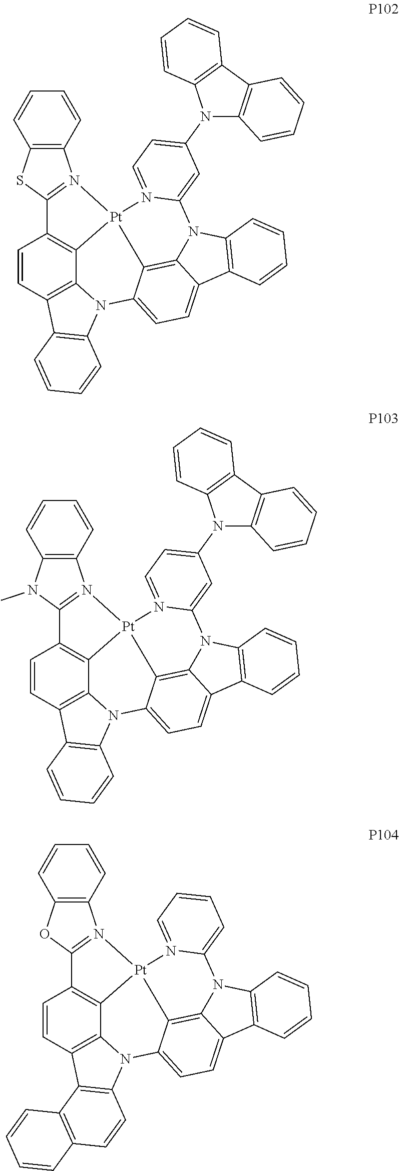

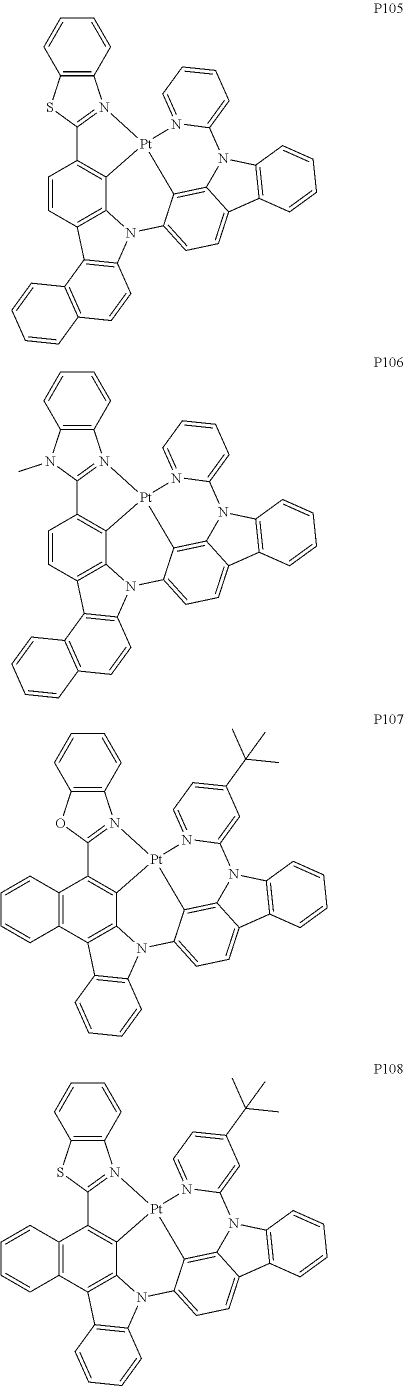

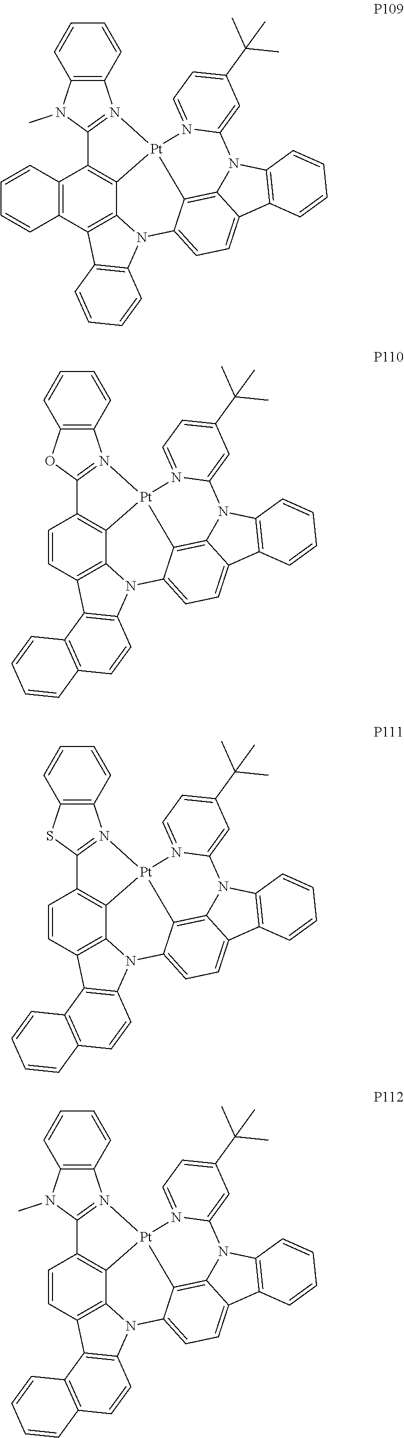

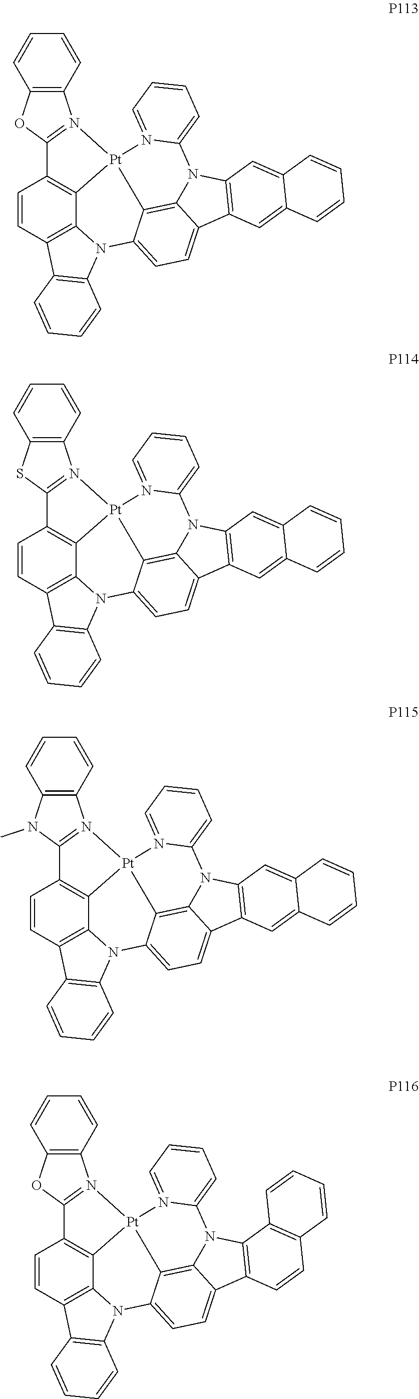

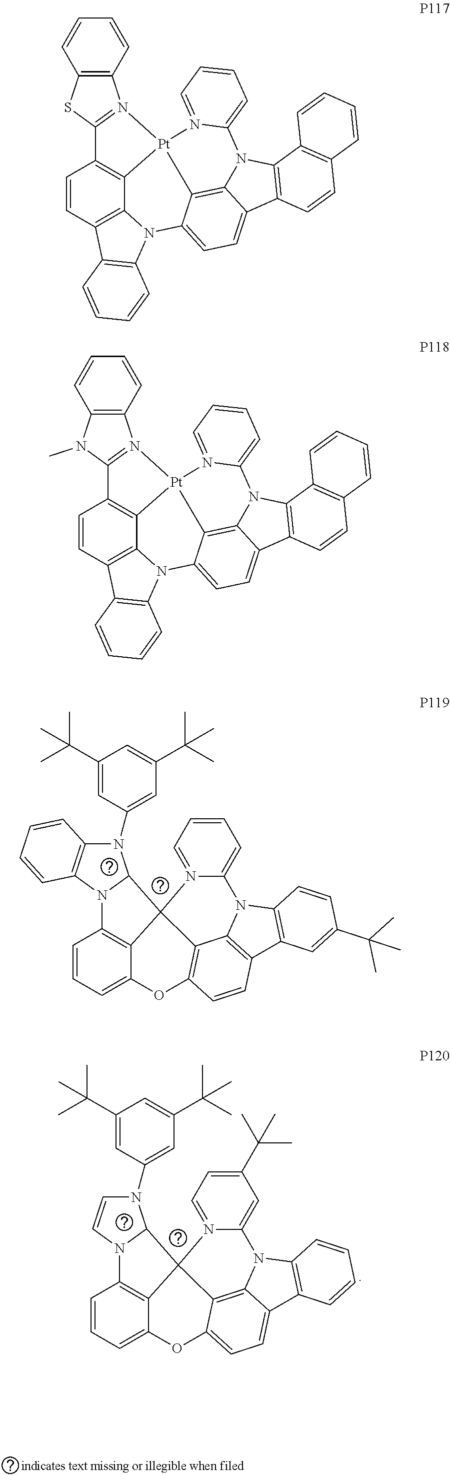

15. The organic electroluminescence device of claim 11, wherein the emission layer further includes a carbazole group-containing compound as a host material.

16. The organic electroluminescence device of claim 13, wherein the emission layer further includes a carbazole group-containing compound as a host material.

17. The organic electroluminescence device of claim 15, wherein the carbazole group-containing compound is a compound represented by Formula (6): 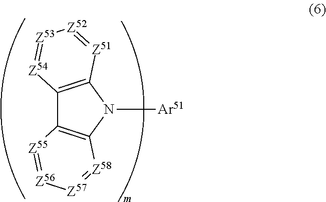
wherein, in Formula (6),
Z⁵¹ is CH, CR⁵¹, or N,
Z⁵² is CH, CR⁵², or N,
Z⁵³ is CH, CR⁵³, or N,
Z⁵⁴ is CH, CR⁵⁴, or N,
Z⁵⁵ is CH, CR⁵⁵, or N,
Z⁵⁶ is CH, CR⁵⁶, or N,
Z⁵⁷ is CH, CR⁵⁷, or N, or
Z⁵⁸ is CH, CR⁵⁸, or N,
R⁵¹ to R⁵⁸ are each independently one of the following groups of (6a) to (6h):
(6a) a cyano group (—CN group),
(6b) a substituted or unsubstituted C1-C20 alkyl group,
(6c) a substituted or unsubstituted C1-C20 alkoxy group,
(6d) a substituted or unsubstituted C6-C20 arylamino group,
(6e) a substituted or unsubstituted phosphoryl group (—POH₂ group),
(6f) a substituted or unsubstituted silyl group (—SiH₃ group),
(6g) a substituted or unsubstituted monovalent aromatic hydrocarbon group, and
(6h) a substituted or unsubstituted monovalent heterocyclic group,
Ar⁵¹ is a group including at least one of an aromatic hydrocarbon group or a heterocyclic group,
m is 1, 2, 3, 4, 5, or 6, and
R⁵¹ and R⁵²; R⁵² and R⁵³; R⁵³ and R⁵⁴; R⁵⁵ and R⁵⁶; R⁵⁶ and R⁵⁷; or R⁵⁷ and R⁵⁸ are optionally bonded together to form an aliphatic hydrocarbon ring, an aromatic hydrocarbon ring, or a heterocyclic ring.

18. The organic electroluminescence device of claim 11, wherein the emission layer further includes a compound having a triazine group as a host material.

19. The organic electroluminescence device of claim 11, wherein the emission layer further includes a compound having a triphenylsilyl group as a host material.

20. The organic electroluminescence device of claim 11, wherein the emission layer further includes a compound having an anthracene ring structure as a host material.

21. The organic electroluminescence device of claim 13, wherein the emission layer further includes a host material, the host material being a compound including a triazine group, a triphenylsilyl group, or an anthracene ring structure.
